(19) United States
(12) Patent Application Publication
(10) Pub. No.: US 2014/0042412 A1
(43) Pub. Date: Feb. 13, 2014

(54) COMPOUND FOR ORGANIC OPTOELECTRONIC DEVICE, ORGANIC LIGHT-EMITTING DIODE INCLUDING THE SAME AND DISPLAY DEVICE INCLUDING THE ORGANIC LIGHT-EMITTING DIODE

(71) Applicants: Dong-Wan RYU, Uiwang-si (KR); Sung-Hyun JUNG, Uiwang-si (KR); Dal-Ho HUH, Uiwang-si (KR); Jin-Seok HONG, Uiwang-si (KR); Gi-Wook KANG, Uiwang-si (KR); Mi-Young CHAE, Uiwang-si (KR)

(72) Inventors: Dong-Wan RYU, Uiwang-si (KR); Sung-Hyun JUNG, Uiwang-si (KR); Dal-Ho HUH, Uiwang-si (KR); Jin-Seok HONG, Uiwang-si (KR); Gi-Wook KANG, Uiwang-si (KR); Mi-Young CHAE, Uiwang-si (KR)

(21) Appl. No.: 14/051,737

(22) Filed: Oct. 11, 2013

Related U.S. Application Data
(63) Continuation of application No. PCT/KR2011/007312, filed on Oct. 4, 2011.

(30) Foreign Application Priority Data
Apr. 15, 2011 (KR) 10-2011-0035292

(51) Int. Cl. H01L 51/00

(52) U.S. Cl. CPC H01L 51/0071; H01L 51/0052; H01L 51/0054; H01L 51/0073; H01L 51/0072; H01L 51/0074; H01L 51/0058
USPC 257/40; 544/102; 544/104; 544/37; 544/46; 544/38; 544/347

(57) ABSTRACT

A compound for an organic optoelectronic device is represented by the following Chemical Formula 1:

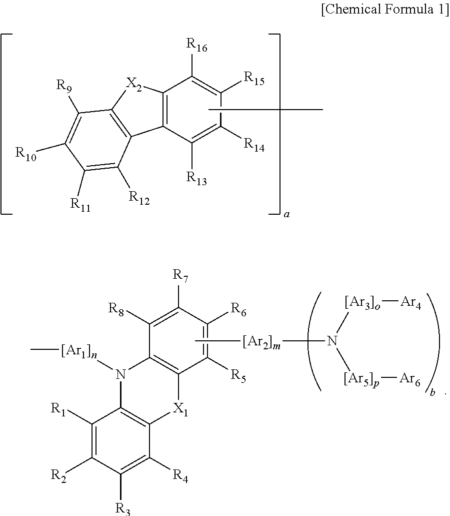

### CROSS-REFERENCE TO RELATED APPLICATION

The present application claims priority under 35 U.S.C. §119 to Korean Patent Application No. 10-2011-0035292, filed on Apr. 15, 2011, in the Korean Intellectual Property Office, and entitled: “Compound for Organic Optoelectronic Device, Organic Light-Emitting Diode Including the Same and Display Device Comprising the Organic Light Emitting Diode,” which is incorporated by reference herein in its entirety.

This application is a continuation of pending International Application No. PCT/KR2011/007312, entitled: “Compound for Organic Optoelectronic Device, Organic Light-Emitting Diode Including the Same and Display Device Comprising the Organic Light Emitting Diode,” which was filed on Oct. 4, 2011, the entire contents of which are hereby incorporated by reference.

### BACKGROUND

1. Field

Embodiments relate to a compound for organic optoelectronic device, an organic light-emitting diode including the same, and a display device including the organic light-emitting diode

2. Description of the Related Art

An organic photoelectric device is a device using a charge exchange between an electrode and an organic material by using holes or electrons.

An organic optoelectronic device may be classified as follows in accordance with its driving principles. A first organic optoelectronic device is an electronic device driven as follows: excitons are generated in an organic material layer by photons from an external light source; the excitons are separated into electrons and holes; and the electrons and holes are transferred to different electrodes as a current source (voltage source).

A second organic optoelectronic device is an electronic device driven as follows: a voltage or a current is applied to at least two electrodes to inject holes and/or electrons into an organic material semiconductor positioned at an interface of the electrodes, and the device is driven by the injected electrons and holes.

### SUMMARY

Embodiments are directed to a compound for an organic optoelectronic device, the compound being represented by the following Chemical Formula 1:

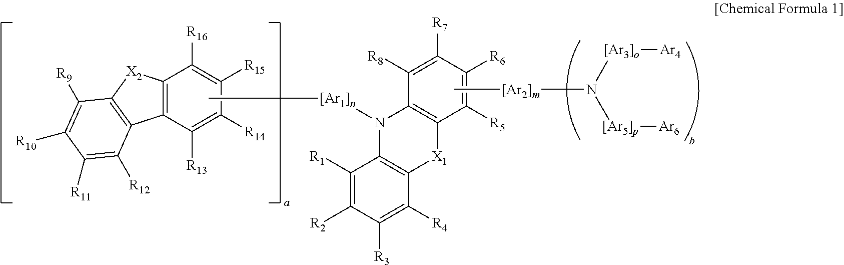

In the above Chemical Formula 1,

R₁ to R₁₆ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 aryithiol group, a substituted or unsubstituted C1 to C20 heterocyclothiol group, a substituted or unsubstituted C1 to C20 ureide group, and a substituted or unsubstituted C3 to C40 silyl group,

one of R₁ to R₈ may link to Ar₂ when Ar₂ is present,

one of R₉ to R₁₆ may link to Ar₁ when Ar₁ is present,

X₁ and X₂ may be the same or different, and may independently be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ may be the same or different, and may independently be a substituted or unsubstituted C6 to C30 arylene group or a substituted or unsubstituted C2 to C30 heteroarylene group,

Ar₄ and Ar₆ may be the same or different, and may independently be a substituted or unsubstituted C6 to C30 aryl group or a substituted or unsubstituted C3 to C30 heteroaryl group,

n, m, o, and p may be the same or different, and may independently be integers ranging from 0 to 4,

a and b may be the same or different, and may independently be integers of 0 or 1, and at least one of a or b may be 1.

The compound may be represented by the following Chemical Formula 2,

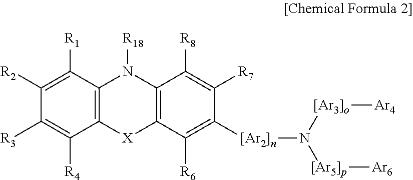

In the above Chemical Formula 2

R₁ to R₅, R₇, R₈, and R₁₈ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X may be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₂ may be a substituted or unsubstituted C6 to C30 arylene group or a substituted or unsubstituted C2 to C30 heteroarylene group,

Ar₃ and Ar₅ may be the same or different, and may independently be a substituted or unsubstituted C6 to C30 arylene group or a substituted or unsubstituted C2 to C30 heteroarylene group,

Ar₄ and Ar₆ may be the same or different, and may independently be a substituted or unsubstituted C6 to C30 aryl group or a substituted or unsubstituted C3 to C30 heteroaryl group, and

n, o, and p may be the same or different, and may independently be integers ranging from 0 to 4.

The compound may be represented by the following Chemical Formula 3,

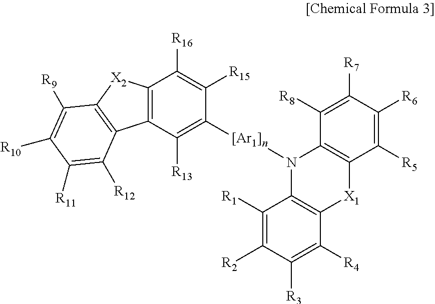

In the above Chemical Formula 3,

R₁ to R₁₃, R₁₅, and R₁₆ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ may be the same or different, and may independently be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₁ may be a substituted or unsubstituted C6 to C30 arylene group or a substituted or unsubstituted C2 to C30 heteroarylene group, and

n may be an integer ranging from 0 to 4.

The compound may be represented by the following Chemical Formula 4,

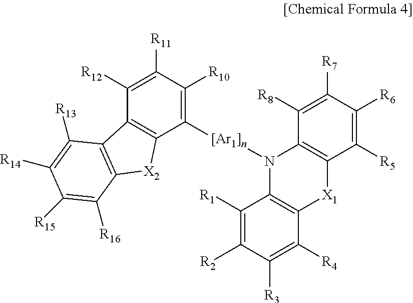

In the above Chemical Formula 4,

R₁ to R₈ and R₁₀ to R₁₆ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ may be the same or different, and may independently be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₁ may be a substituted or unsubstituted C6 to C30 arylene group or a substituted or unsubstituted C2 to C30 heteroarylene group, and

n may be an integer ranging from 0 to 4.

In an example embodiment, the compound may be represented by the following Chemical Formula 5,

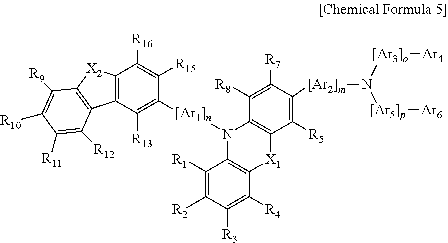

In the above Chemical Formula 5,

R₁ to R₅, R₇ to R₁₃, R₁₅, and R₁₆ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ may be the same or different, and may independently be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ may be the same or different, and may independently be a substituted or unsubstituted C6 to C30 arylene group or a substituted or unsubstituted C2 to C30 heteroarylene group,

Ar₄ and Ar₆ may be the same or different, and may independently be a substituted or unsubstituted C6 to C30 aryl group or a substituted or unsubstituted C3 to C30 heteroaryl group, and

n, m, o, and p may be the same or different, and may independently be integers ranging from 0 to 4.

The compound may be represented by the following Chemical Formula 6,

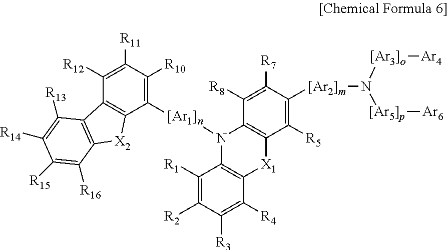

In the above Chemical Formula 6,

R₁ to R₅, R₇, R₈, and R₁₀ to R₁₆ may be the same or different, and may independently be selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ may be the same or different, and may independently be NR₁₇, O, S, SO₂ (O═S═O), or PR₁₇, wherein R₁₇ may be selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ may be the same or different, and may independently be a substituted or unsubstituted C6 to C30 arylene group or a substituted or unsubstituted C2 to C30 heteroarylene group,

Ar₄ and Ar₆ may be the same or different, and may independently be a substituted or unsubstituted C6 to C30 aryl group or a substituted or unsubstituted C3 to C30 heteroaryl group, and

n, m, o, and p may be the same or different, and may independently be integers ranging from 0 to 4.

Embodiments are also directed to an organic light emitting diode including an anode, a cathode, and one or more organic thin layers between the anode and the cathode, wherein at least one of the organic thin layers includes the compound for an organic optoelectronic device.

Embodiments are also directed to a display device including the organic light emitting diode.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views showing organic light emitting diodes according to various embodiments including compound for an organic optoelectronic device according to example embodiments.

FIG. 6 illustrates ¹H-NMR data of the compound A-140 according to Example 1.

FIG. 7 illustrates ¹H-NMR data of the compound A-142 according to Example 2.

FIG. 8 illustrates ¹H-NMR data of the compound A-216 according to Example 3.

FIG. 9 illustrates ¹H-NMR data of the compound A-217 according to Example 4.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

In the present specification, when specific definition is not otherwise provided, the term “substituted” refers to one substituted with deuterium; a C1 to C30 alkyl group; a C1 to C10 alkylsilyl group; a C3 to C30 cycloalkyl group; a C6 to C30 aryl group; a C1 to C10 alkoxy group; a fluoro group, a C1 to C10 trifluoroalkyl group such as trifluoromethyl group and the like; or a cyano group, instead of hydrogen of a compound.

In the present specification, when specific definition is not otherwise provided, the team “hetero” refers to one including 1 to 3 hetero atoms selected from N, O, S, and P, and remaining carbons in one compound or substituent.

In the present specification, when a definition is not otherwise provided, the term “combination thereof” refers to at least two substituents bound to each other by a linker, or at least two substituents condensed to each other.

In the specification, when a definition is not otherwise provided, “alkyl group” may refer to “a saturated group” without any alkene group or alkyne group; or “an unsaturated alkyl group” with at least one alkene group or alkyne group. The “alkene group” may refer to a substituent of at least one carbon-carbon double bond of at least two carbons, and the “alkyne group” may refer to a substituent of at least one carbon-carbon triple bond of at least two carbons. The alkyl group may be branched, linear, or cyclic.

The alkyl group may be a C1 to C20 alkyl group, and specifically a C1 to C6 lower alkyl group, a C7 to C10 medium-sized alkyl group, or a C11 to C20 higher alkyl group.

For example, a C1 to C4 alkyl group may have 1 to 4 carbon atoms and may be selected from methyl, ethyl, propyl, iso-propyl, n-butyl, iso-butyl, sec-butyl, and t-butyl.

Typical examples of alkyl group may be a methyl group, an ethyl group, a propyl group, an isopropyl group, a butyl group, an isobutyl group, a t-butyl group, a pentyl group, a hexyl group, an ethenyl group, a propenyl group, a butenyl group, a cyclopropyl group, a cyclobutyl group, a cyclopentyl group, a cyclohexyl group, and the like.

“Aromatic group” may refer to a substituent including all element of the cycle having p-orbitals which form conjugation. Examples may include aryl group and a heteroaryl group.

“Aryl group” may refer to a monocyclic or fused ring polycyclic (i.e., rings sharing adjacent pairs of carbon atoms) substituent.

“Heteroaryl group” may refer to aryl group including 1 to 3 hetero atoms selected from N, O, S, and P, and remaining carbons in one functional group. The aryl group may be a fused ring where each ring may include the 1 to 3 heteroatoms.

“Spiro structure” may refer to a plurality of cyclic structures having a contact point of one carbon. The spiro structure may include a compound having a spiro structure or a substituent having a spiro structure.

In the present specification, an organic optoelectronic device may include an organic compound and a device to convert light into electricity and/or a device to convert electricity into light.

According to an example embodiment, a compound for an organic optoelectronic device includes a core including a fused ring including a plurality of hetero atoms, and a carbazole derivative and/or a substituted amine group selectively bonded thereto.

In the present specification, a carbazolyl group derivative refers to a substituent where nitrogen of a carbazolyl group is substituted with NR′, O, S, SO₂ (O═S═O), or PR′.

Herein, the R′ is a substituted or unsubstituted C1 to C20 alkyl group, a substituted or unsubstituted C6 to C30 aryl group, a substituted or unsubstituted C2 to C30 heteroaryl group, and the like.

The core may have excellent hole characteristics due to a carbazolyl group or carbazolyl group derivative having excellent hole characteristics; and/or a substituted amine group. In addition, it may be used as a host of an emission layer by combining with an appropriate dopant.

The hole characteristics refer to characteristics that hole formed in the anode is easily injected into the emission layer and transported in the emission layer due to conductive characteristics according to HOMO level.

The electron characteristics refer to characteristics that electron formed in the cathode is easily injected into the emission layer and transported in the emission layer due to conductive characteristics according to LUMO level.

The compound for an organic optoelectronic device includes a core part and various substituents for substituting the core part and thus may have various energy bandgaps. The compound may be used in a hole injection layer (HIL) and a transport layer, or emission layer.

The compound may have an appropriate energy level depending on the substituents and, thus, may fortify hole characteristics of an organic photoelectric device and bring about excellent effects on efficiency and driving voltage and also, have excellent electrochemical and thermal stability and, thus, improve life-span characteristics during the operation of the organic photoelectric device.

According to an example embodiment, a compound for an organic optoelectronic device is represented by the following Chemical Formula 1.

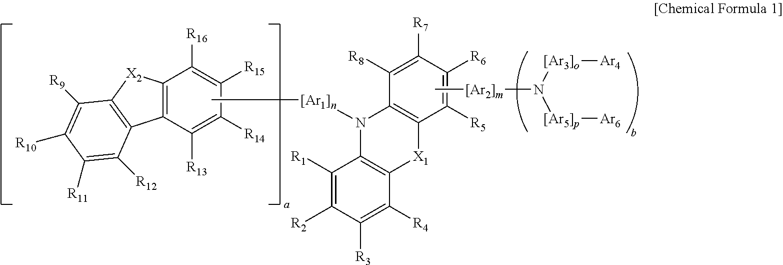

In the present example embodiment, in the above Chemical Formula 1,

R₁ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

one of R₁ to R₈ links to Ar₂ when Ar₂ is present,

one of R₉ to R₁₆ links to Ar₁ when Ar₁ is present,

X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ are the same or different, and are independently substituted or unsubstituted C6 to C30 arylene group, or a substituted or unsubstituted C2 to C30 heteroarylene group,

Ar₄ and Ar₆ are the same or different, and are independently a substituted or unsubstituted C6 to C30 aryl group or a substituted or unsubstituted C3 to C30 heteroaryl group,

n, m, o, and p are the same or different, and are independently integers ranging from 0 to 4, and

a and b are the same or different, and are independently integers of 0 or 1, and at least one of a or b is 1.

In an implementation, linking groups may be, e.g., a single bond, a substituted or unsubstituted C2 to C6 alkenylene group, a substituted or unsubstituted C2 to C6 alkynylene group, a substituted or unsubstituted C6 to C30 arylene group, or a substituted or unsubstituted C2 to C30 heteroarylene group.

In an implementation, n, m, and o are the same or different, and are independently integers of 1 to 4.

The Ar1 to Ar3 and Ar5 may increase a triplet energy bandgap by controlling the total π-conjugation length of compound, so as to be very usefully applied to the emission layer of organic photoelectric device as a phosphorescent host.

As described above, hole characteristics and bi-polar characteristics of the compound may be improved due to the carbazolyl group or carbazolyl group-based derivative depending on the X¹ or X².

In the present example embodiment, the Ar⁴ and Ar⁶ are the same or different, and are independently a substituted or unsubstituted C6 to C30 aryl group or a substituted or unsubstituted C2 to C30 heteroaryl group.

Specific examples of the Ar⁴ and/or Ar⁶ may be selected from a phenyl group, a naphthyl group, an anthracenyl group, a phenanthryl group, a naphthacenyl group, a pyrenyl group, a biphenylyl group, a p-terphenyl group, a m-terphenyl group, a chrysenyl group, triphenylenyl group, a perylenyl group, an indenyl group, a furanyl group, a thiophenyl group, a pyrrolyl group, a pyrazolyl group, an imidazolyl group, a triazolyl group, an oxazolyl group, a thiazolyl group, an oxadiazolyl group, a thiadiazolyl group, a pyridyl group, a pyrimidinyl group, a pyrazinyl group, a triazinyl group, a benzofuranyl group, a benzothiophenyl group, a benzimidazolyl group, an indolyl group, a quinolinyl group, an isoquinolinyl group, a quinazolinyl group, a quinoxalinyl group, naphthyridinyl group, a benzoxazinyl group, a benzthiazinyl group, an acridinyl group, a phenazinyl group, a phenothiazinyl group, and a phenoxazinyl group.

The triphenylenyl group of the substituents may provide a bulky structure and cause a resonance effect and, thus, may suppress a side reaction possibly occurring in a solid state and improve performance of an organic light emitting diode.

In addition, the triphenylenyl group makes the compound bulky and, thus, may have an effect on lowering crystallinity and increasing life-span.

The triphenylenyl group has a wider band gap and high triplet excitation energy relative to some other substituents and, thus, may be bonded with carbazole with little or no decrease in the band gap or triplet excitation energy of the compound.

In addition, an appropriate combination of the substituents may provide a compound having excellent thermal stability or resistance against oxidation. An appropriate combination of the substituents may provide a compound having asymmetric bipolar characteristic. The asymmetric bipolar characteristics may improve hole and electron transport capability and, thus, luminous efficiency and performance of a device.

In addition, the R₁ to R₁₆ may be adjusted to make the structure of a compound bulky and, thus, decrease crystallinity of the compound. Accordingly, the compound may have low crystallinity and may improve life-span of a device.

The compound for an organic optoelectronic device may be represented by the following Chemical Formula 2.

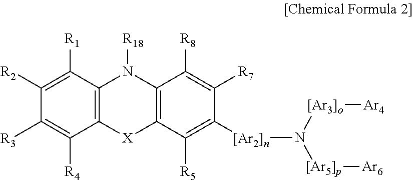

In the present example embodiment, in the above Chemical Formula 2,

R₁ to R₅, R₇, R₈, and R₁₈ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X is NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₂ is a substituted or unsubstituted C6 to C30 arylene group, or a substituted or unsubstituted C2 to C30 heteroarylene group,

Ar₄ and Ar₆ are the same or different, and are independently a substituted or unsubstituted C6 to C30 aryl group or a substituted or unsubstituted C3 to C30 heteroaryl group, and

n, o, and p are the same or different, and are independently integers ranging from 0 to 4.

The structure of the above Chemical Formula 2 is a structure selectively excluding the carbazole derivative structure in the structure of the above Chemical Formula 1. The substituents may be excluded depending on appropriate hole characteristics desired in an organic photoelectric device.

The structure of the above Chemical Formula 2 may have relatively improved solubility and excellent thermal stability, and excellent thin film stability due to an asymmetric structure.

The other substituents are the same as in the above-described Chemical Formula 1 and descriptions thereof are not repeated.

The compound for an organic optoelectronic device may be represented by the following Chemical Formula 3.

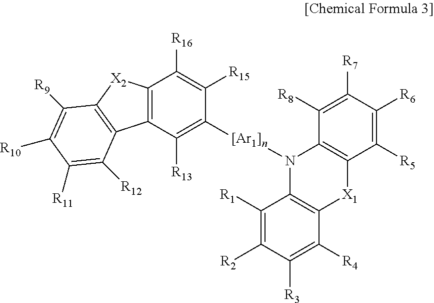

In the present example embodiment, in the above Chemical Formula 3,

R₁ to R₁₃, R₁₅, and R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₁ is a substituted or unsubstituted C6 to C30 arylene group or a substituted or unsubstituted C2 to C30 heteroarylene group, and

n is an integer ranging from 0 to 4.

The compound for an organic optoelectronic device may be represented by the following Chemical Formula 4.

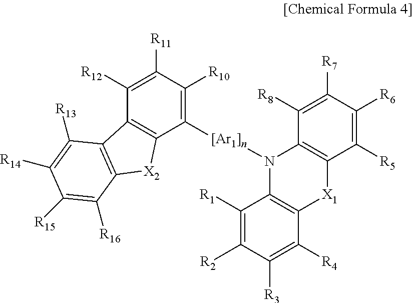

In the present example embodiment, in the above Chemical Formula 4,

R₁ to R₈ and R₁₀ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ are the same or different, and are independently NR₁₇, O, S, SO₂ (O═S═O) or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₁ is a substituted or unsubstituted C6 to C30 arylene group or a substituted or unsubstituted C2 to C30 heteroarylene group, and

n is an integer ranging from 0 to 4.

The structure of the above Chemical Formula 3 or 4 is a structure selectively excluding the substituted amine group in the structure of the above Chemical Formula 1. The structure of Chemical Formula 3 or 4 may provide a compound having hole characteristics within appropriate ranges by including the carbazole-based derivative having hole characteristics and excluding the substituted amine group having excellent hole characteristics.

The structure of the above Chemical Formula 3 or 4 may have relatively improved solubility and excellent thermal stability, and excellent thin film stability due to an asymmetric structure.

The other substituents are the same as in the above-described Chemical Formula 1 and descriptions thereof are not repeated.

The compound for an organic optoelectronic device may be represented by the following Chemical Formula 5.

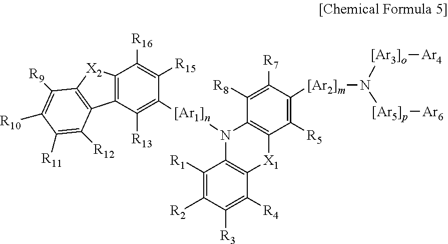

In the present example embodiment, in the above Chemical Formula 5,

R₁ to R₅, R₇ to R₁₃, R₁₅ and R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ are the same or different, and are independently a substituted or unsubstituted C6 to C30 arylene group or a substituted or unsubstituted C2 to C30 heteroarylene group,

Ar₄ and Ar₆ are the same or different, and are independently a substituted or unsubstituted C6 to C30 aryl group or a substituted or unsubstituted C3 to C30 heteroaryl group, and

n, m, o, and p are the same or different, and are independently integers ranging from 0 to 4.

The compound for an organic optoelectronic device may be represented by the following Chemical Formula 6.

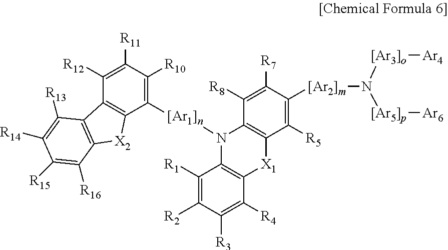

In the present example embodiment, in the above Chemical Formula 6,

R₁ to R₅, R₇, R₉, and R₁₀ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 aryloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,

X₁ and X₂ are the same or different, and are independently NR₁₇, O, S, SO₂ (O═S═O) or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,

Ar₁, Ar₂, Ar₃, and Ar₅ are the same or different, and are independently a substituted or unsubstituted C6 to C30 arylene group or a substituted or unsubstituted C2 to C30 heteroarylene group,

Ar₄ and Ar₆ are the same or different, and are independently a substituted or unsubstituted C6 to C30 aryl group or a substituted or unsubstituted C3 to C30 heteroaryl group, and

n, m, o, and p are the same or different, and are independently integers ranging from 0 to 4.

The structure of the above Chemical Formula 5 and/or 6 is a structure selectively including both the carbazole derivative and substituted amine group in the structure of the above Chemical Formula 1.

The structure may have relatively improved solubility and excellent thermal stability, and excellent thin film stability due to an asymmetric structure.

The compound for an organic optoelectronic device may be represented by, e.g., one of the following Chemical Formulae A-1 to A-21 and A-23 to A-290.

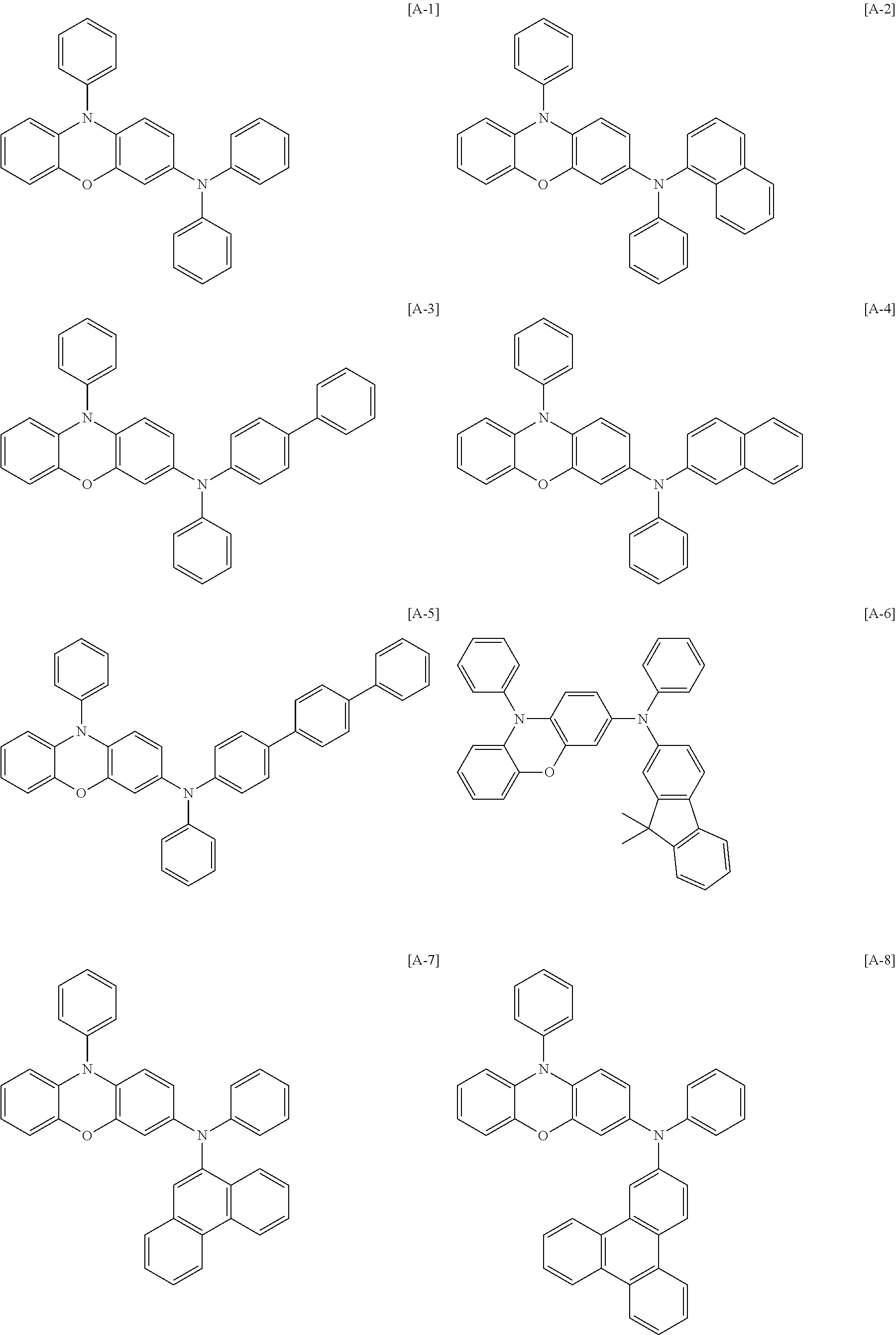

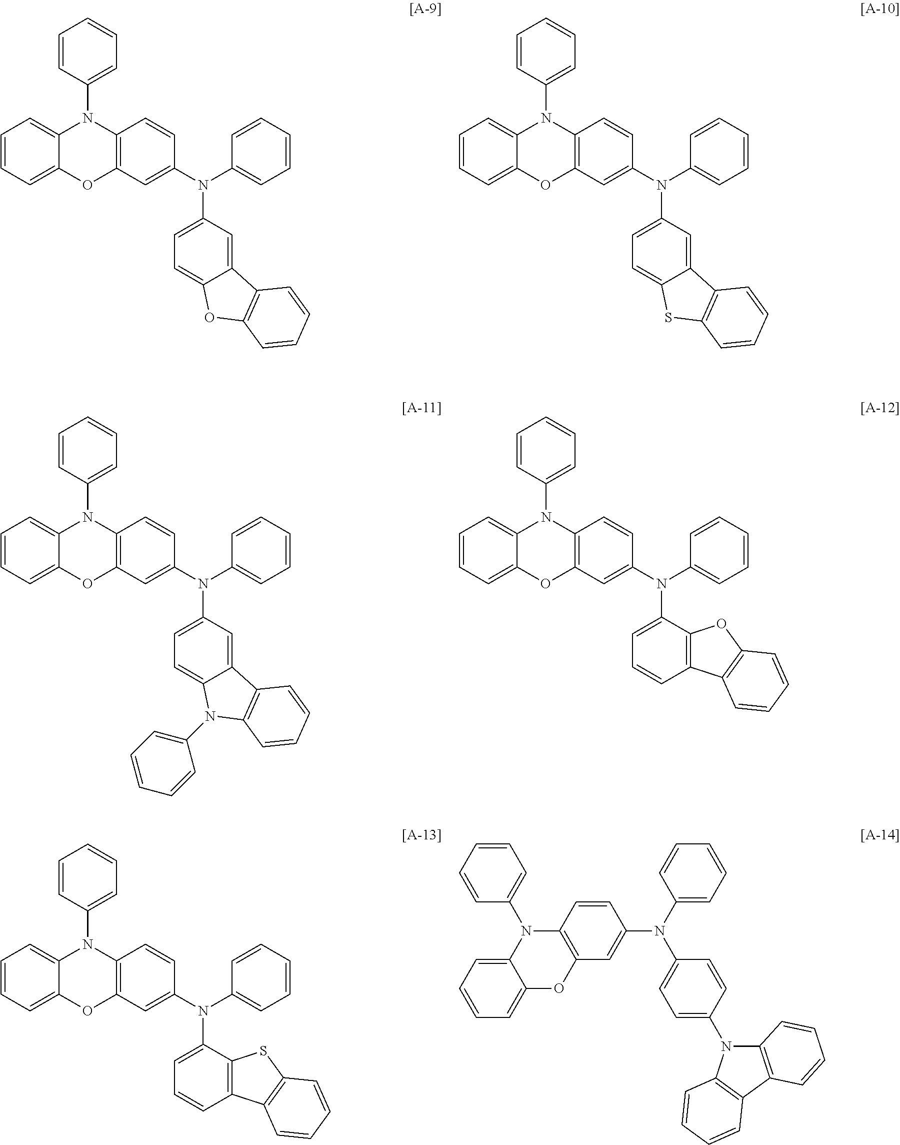 [SMILES: c1ccc(N(c2ccc3c(c2)Oc2ccccc2N3c2ccccc2)c2ccc3oc4ccccc4c3c2)cc1 ; c1ccc(N(c2ccc3c(c2)Oc2ccccc2N3c2ccccc2)c2ccc3sc4ccccc4c3c2)cc1 ; c1ccc(N(c2ccc3c(c2)Oc2ccccc2N3c2ccccc2)c2ccc3c(c2)c2ccccc2n3-c2ccccc2)cc1 ; c1ccc(N2c3ccccc3Oc3cc(N(c4ccccc4)c4cccc5c4oc4ccccc45)ccc32)cc1 ; c1ccc(N2c3ccccc3Oc3cc(N(c4ccccc4)c4cccc5c4sc4ccccc45)ccc32)cc1 ; c1ccc(N(c2ccc(-n3c4ccccc4c4ccccc43)cc2)c2ccc3c(c2)Oc2ccccc2N3c2ccccc2)cc1]

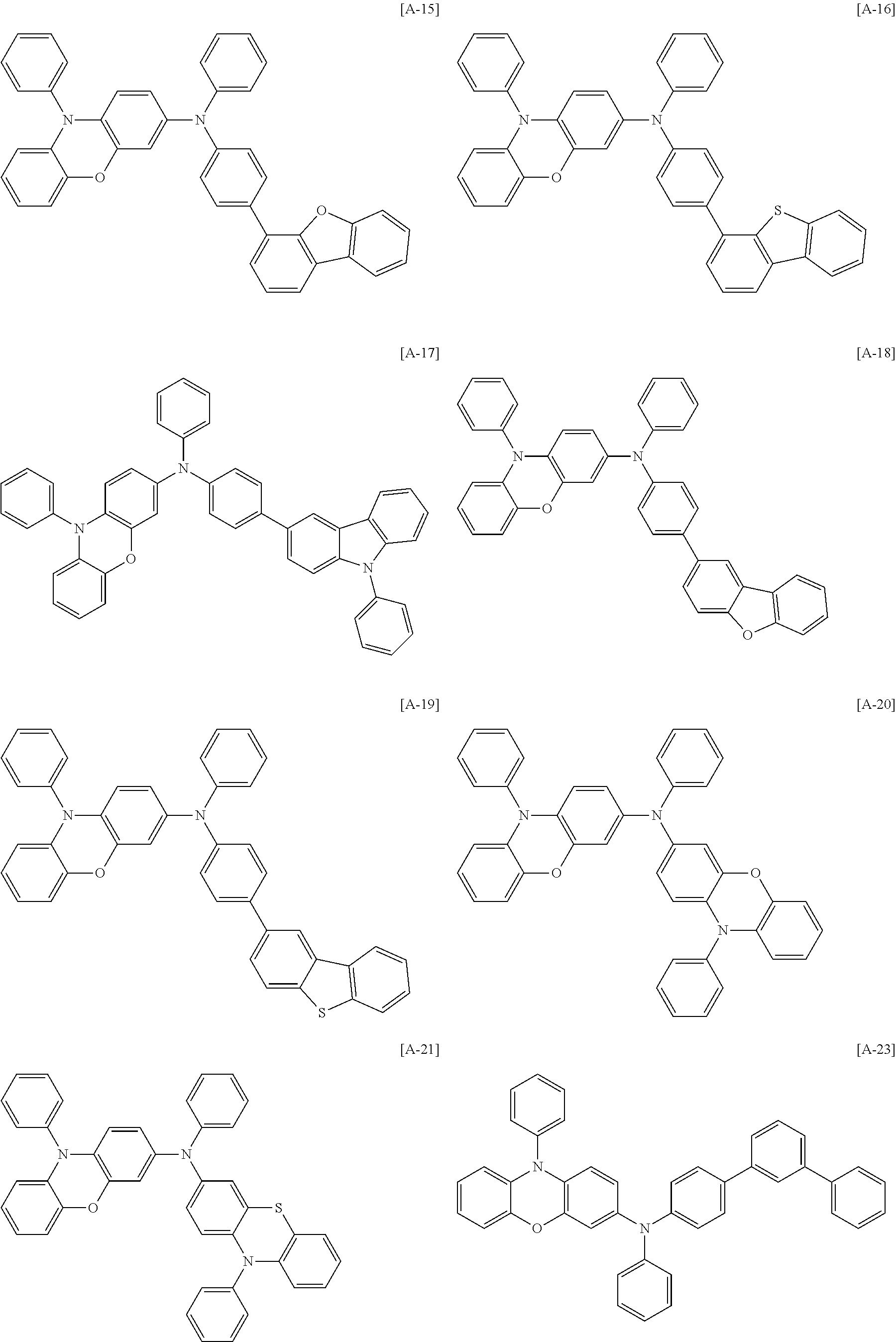

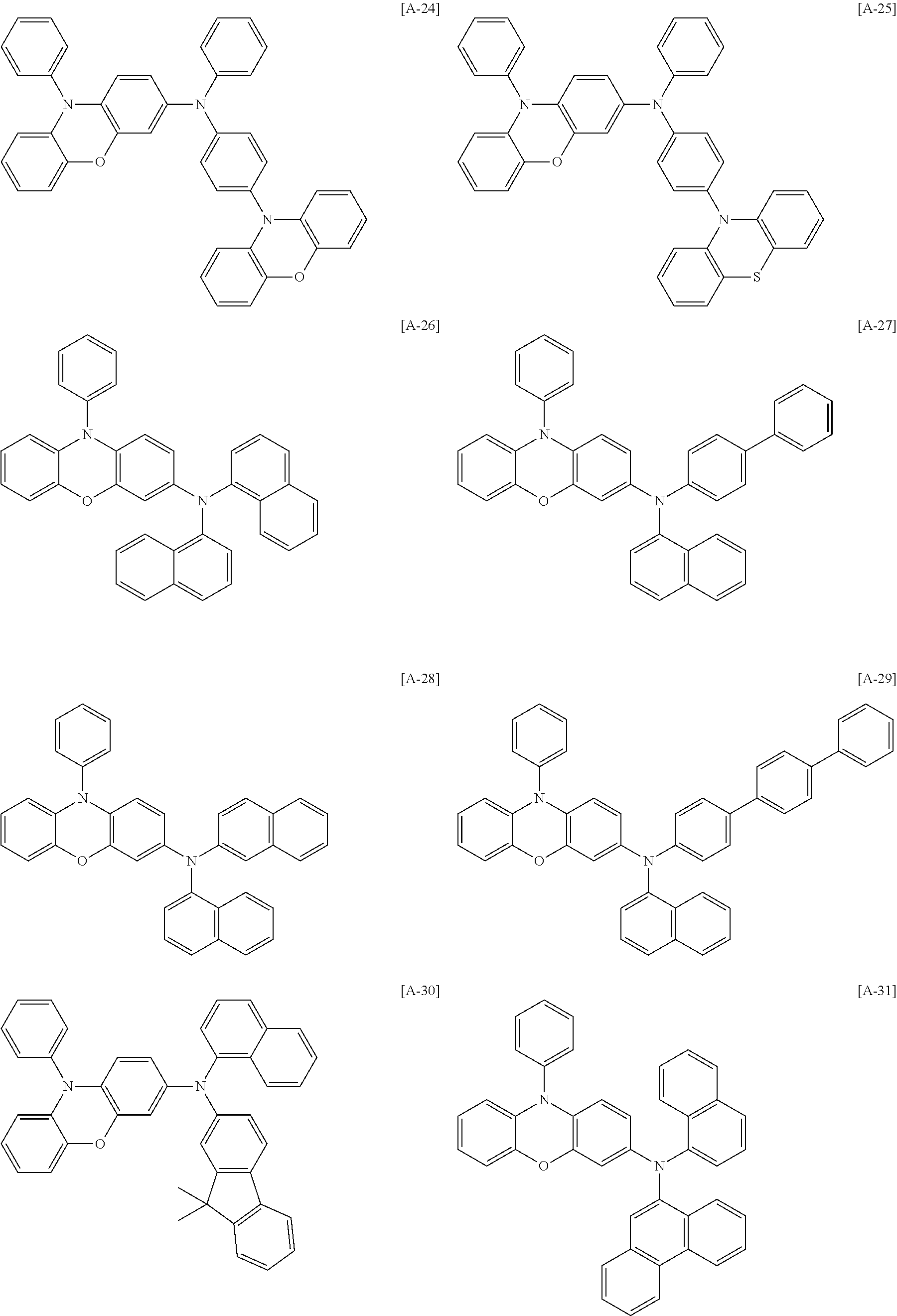

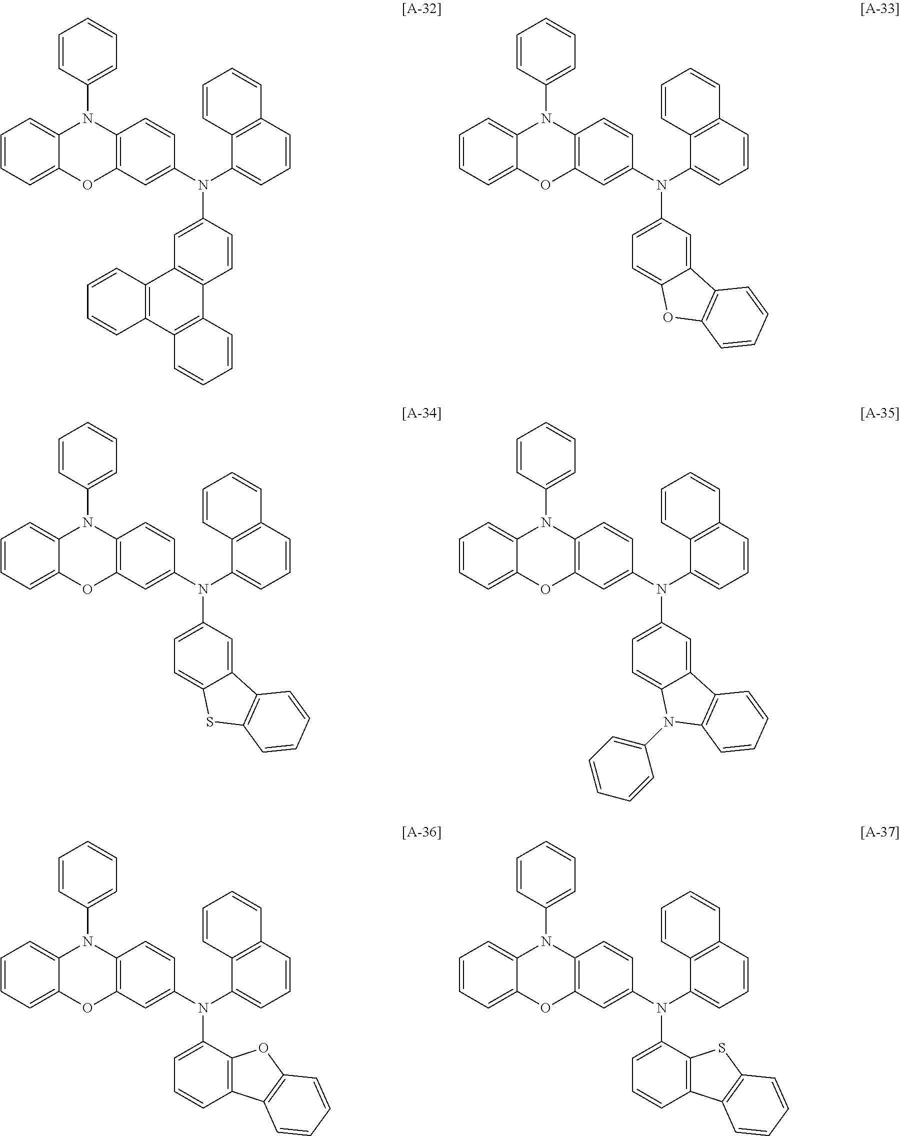 [SMILES: c1ccc(N2c3ccccc3Oc3cc(N(c4ccc5c6ccccc6c6ccccc6c5c4)c4cccc5ccccc45)ccc32)cc1 ; c1ccc(N2c3ccccc3Oc3cc(N(c4ccc5oc6ccccc6c5c4)c4cccc5ccccc45)ccc32)cc1 ; c1ccc(N2c3ccccc3Oc3cc(N(c4ccc5sc6ccccc6c5c4)c4cccc5ccccc45)ccc32)cc1 ; c1ccc(N2c3ccccc3Oc3cc(N(c4ccc5c(c4)c4ccccc4n5-c4ccccc4)c4cccc5ccccc45)ccc32)cc1 ; c1ccc(N2c3ccccc3Oc3cc(N(c4cccc5ccccc45)c4cccc5c4oc4ccccc45)ccc32)cc1 ; c1ccc(N2c3ccccc3Oc3cc(N(c4cccc5ccccc45)c4cccc5c4sc4ccccc45)ccc32)cc1]

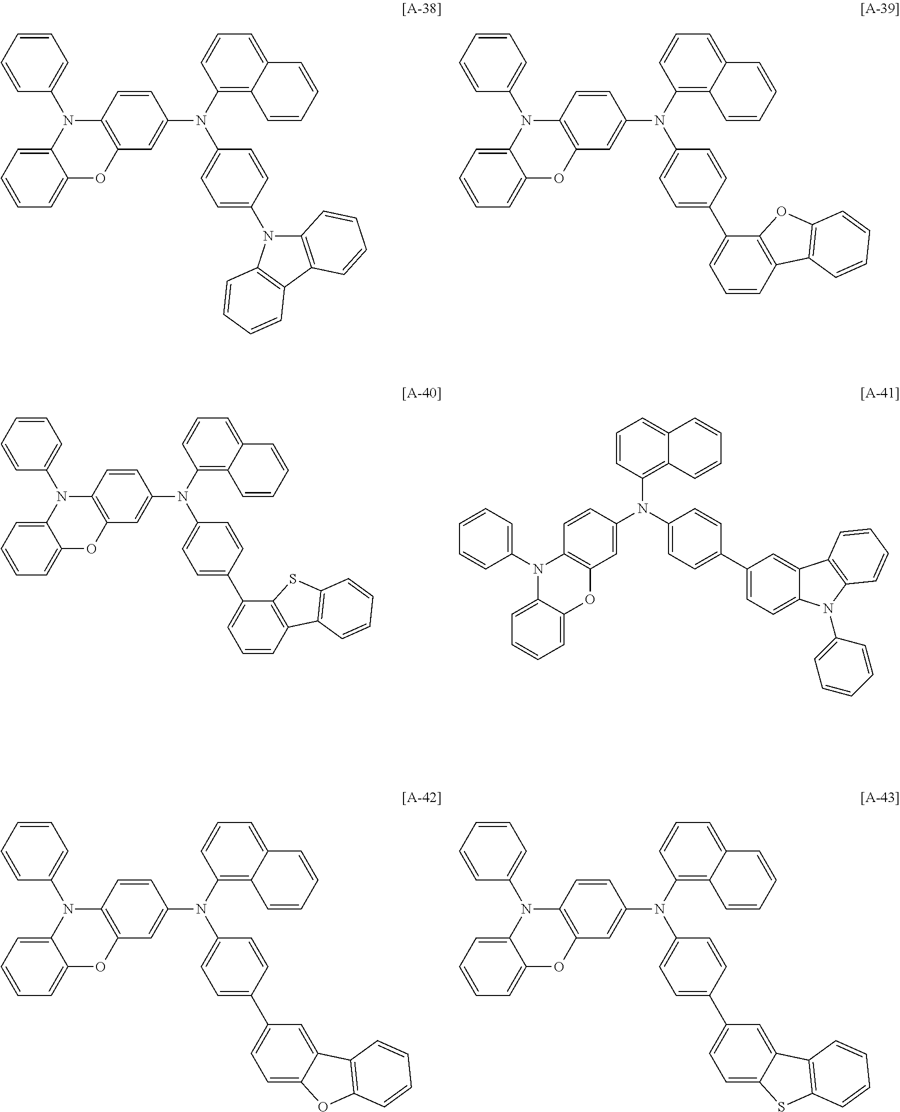 [SMILES: c1ccc(N2c3ccccc3Oc3cc(N(c4ccc(-n5c6ccccc6c6ccccc65)cc4)c4cccc5ccccc45)ccc32)cc1 ; c1ccc(N2c3ccccc3Oc3cc(N(c4ccc(-c5cccc6c5oc5ccccc56)cc4)c4cccc5ccccc45)ccc32)cc1 ; c1ccc(N2c3ccccc3Oc3cc(N(c4ccc(-c5cccc6c5sc5ccccc56)cc4)c4cccc5ccccc45)ccc32)cc1 ; c1ccc(N2c3ccccc3Oc3cc(N(c4ccc(-c5ccc6c(c5)c5ccccc5n6-c5ccccc5)cc4)c4cccc5ccccc45)ccc32)cc1 ; c1ccc(N2c3ccccc3Oc3cc(N(c4ccc(-c5ccc6oc7ccccc7c6c5)cc4)c4cccc5ccccc45)ccc32)cc1 ; c1ccc(N2c3ccccc3Oc3cc(N(c4ccc(-c5ccc6sc7ccccc7c6c5)cc4)c4cccc5ccccc45)ccc32)cc1]

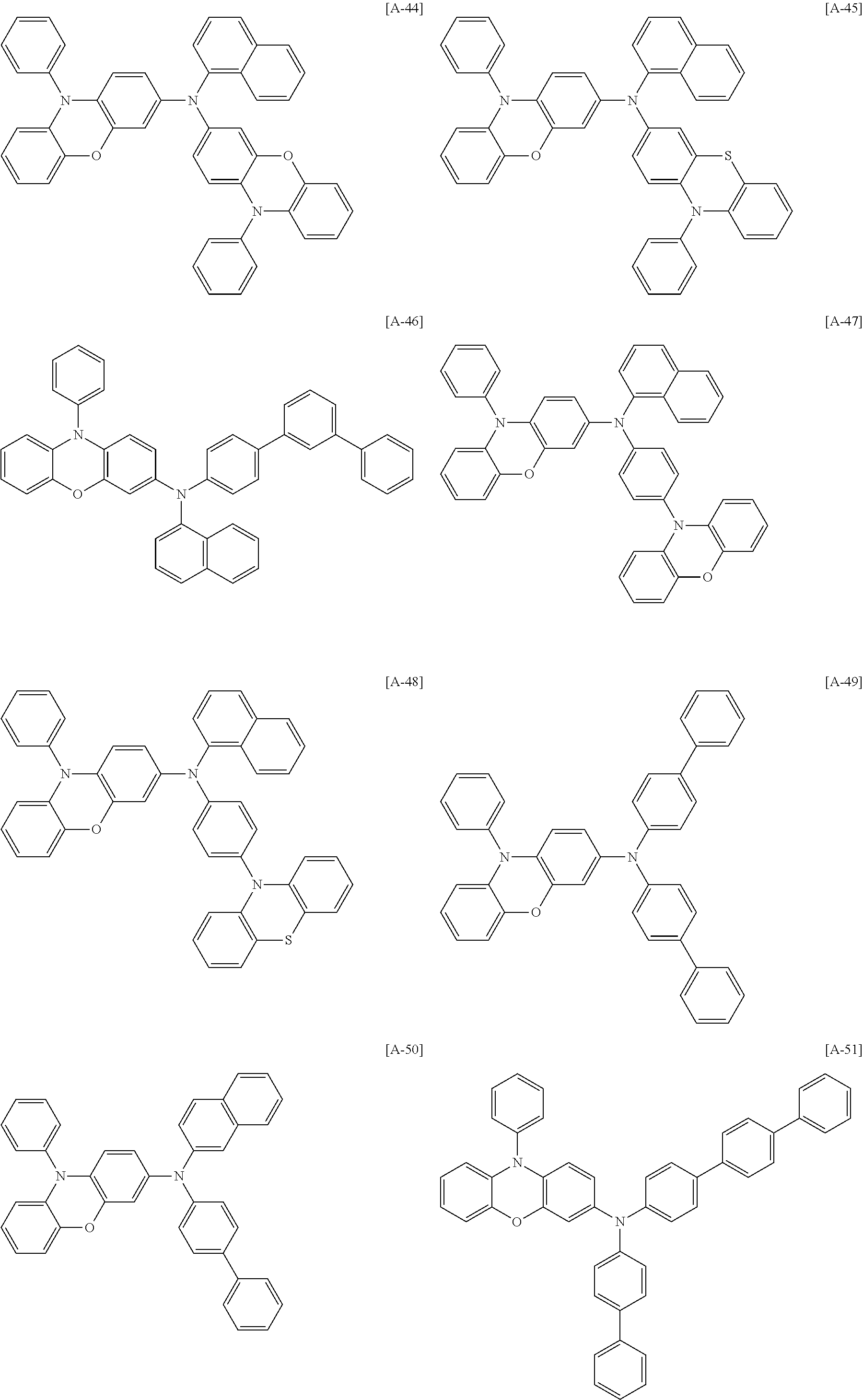

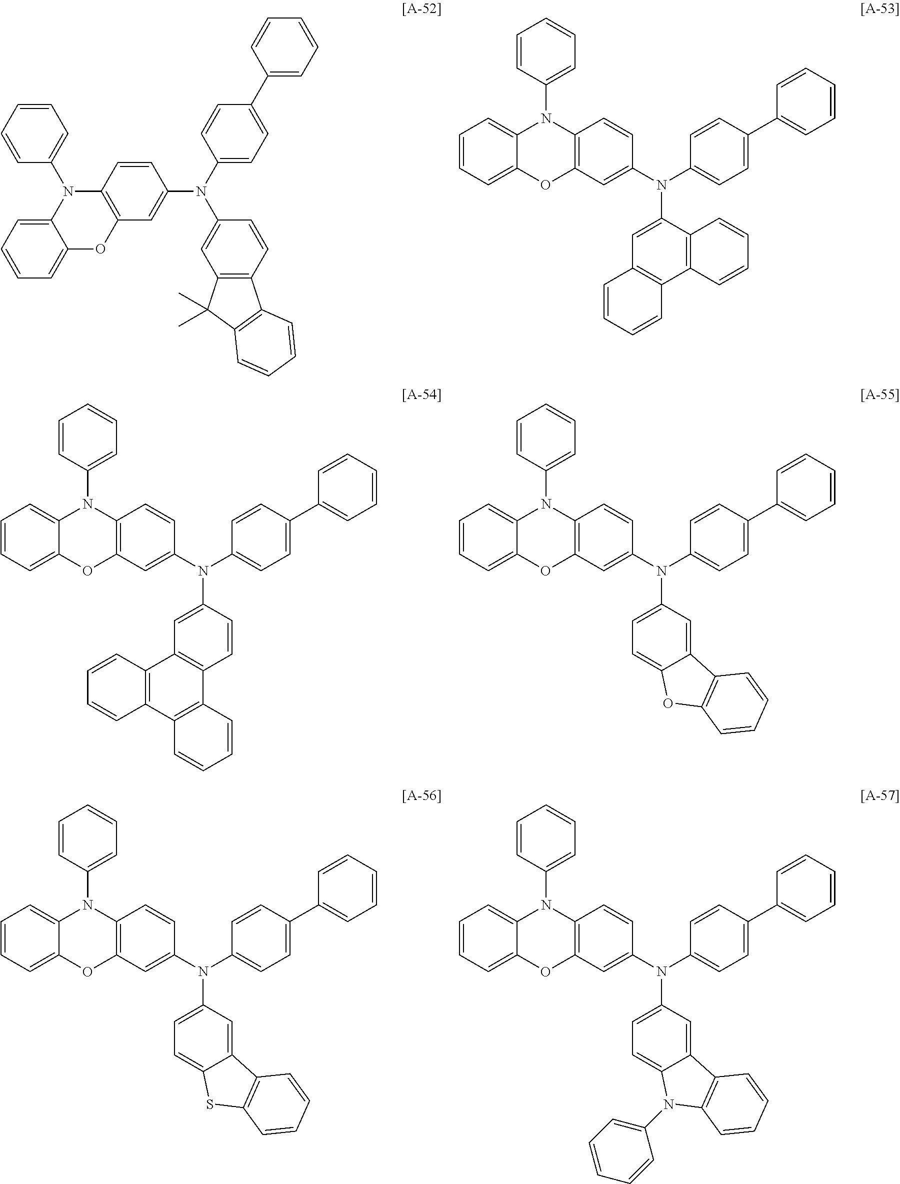 [SMILES: CC1(C)c2ccccc2-c2ccc(N(c3ccc(-c4ccccc4)cc3)c3ccc4c(c3)Oc3ccccc3N4c3ccccc3)cc21 ; c1ccc(-c2ccc(N(c3ccc4c(c3)Oc3ccccc3N4c3ccccc3)c3cc4ccccc4c4ccccc34)cc2)cc1 ; c1ccc(-c2ccc(N(c3ccc4c(c3)Oc3ccccc3N4c3ccccc3)c3ccc4c5ccccc5c5ccccc5c4c3)cc2)cc1 ; c1ccc(-c2ccc(N(c3ccc4c(c3)Oc3ccccc3N4c3ccccc3)c3ccc4oc5ccccc5c4c3)cc2)cc1 ; c1ccc(-c2ccc(N(c3ccc4c(c3)Oc3ccccc3N4c3ccccc3)c3ccc4sc5ccccc5c4c3)cc2)cc1 ; c1ccc(-c2ccc(N(c3ccc4c(c3)Oc3ccccc3N4c3ccccc3)c3ccc4c(c3)c3ccccc3n4-c3ccccc3)cc2)cc1]

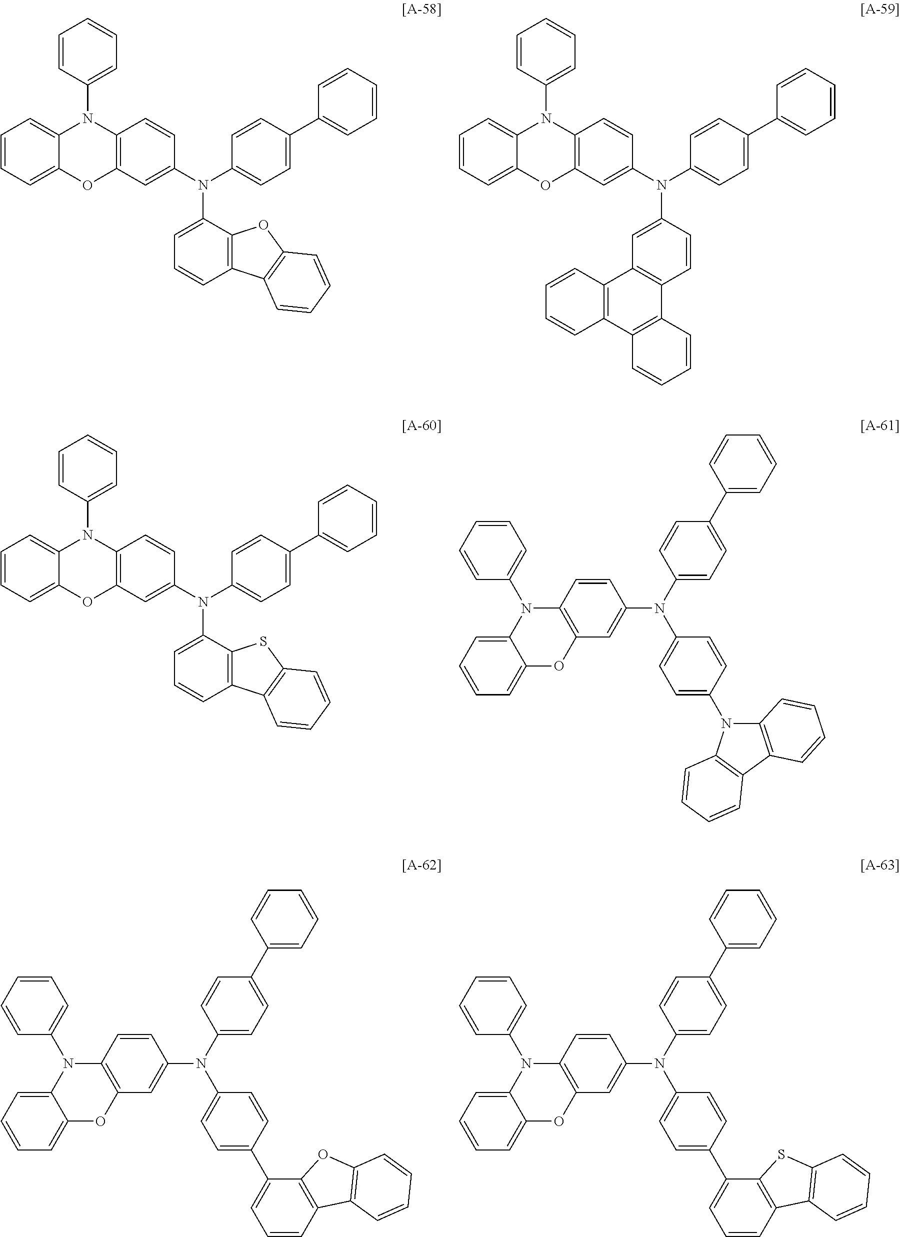 [SMILES: c1ccc(-c2ccc(N(c3ccc4c(c3)Oc3ccccc3N4c3ccccc3)c3cccc4c3oc3ccccc34)cc2)cc1 ; c1ccc(-c2ccc(N(c3ccc4c(c3)Oc3ccccc3N4c3ccccc3)c3ccc4c5ccccc5c5ccccc5c4c3)cc2)cc1 ; c1ccc(-c2ccc(N(c3ccc4c(c3)Oc3ccccc3N4c3ccccc3)c3cccc4c3sc3ccccc34)cc2)cc1 ; c1ccc(-c2ccc(N(c3ccc(-n4c5ccccc5c5ccccc54)cc3)c3ccc4c(c3)Oc3ccccc3N4c3ccccc3)cc2)cc1 ; c1ccc(-c2ccc(N(c3ccc(-c4cccc5c4oc4ccccc45)cc3)c3ccc4c(c3)Oc3ccccc3N4c3ccccc3)cc2)cc1 ; c1ccc(-c2ccc(N(c3ccc(-c4cccc5c4sc4ccccc45)cc3)c3ccc4c(c3)Oc3ccccc3N4c3ccccc3)cc2)cc1]

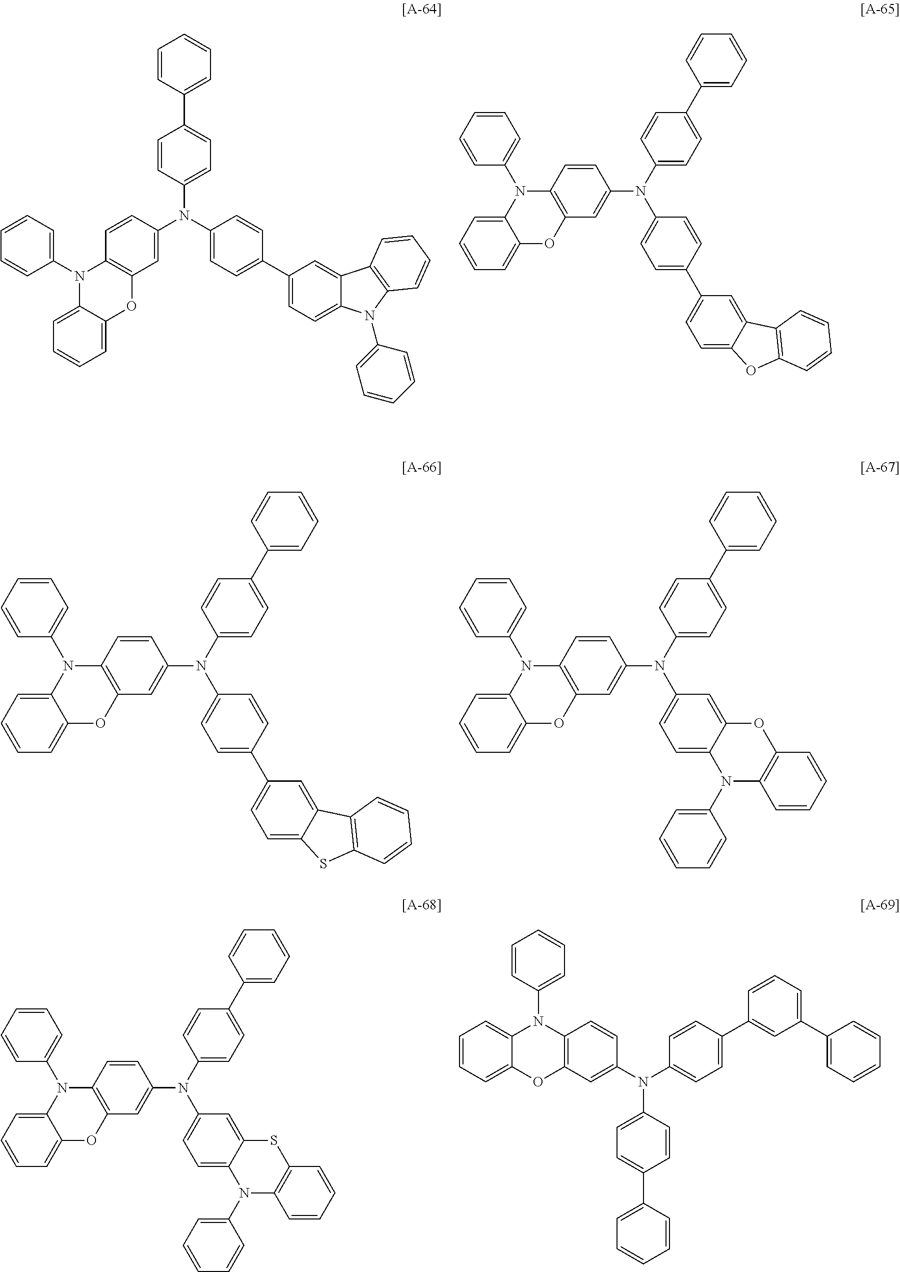

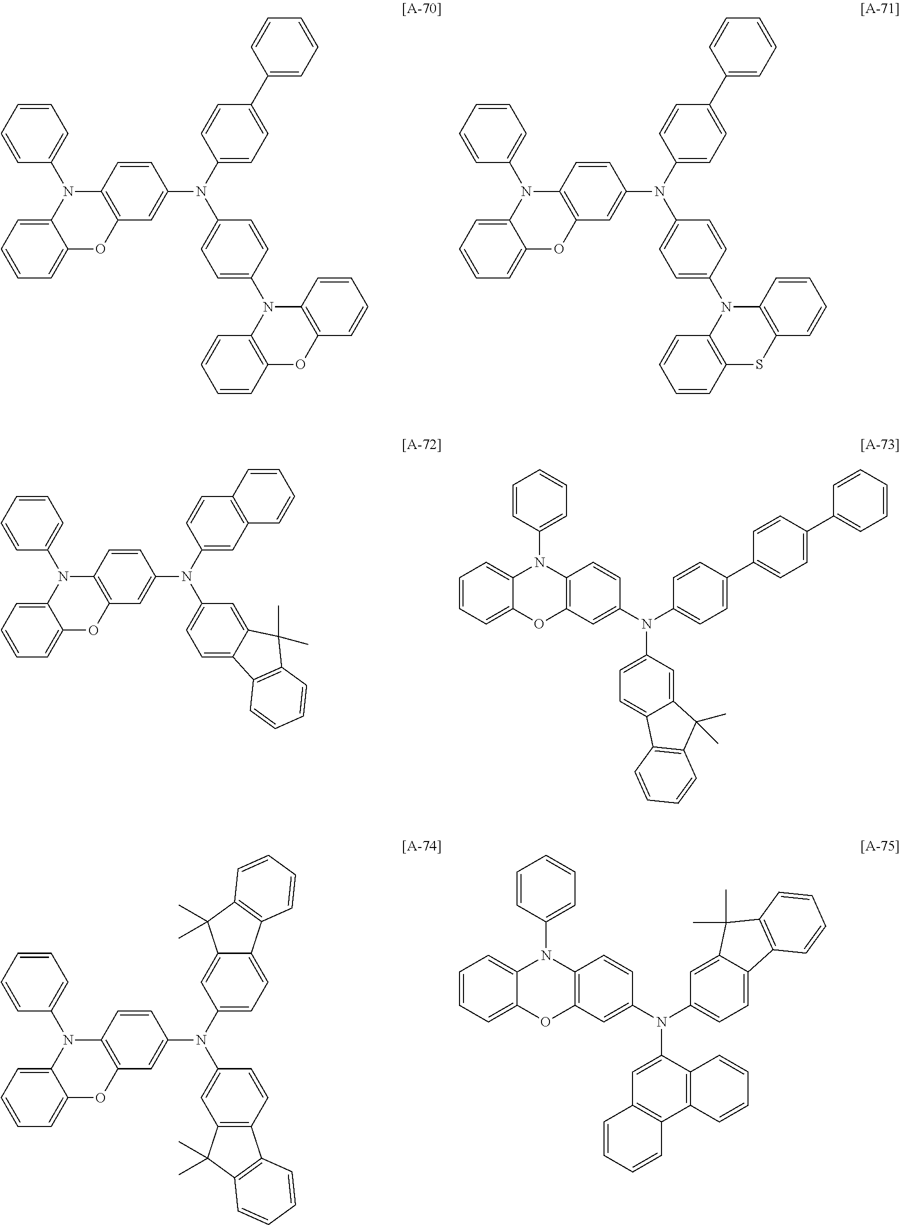

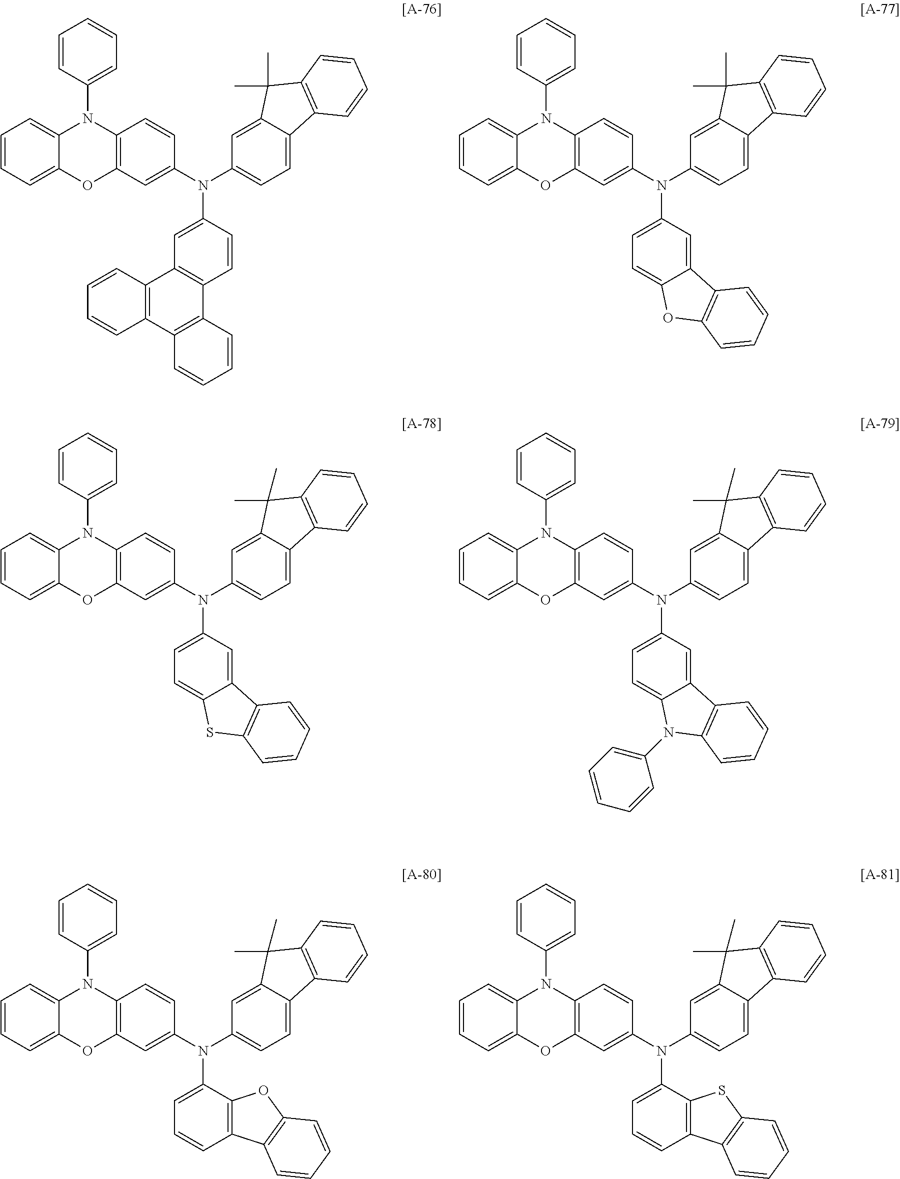

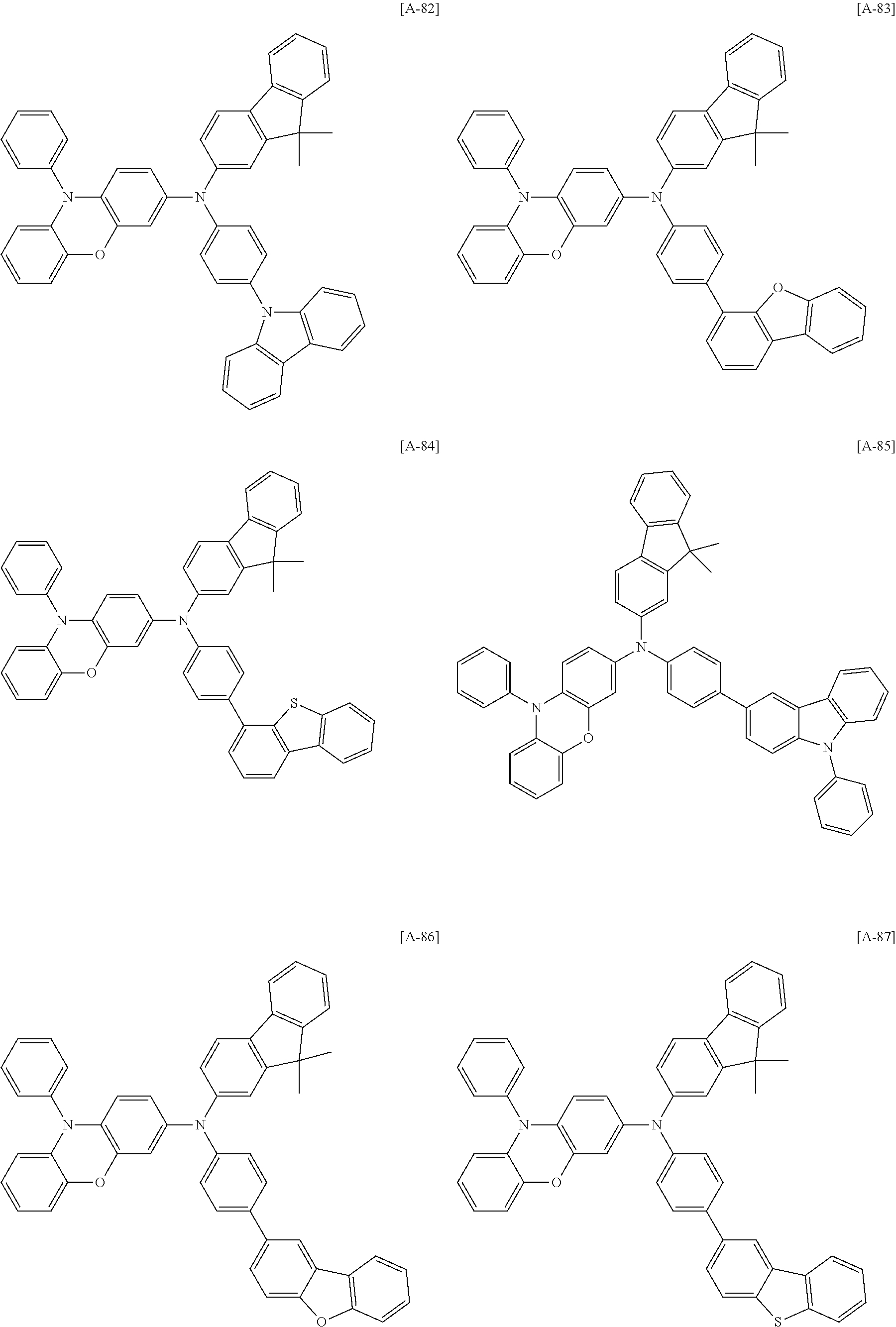

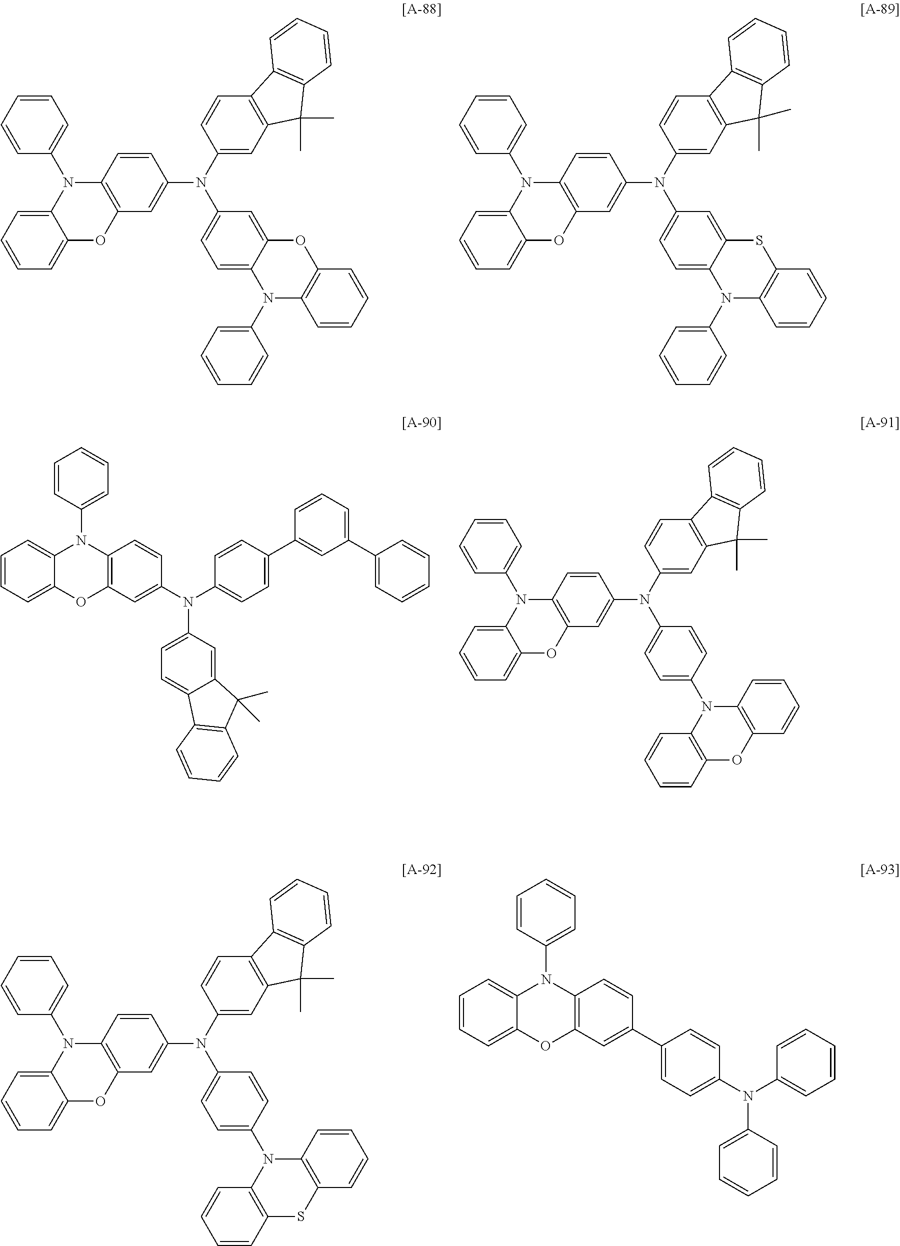

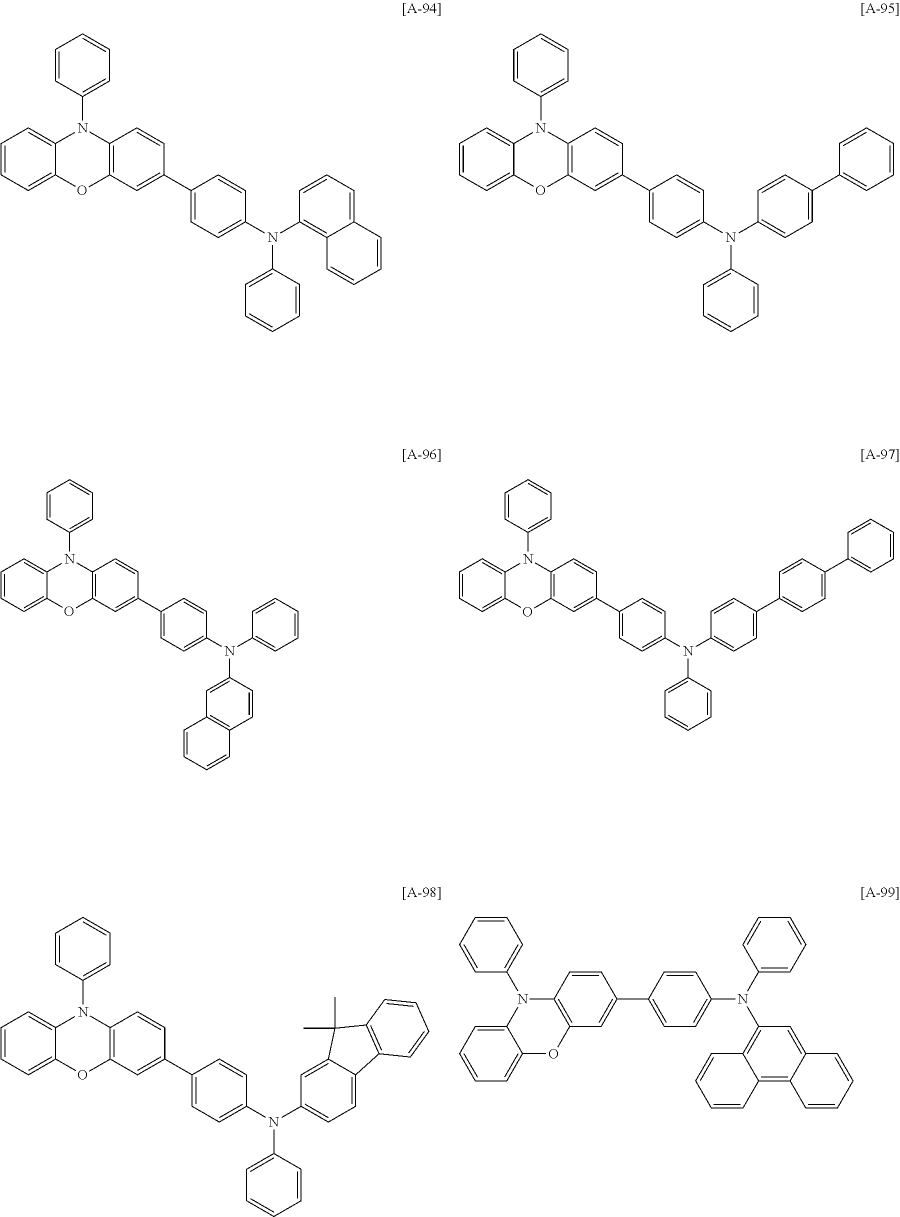

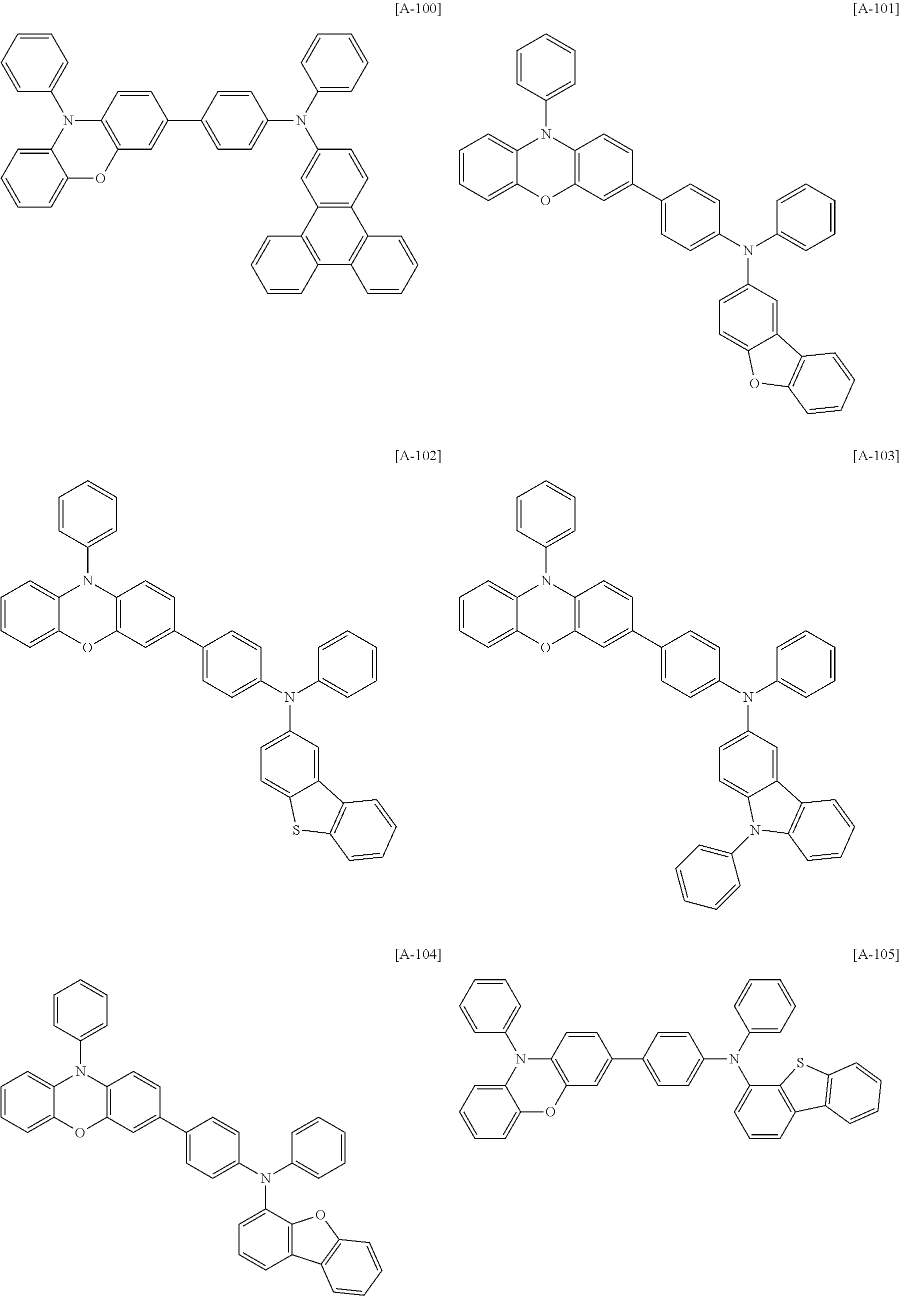 [SMILES: c1ccc(N(c2ccc(-c3ccc4c(c3)Oc3ccccc3N4c3ccccc3)cc2)c2ccc3c4ccccc4c4ccccc4c3c2)cc1 ; c1ccc(N(c2ccc(-c3ccc4c(c3)Oc3ccccc3N4c3ccccc3)cc2)c2ccc3oc4ccccc4c3c2)cc1 ; c1ccc(N(c2ccc(-c3ccc4c(c3)Oc3ccccc3N4c3ccccc3)cc2)c2ccc3sc4ccccc4c3c2)cc1 ; c1ccc(N(c2ccc(-c3ccc4c(c3)Oc3ccccc3N4c3ccccc3)cc2)c2ccc3c(c2)c2ccccc2n3-c2ccccc2)cc1 ; c1ccc(N2c3ccccc3Oc3cc(-c4ccc(N(c5ccccc5)c5cccc6c5oc5ccccc56)cc4)ccc32)cc1 ; c1ccc(N2c3ccccc3Oc3cc(-c4ccc(N(c5ccccc5)c5cccc6c5sc5ccccc56)cc4)ccc32)cc1]

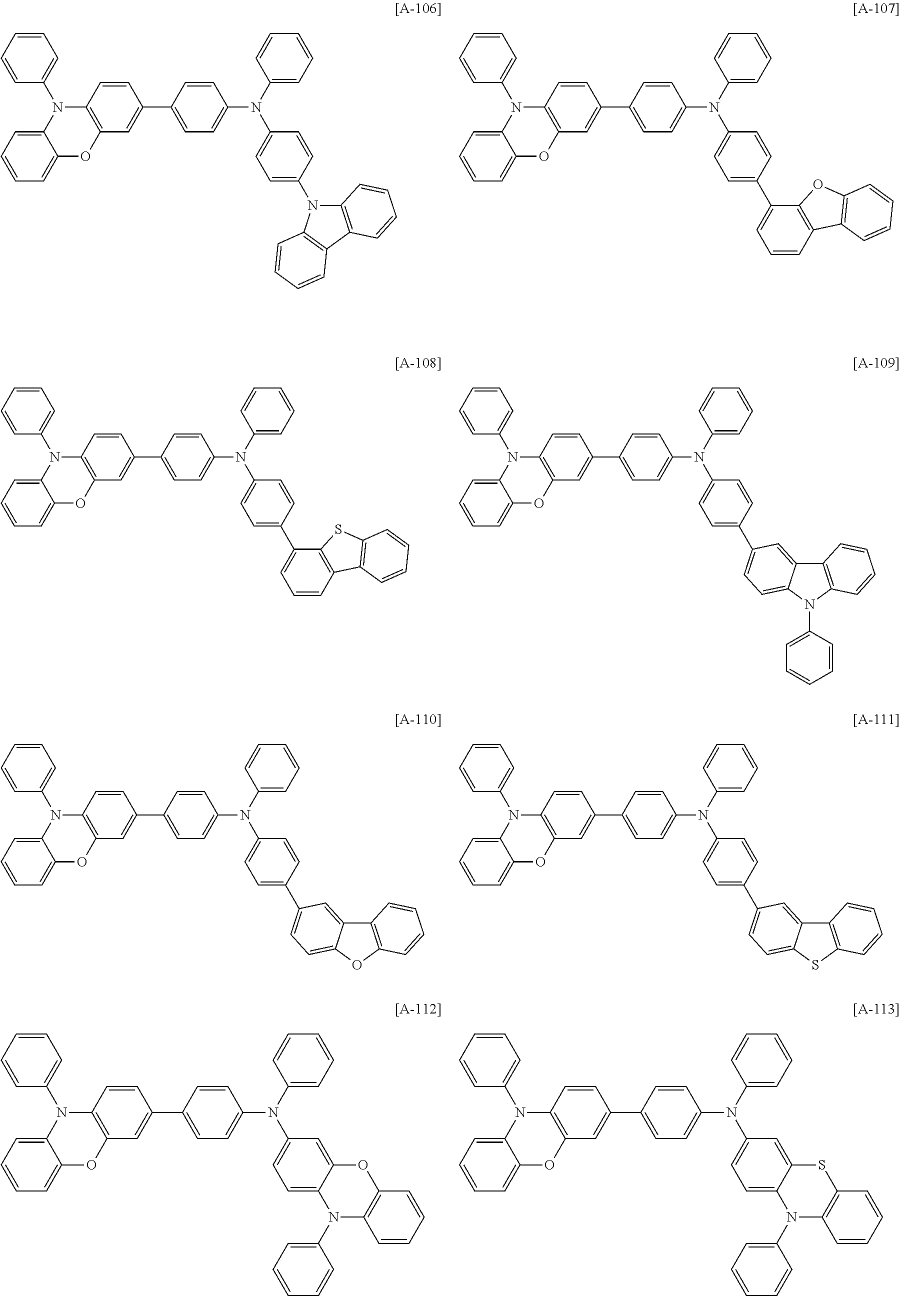

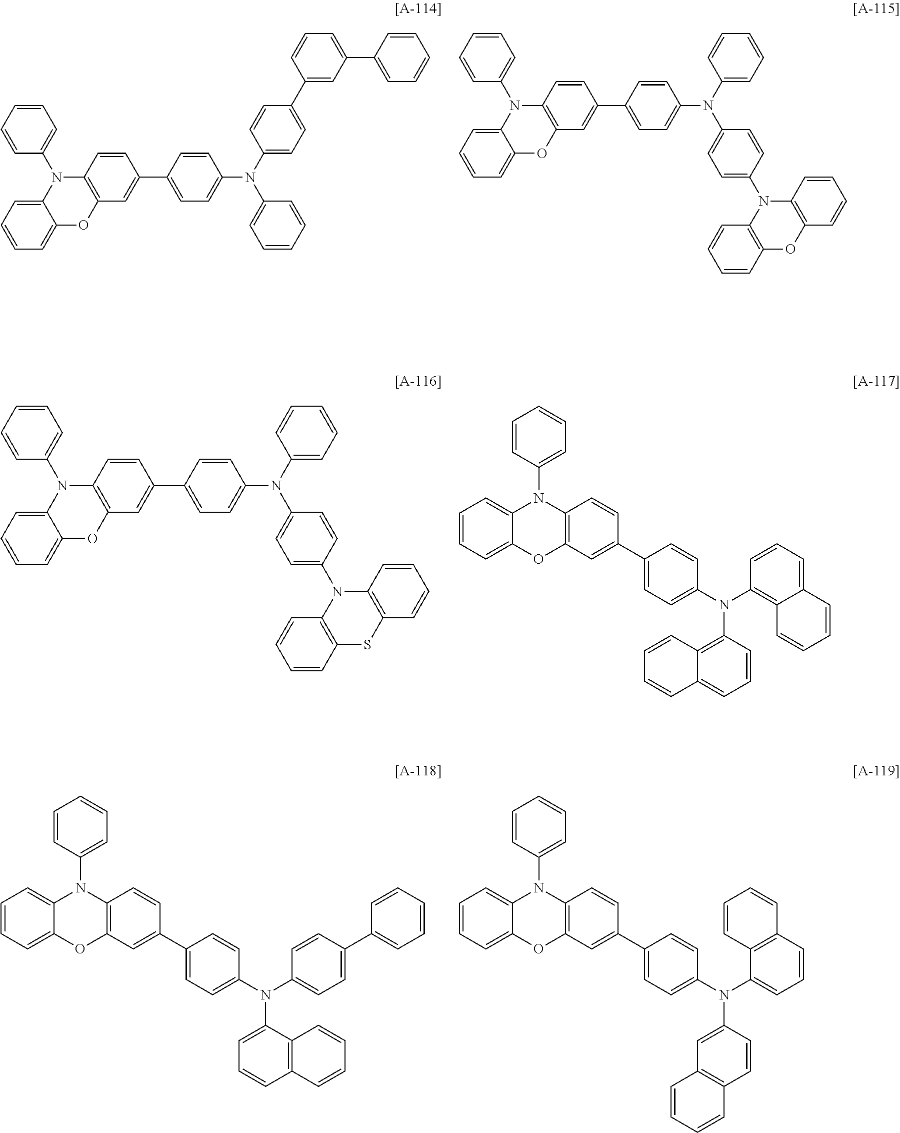

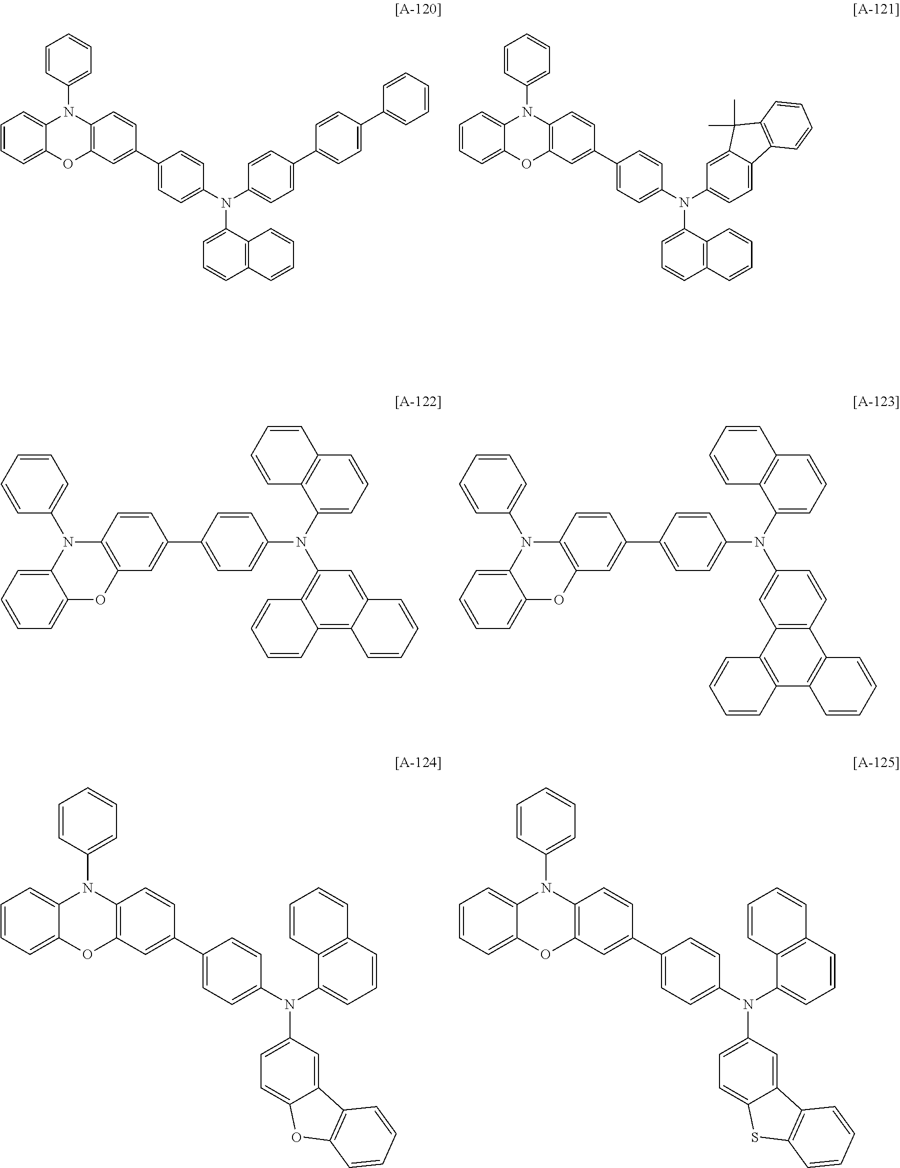

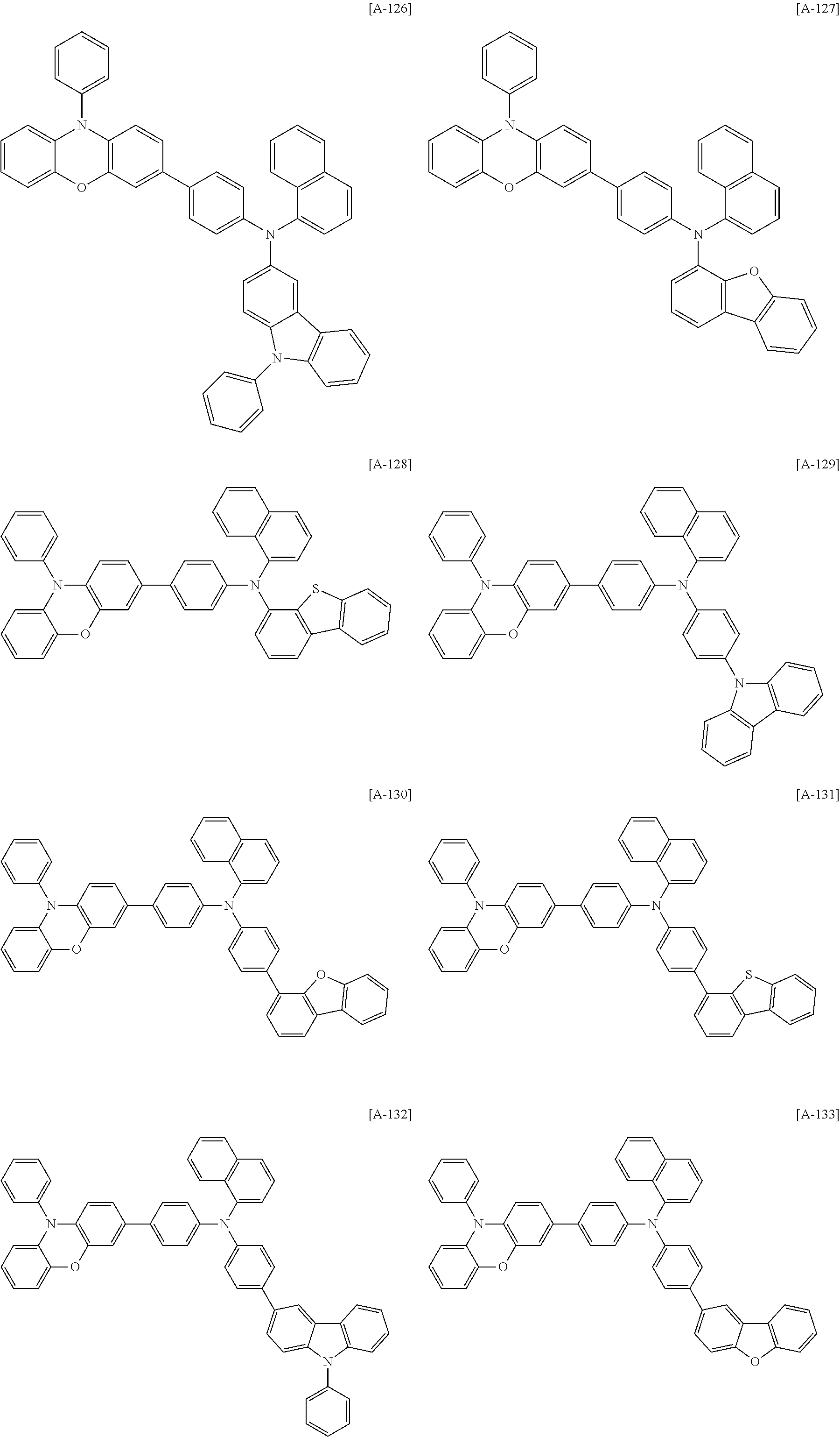

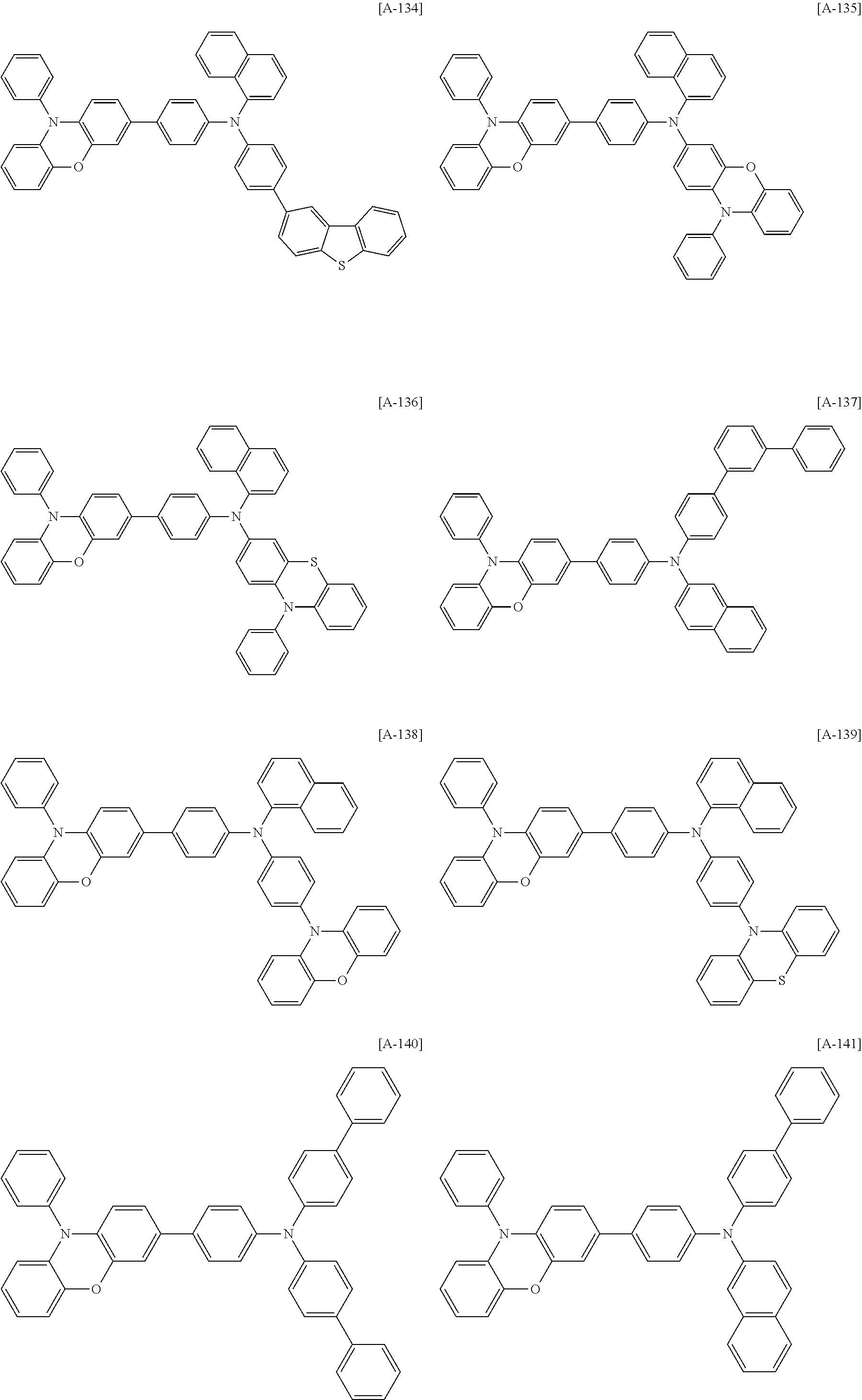

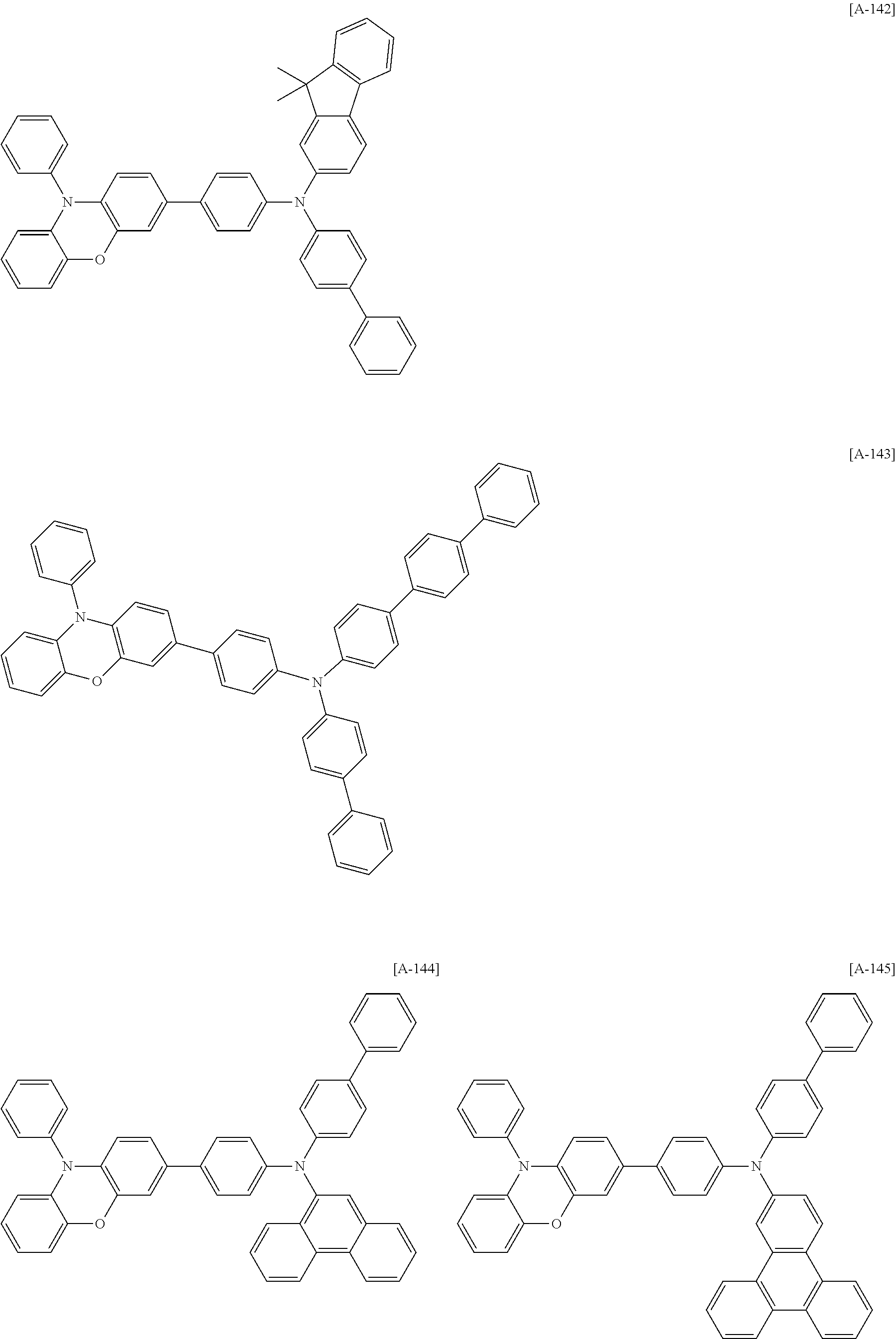 [SMILES: CC1(C)c2ccccc2-c2ccc(N(c3ccc(-c4ccccc4)cc3)c3ccc(-c4ccc5c(c4)Oc4ccccc4N5c4ccccc4)cc3)cc21 ; c1ccc(-c2ccc(-c3ccc(N(c4ccc(-c5ccccc5)cc4)c4ccc(-c5ccc6c(c5)Oc5ccccc5N6c5ccccc5)cc4)cc3)cc2)cc1 ; c1ccc(-c2ccc(N(c3ccc(-c4ccc5c(c4)Oc4ccccc4N5c4ccccc4)cc3)c3cc4ccccc4c4ccccc34)cc2)cc1 ; c1ccc(-c2ccc(N(c3ccc(-c4ccc5c(c4)Oc4ccccc4N5c4ccccc4)cc3)c3ccc4c5ccccc5c5ccccc5c4c3)cc2)cc1]

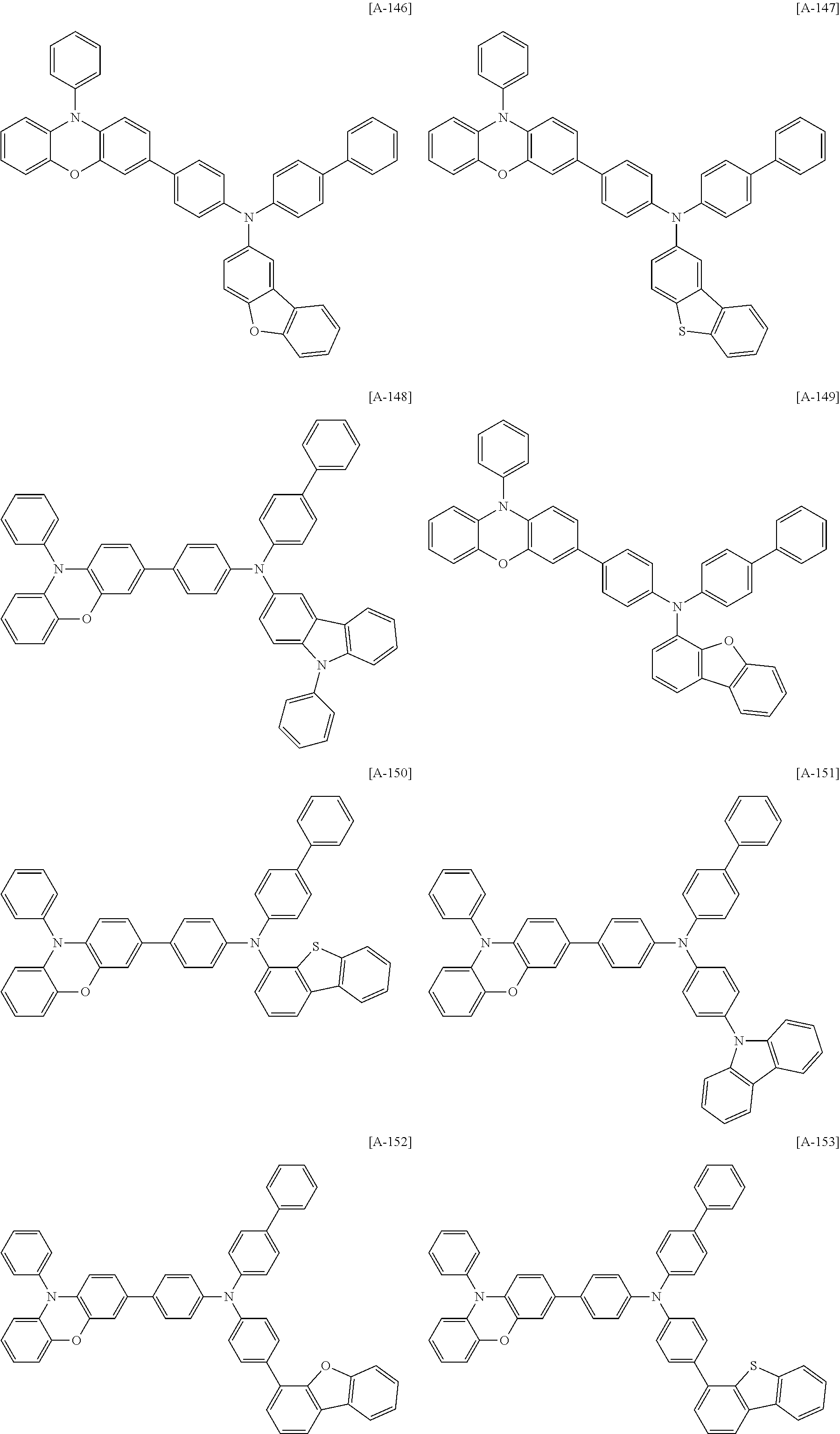

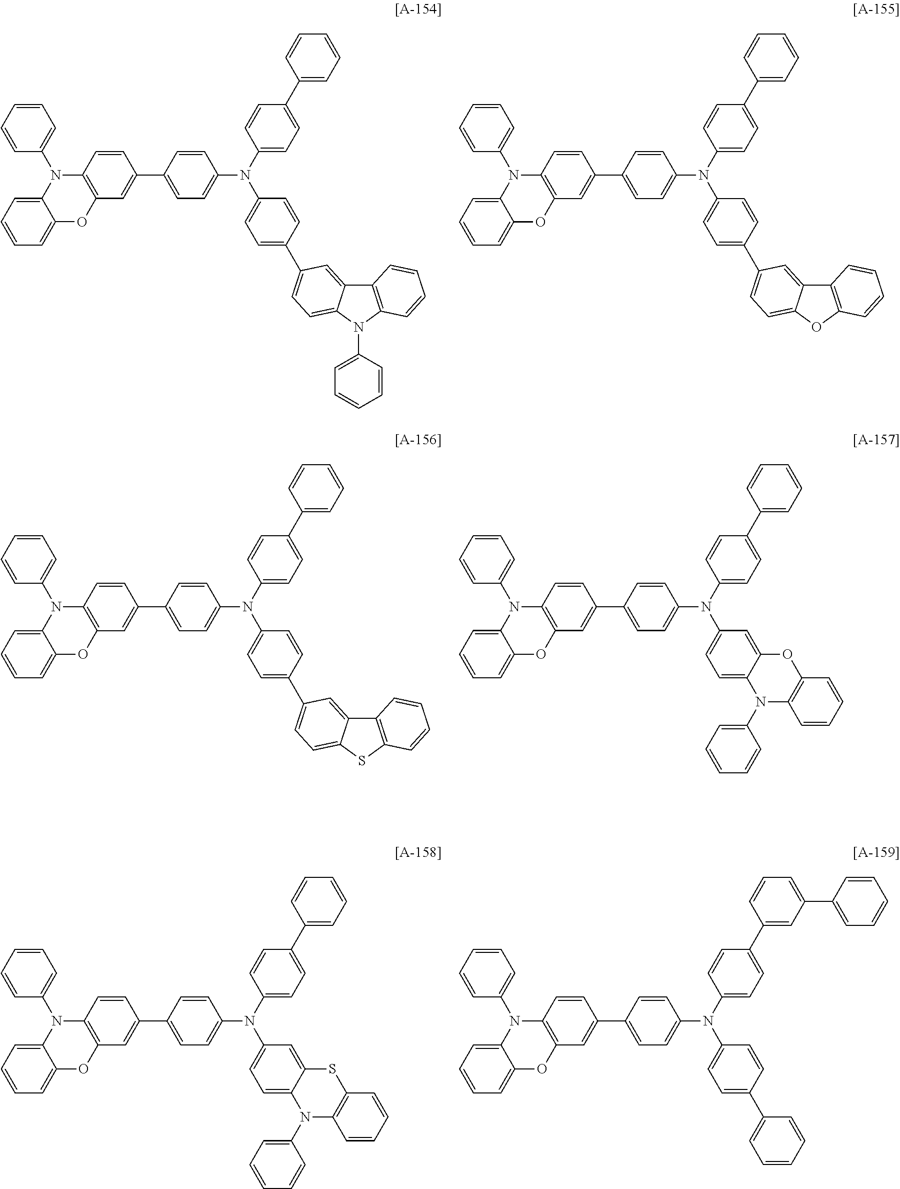

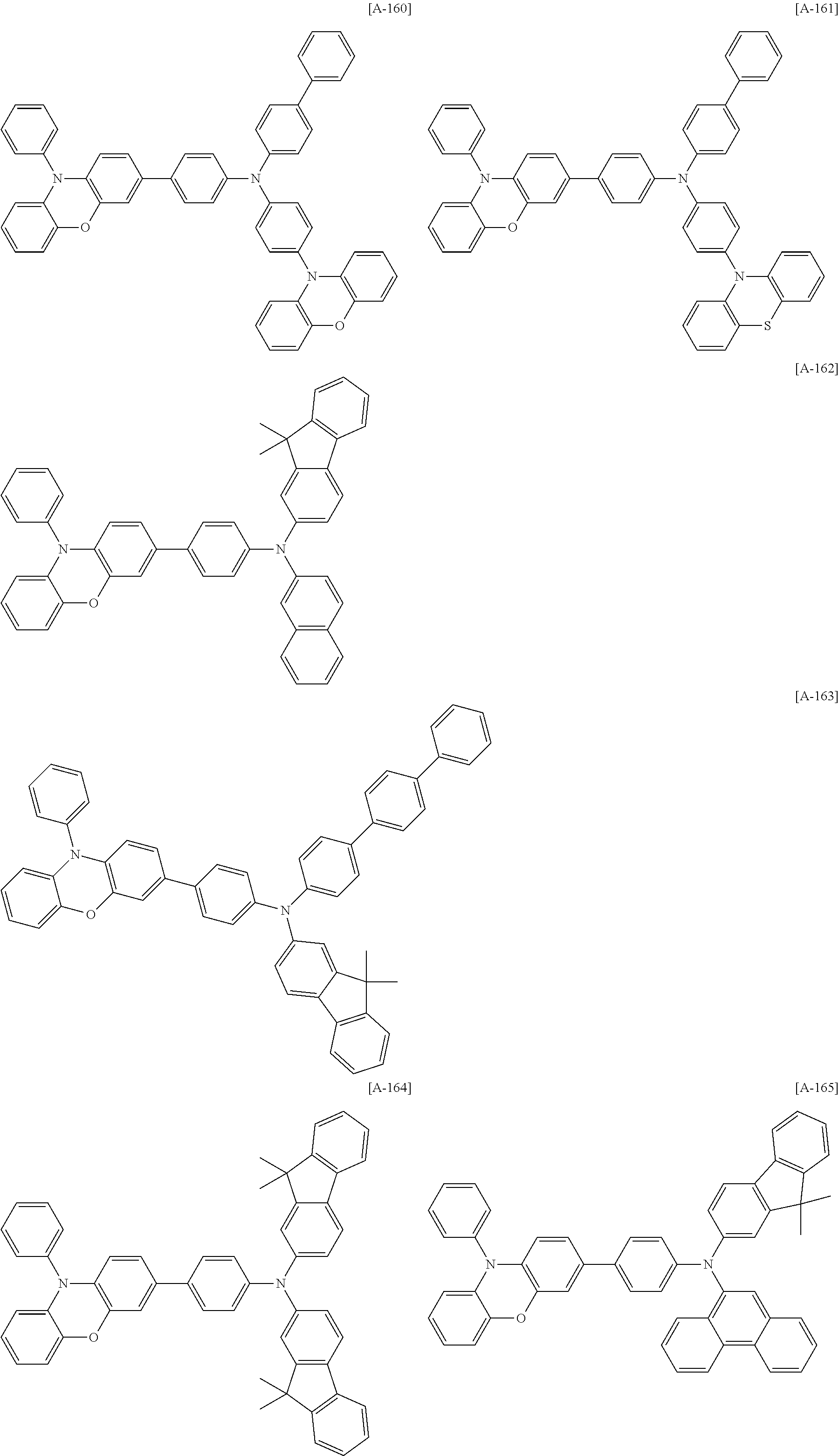

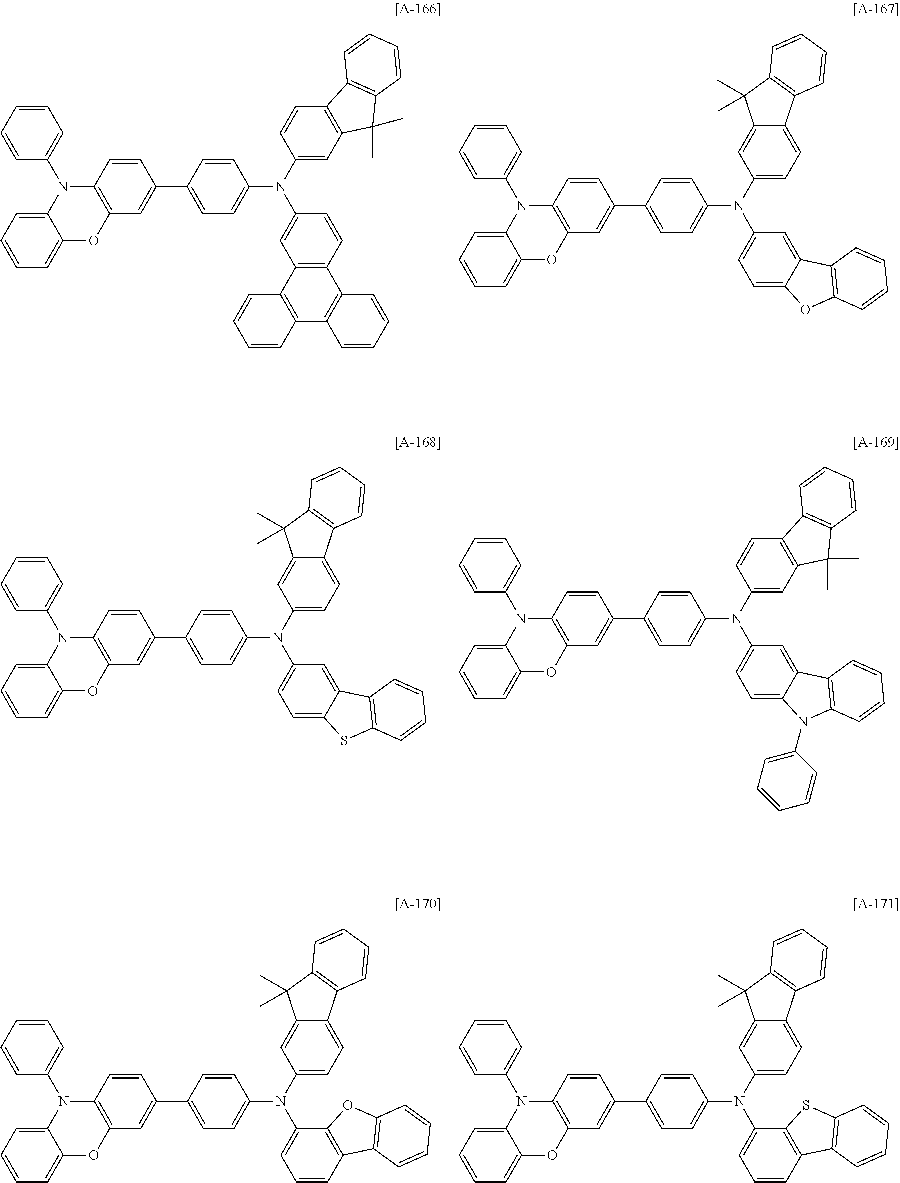

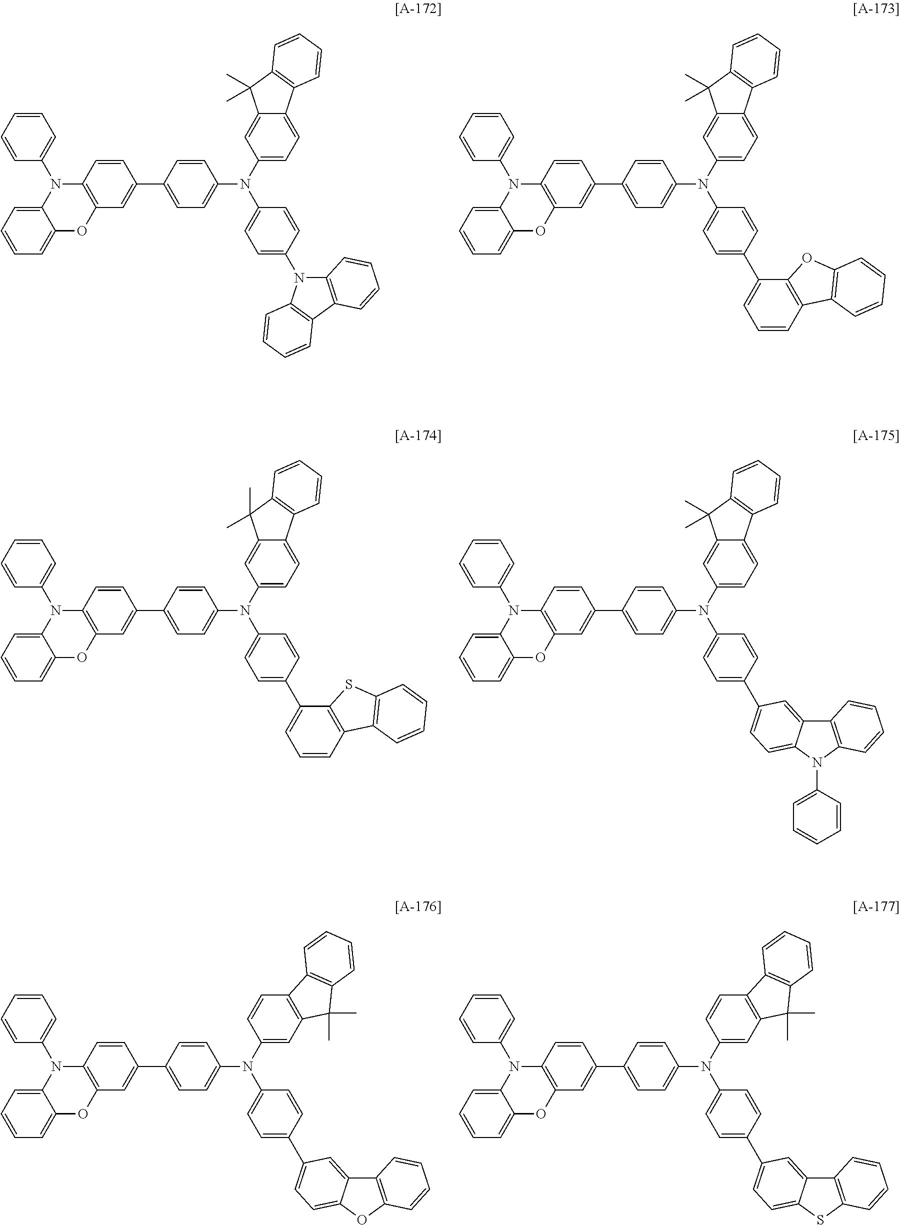

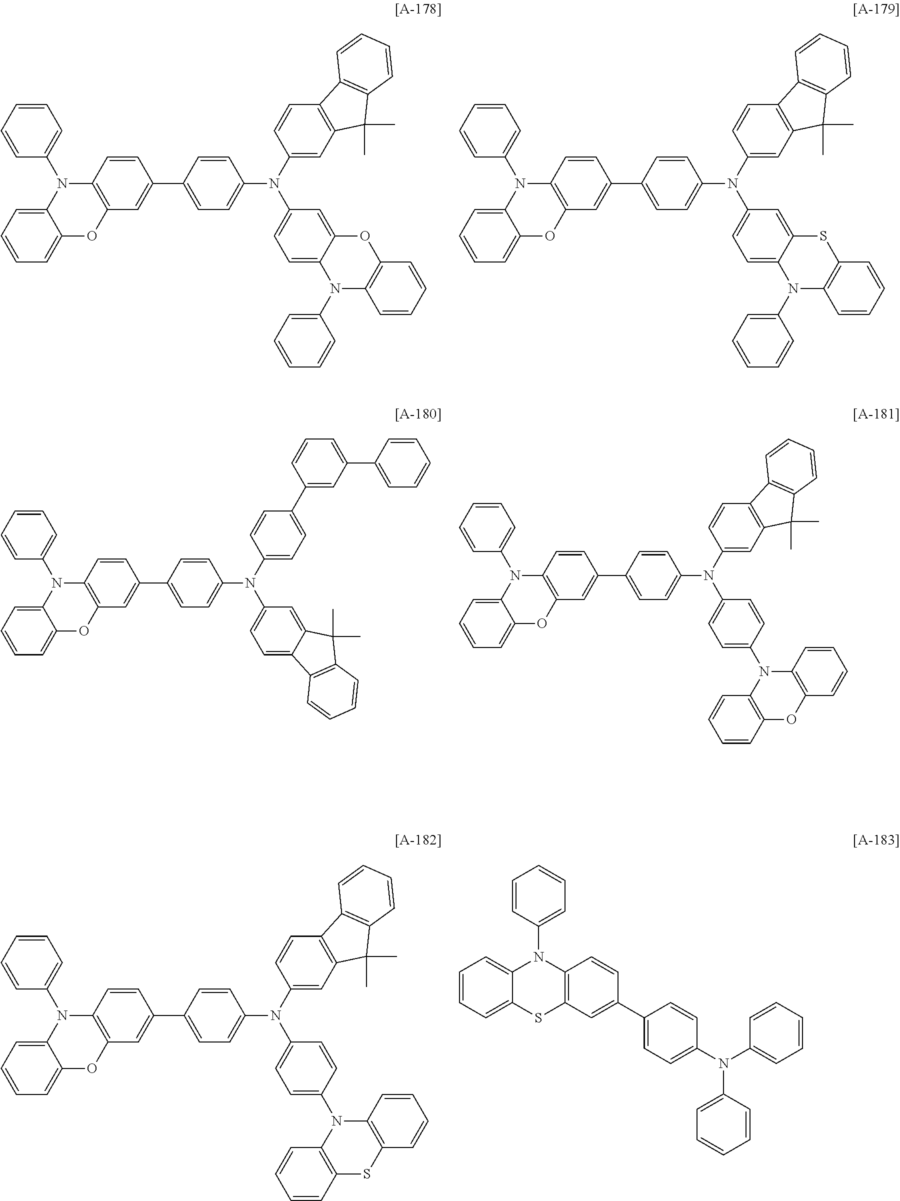

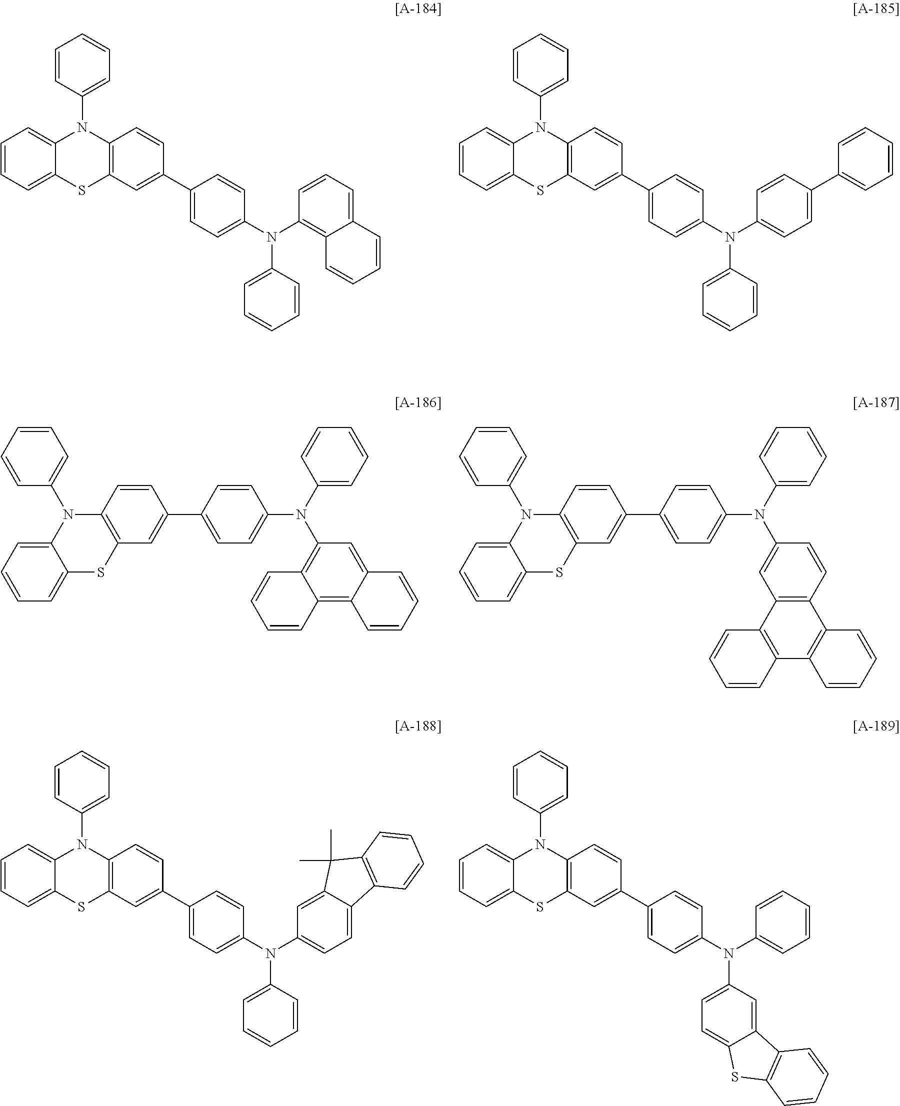

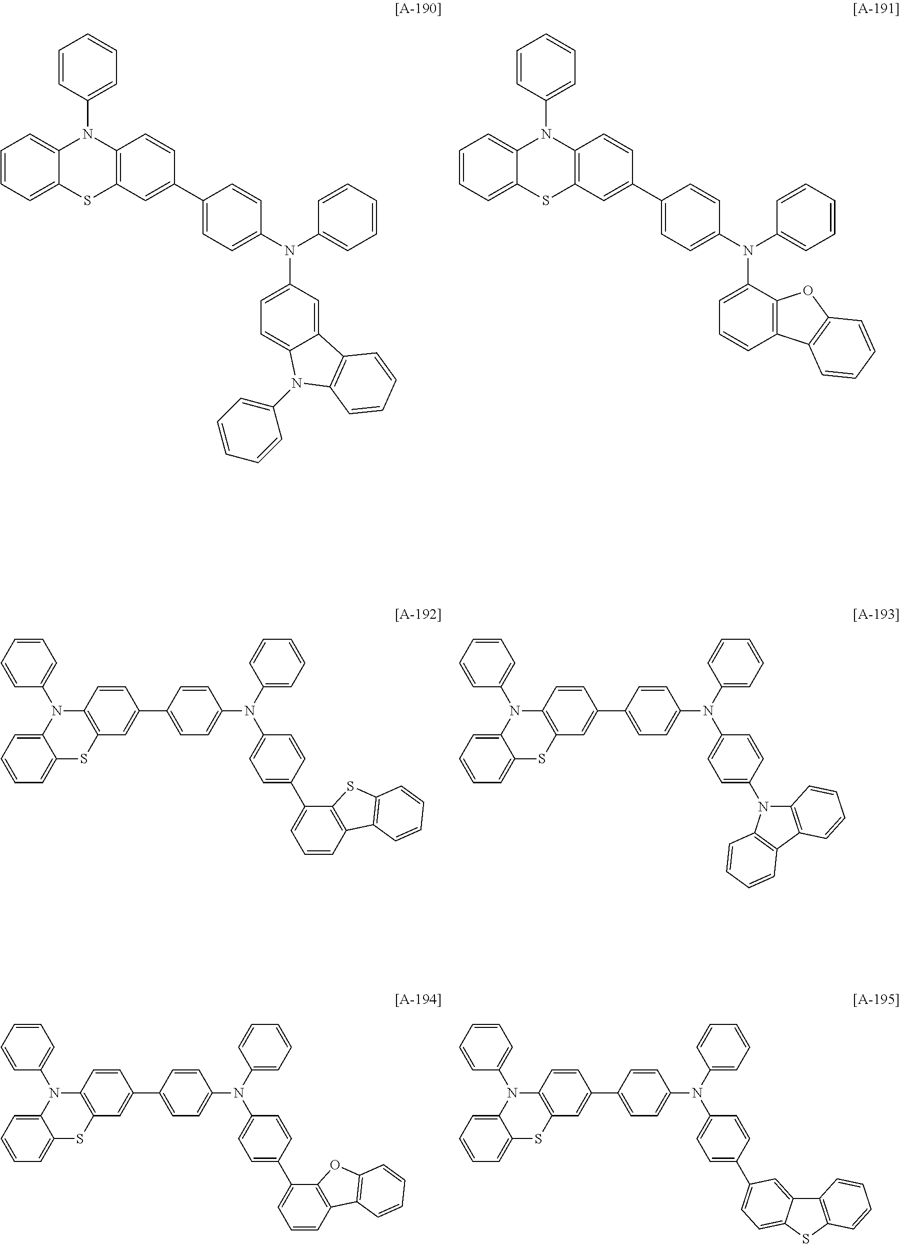

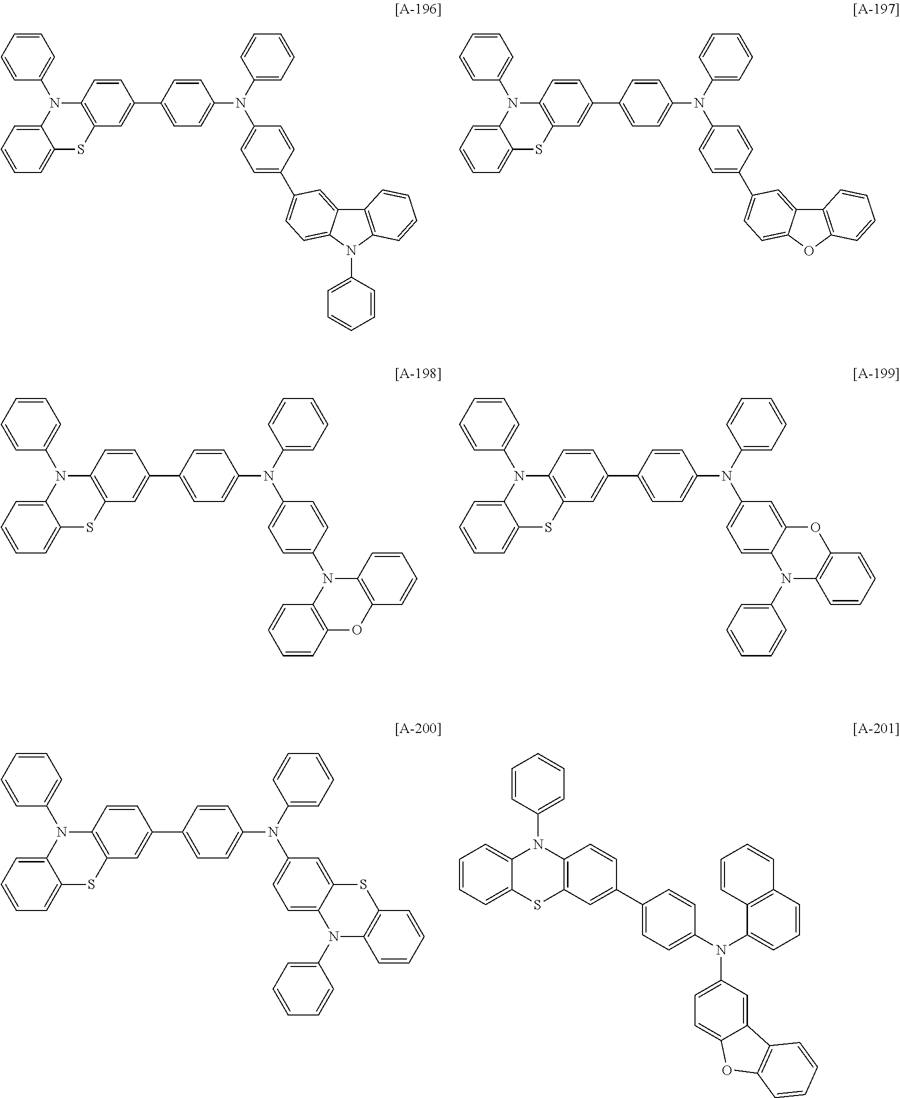

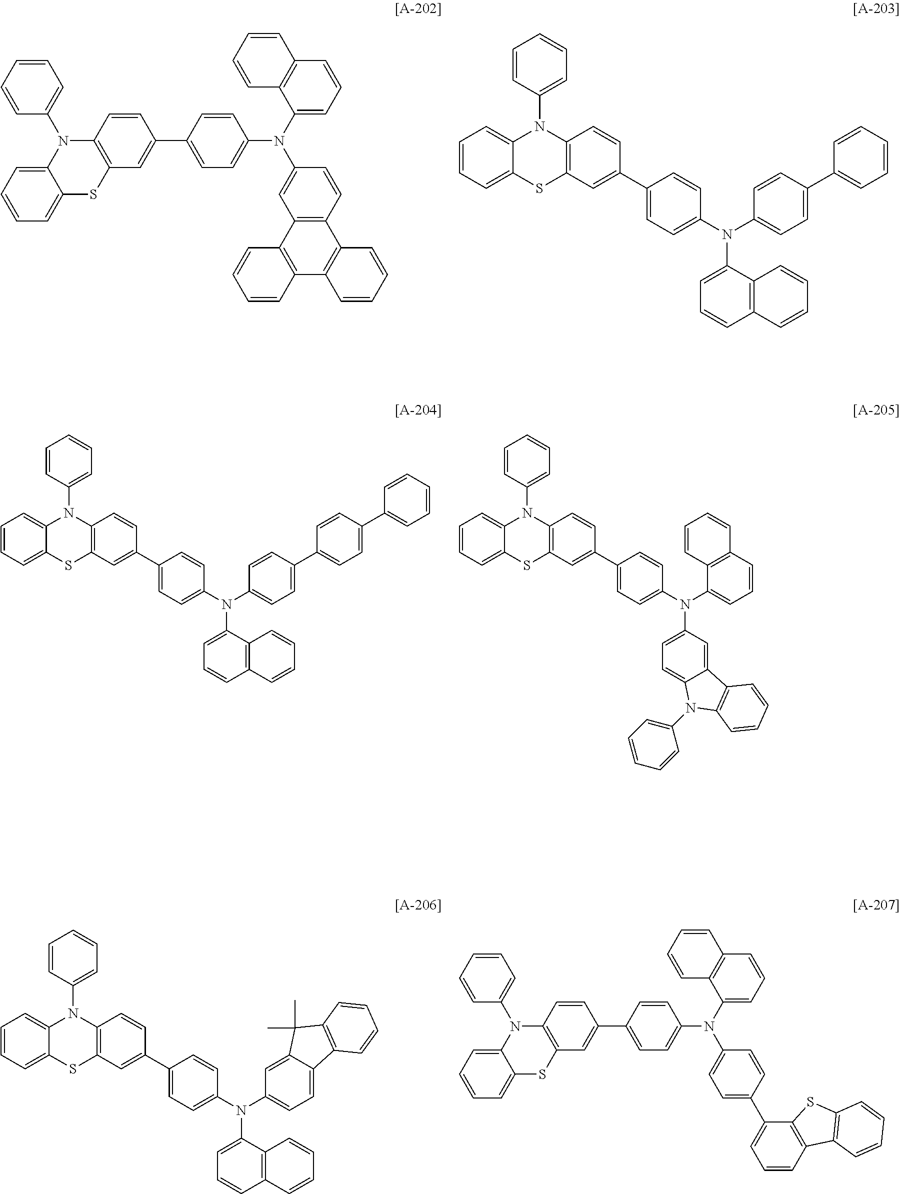

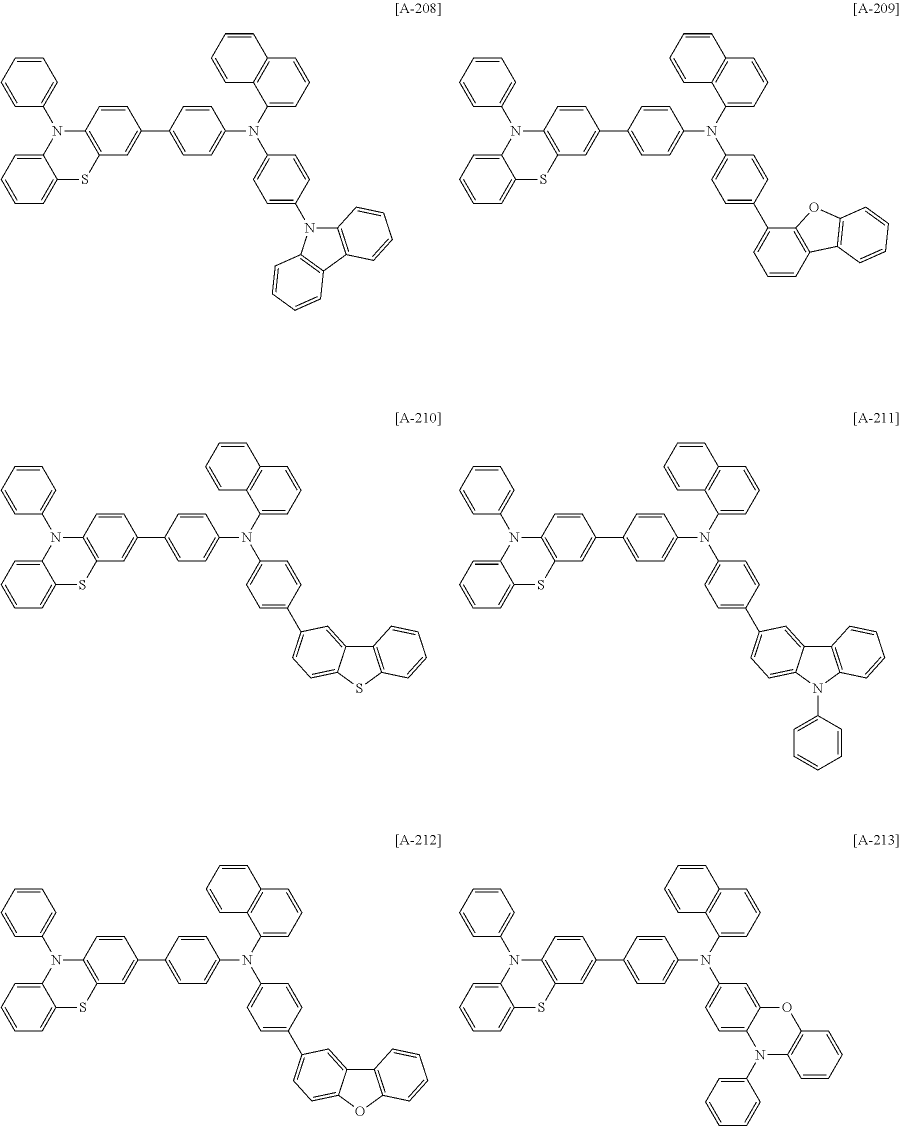

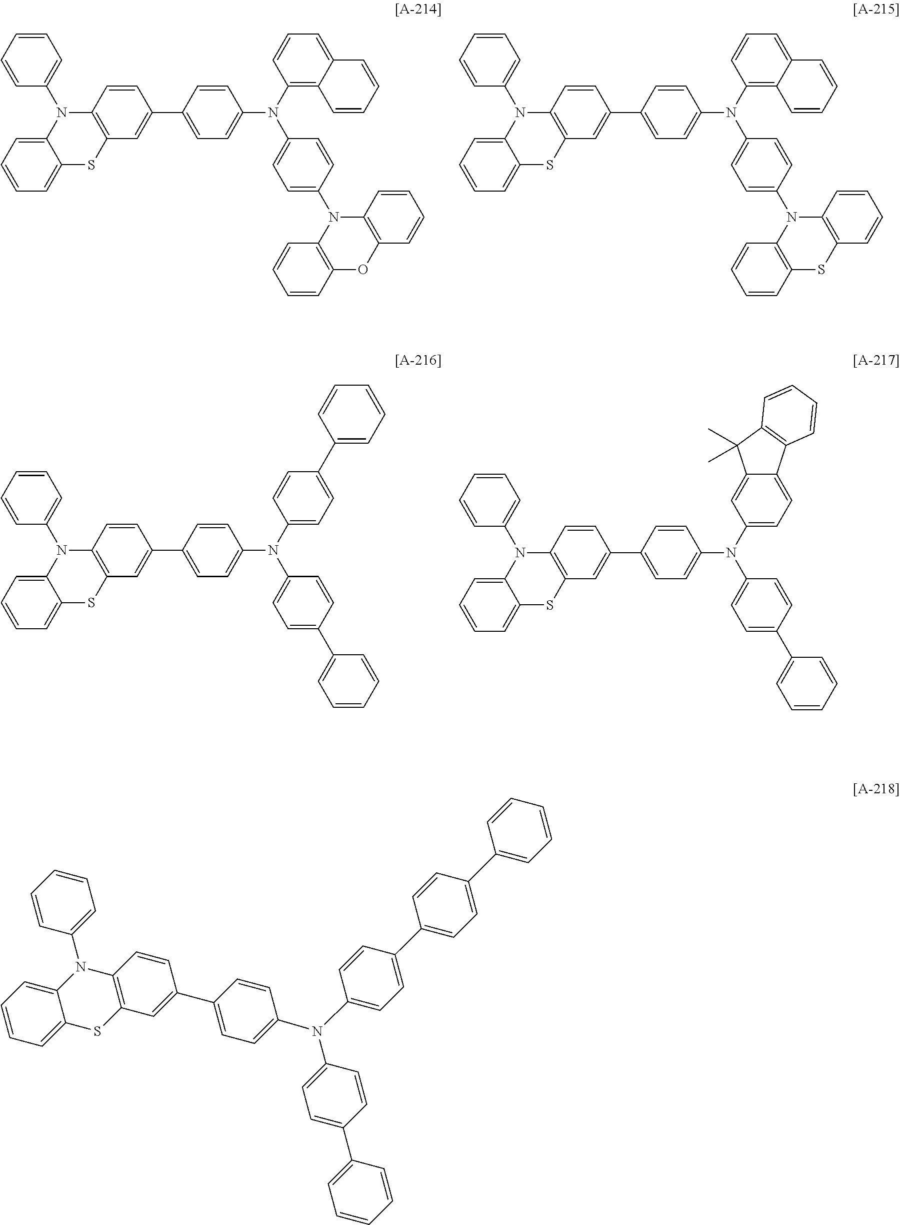 [SMILES: c1ccc(N2c3ccccc3Sc3cc(-c4ccc(N(c5ccc(N6c7ccccc7Oc7ccccc76)cc5)c5cccc6ccccc56)cc4)ccc32)cc1 ; c1ccc(N2c3ccccc3Sc3cc(-c4ccc(N(c5ccc(N6c7ccccc7Sc7ccccc76)cc5)c5cccc6ccccc56)cc4)ccc32)cc1 ; c1ccc(-c2ccc(N(c3ccc(-c4ccccc4)cc3)c3ccc(-c4ccc5c(c4)Sc4ccccc4N5c4ccccc4)cc3)cc2)cc1 ; CC1(C)c2ccccc2-c2ccc(N(c3ccc(-c4ccccc4)cc3)c3ccc(-c4ccc5c(c4)Sc4ccccc4N5c4ccccc4)cc3)cc21 ; c1ccc(-c2ccc(-c3ccc(N(c4ccc(-c5ccccc5)cc4)c4ccc(-c5ccc6c(c5)Sc5ccccc5N6c5ccccc5)cc4)cc3)cc2)cc1]

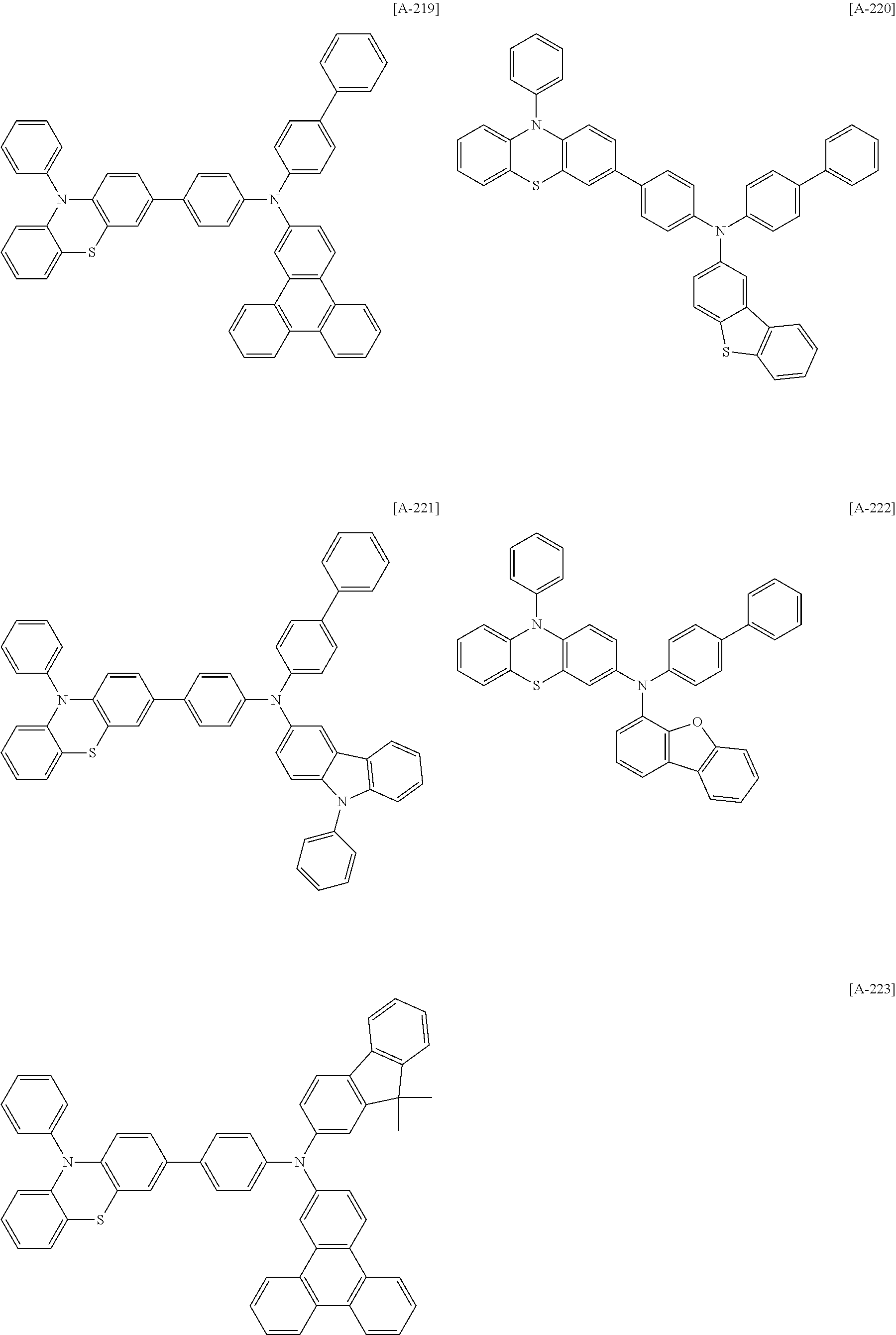 [SMILES: c1ccc(-c2ccc(N(c3ccc(-c4ccc5c(c4)Sc4ccccc4N5c4ccccc4)cc3)c3ccc4c5ccccc5c5ccccc5c4c3)cc2)cc1 ; c1ccc(-c2ccc(N(c3ccc(-c4ccc5c(c4)Sc4ccccc4N5c4ccccc4)cc3)c3ccc4sc5ccccc5c4c3)cc2)cc1 ; c1ccc(-c2ccc(N(c3ccc(-c4ccc5c(c4)Sc4ccccc4N5c4ccccc4)cc3)c3ccc4c(c3)c3ccccc3n4-c3ccccc3)cc2)cc1 ; c1ccc(-c2ccc(N(c3ccc4c(c3)Sc3ccccc3N4c3ccccc3)c3cccc4c3oc3ccccc34)cc2)cc1 ; CC1(C)c2ccccc2-c2ccc(N(c3ccc(-c4ccc5c(c4)Sc4ccccc4N5c4ccccc4)cc3)c3ccc4c5ccccc5c5ccccc5c4c3)cc21]

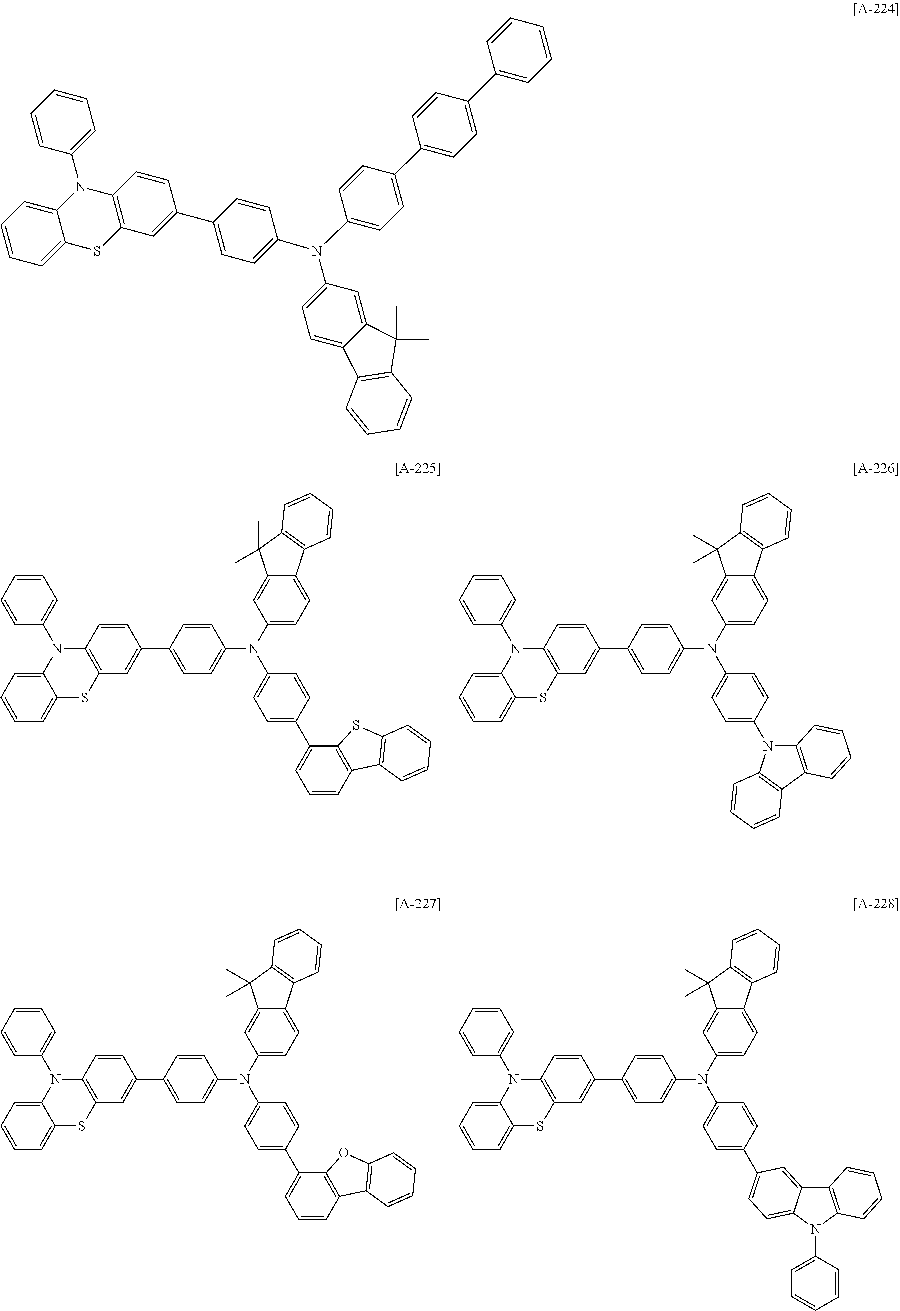

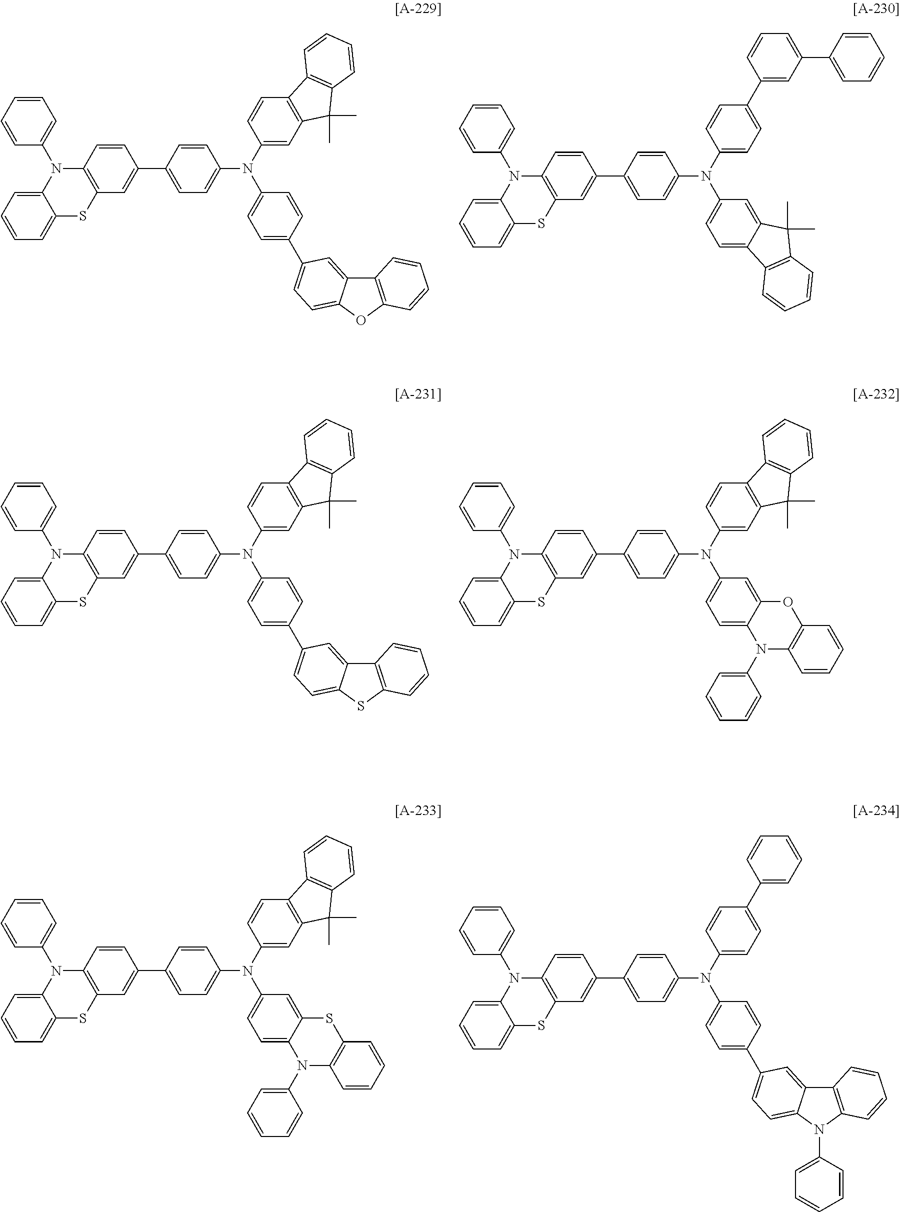

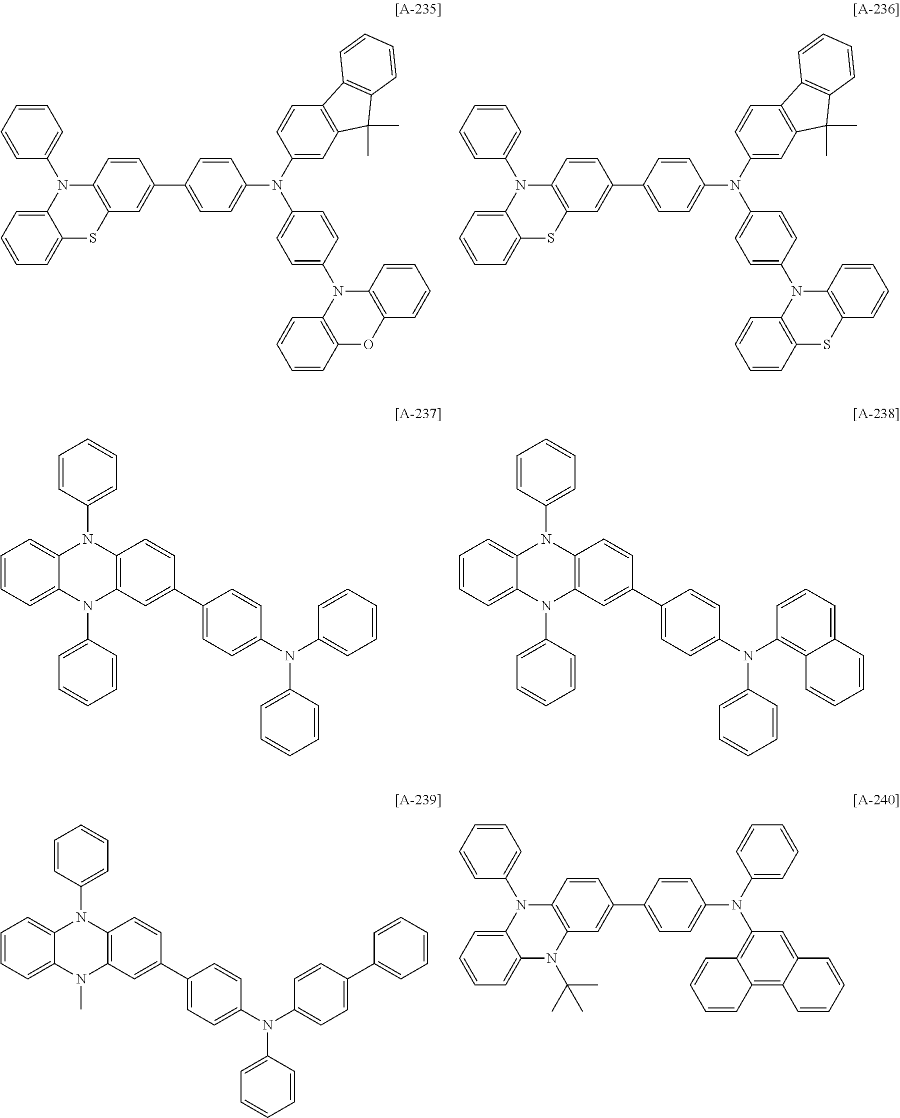

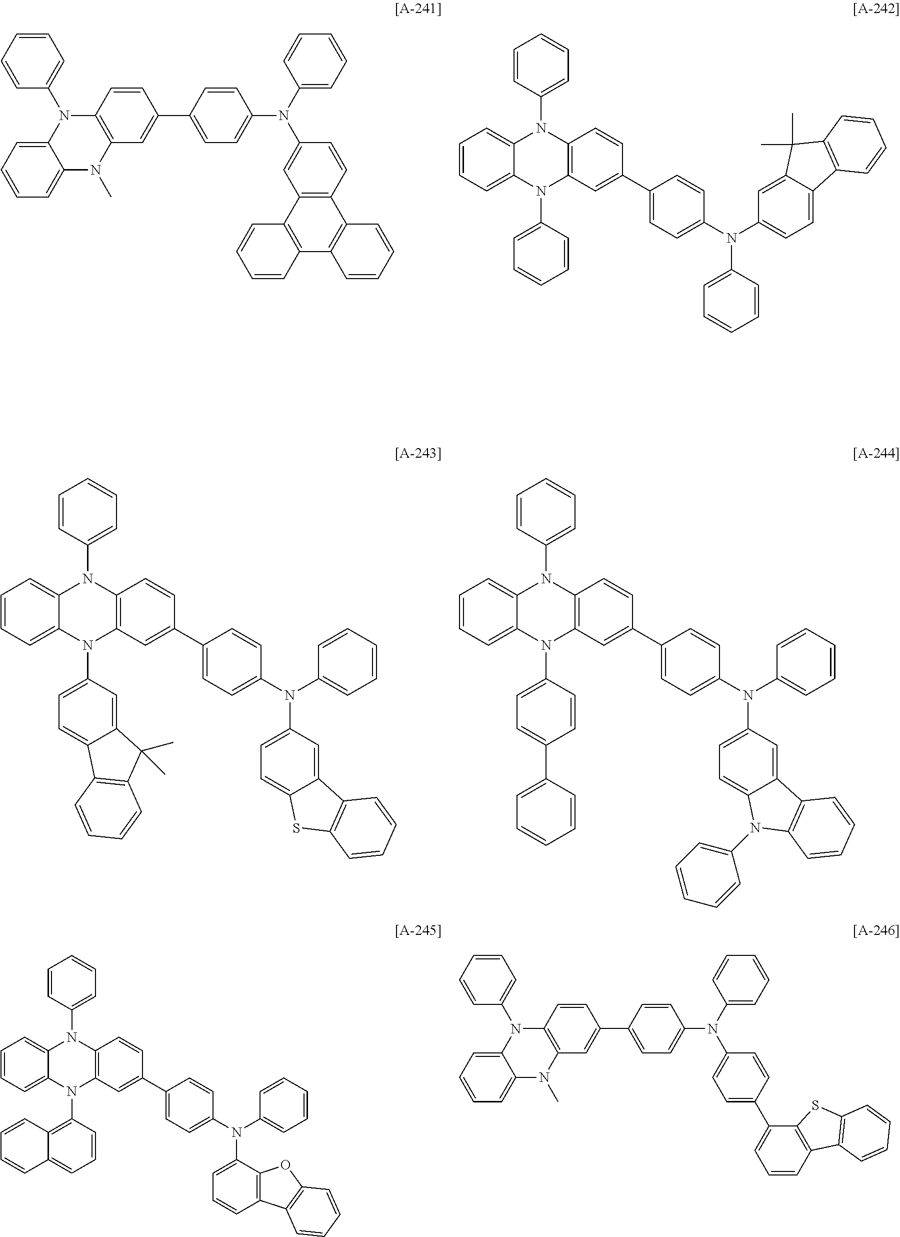

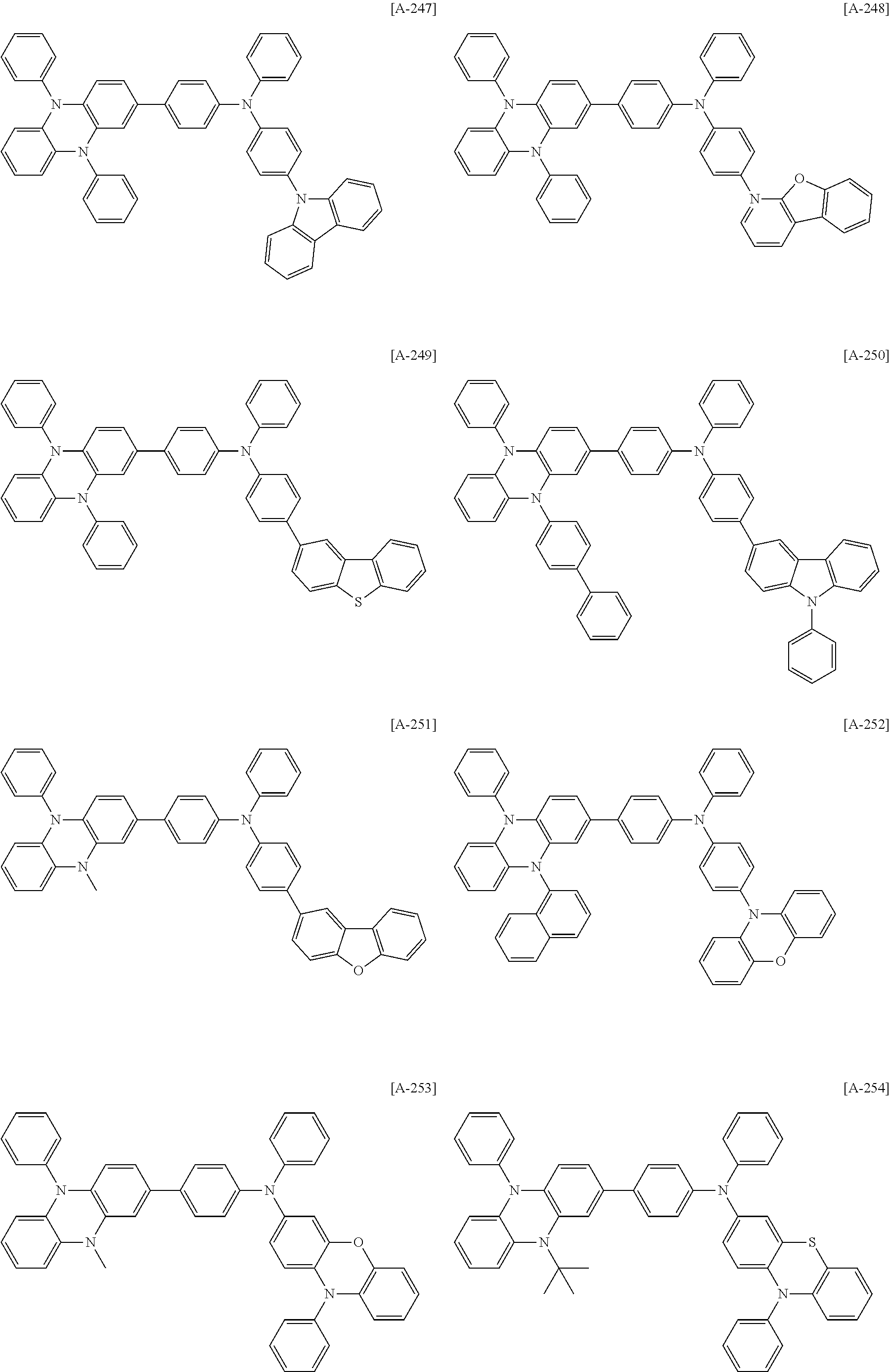

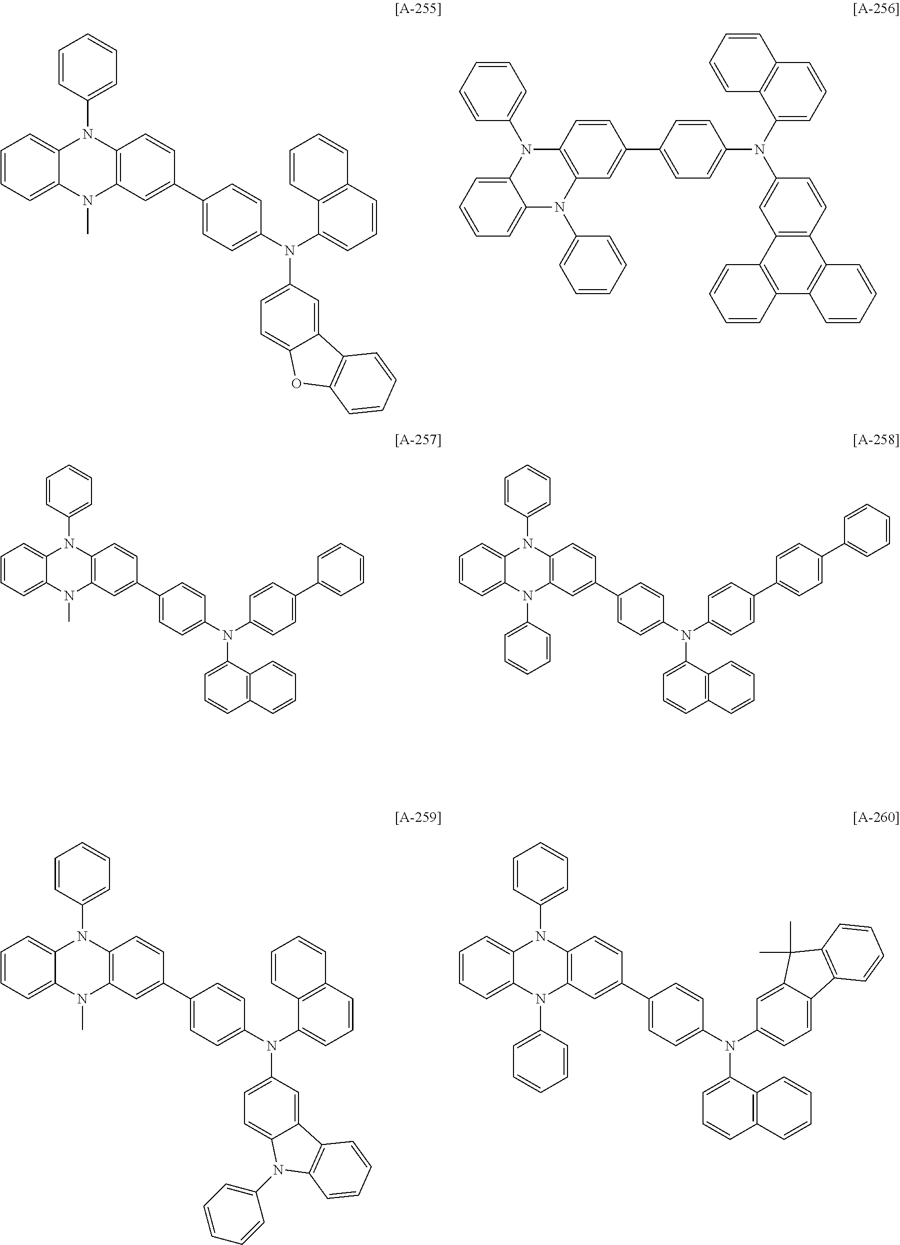

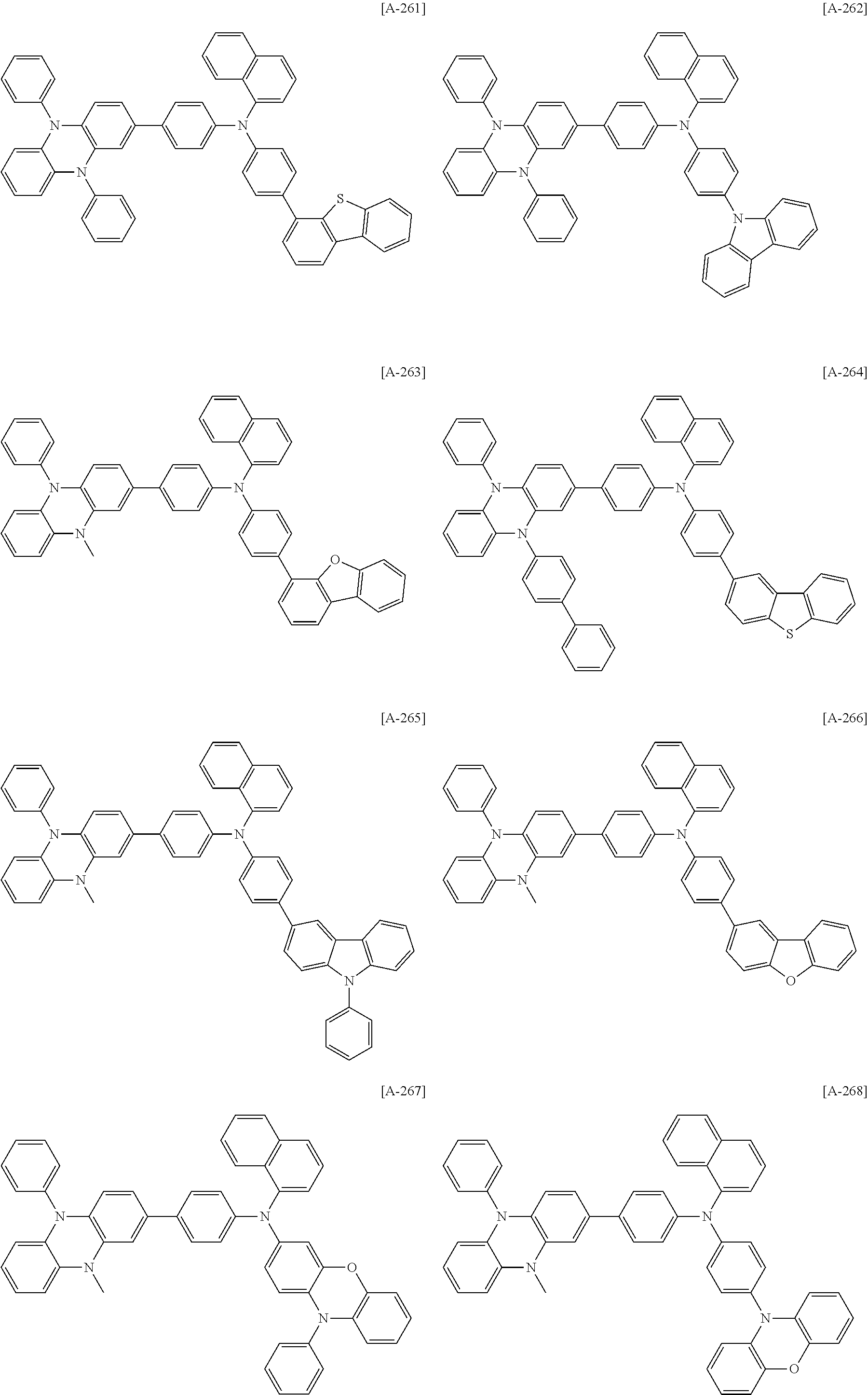

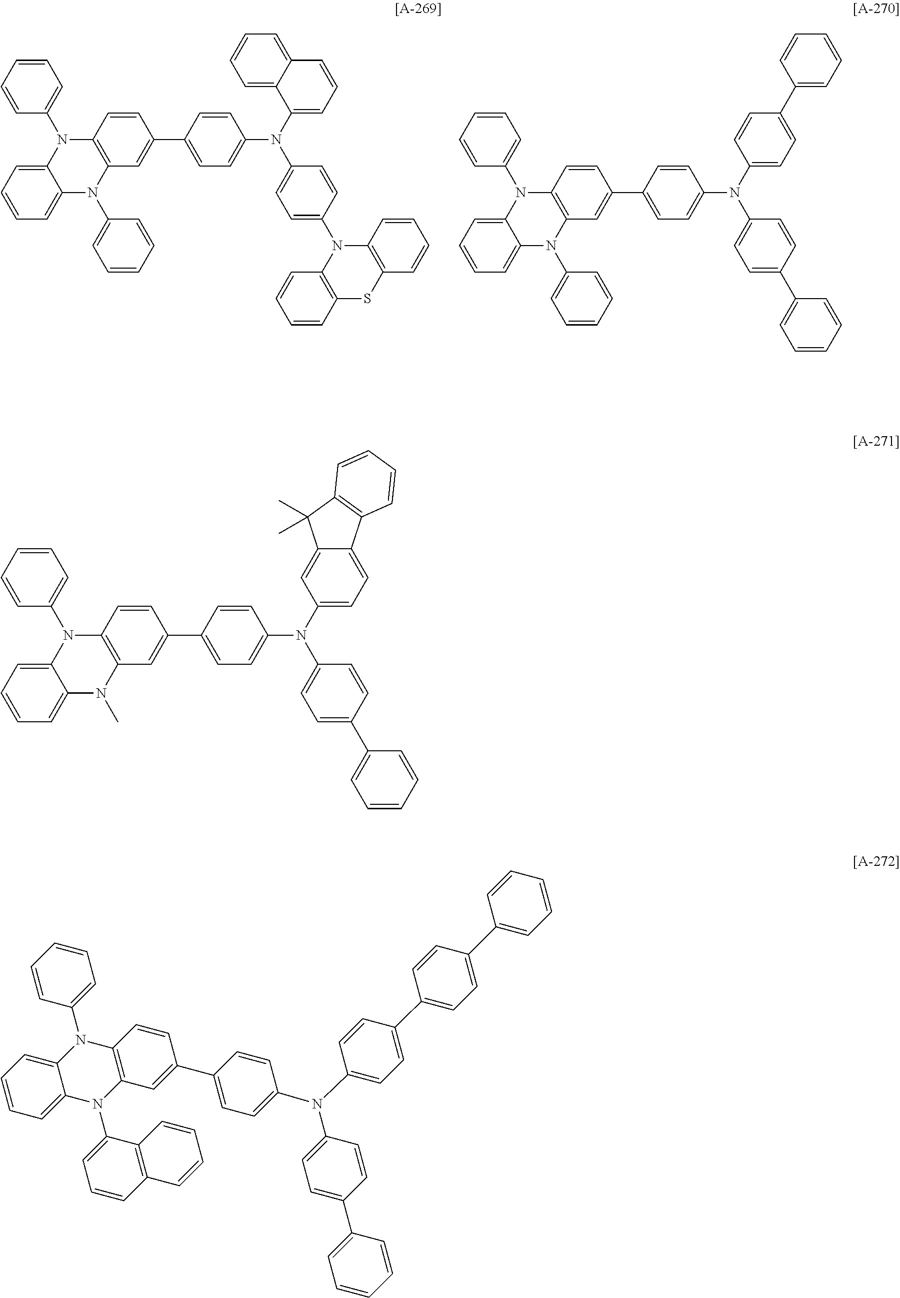

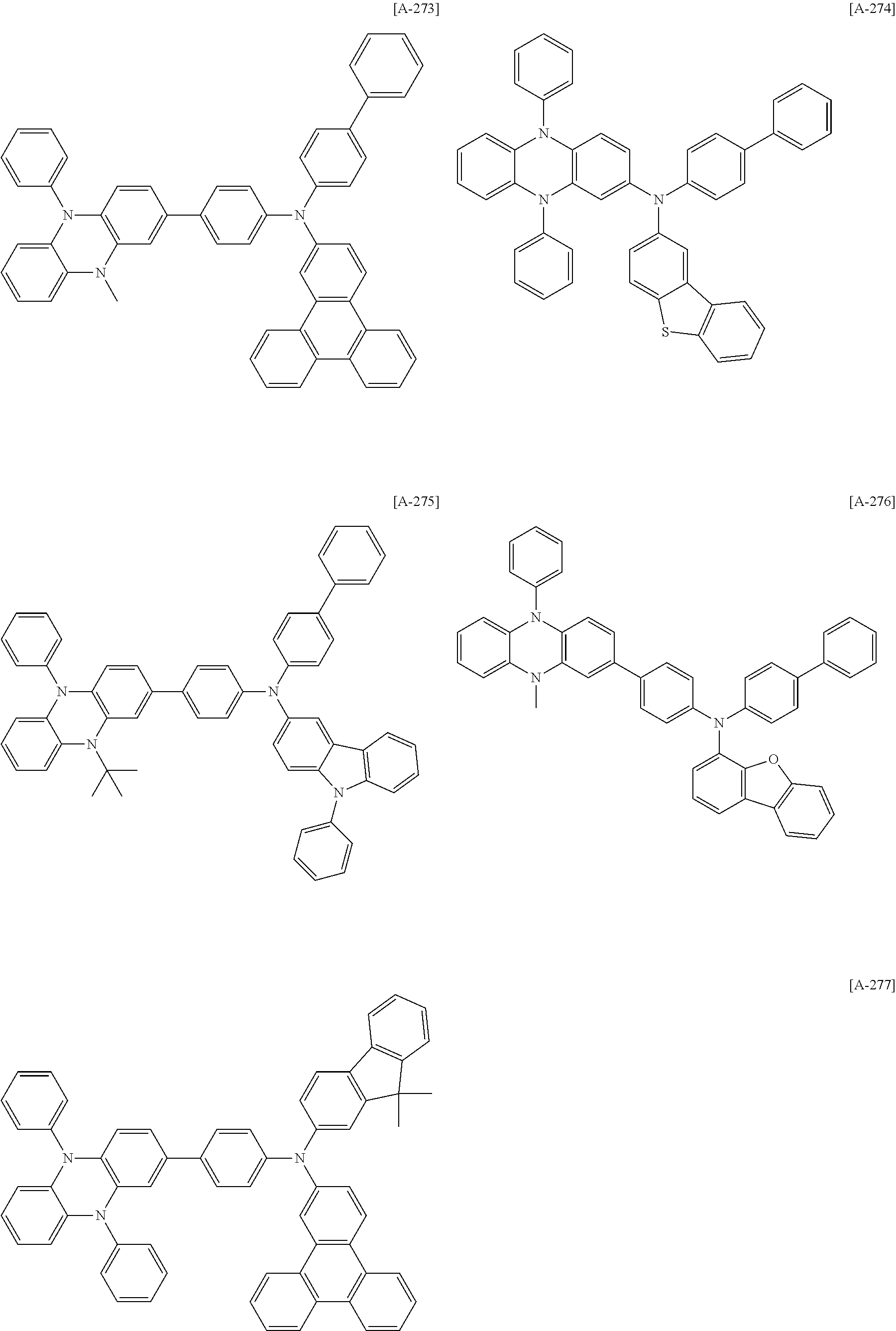 [SMILES: CN1c2ccccc2N(c2ccccc2)c2ccc(-c3ccc(N(c4ccc(-c5ccccc5)cc4)c4ccc5c6ccccc6c6ccccc6c5c4)cc3)cc21 ; c1ccc(-c2ccc(N(c3ccc4c(c3)N(c3ccccc3)c3ccccc3N4c3ccccc3)c3ccc4sc5ccccc5c4c3)cc2)cc1 ; CC(C)(C)N1c2ccccc2N(c2ccccc2)c2ccc(-c3ccc(N(c4ccc(-c5ccccc5)cc4)c4ccc5c(c4)c4ccccc4n5-c4ccccc4)cc3)cc21 ; CN1c2ccccc2N(c2ccccc2)c2ccc(-c3ccc(N(c4ccc(-c5ccccc5)cc4)c4cccc5c4oc4ccccc45)cc3)cc21 ; CC1(C)c2ccccc2-c2ccc(N(c3ccc(-c4ccc5c(c4)N(c4ccccc4)c4ccccc4N5c4ccccc4)cc3)c3ccc4c5ccccc5c5ccccc5c4c3)cc21]

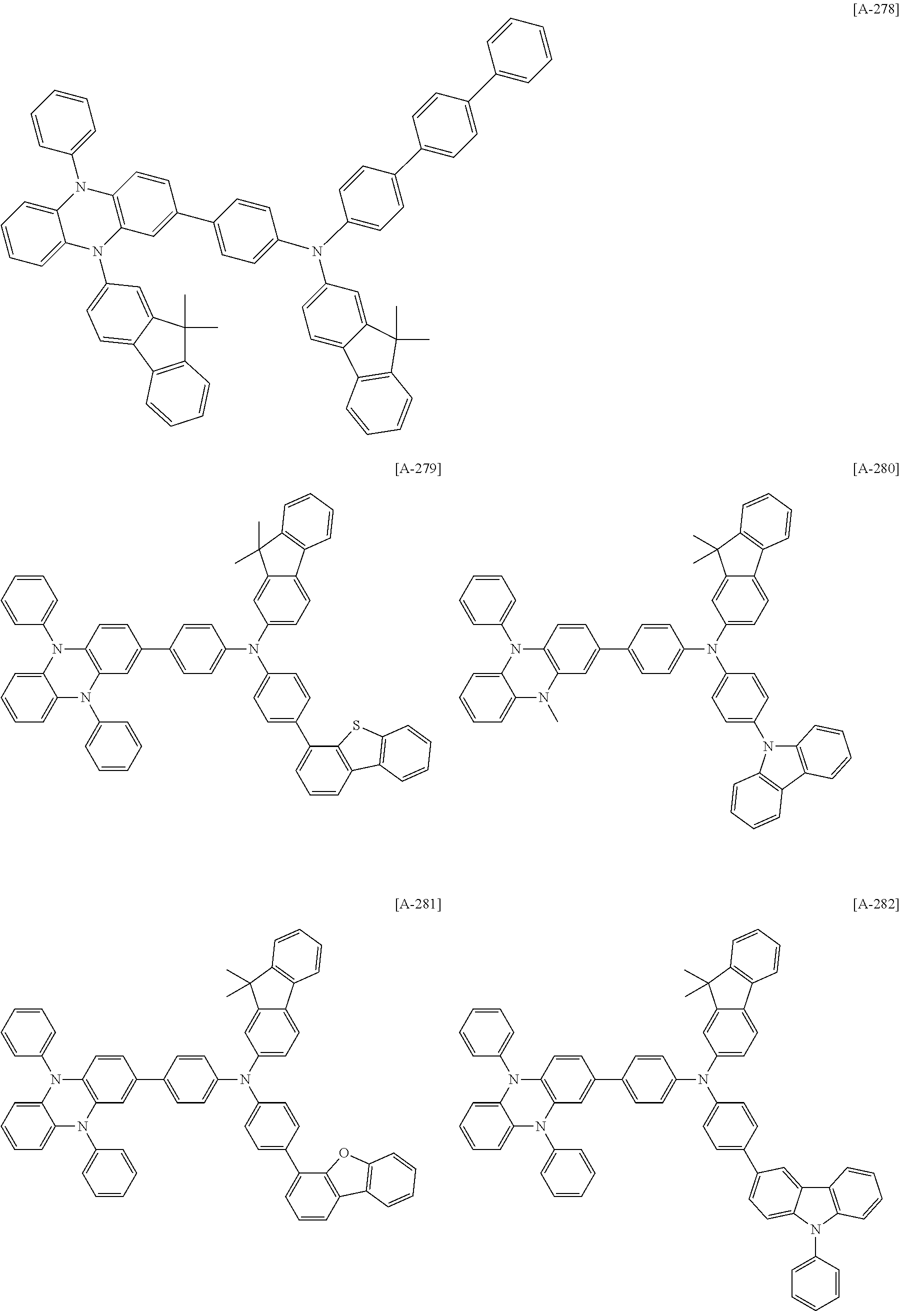

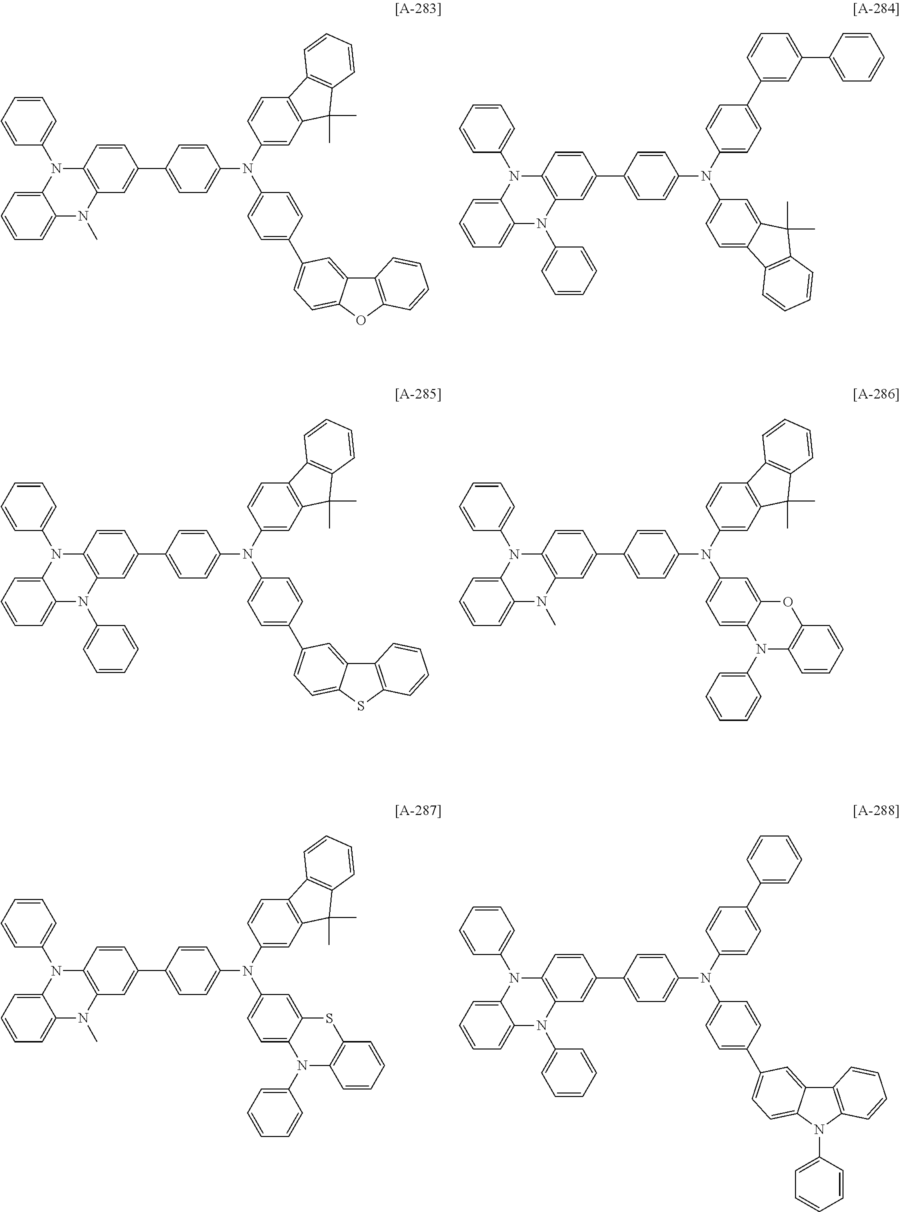

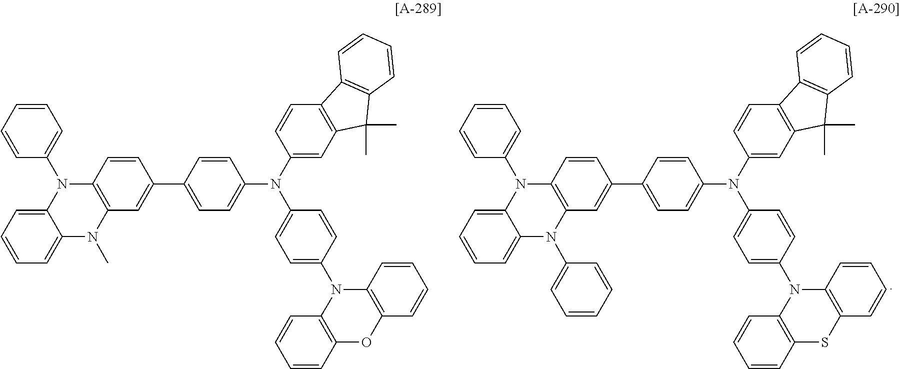 [SMILES: CN1c2ccccc2N(c2ccccc2)c2ccc(-c3ccc(N(c4ccc(N5c6ccccc6Oc6ccccc65)cc4)c4ccc5c(c4)C(C)(C)c4ccccc4-5)cc3)cc21 ; CC1(C)c2ccccc2-c2ccc(N(c3ccc(-c4ccc5c(c4)N(c4ccccc4)c4ccccc4N5c4ccccc4)cc3)c3ccc(N4c5ccccc5Sc5ccccc54)cc3)cc21]

The compound for an organic optoelectronic device may be represented by one of the following Chemical Formulae B-1 to B-81, but is not limited thereto.

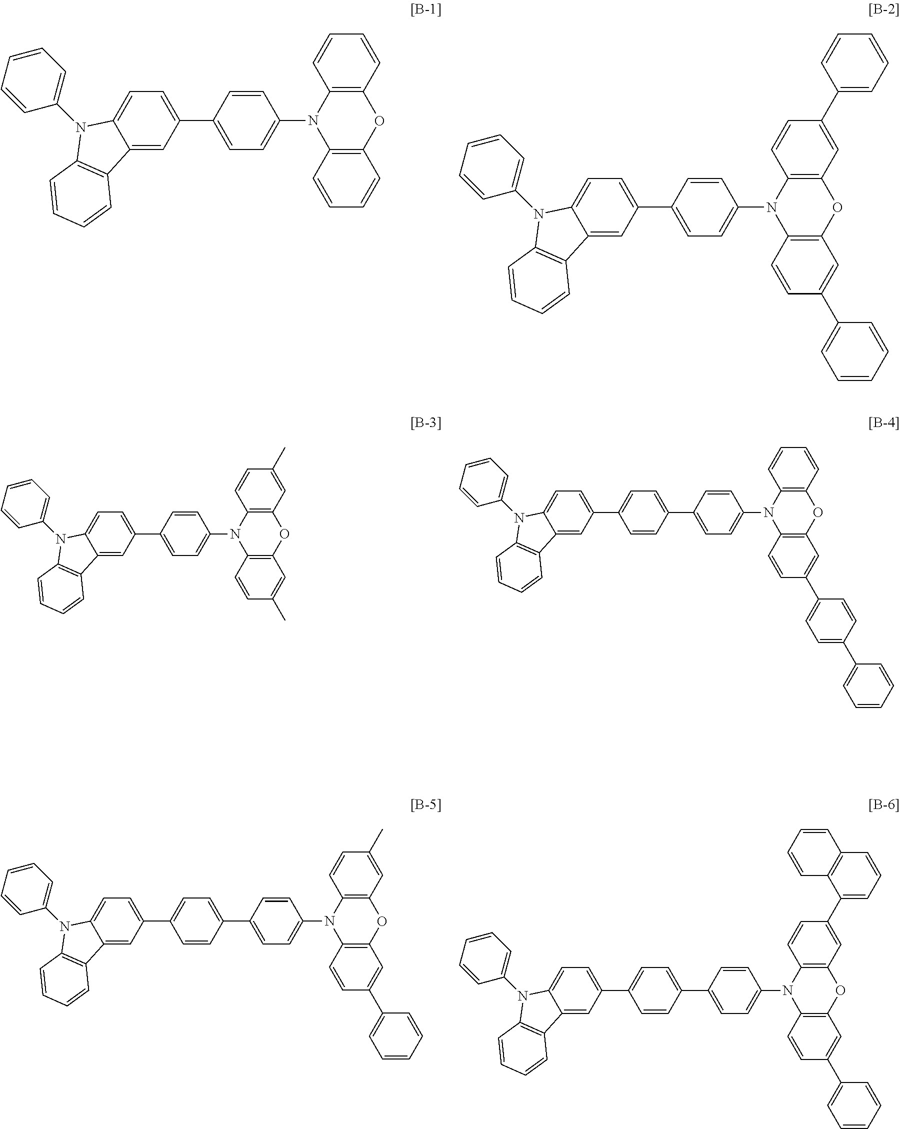

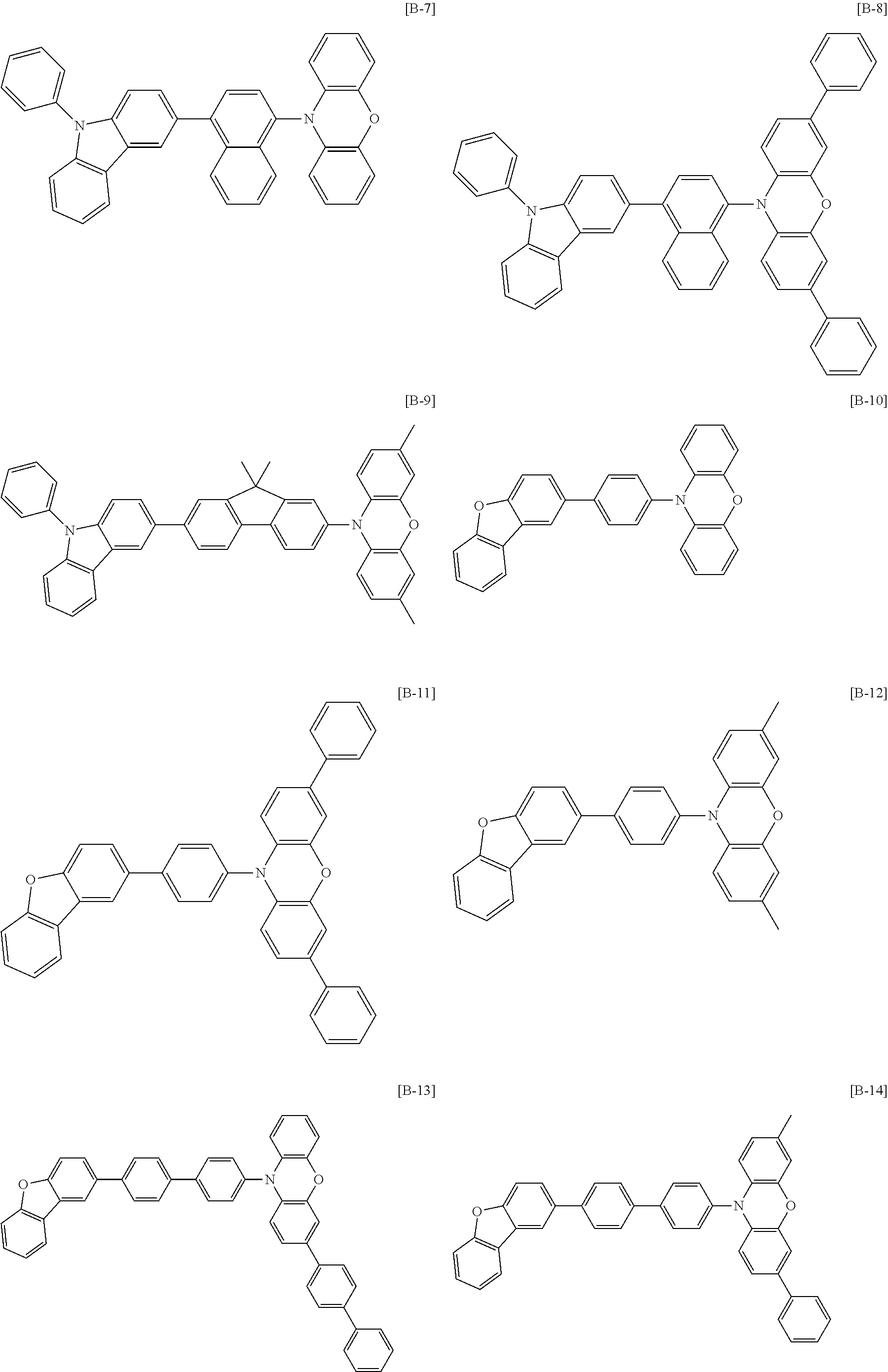

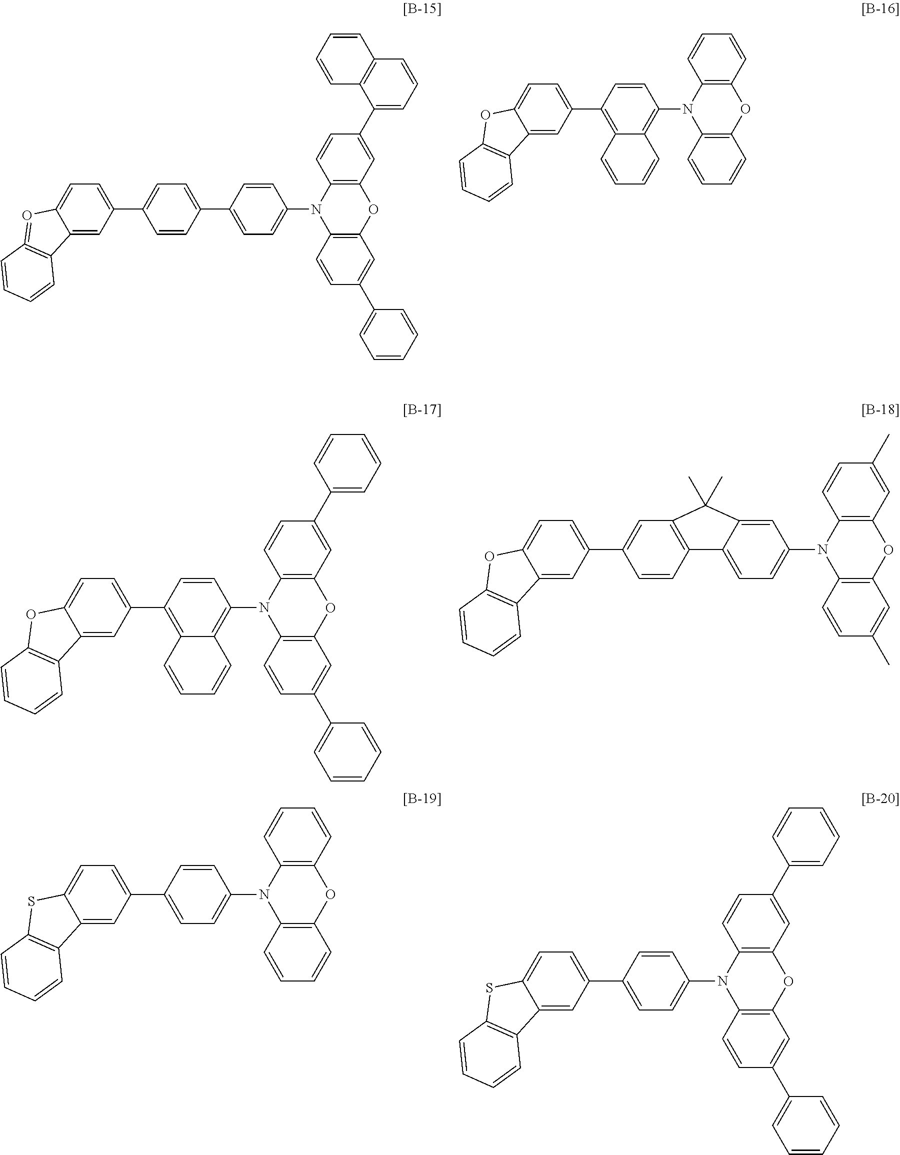

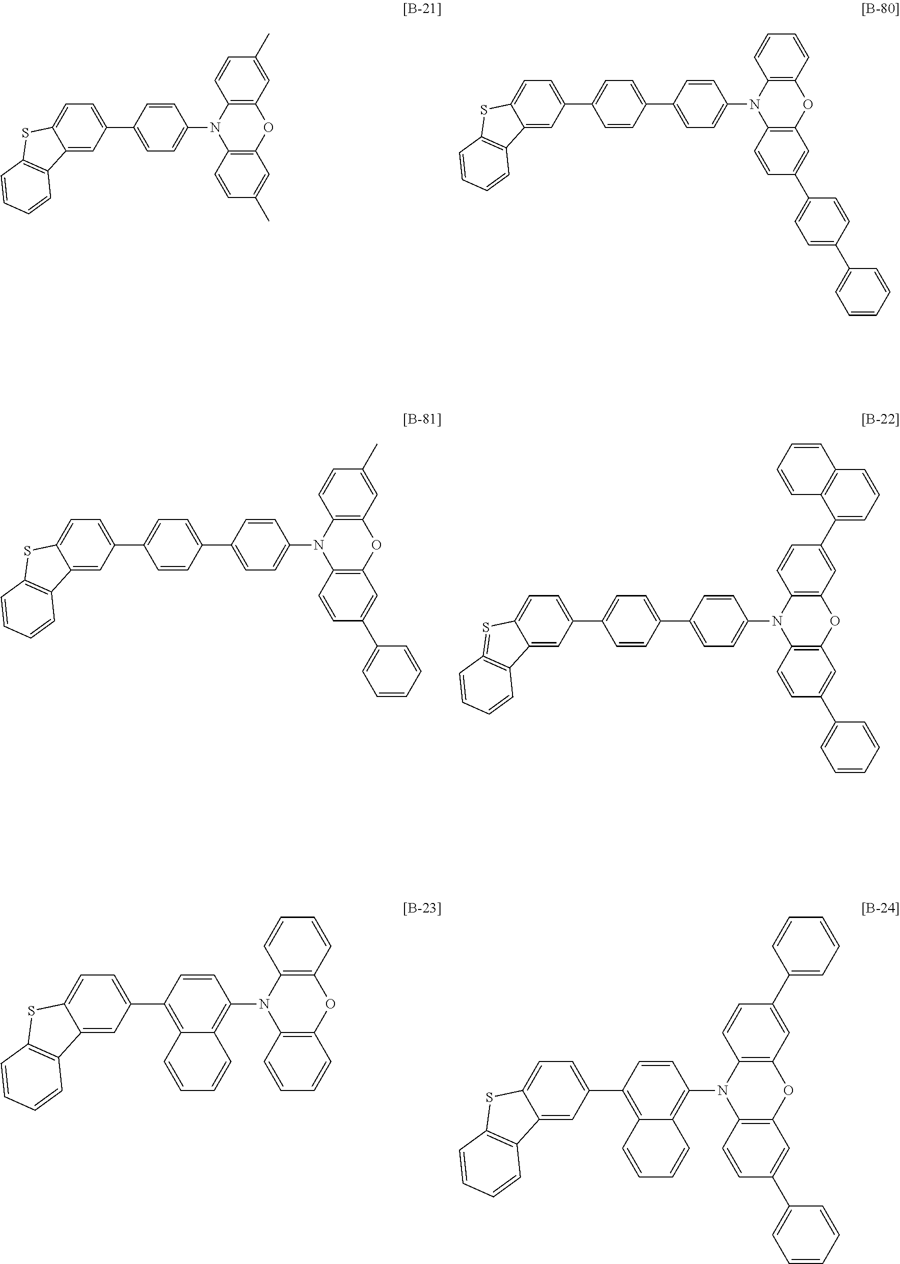

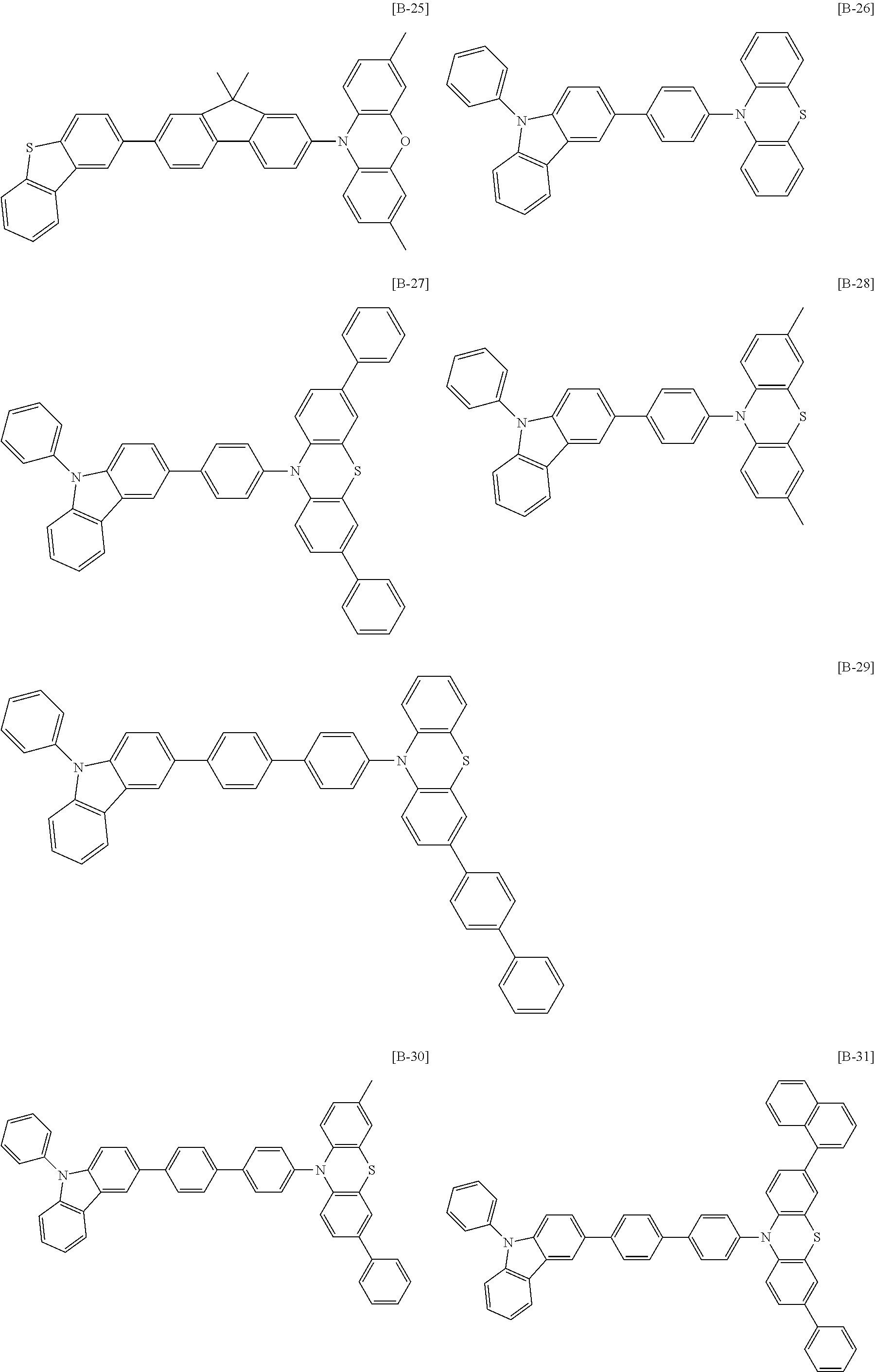

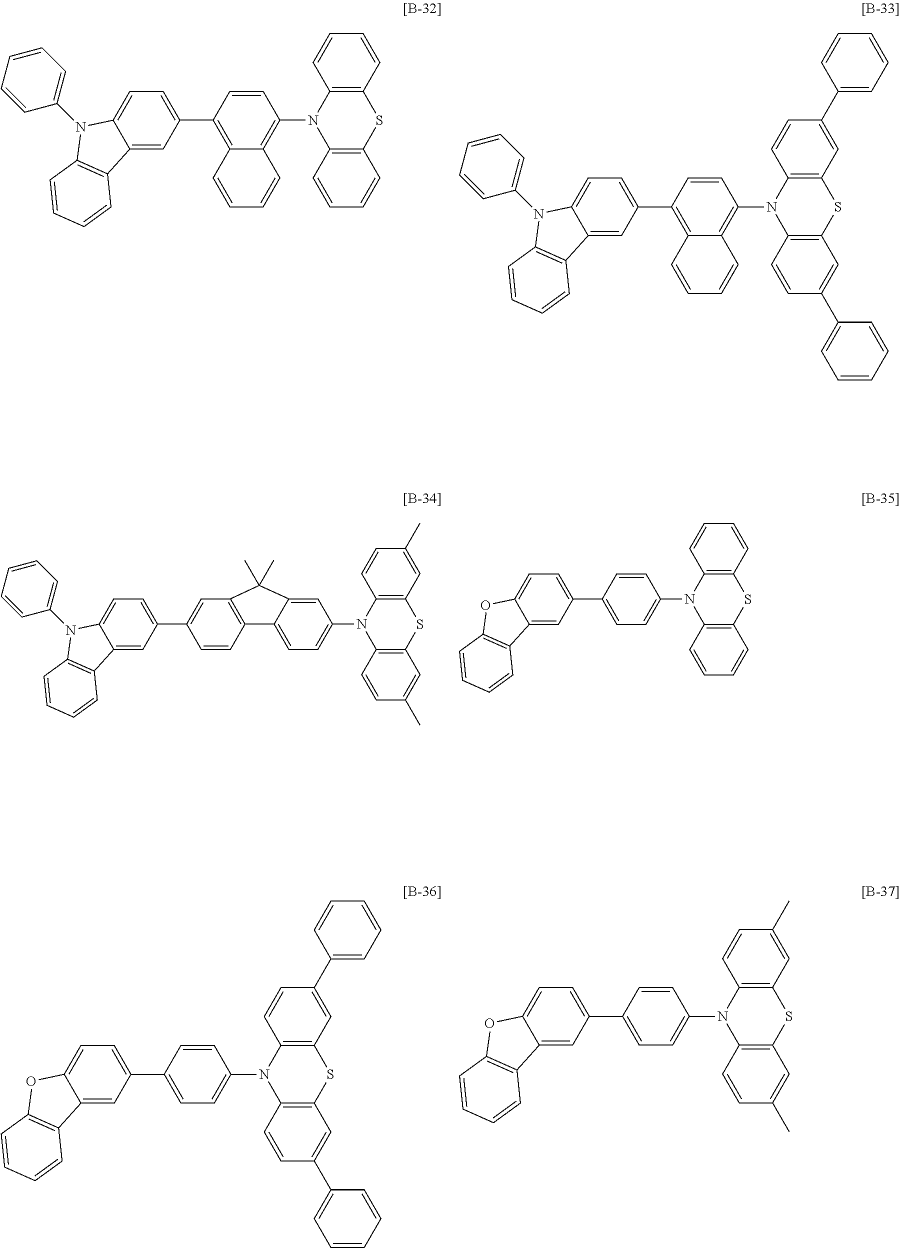

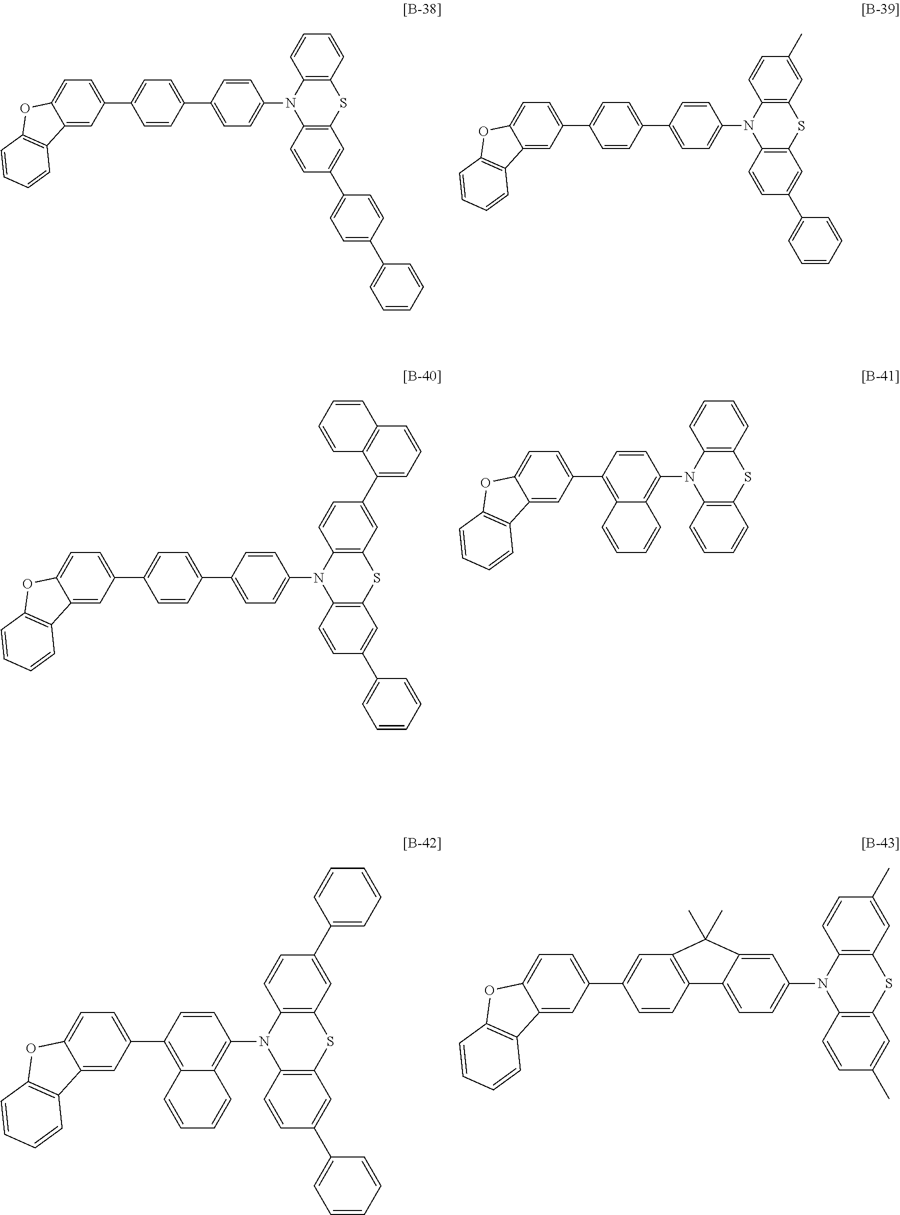 [SMILES: c1ccc(-c2ccc(-c3ccc4c(c3)Sc3ccccc3N4c3ccc(-c4ccc(-c5ccc6oc7ccccc7c6c5)cc4)cc3)cc2)cc1 ; Cc1ccc2c(c1)Sc1cc(-c3ccccc3)ccc1N2c1ccc(-c2ccc(-c3ccc4oc5ccccc5c4c3)cc2)cc1 ; c1ccc(-c2ccc3c(c2)Sc2cc(-c4cccc5ccccc45)ccc2N3c2ccc(-c3ccc(-c4ccc5oc6ccccc6c5c4)cc3)cc2)cc1 ; c1ccc2c(c1)Sc1ccccc1N2c1ccc(-c2ccc3oc4ccccc4c3c2)c2ccccc12 ; c1ccc(-c2ccc3c(c2)Sc2cc(-c4ccccc4)ccc2N3c2ccc(-c3ccc4oc5ccccc5c4c3)c3ccccc23)cc1 ; Cc1ccc2c(c1)Sc1cc(C)ccc1N2c1ccc2c(c1)C(C)(C)c1cc(-c3ccc4oc5ccccc5c4c3)ccc1-2]

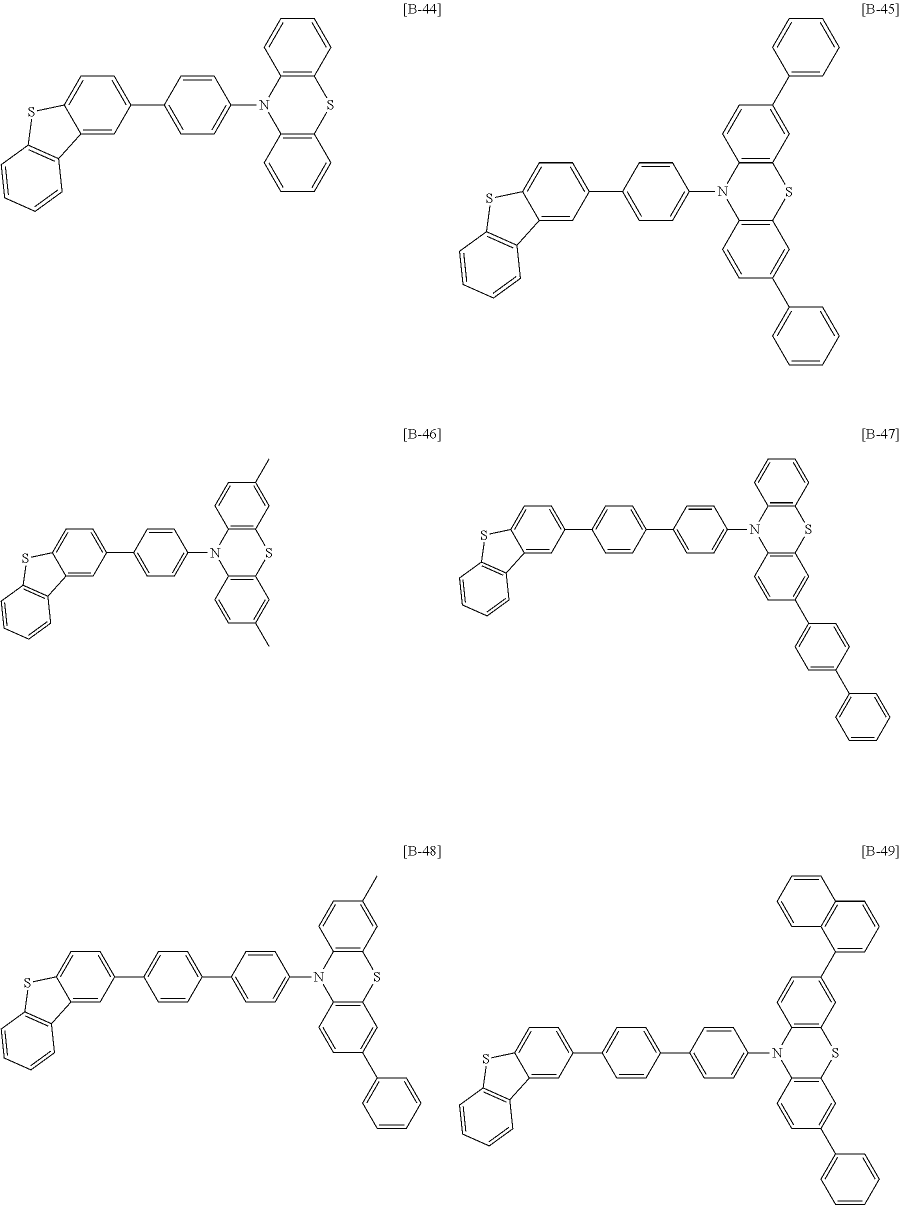

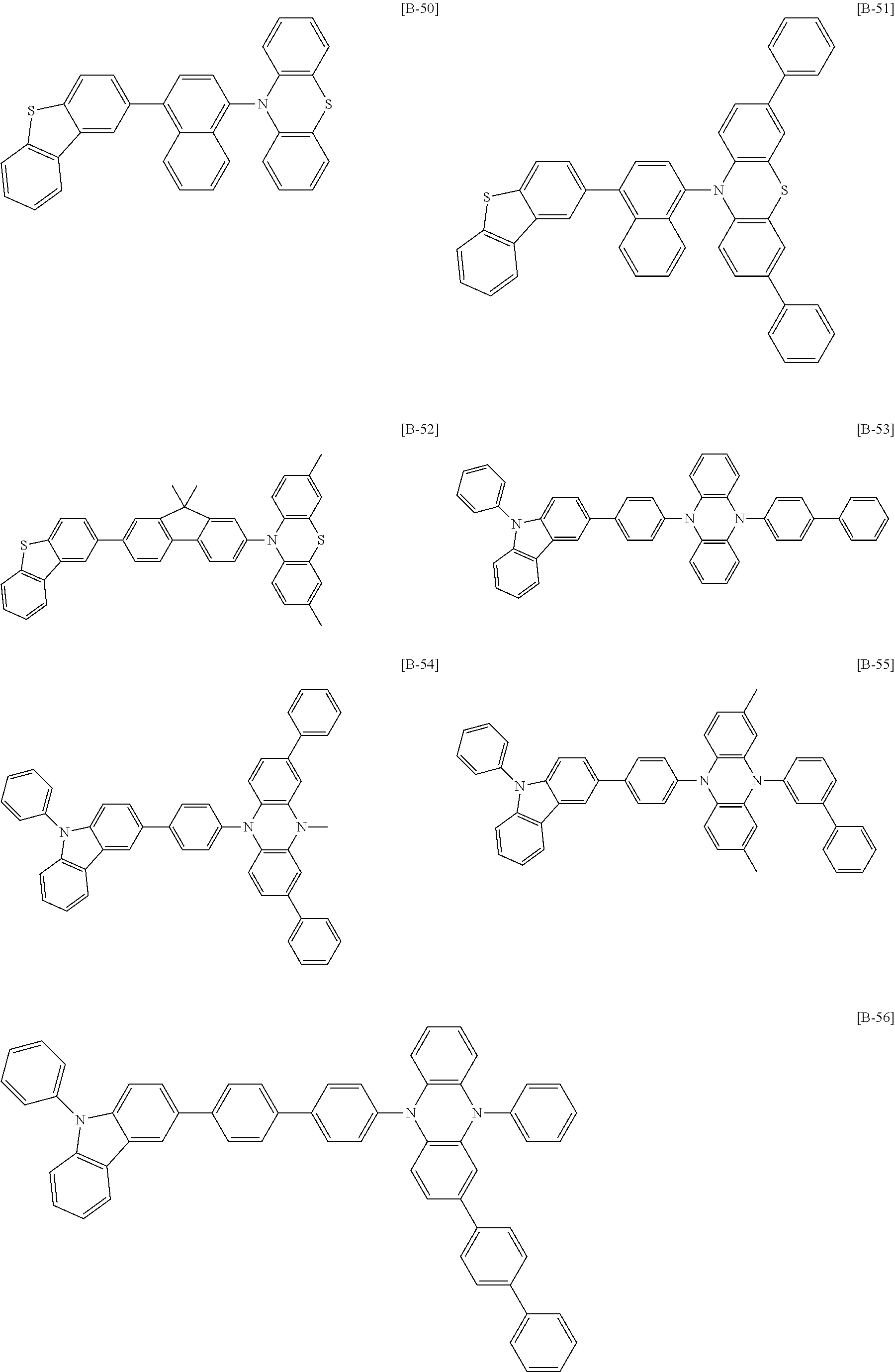

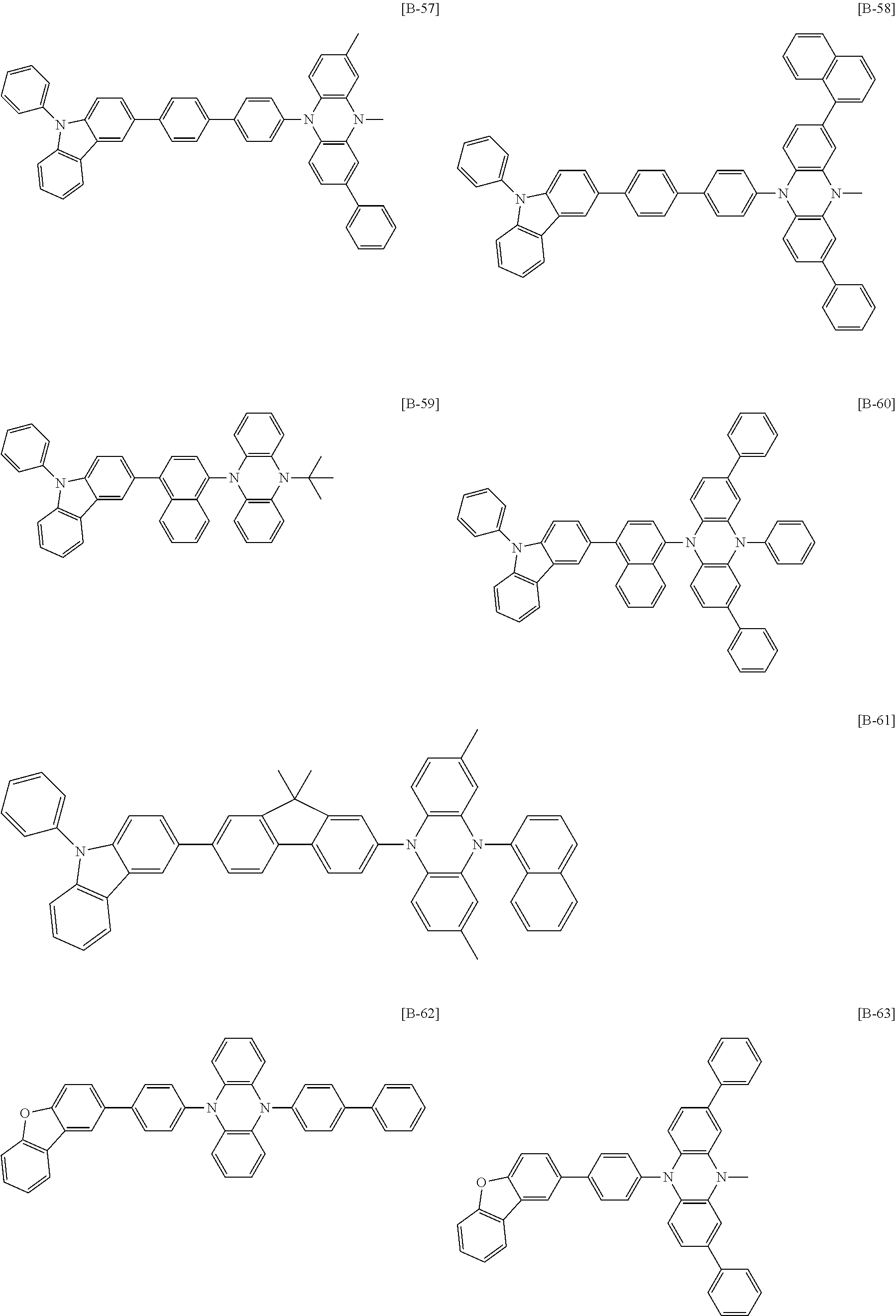

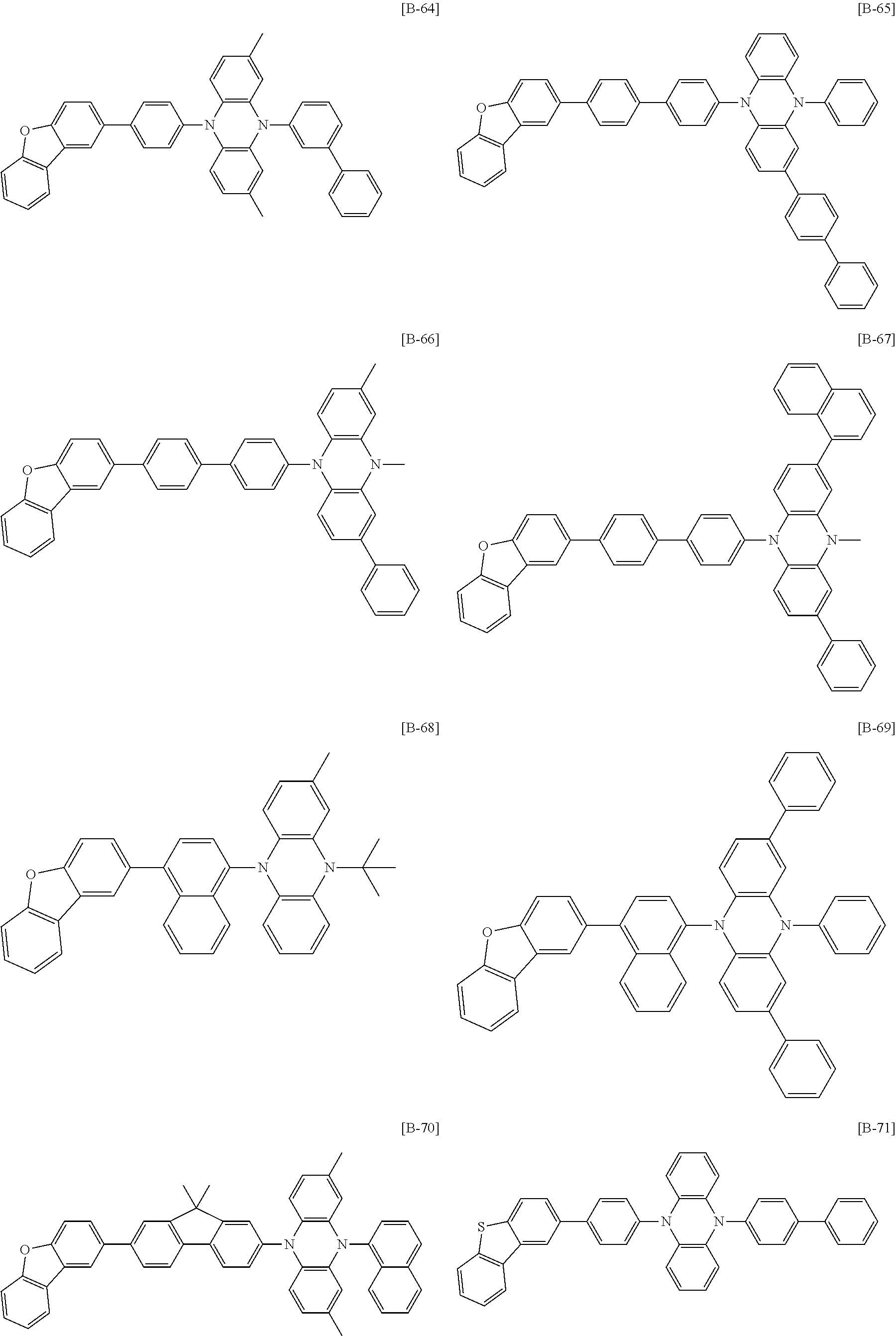

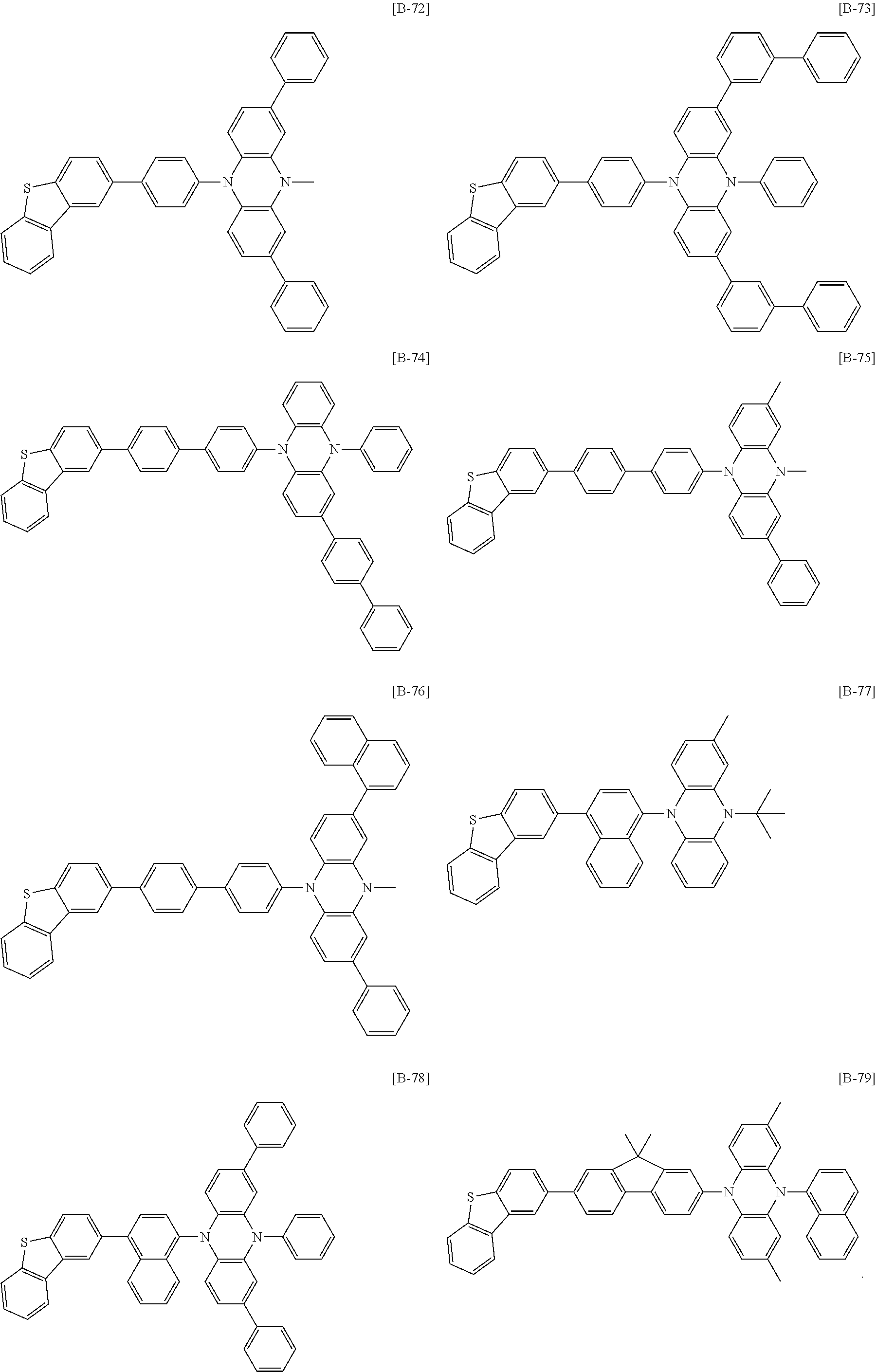

The compound for an organic optoelectronic device may be represented by the following Chemical Formulae C-1 to C-54, but is not limited thereto.

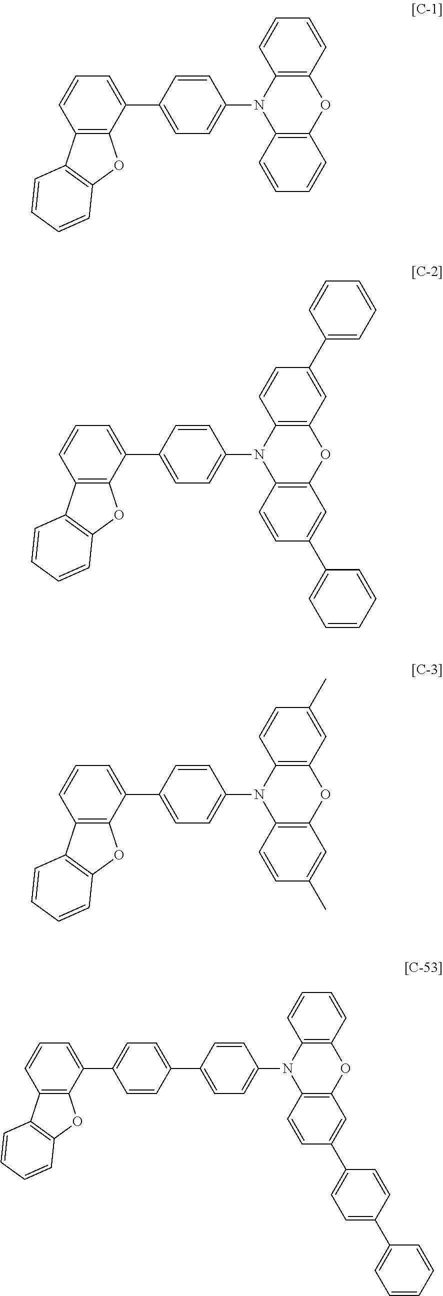 [SMILES: c1ccc2c(c1)Oc1ccccc1N2c1ccc(-c2cccc3c2oc2ccccc23)cc1 ; c1ccc(-c2ccc3c(c2)Oc2cc(-c4ccccc4)ccc2N3c2ccc(-c3cccc4c3oc3ccccc34)cc2)cc1 ; Cc1ccc2c(c1)Oc1cc(C)ccc1N2c1ccc(-c2cccc3c2oc2ccccc23)cc1 ; c1ccc(-c2ccc(-c3ccc4c(c3)Oc3ccccc3N4c3ccc(-c4ccc(-c5cccc6c5oc5ccccc56)cc4)cc3)cc2)cc1]

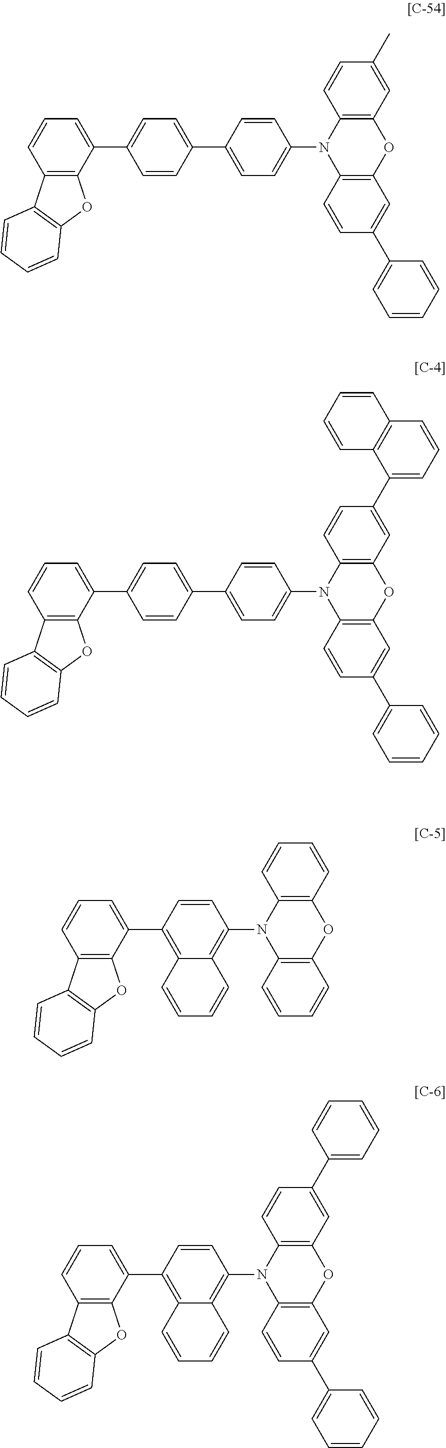 [SMILES: Cc1ccc2c(c1)Oc1cc(-c3ccccc3)ccc1N2c1ccc(-c2ccc(-c3cccc4c3oc3ccccc34)cc2)cc1 ; c1ccc(-c2ccc3c(c2)Oc2cc(-c4cccc5ccccc45)ccc2N3c2ccc(-c3ccc(-c4cccc5c4oc4ccccc45)cc3)cc2)cc1 ; c1ccc2c(c1)Oc1ccccc1N2c1ccc(-c2cccc3c2oc2ccccc23)c2ccccc12 ; c1ccc(-c2ccc3c(c2)Oc2cc(-c4ccccc4)ccc2N3c2ccc(-c3cccc4c3oc3ccccc34)c3ccccc23)cc1]

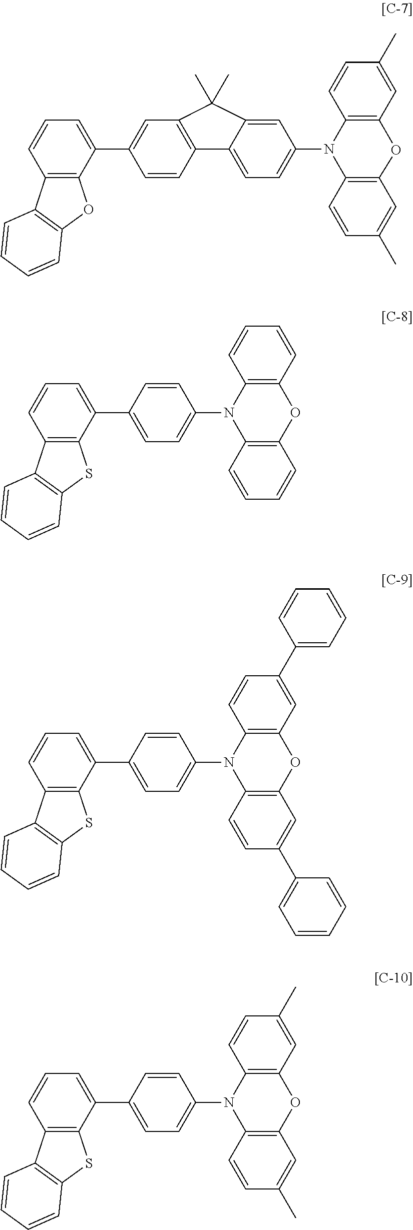 [SMILES: Cc1ccc2c(c1)Oc1cc(C)ccc1N2c1ccc2c(c1)C(C)(C)c1cc(-c3cccc4c3oc3ccccc34)ccc1-2 ; c1ccc2c(c1)Oc1ccccc1N2c1ccc(-c2cccc3c2sc2ccccc23)cc1 ; c1ccc(-c2ccc3c(c2)Oc2cc(-c4ccccc4)ccc2N3c2ccc(-c3cccc4c3sc3ccccc34)cc2)cc1 ; Cc1ccc2c(c1)Oc1cc(C)ccc1N2c1ccc(-c2cccc3c2sc2ccccc23)cc1]

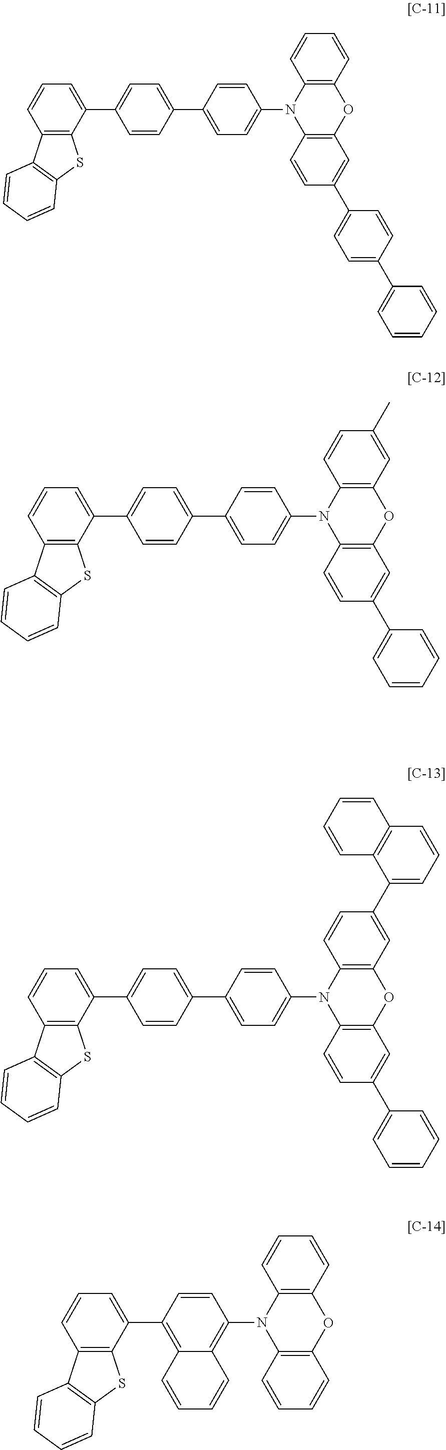 [SMILES: c1ccc(-c2ccc(-c3ccc4c(c3)Oc3ccccc3N4c3ccc(-c4ccc(-c5cccc6c5sc5ccccc56)cc4)cc3)cc2)cc1 ; Cc1ccc2c(c1)Oc1cc(-c3ccccc3)ccc1N2c1ccc(-c2ccc(-c3cccc4c3sc3ccccc34)cc2)cc1 ; c1ccc(-c2ccc3c(c2)Oc2cc(-c4cccc5ccccc45)ccc2N3c2ccc(-c3ccc(-c4cccc5c4sc4ccccc45)cc3)cc2)cc1 ; c1ccc2c(c1)Oc1ccccc1N2c1ccc(-c2cccc3c2sc2ccccc23)c2ccccc12]

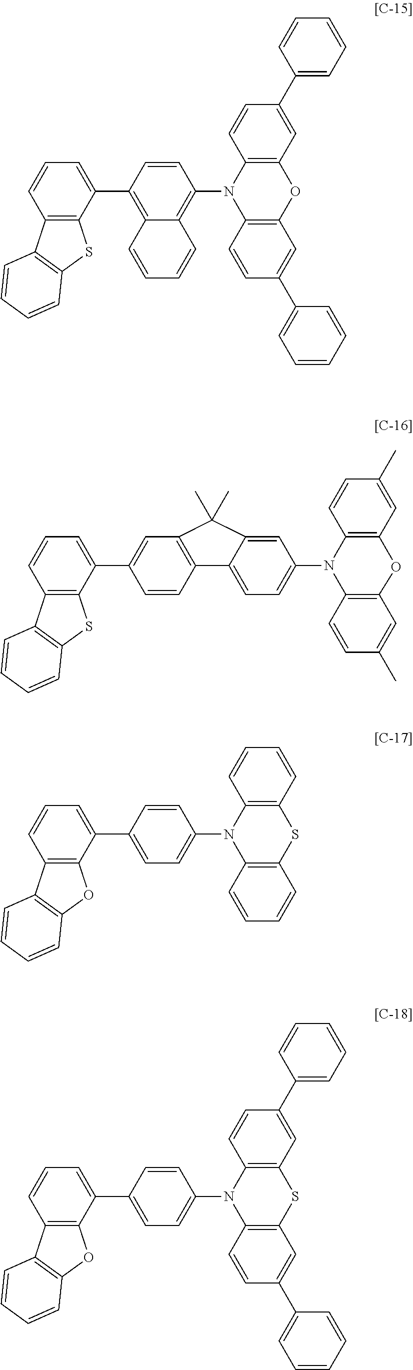 [SMILES: c1ccc(-c2ccc3c(c2)Oc2cc(-c4ccccc4)ccc2N3c2ccc(-c3cccc4c3sc3ccccc34)c3ccccc23)cc1 ; Cc1ccc2c(c1)Oc1cc(C)ccc1N2c1ccc2c(c1)C(C)(C)c1cc(-c3cccc4c3sc3ccccc34)ccc1-2 ; c1ccc2c(c1)Sc1ccccc1N2c1ccc(-c2cccc3c2oc2ccccc23)cc1 ; c1ccc(-c2ccc3c(c2)Sc2cc(-c4ccccc4)ccc2N3c2ccc(-c3cccc4c3oc3ccccc34)cc2)cc1]

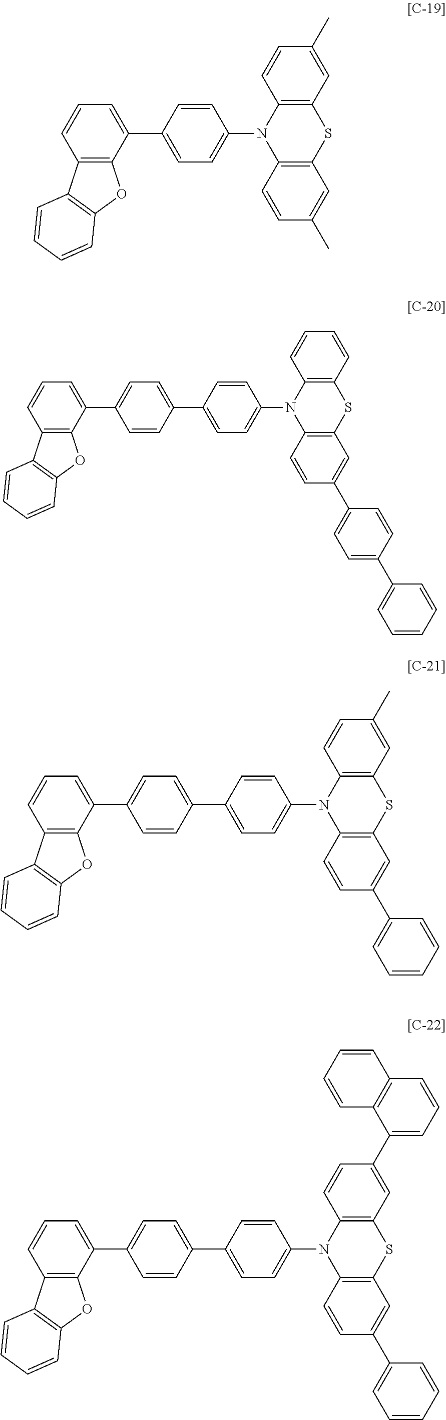 [SMILES: Cc1ccc2c(c1)Sc1cc(C)ccc1N2c1ccc(-c2cccc3c2oc2ccccc23)cc1 ; c1ccc(-c2ccc(-c3ccc4c(c3)Sc3ccccc3N4c3ccc(-c4ccc(-c5cccc6c5oc5ccccc56)cc4)cc3)cc2)cc1 ; Cc1ccc2c(c1)Sc1cc(-c3ccccc3)ccc1N2c1ccc(-c2ccc(-c3cccc4c3oc3ccccc34)cc2)cc1 ; c1ccc(-c2ccc3c(c2)Sc2cc(-c4cccc5ccccc45)ccc2N3c2ccc(-c3ccc(-c4cccc5c4oc4ccccc45)cc3)cc2)cc1]

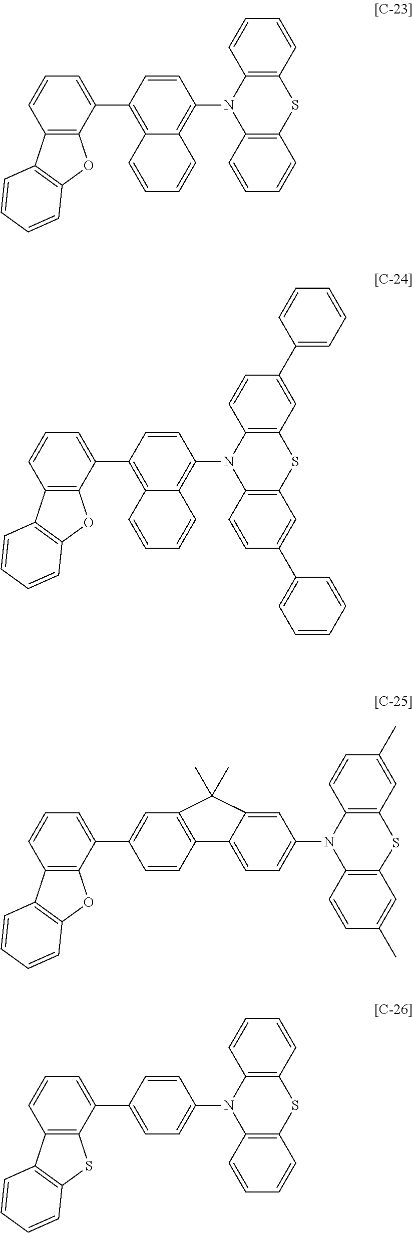 [SMILES: c1ccc2c(c1)Sc1ccccc1N2c1ccc(-c2cccc3c2oc2ccccc23)c2ccccc12 ; c1ccc(-c2ccc3c(c2)Sc2cc(-c4ccccc4)ccc2N3c2ccc(-c3cccc4c3oc3ccccc34)c3ccccc23)cc1 ; Cc1ccc2c(c1)Sc1cc(C)ccc1N2c1ccc2c(c1)C(C)(C)c1cc(-c3cccc4c3oc3ccccc34)ccc1-2 ; c1ccc2c(c1)Sc1ccccc1N2c1ccc(-c2cccc3c2sc2ccccc23)cc1]

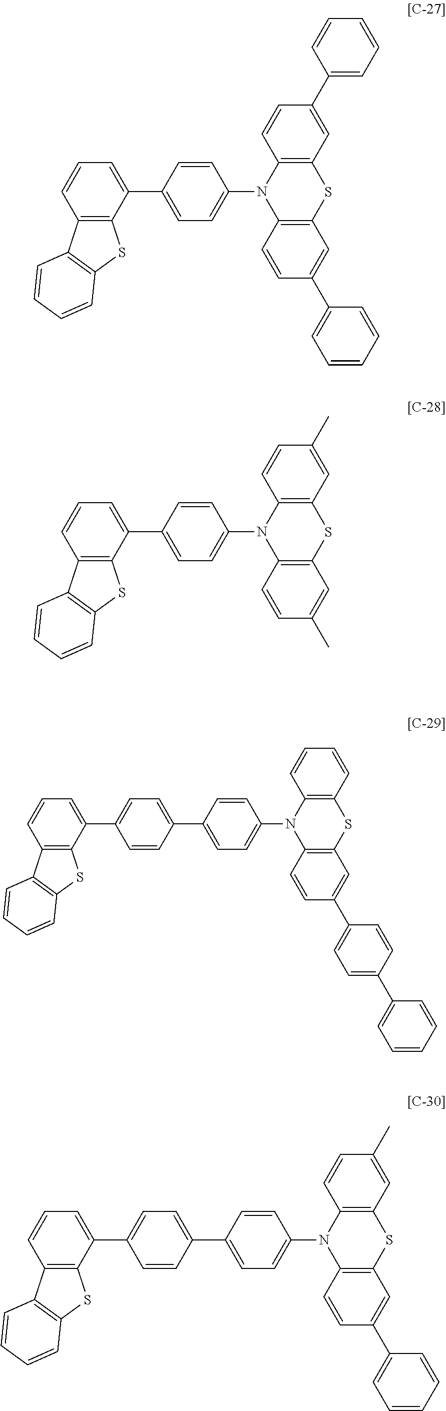 [SMILES: c1ccc(-c2ccc3c(c2)Sc2cc(-c4ccccc4)ccc2N3c2ccc(-c3cccc4c3sc3ccccc34)cc2)cc1 ; Cc1ccc2c(c1)Sc1cc(C)ccc1N2c1ccc(-c2cccc3c2sc2ccccc23)cc1 ; c1ccc(-c2ccc(-c3ccc4c(c3)Sc3ccccc3N4c3ccc(-c4ccc(-c5cccc6c5sc5ccccc56)cc4)cc3)cc2)cc1 ; Cc1ccc2c(c1)Sc1cc(-c3ccccc3)ccc1N2c1ccc(-c2ccc(-c3cccc4c3sc3ccccc34)cc2)cc1]

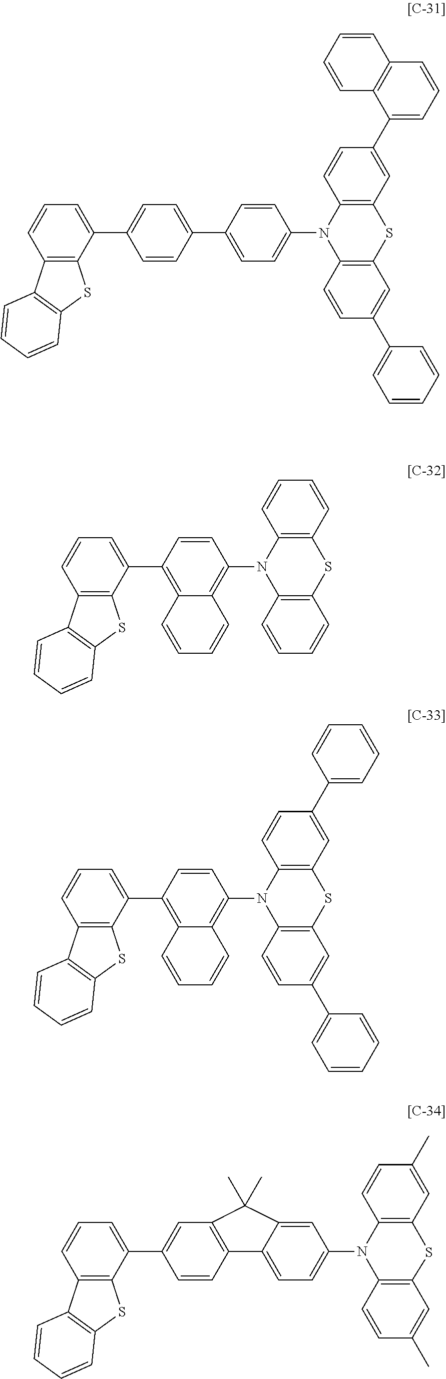 [SMILES: c1ccc(-c2ccc3c(c2)Sc2cc(-c4cccc5ccccc45)ccc2N3c2ccc(-c3ccc(-c4cccc5c4sc4ccccc45)cc3)cc2)cc1 ; c1ccc2c(c1)Sc1ccccc1N2c1ccc(-c2cccc3c2sc2ccccc23)c2ccccc12 ; c1ccc(-c2ccc3c(c2)Sc2cc(-c4ccccc4)ccc2N3c2ccc(-c3cccc4c3sc3ccccc34)c3ccccc23)cc1 ; Cc1ccc2c(c1)Sc1cc(C)ccc1N2c1ccc2c(c1)C(C)(C)c1cc(-c3cccc4c3sc3ccccc34)ccc1-2]

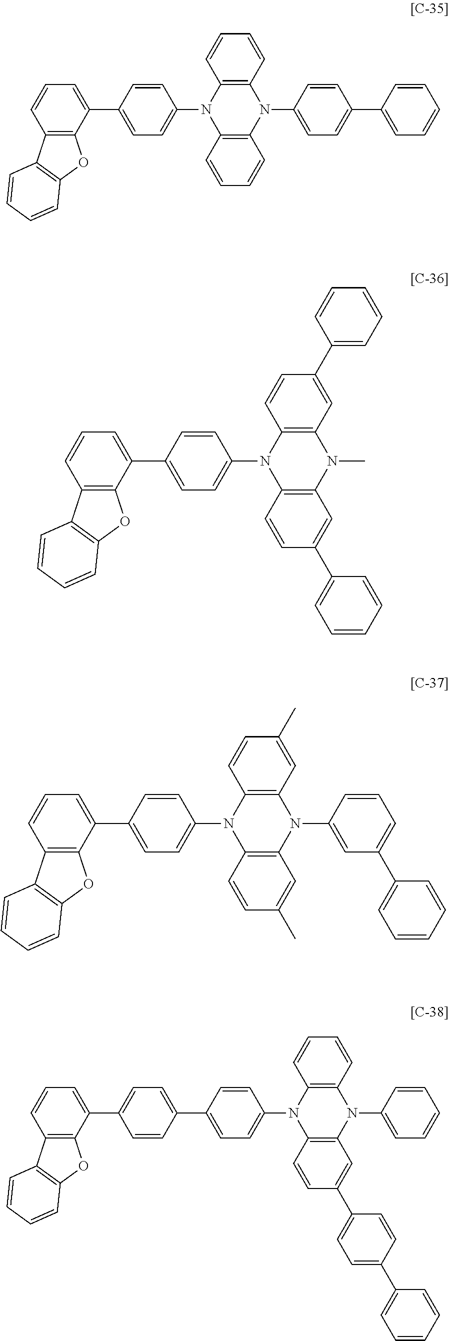 [SMILES: c1ccc(-c2ccc(N3c4ccccc4N(c4ccc(-c5cccc6c5oc5ccccc56)cc4)c4ccccc43)cc2)cc1 ; CN1c2cc(-c3ccccc3)ccc2N(c2ccc(-c3cccc4c3oc3ccccc34)cc2)c2ccc(-c3ccccc3)cc21 ; Cc1ccc2c(c1)N(c1cccc(-c3ccccc3)c1)c1cc(C)ccc1N2c1ccc(-c2cccc3c2oc2ccccc23)cc1 ; c1ccc(-c2ccc(-c3ccc4c(c3)N(c3ccccc3)c3ccccc3N4c3ccc(-c4ccc(-c5cccc6c5oc5ccccc56)cc4)cc3)cc2)cc1]

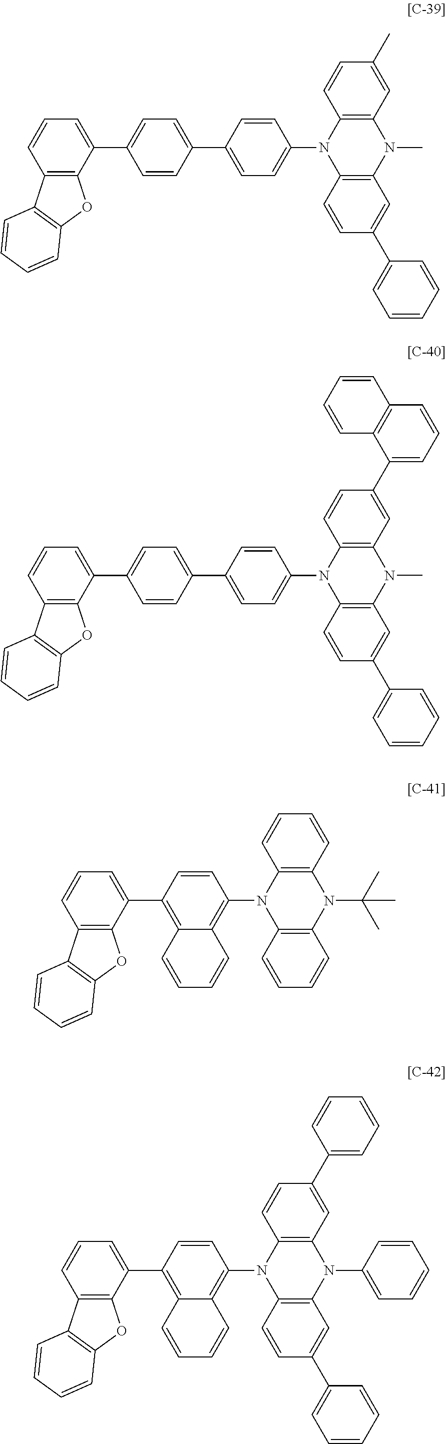 [SMILES: Cc1ccc2c(c1)N(C)c1cc(-c3ccccc3)ccc1N2c1ccc(-c2ccc(-c3cccc4c3oc3ccccc34)cc2)cc1 ; CN1c2cc(-c3ccccc3)ccc2N(c2ccc(-c3ccc(-c4cccc5c4oc4ccccc45)cc3)cc2)c2ccc(-c3cccc4ccccc34)cc21 ; CC(C)(C)N1c2ccccc2N(c2ccc(-c3cccc4c3oc3ccccc34)c3ccccc23)c2ccccc21 ; c1ccc(-c2ccc3c(c2)N(c2ccccc2)c2cc(-c4ccccc4)ccc2N3c2ccc(-c3cccc4c3oc3ccccc34)c3ccccc23)cc1]

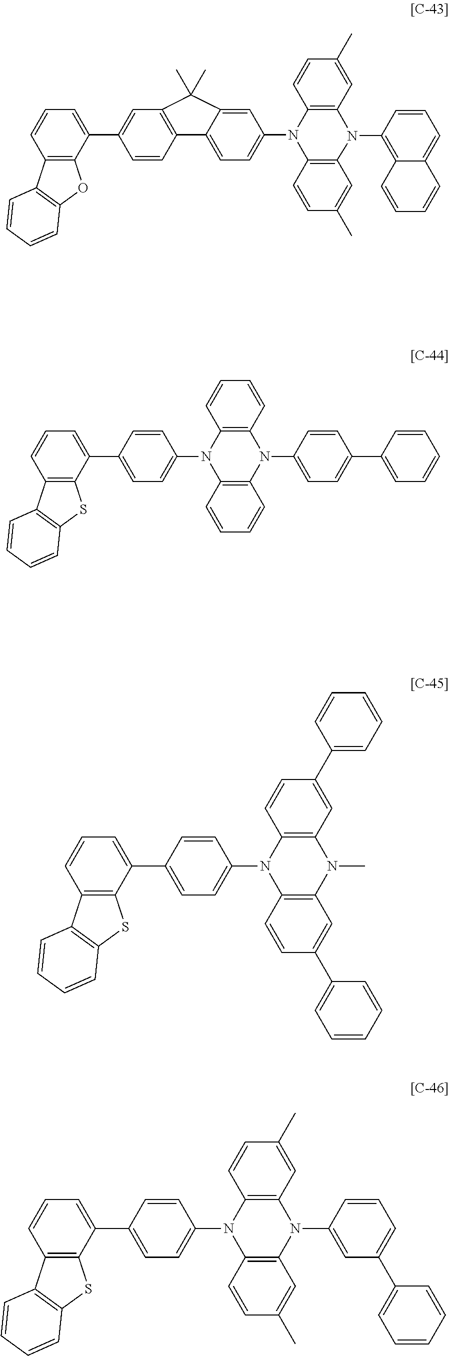 [SMILES: Cc1ccc2c(c1)N(c1cccc3ccccc13)c1cc(C)ccc1N2c1ccc2c(c1)C(C)(C)c1cc(-c3cccc4c3oc3ccccc34)ccc1-2 ; c1ccc(-c2ccc(N3c4ccccc4N(c4ccc(-c5cccc6c5sc5ccccc56)cc4)c4ccccc43)cc2)cc1 ; CN1c2cc(-c3ccccc3)ccc2N(c2ccc(-c3cccc4c3sc3ccccc34)cc2)c2ccc(-c3ccccc3)cc21 ; Cc1ccc2c(c1)N(c1cccc(-c3ccccc3)c1)c1cc(C)ccc1N2c1ccc(-c2cccc3c2sc2ccccc23)cc1]

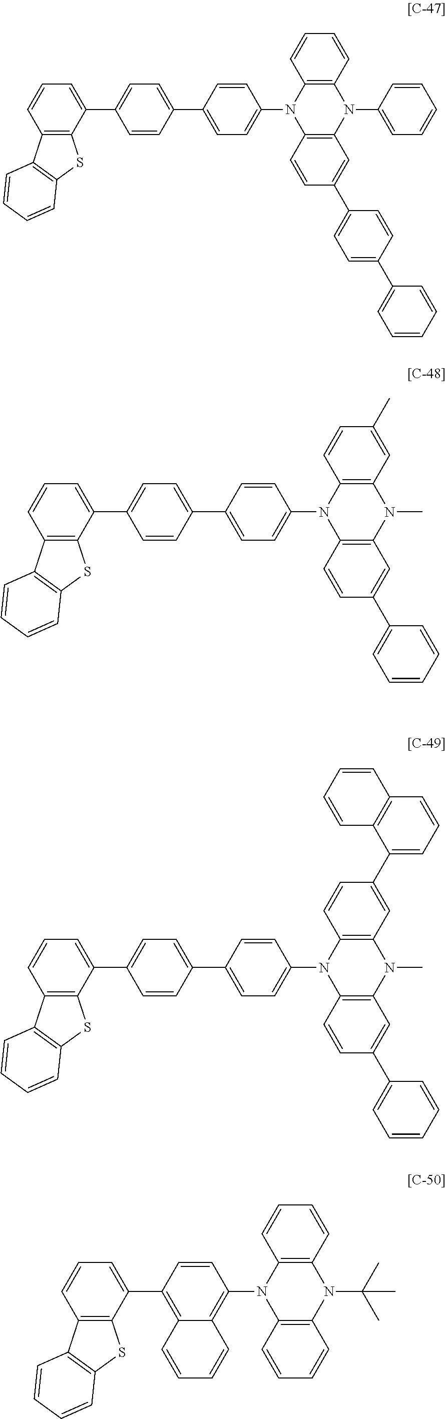 [SMILES: c1ccc(-c2ccc(-c3ccc4c(c3)N(c3ccccc3)c3ccccc3N4c3ccc(-c4ccc(-c5cccc6c5sc5ccccc56)cc4)cc3)cc2)cc1 ; Cc1ccc2c(c1)N(C)c1cc(-c3ccccc3)ccc1N2c1ccc(-c2ccc(-c3cccc4c3sc3ccccc34)cc2)cc1 ; CN1c2cc(-c3ccccc3)ccc2N(c2ccc(-c3ccc(-c4cccc5c4sc4ccccc45)cc3)cc2)c2ccc(-c3cccc4ccccc34)cc21 ; CC(C)(C)N1c2ccccc2N(c2ccc(-c3cccc4c3sc3ccccc34)c3ccccc23)c2ccccc21]

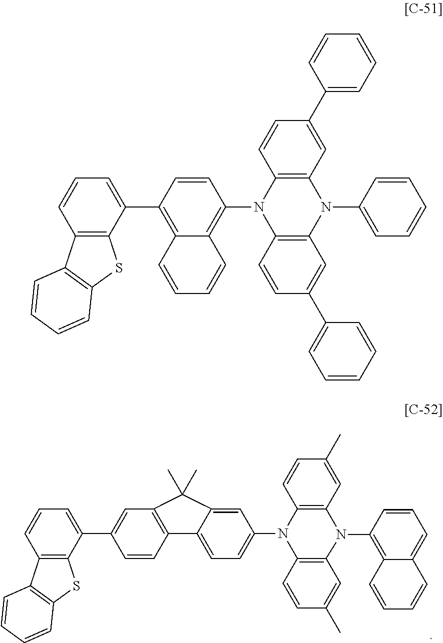 [SMILES: c1ccc(-c2ccc3c(c2)N(c2ccccc2)c2cc(-c4ccccc4)ccc2N3c2ccc(-c3cccc4c3sc3ccccc34)c3ccccc23)cc1 ; Cc1ccc2c(c1)N(c1cccc3ccccc13)c1cc(C)ccc1N2c1ccc2c(c1)C(C)(C)c1cc(-c3cccc4c3sc3ccccc34)ccc1-2]

The compound for an organic optoelectronic device may be represented by the following Chemical Formulae D-1 to D-36, but is not limited thereto.

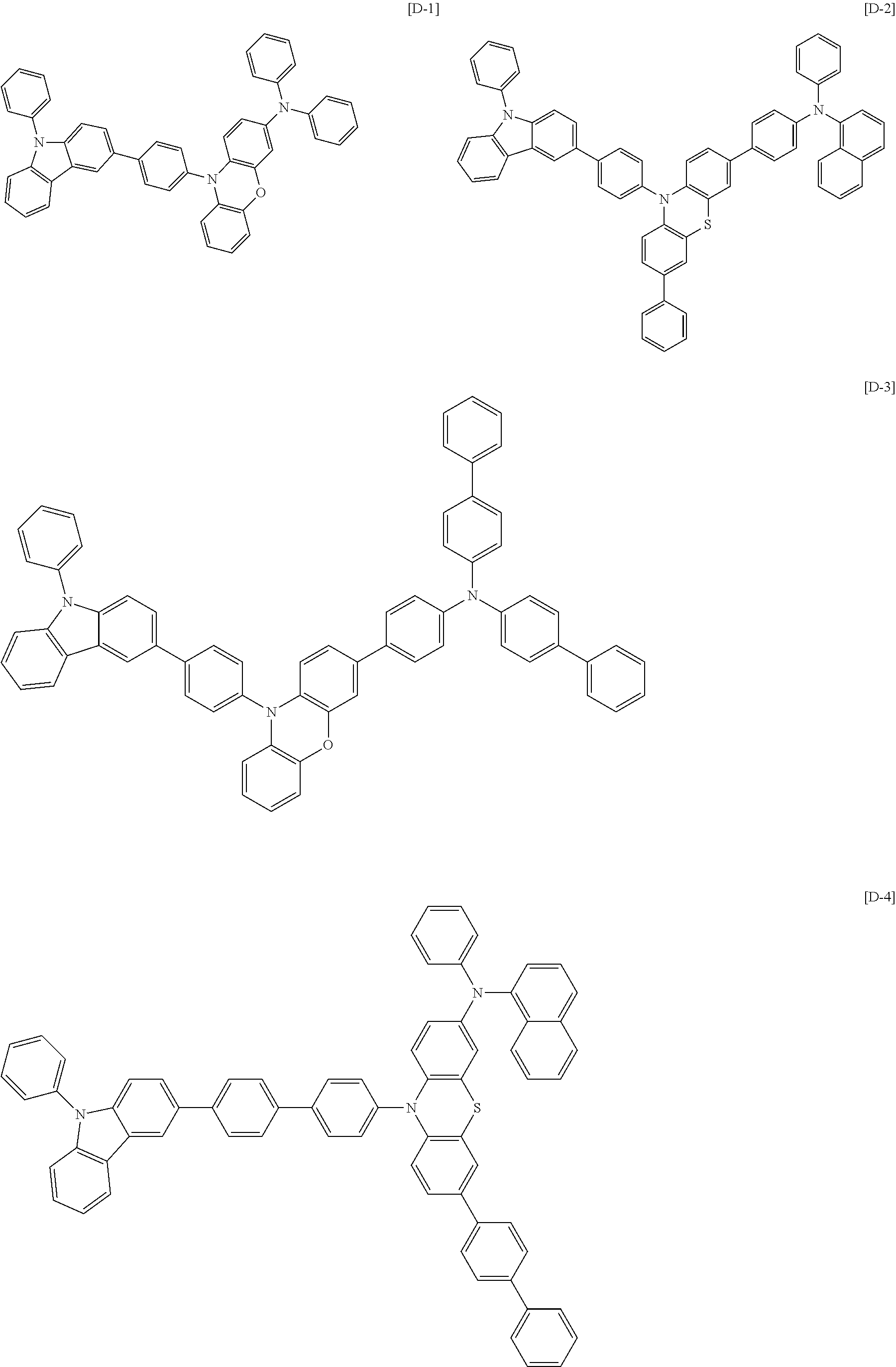 [SMILES: c1ccc(N(c2ccccc2)c2ccc3c(c2)Oc2ccccc2N3c2ccc(-c3ccc4c(c3)c3ccccc3n4-c3ccccc3)cc2)cc1 ; c1ccc(-c2ccc3c(c2)Sc2cc(-c4ccc(N(c5ccccc5)c5cccc6ccccc56)cc4)ccc2N3c2ccc(-c3ccc4c(c3)c3ccccc3n4-c3ccccc3)cc2)cc1 ; c1ccc(-c2ccc(N(c3ccc(-c4ccccc4)cc3)c3ccc(-c4ccc5c(c4)Oc4ccccc4N5c4ccc(-c5ccc6c(c5)c5ccccc5n6-c5ccccc5)cc4)cc3)cc2)cc1 ; c1ccc(-c2ccc(-c3ccc4c(c3)Sc3cc(N(c5ccccc5)c5cccc6ccccc56)ccc3N4c3ccc(-c4ccc(-c5ccc6c(c5)c5ccccc5n6-c5ccccc5)cc4)cc3)cc2)cc1]

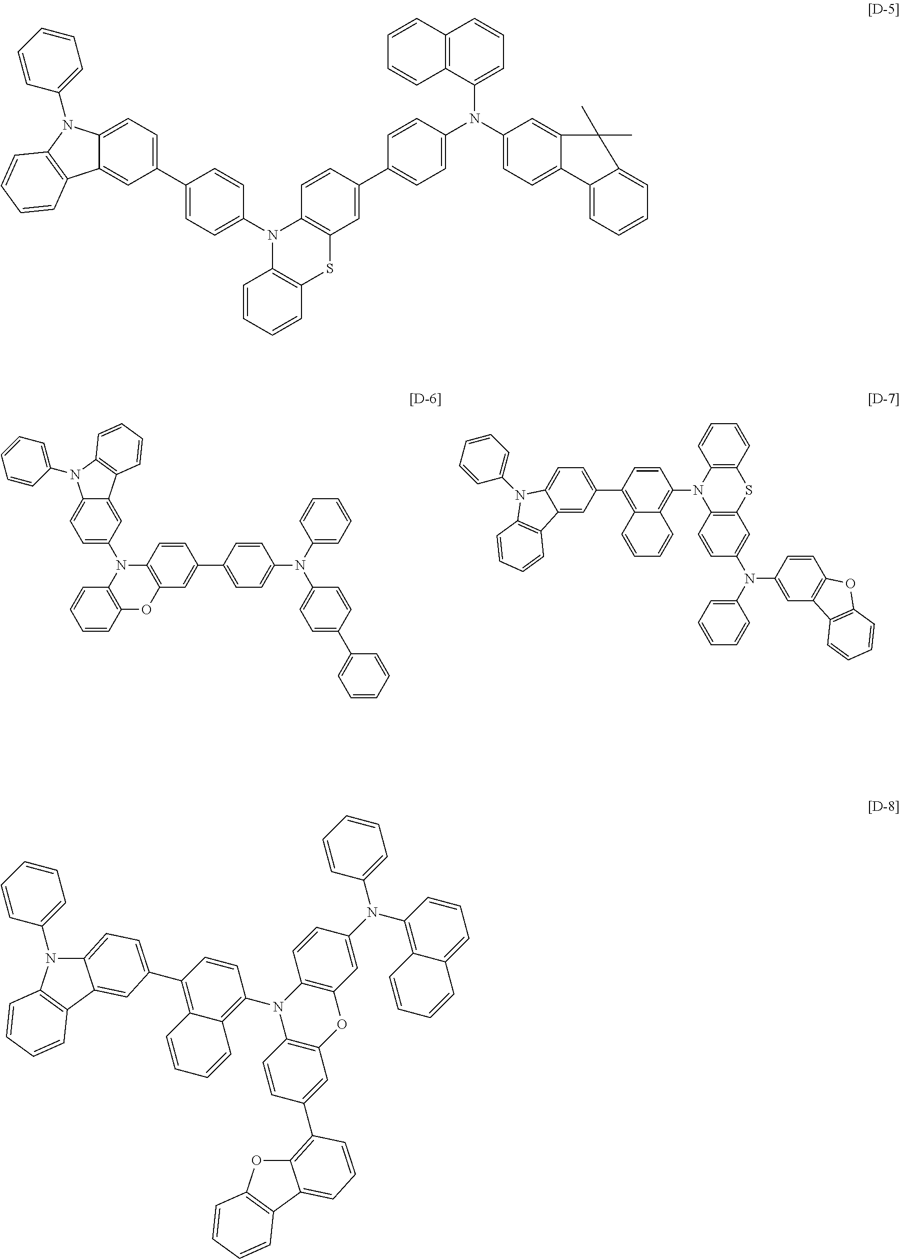 [SMILES: CC1(C)c2ccccc2-c2ccc(N(c3ccc(-c4ccc5c(c4)Sc4ccccc4N5c4ccc(-c5ccc6c(c5)c5ccccc5n6-c5ccccc5)cc4)cc3)c3cccc4ccccc34)cc21 ; c1ccc(-c2ccc(N(c3ccccc3)c3ccc(-c4ccc5c(c4)Oc4ccccc4N5c4ccc5c(c4)c4ccccc4n5-c4ccccc4)cc3)cc2)cc1 ; c1ccc(N(c2ccc3c(c2)Sc2ccccc2N3c2ccc(-c3ccc4c(c3)c3ccccc3n4-c3ccccc3)c3ccccc23)c2ccc3oc4ccccc4c3c2)cc1 ; c1ccc(N(c2ccc3c(c2)Oc2cc(-c4cccc5c4oc4ccccc45)ccc2N3c2ccc(-c3ccc4c(c3)c3ccccc3n4-c3ccccc3)c3ccccc23)c2cccc3ccccc23)cc1]

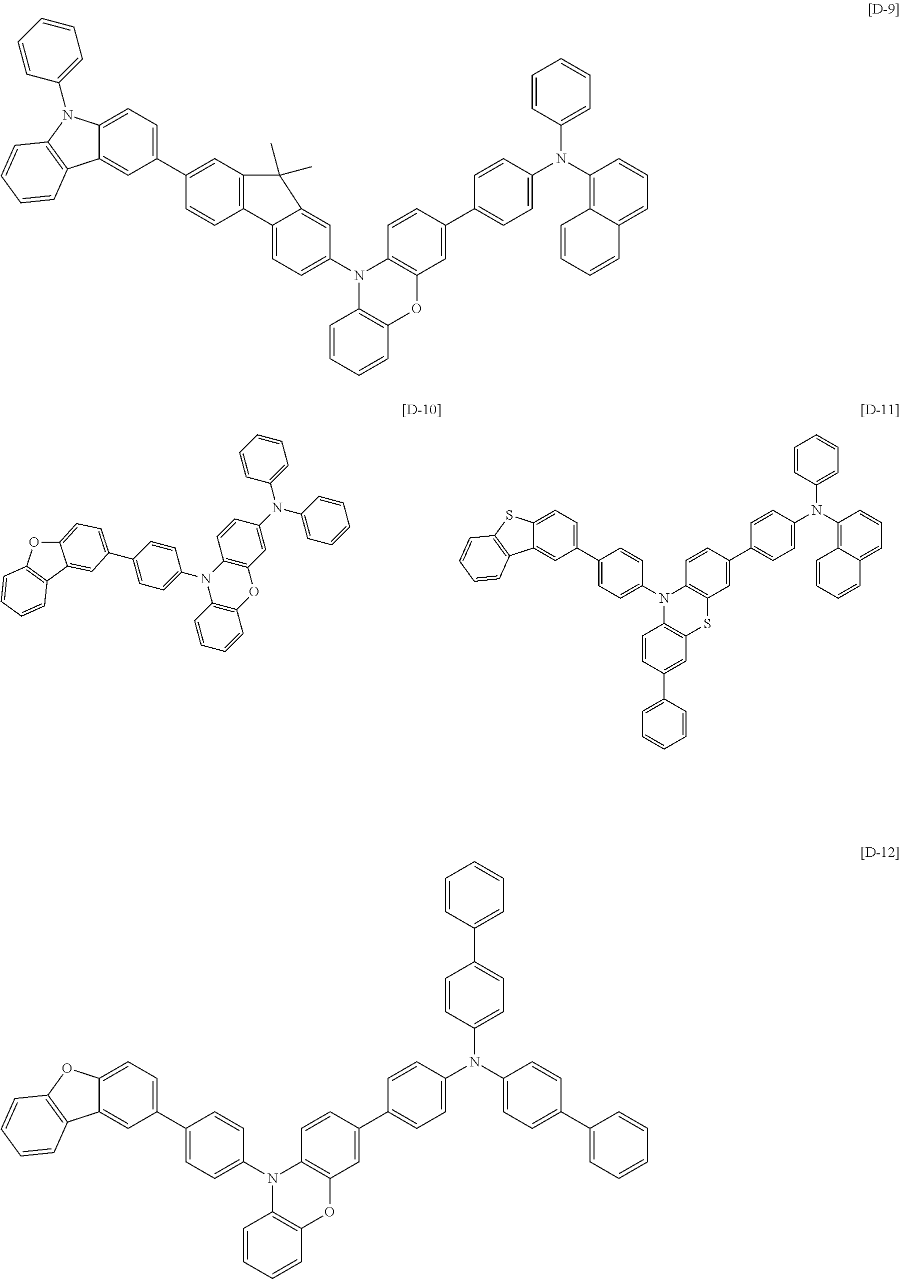 [SMILES: CC1(C)c2cc(-c3ccc4c(c3)c3ccccc3n4-c3ccccc3)ccc2-c2ccc(N3c4ccccc4Oc4cc(-c5ccc(N(c6ccccc6)c6cccc7ccccc67)cc5)ccc43)cc21 ; c1ccc(N(c2ccccc2)c2ccc3c(c2)Oc2ccccc2N3c2ccc(-c3ccc4oc5ccccc5c4c3)cc2)cc1 ; c1ccc(-c2ccc3c(c2)Sc2cc(-c4ccc(N(c5ccccc5)c5cccc6ccccc56)cc4)ccc2N3c2ccc(-c3ccc4sc5ccccc5c4c3)cc2)cc1 ; c1ccc(-c2ccc(N(c3ccc(-c4ccccc4)cc3)c3ccc(-c4ccc5c(c4)Oc4ccccc4N5c4ccc(-c5ccc6oc7ccccc7c6c5)cc4)cc3)cc2)cc1]

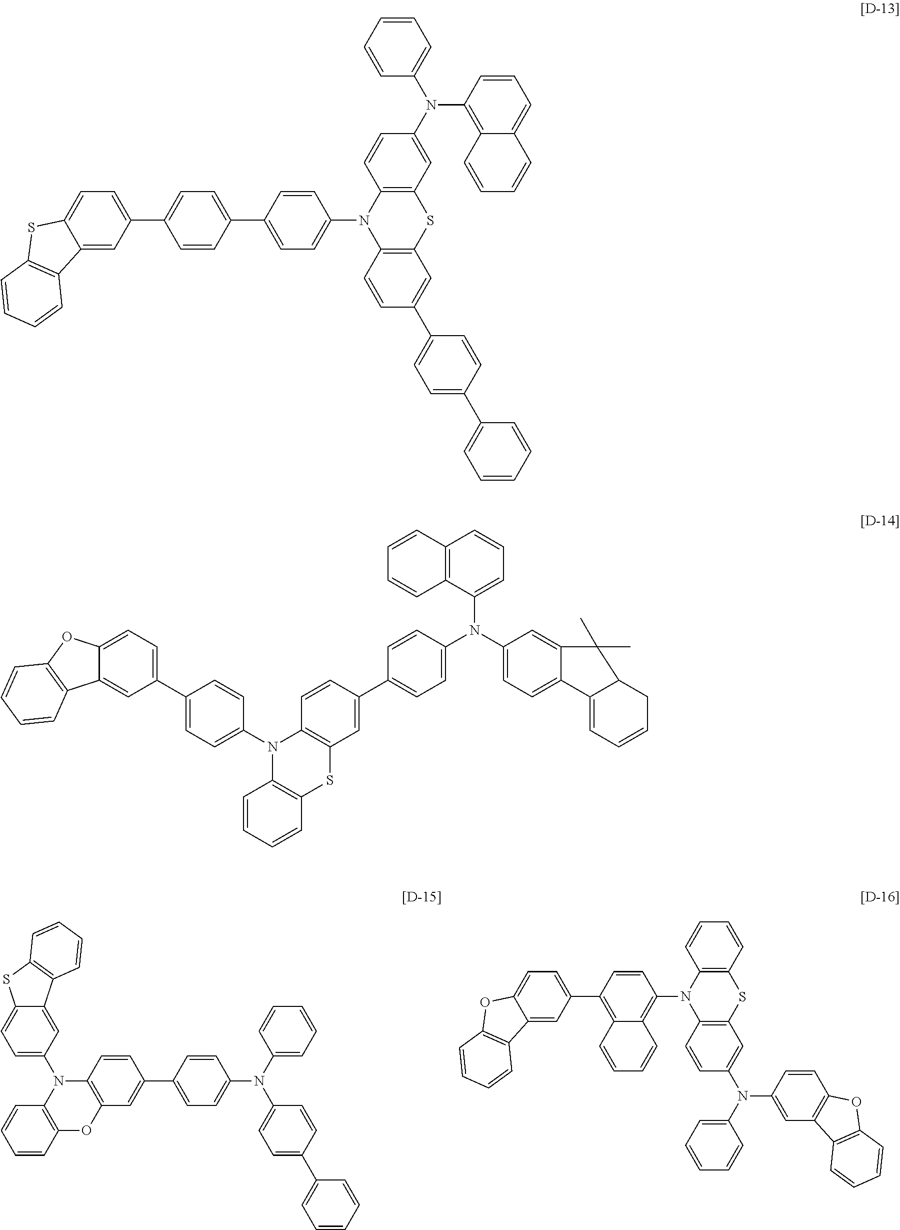 [SMILES: c1ccc(-c2ccc(-c3ccc4c(c3)Sc3cc(N(c5ccccc5)c5cccc6ccccc56)ccc3N4c3ccc(-c4ccc(-c5ccc6sc7ccccc7c6c5)cc4)cc3)cc2)cc1 ; CC1(C)c2cc(N(c3ccc(-c4ccc5c(c4)Sc4ccccc4N5c4ccc(-c5ccc6oc7ccccc7c6c5)cc4)cc3)c3cccc4ccccc34)ccc2C2=CC=CCC21 ; c1ccc(-c2ccc(N(c3ccccc3)c3ccc(-c4ccc5c(c4)Oc4ccccc4N5c4ccc5sc6ccccc6c5c4)cc3)cc2)cc1 ; c1ccc(N(c2ccc3c(c2)Sc2ccccc2N3c2ccc(-c3ccc4oc5ccccc5c4c3)c3ccccc23)c2ccc3oc4ccccc4c3c2)cc1]

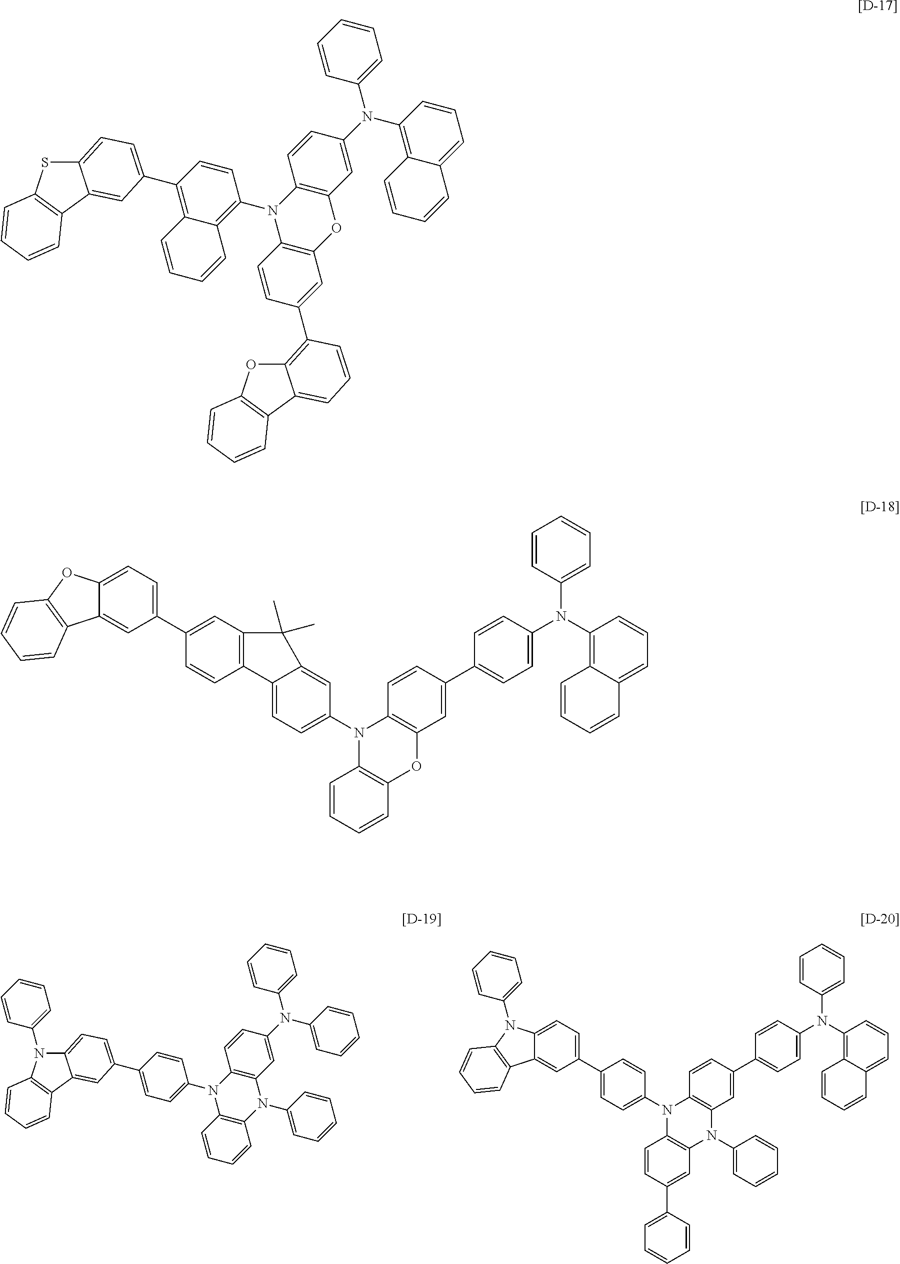

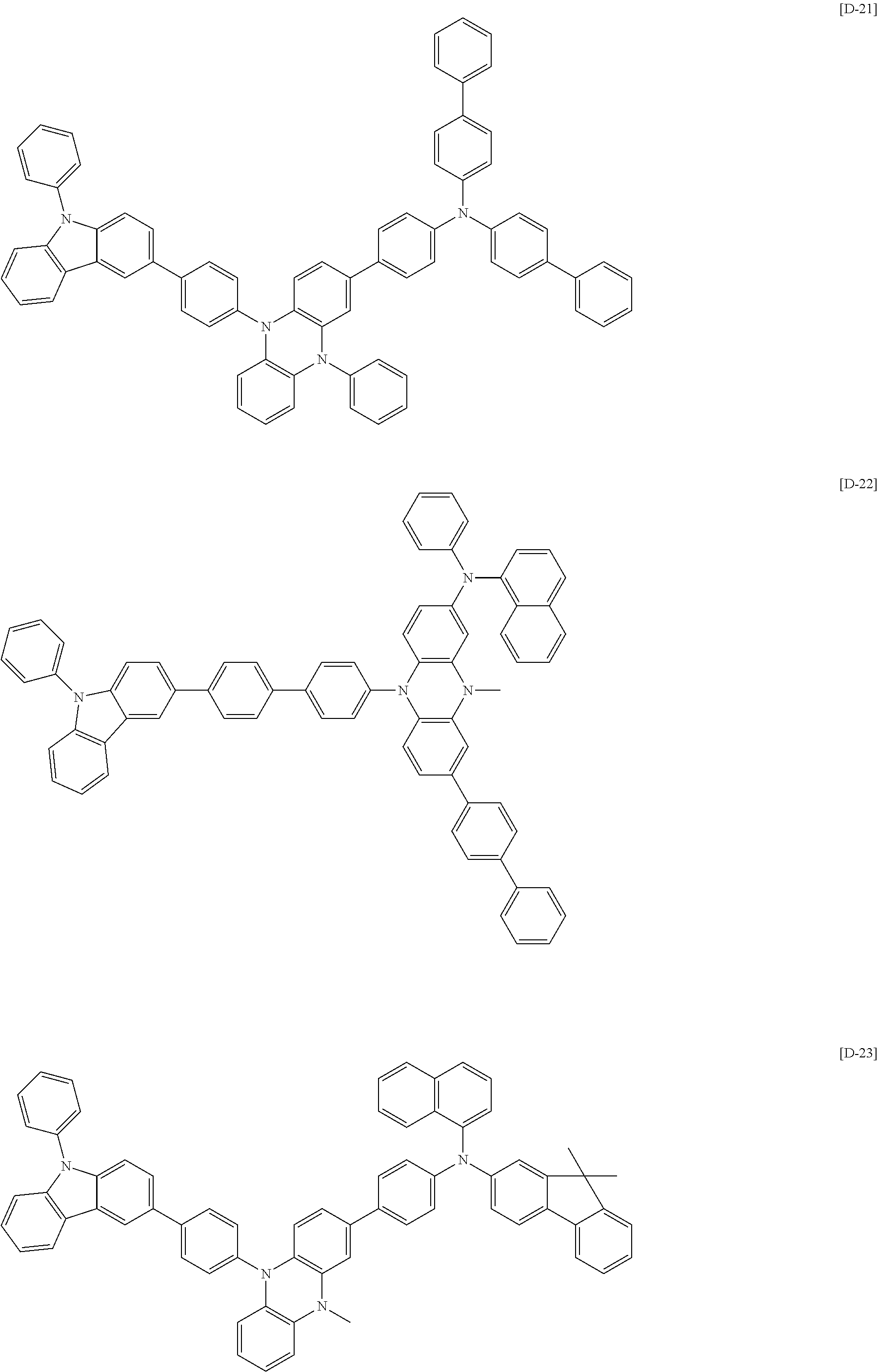 [SMILES: c1ccc(-c2ccc(N(c3ccc(-c4ccccc4)cc3)c3ccc(-c4ccc5c(c4)N(c4ccccc4)c4ccccc4N5c4ccc(-c5ccc6c(c5)c5ccccc5n6-c5ccccc5)cc4)cc3)cc2)cc1 ; CN1c2cc(-c3ccc(-c4ccccc4)cc3)ccc2N(c2ccc(-c3ccc(-c4ccc5c(c4)c4ccccc4n5-c4ccccc4)cc3)cc2)c2ccc(N(c3ccccc3)c3cccc4ccccc34)cc21 ; CN1c2ccccc2N(c2ccc(-c3ccc4c(c3)c3ccccc3n4-c3ccccc3)cc2)c2ccc(-c3ccc(N(c4ccc5c(c4)C(C)(C)c4ccccc4-5)c4cccc5ccccc45)cc3)cc21]

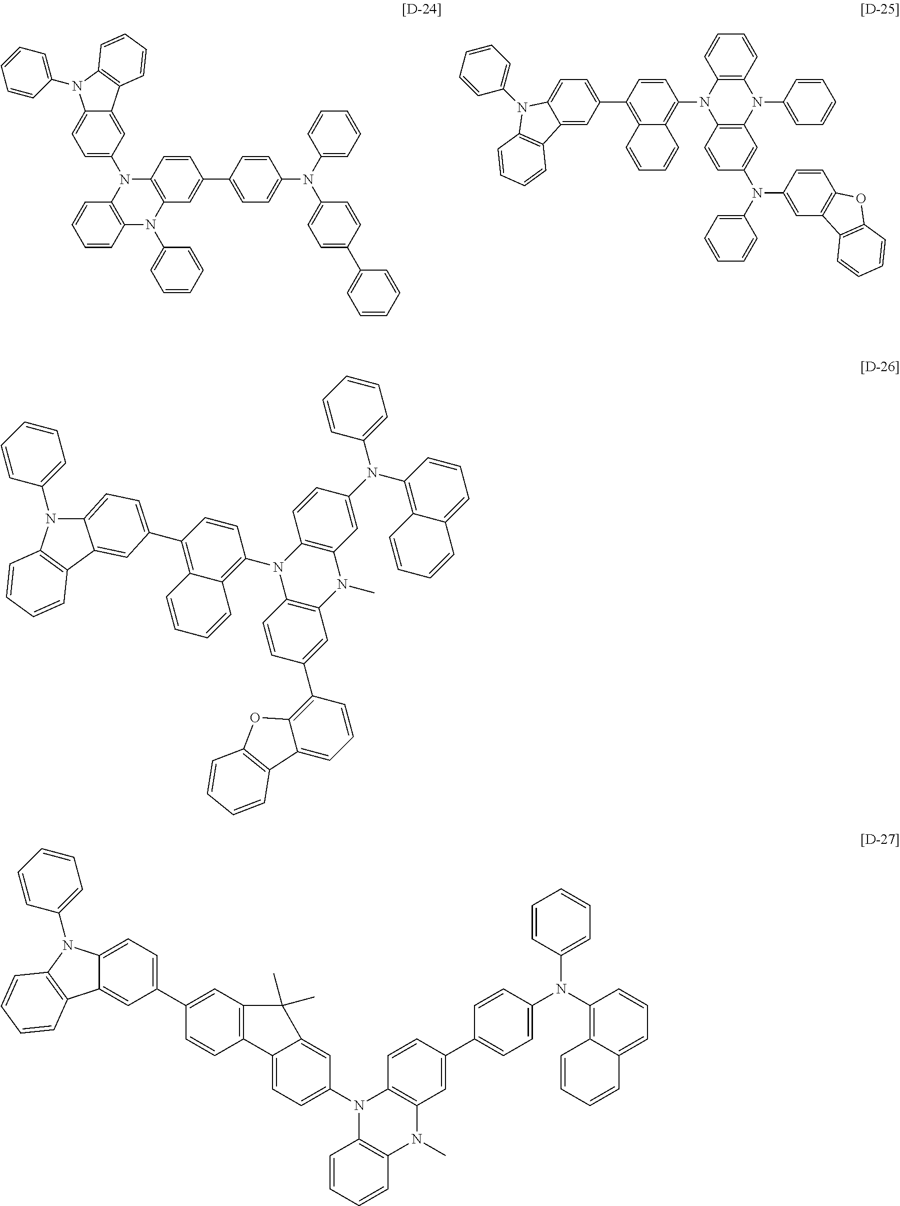 [SMILES: c1ccc(-c2ccc(N(c3ccccc3)c3ccc(-c4ccc5c(c4)N(c4ccccc4)c4ccccc4N5c4ccc5c(c4)c4ccccc4n5-c4ccccc4)cc3)cc2)cc1 ; c1ccc(N(c2ccc3c(c2)N(c2ccccc2)c2ccccc2N3c2ccc(-c3ccc4c(c3)c3ccccc3n4-c3ccccc3)c3ccccc23)c2ccc3oc4ccccc4c3c2)cc1 ; CN1c2cc(-c3cccc4c3oc3ccccc34)ccc2N(c2ccc(-c3ccc4c(c3)c3ccccc3n4-c3ccccc3)c3ccccc23)c2ccc(N(c3ccccc3)c3cccc4ccccc34)cc21 ; CN1c2ccccc2N(c2ccc3c(c2)C(C)(C)c2cc(-c4ccc5c(c4)c4ccccc4n5-c4ccccc4)ccc2-3)c2ccc(-c3ccc(N(c4ccccc4)c4cccc5ccccc45)cc3)cc21]

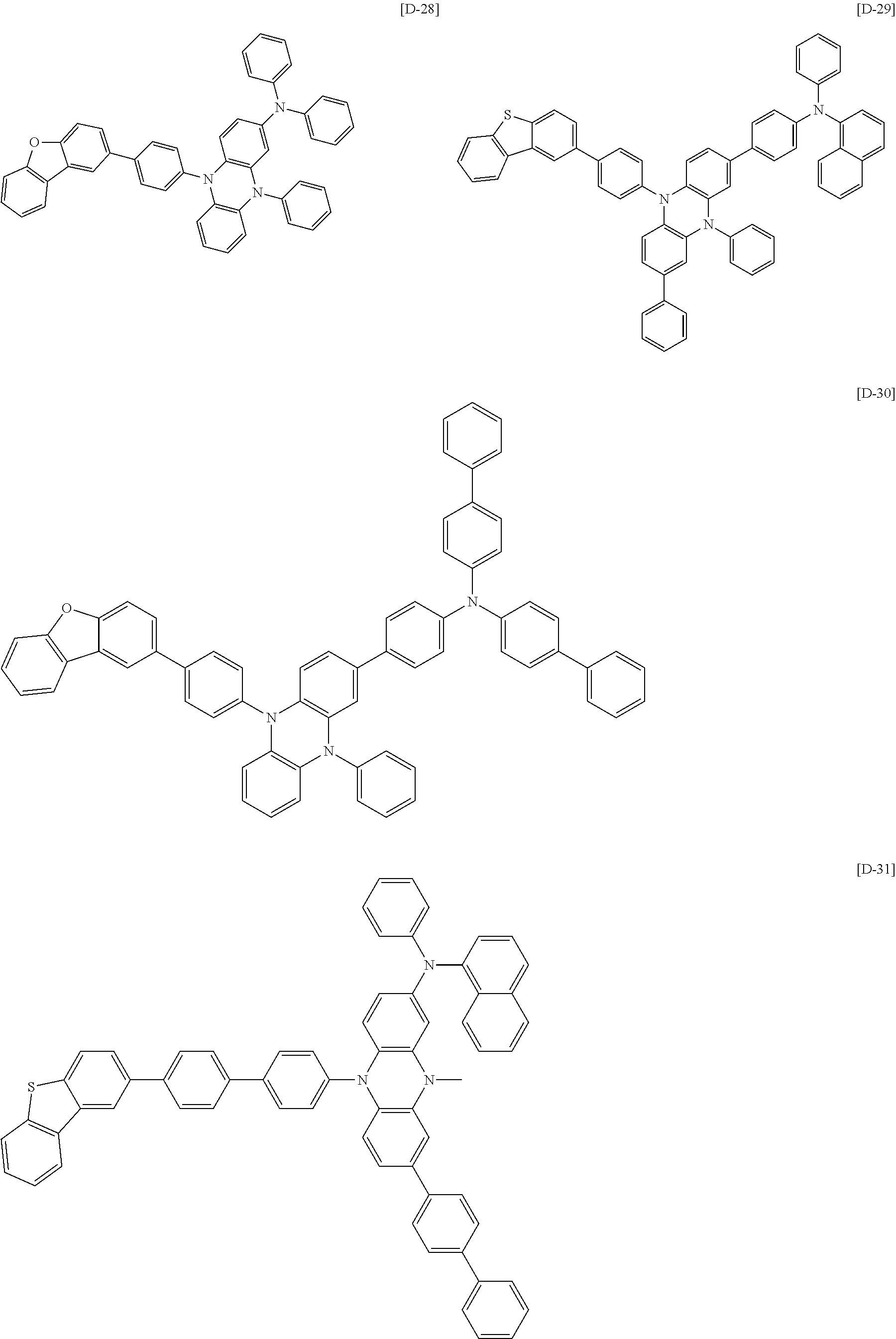 [SMILES: c1ccc(N(c2ccccc2)c2ccc3c(c2)N(c2ccccc2)c2ccccc2N3c2ccc(-c3ccc4oc5ccccc5c4c3)cc2)cc1 ; c1ccc(-c2ccc3c(c2)N(c2ccccc2)c2cc(-c4ccc(N(c5ccccc5)c5cccc6ccccc56)cc4)ccc2N3c2ccc(-c3ccc4sc5ccccc5c4c3)cc2)cc1 ; c1ccc(-c2ccc(N(c3ccc(-c4ccccc4)cc3)c3ccc(-c4ccc5c(c4)N(c4ccccc4)c4ccccc4N5c4ccc(-c5ccc6oc7ccccc7c6c5)cc4)cc3)cc2)cc1 ; CN1c2cc(-c3ccc(-c4ccccc4)cc3)ccc2N(c2ccc(-c3ccc(-c4ccc5sc6ccccc6c5c4)cc3)cc2)c2ccc(N(c3ccccc3)c3cccc4ccccc34)cc21]

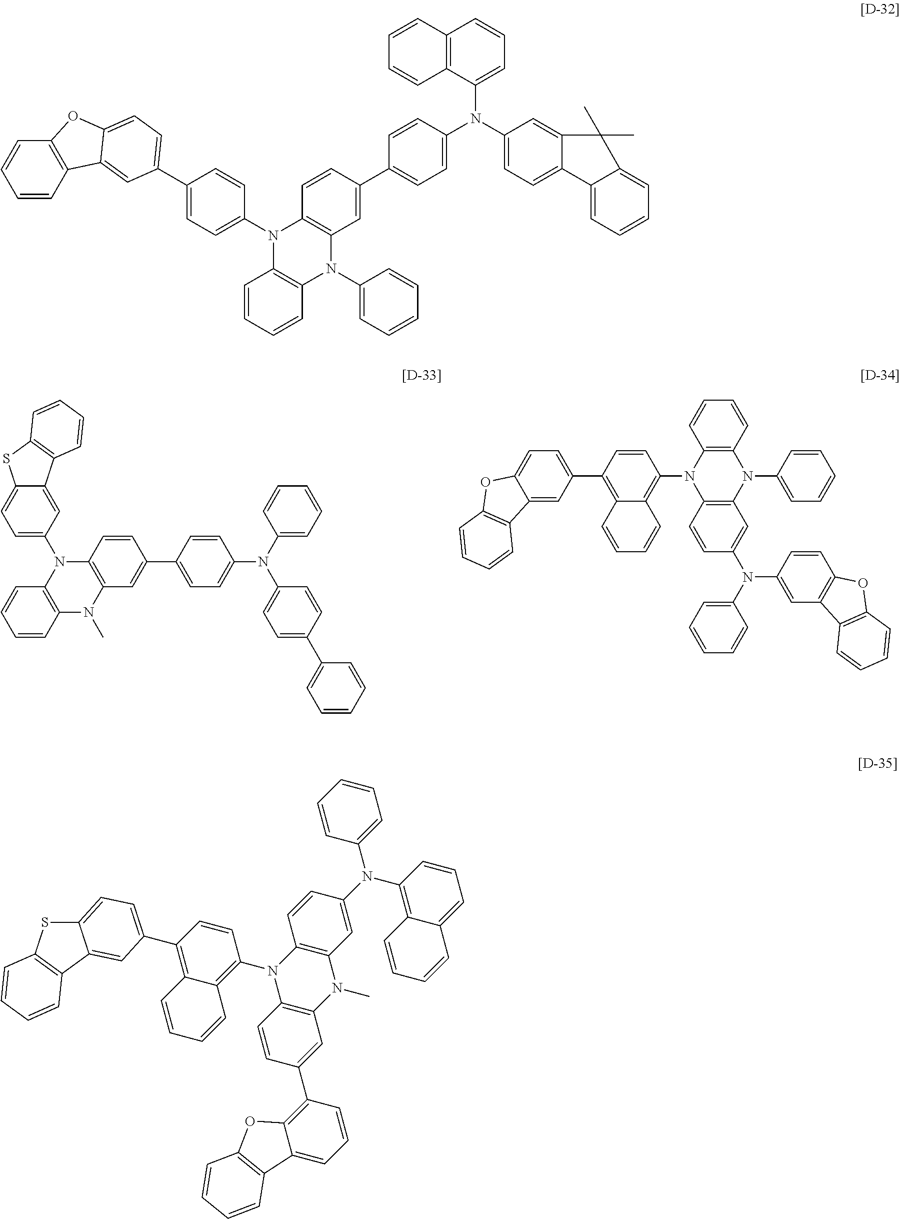

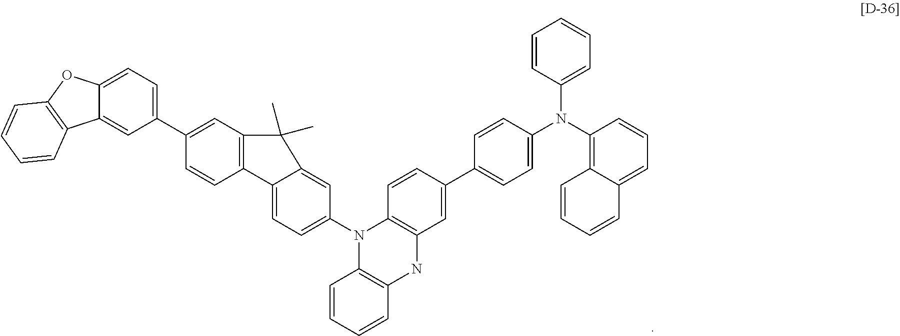 [SMILES: CC1(C)c2cc(-c3ccc4oc5ccccc5c4c3)ccc2-c2ccc(N3c4ccccc4Nc4cc(-c5ccc(N(c6ccccc6)c6cccc7ccccc67)cc5)ccc43)cc21]

The compound for an organic optoelectronic device may be represented by the following Chemical Formulae E-1 to E-18, but is not limited thereto.

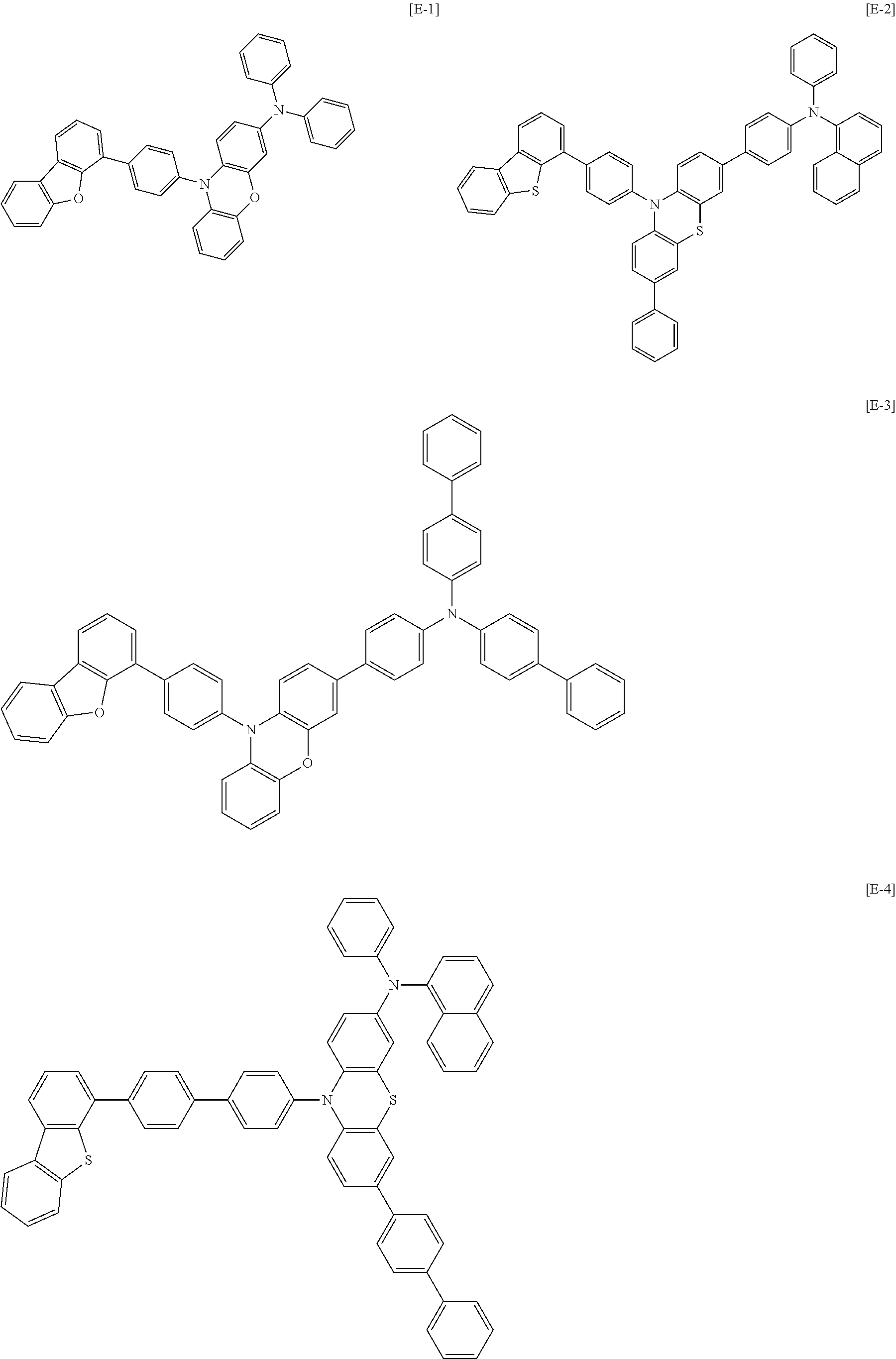 [SMILES: c1ccc(N(c2ccccc2)c2ccc3c(c2)Oc2ccccc2N3c2ccc(-c3cccc4c3oc3ccccc34)cc2)cc1 ; c1ccc(-c2ccc3c(c2)Sc2cc(-c4ccc(N(c5ccccc5)c5cccc6ccccc56)cc4)ccc2N3c2ccc(-c3cccc4c3sc3ccccc34)cc2)cc1 ; c1ccc(-c2ccc(N(c3ccc(-c4ccccc4)cc3)c3ccc(-c4ccc5c(c4)Oc4ccccc4N5c4ccc(-c5cccc6c5oc5ccccc56)cc4)cc3)cc2)cc1 ; c1ccc(-c2ccc(-c3ccc4c(c3)Sc3cc(N(c5ccccc5)c5cccc6ccccc56)ccc3N4c3ccc(-c4ccc(-c5cccc6c5sc5ccccc56)cc4)cc3)cc2)cc1]

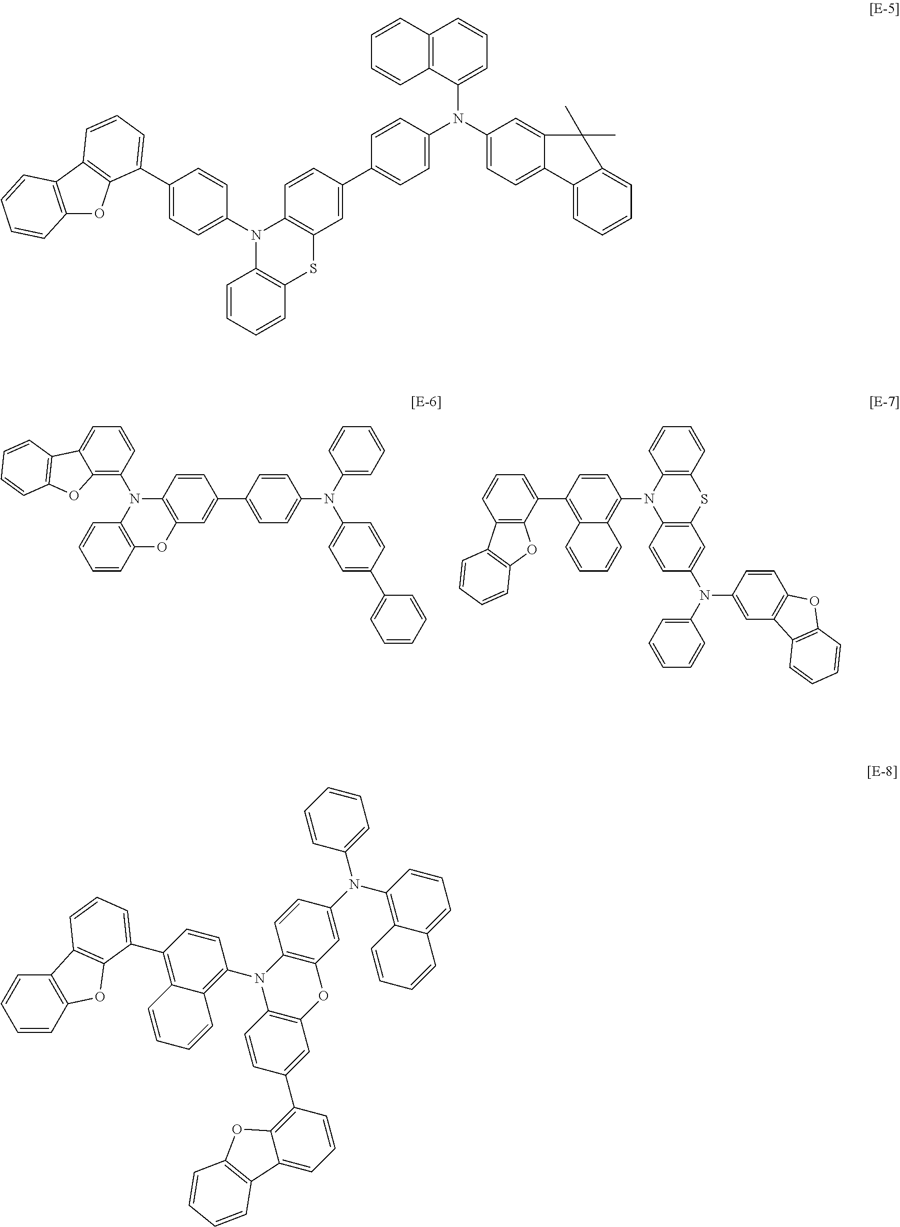

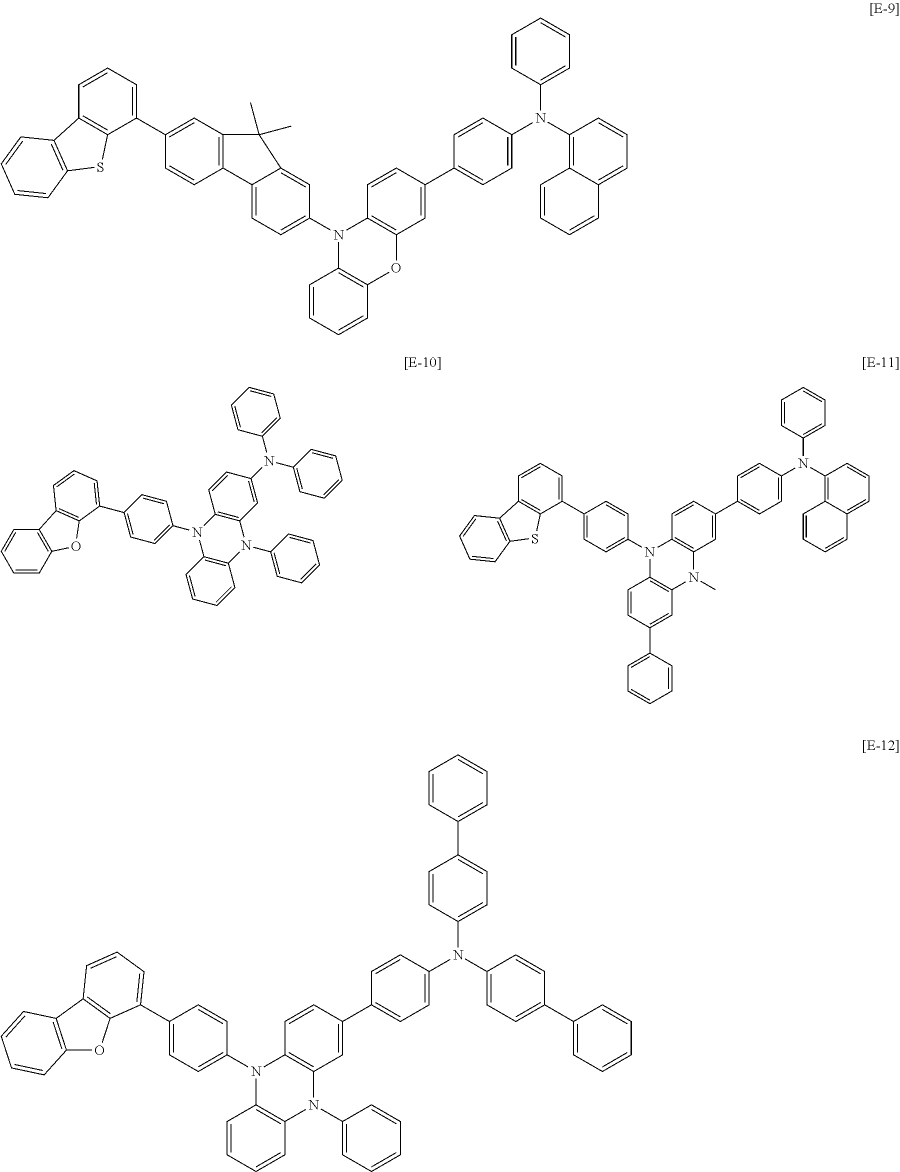 [SMILES: CC1(C)c2cc(-c3cccc4c3sc3ccccc34)ccc2-c2ccc(N3c4ccccc4Oc4cc(-c5ccc(N(c6ccccc6)c6cccc7ccccc67)cc5)ccc43)cc21 ; c1ccc(N(c2ccccc2)c2ccc3c(c2)N(c2ccccc2)c2ccccc2N3c2ccc(-c3cccc4c3oc3ccccc34)cc2)cc1 ; CN1c2cc(-c3ccccc3)ccc2N(c2ccc(-c3cccc4c3sc3ccccc34)cc2)c2ccc(-c3ccc(N(c4ccccc4)c4cccc5ccccc45)cc3)cc21 ; c1ccc(-c2ccc(N(c3ccc(-c4ccccc4)cc3)c3ccc(-c4ccc5c(c4)N(c4ccccc4)c4ccccc4N5c4ccc(-c5cccc6c5oc5ccccc56)cc4)cc3)cc2)cc1]

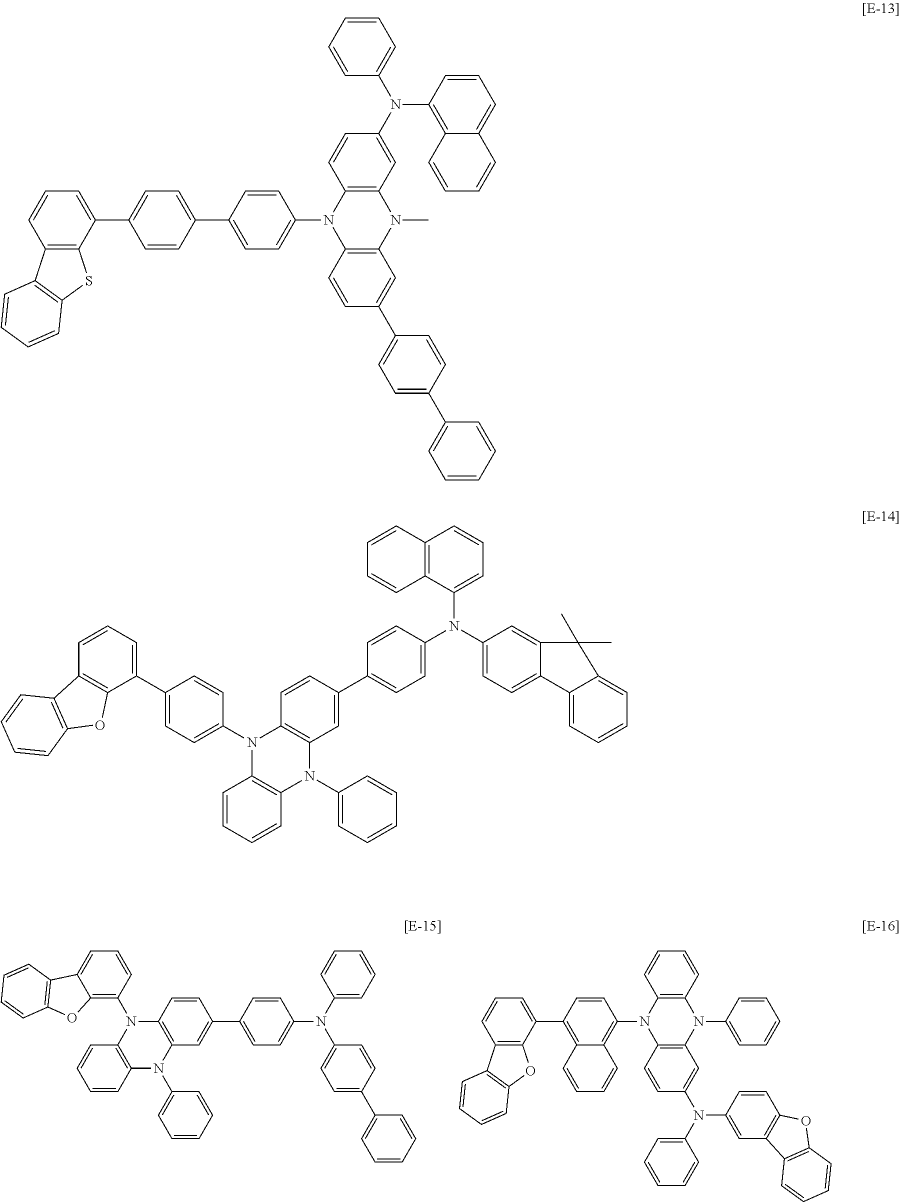 [SMILES: CN1c2cc(-c3ccc(-c4ccccc4)cc3)ccc2N(c2ccc(-c3ccc(-c4cccc5c4sc4ccccc45)cc3)cc2)c2ccc(N(c3ccccc3)c3cccc4ccccc34)cc21 ; CC1(C)c2ccccc2-c2ccc(N(c3ccc(-c4ccc5c(c4)N(c4ccccc4)c4ccccc4N5c4ccc(-c5cccc6c5oc5ccccc56)cc4)cc3)c3cccc4ccccc34)cc21 ; c1ccc(-c2ccc(N(c3ccccc3)c3ccc(-c4ccc5c(c4)N(c4ccccc4)c4ccccc4N5c4cccc5c4oc4ccccc45)cc3)cc2)cc1 ; c1ccc(N(c2ccc3c(c2)N(c2ccccc2)c2ccccc2N3c2ccc(-c3cccc4c3oc3ccccc34)c3ccccc23)c2ccc3oc4ccccc4c3c2)cc1]

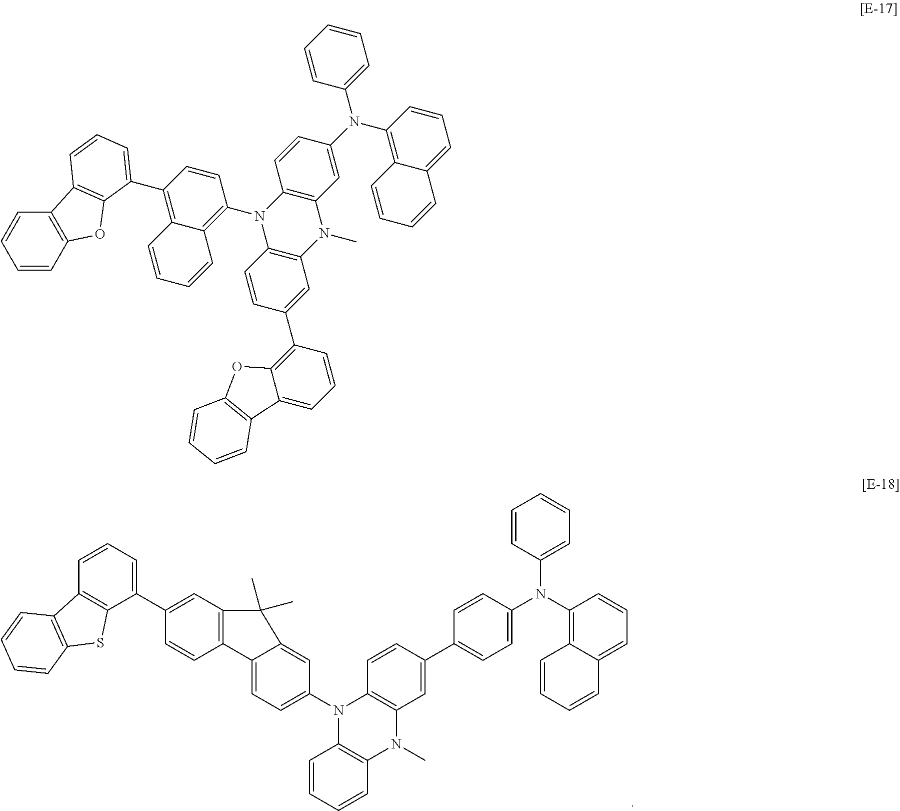 [SMILES: CN1c2cc(-c3cccc4c3oc3ccccc34)ccc2N(c2ccc(-c3cccc4c3oc3ccccc34)c3ccccc23)c2ccc(N(c3ccccc3)c3cccc4ccccc34)cc21 ; CN1c2ccccc2N(c2ccc3c(c2)C(C)(C)c2cc(-c4cccc5c4sc4ccccc45)ccc2-3)c2ccc(-c3ccc(N(c4ccccc4)c4cccc5ccccc45)cc3)cc21]

When the compound for an organic optoelectronic device according to the above-described embodiment is used in an electron blocking layer (or hole transport layer (HTL)) of an organic light emitting diode, electron inhibiting properties of important characteristics may tend to be deteriorated due to a functional group having electron characteristics in the molecule. Therefore, in an embodiment, the compound may not include a functional group having electron characteristics so that it may be used in an electron blocking layer. Examples of the functional group having electron characteristics may be benzoimidazole, pyridine, pyrazine, pyrimidine, triazine, quinoline, isoquinoline, and the like. The above descriptions are limited to using the compound in an electron blocking layer or hole transport layer (HTL) (or hole injection layer (HIL)).

The compound for an organic optoelectronic device including the above compounds may have a glass transition temperature of greater than or equal to 110° C. and a thermal decomposition temperature of greater than or equal to 400° C., indicating improved thermal stability. Thereby, it may be possible to produce an organic optoelectronic device having a high efficiency.

The compound for an organic optoelectronic device including the above compounds may play a role for emitting light or injecting and/or transporting holes, and also act as a light emitting host with an appropriate dopant. In other words, the compound for an organic optoelectronic device may be used as a phosphorescent or fluorescent host material, a blue light emitting dopant material, or an electron transport material.

The compound for an organic optoelectronic device according to an example embodiment may be used for an organic thin layer, and it may improve the life-span characteristic, efficiency characteristic, electrochemical stability, and thermal stability of an organic photoelectric device, and decrease the driving voltage.

Another example embodiment provides an organic optoelectronic device that includes the compound for an organic optoelectronic device according to an embodiment. The organic optoelectronic device may include, e.g., an organic photoelectric device, an organic light emitting diode, an organic solar cell, an organic transistor, an organic photo-conductor drum, an organic memory device, or the like. For example, the compound for an organic optoelectronic device according to an example embodiment may be included in an electrode or an electrode buffer layer in the organic solar cell to improve the quantum efficiency, and it may be used as an electrode material for a gate, a source-drain electrode, or the like in the organic transistor.

Another embodiment includes an anode, a cathode, and at least one or more organic thin layer between the anode and the cathode, and at least one of the organic thin layers may include the compound for an organic optoelectronic device according to an example embodiment.

The organic thin layer that may include the compound for an organic optoelectronic device may include a layer selected from an emission layer, a hole transport layer (HTL), a hole injection layer (HIL), an electron transport layer (ETL), an electron injection layer (EIL), a hole blocking layer, and a combination thereof. The at least one layer includes the compound for an organic optoelectronic device according to an example embodiment. Particularly, the compound for an organic optoelectronic device according to an example embodiment may be included in an electron transport layer (ETL) or electron injection layer (EIL). In addition, when the compound for an organic optoelectronic device is included in the emission layer, the compound for an organic optoelectronic device may be included as a phosphorescent or fluorescent host, and particularly, as a fluorescent blue dopant material.

FIGS. 1 to 5 illustrate cross-sectional views showing organic light emitting diodes including the compound for an organic optoelectronic device according to example embodiments.

Referring to FIGS. 1 to 5, organic light emitting diodes 100, 200, 300, 400, and 500 according to example embodiments include at least one organic thin layer 105 interposed between an anode 120 and a cathode 110.

The anode 120 may include an anode material having a large work function to help hole injection into an organic thin layer. The anode material may include, e.g., a metal such as nickel, platinum, vanadium, chromium, copper, zinc, gold, or alloys thereof; a metal oxide such as zinc oxide, indium oxide, indium tin oxide (ITO), or indium zinc oxide (IZO); a bonded metal and oxide such as ZnO:Al or SnO₂:Sb; or a conductive polymer such as poly(3-methylthiophene), poly[3,4-(ethylene-1,2-dioxy)thiophene] (PEDT), polypyrrole, or polyaniline, etc. In an implementation, a transparent electrode including indium tin oxide (ITO) may be included as an anode.

The cathode 110 may include a cathode material having a small work function to help electron injection into an organic thin layer. The cathode material may include, e.g., a metal such as magnesium, calcium, sodium, potassium, titanium, indium, yttrium, lithium, gadolinium, aluminum, silver, tin, lead, or alloys thereof; or a multi-layered material such as LiF/Al, Liq/Al, LiO₂/Al, LiF/Ca, LiF/Al, or BaF₂/Ca, etc. In an implementation, a metal electrode including aluminum may be included as a cathode.

Referring to FIG. 1, in an example embodiment the organic photoelectric device 100 includes an organic thin layer 105 including only an emission layer 130.

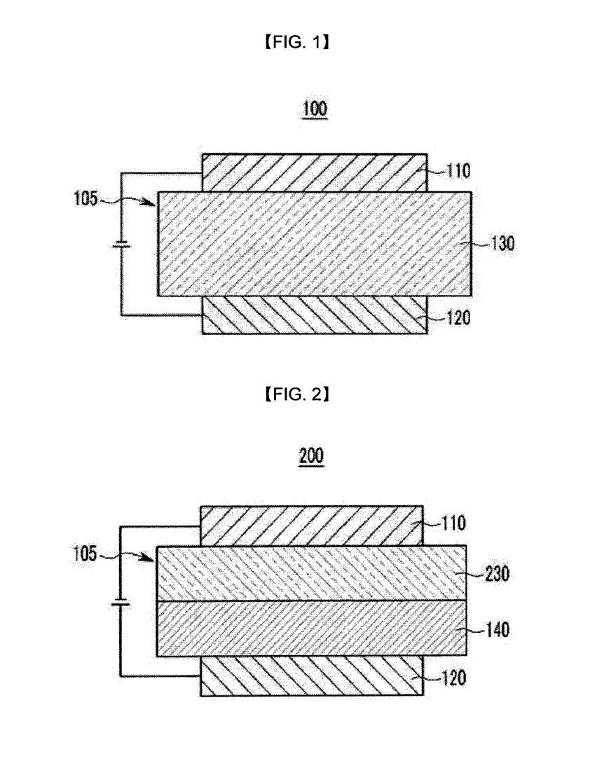

Referring to FIG. 2, in an example embodiment a double-layered organic photoelectric device 200 includes an organic thin layer 105 including an emission layer 230 including an electron transport layer (ETL), and a hole transport layer (HTL) 140. As shown in FIG. 2, the organic thin layer 105 includes a double layer of the emission layer 230 and hole transport layer (HTL) 140. The emission layer 130 also functions as an electron transport layer (ETL), and the hole transport layer (HTL) 140 layer may have an excellent binding property with a transparent electrode such as ITO or an excellent hole transport capability.

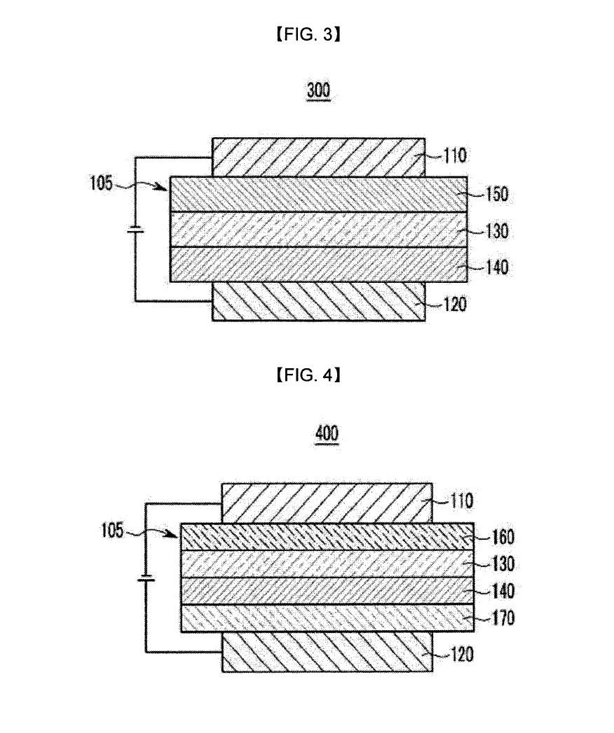

Referring to FIG. 3, in an example embodiment a three-layered organic photoelectric device 300 includes an organic thin layer 105 including an electron transport layer (ETL) 150, an emission layer 130, and a hole transport layer (HTL) 140. The emission layer 130 is independently installed, and layers having an excellent electron transport capability or an excellent hole transport capability may be separately stacked.

As shown in FIG. 4, in an example embodiment a four-layered organic photoelectric device 400 includes an organic thin layer 105 including an electron injection layer (EIL) 160, an emission layer 130, a hole transport layer (HTL) 140, and a hole injection layer (HIL) 170 that may enhance adherence with the cathode of ITO.

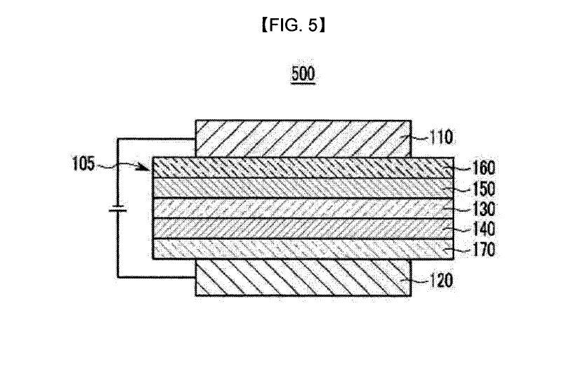

As shown in FIG. 5, in an example embodiment a five layered organic photoelectric device 500 includes an organic thin layer 105 including an electron transport layer (ETL) 150, an emission layer 130, a hole transport layer (HTL) 140, and a hole injection layer (HIL) 170, and further includes an electron injection layer (EIL) 160, which may provide a low voltage.

In FIGS. 1 to 5, the organic thin layer 105 including at least one selected from an electron transport layer (ETL) 150, an electron injection layer (EIL) 160, emission layers 130 and 230, a hole transport layer (HTL) 140, a hole injection layer (HIL) 170, and combinations thereof includes a compound for an organic optoelectronic device according to an embodiment. The compound for an organic optoelectronic device may be used for an electron transport layer (ETL) 150 including the electron transport layer (ETL) 150 or electron injection layer (EIL) 160. When it is used for the electron transport layer (ETL), it may be possible to provide an organic photoelectric device having a simpler structure by omitting an additional hole blocking layer (not shown).

Furthermore, when the compound for an organic photoelectric device is included in the emission layers 130 and 230, the compound for the organic photoelectric device may be included as a phosphorescent or fluorescent host or a fluorescent blue dopant.

The organic light emitting diode may be fabricated by, e.g.: forming an anode on a substrate; forming an organic thin layer in accordance with a dry coating method such as evaporation, sputtering, plasma plating, and ion plating, or a wet coating method such as spin coating, dipping, and flow coating; and providing a cathode thereon.

Another example embodiment provides a display device including an organic photoelectric device according to an embodiment.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

(Preparation of Compound for Organic Optoelectronic Device)

Synthesis of Intermediate

Synthesis of Intermediate M-1

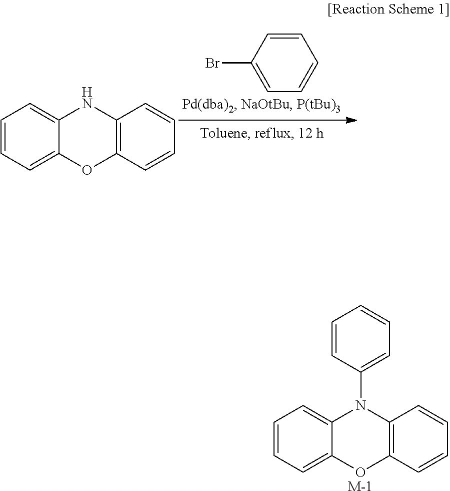

30 g (163.8 mmol) of phenoxazine, 30.8 g (196.6 mmol) of bromobenzene, 23.6 g (245.8 mmol) of sodium t-butoxide, and 1.0 g (4.92 mmol) of tri-tert-butylphosphine were dissolved in 330 ml of toluene, 0.94 g (1.64 mmol) of Pd(dba)₂ was added thereto, and the mixture was agitated for 6 hours under a nitrogen atmosphere while being refluxed. When the reaction was complete, the resultant was extracted with ethyl acetate and distilled water, an organic layer obtained therefrom was dried with magnesium sulfate and filtered, and the filtered solution was concentrated under a reduced pressure. Then, the concentrated product was purified with n-hexane/dichloromethane (7:3 of a volume ratio) through silica gel column chromatography, obtaining 40.3 g of a white solid compound, an intermediate M-1 (95% of a yield).

LC-Mass (calcd.: 259.10 g/mol, measured.: M+1=260 g/mol)

Synthesis of Intermediate M-2

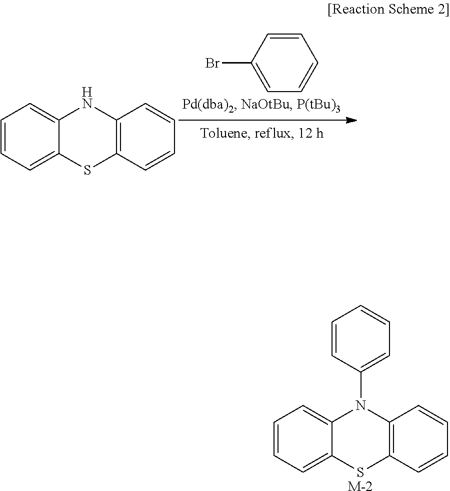

50 g (250.9 mmol) of phenothiazine, 47.3 g (301.1 mmol) of bromobenzene, 36.2 g (376.4 mmol) of sodium t-butoxide, and 1.52 g (7.53 mmol) of tri-tert-butylphosphine were dissolved in 500 ml of toluene, 1.44 g (2.51 mmol) of Pd(dba)₂ was added thereto, and the mixture was agitated for 6 hours under a nitrogen atmosphere while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 61.7 g of a white solid compound, an intermediate M-2 (89% of a yield).

LC-Mass (calcd.: 275.08 g/mol, measured.: M+1=276 g/mol)

Synthesis of Intermediate M-3

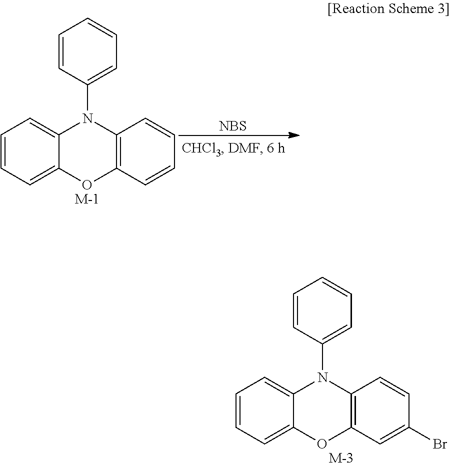

40 g (154.2 mmol) of the intermediate M-1 was dissolved in 400 ml of chloroform, and another solution prepared by dissolving 27.4 g (154.2 mmol) of N-bromosuccinimide in 120 ml of dimethylformamide was slowly added thereto for 4 hours, while the former solution was agitated at 0° C. The reactant was agitated at room temperature for 2 hours and then extracted with distilled water and dichloromethane. An organic layer obtained therefrom was dried with potassium carbonate and filtered, and the filtered solution was concentrated under a reduced pressure. The concentrated product was purified with n-hexane through silica gel column chromatography, obtaining 31.8 g of a white solid compound, an intermediate M-3 (61% of a yield).

LC-Mass (calcd.: 337.01 g/mol, measured.: M+1=339 g/mol)

Synthesis of Intermediate M-4

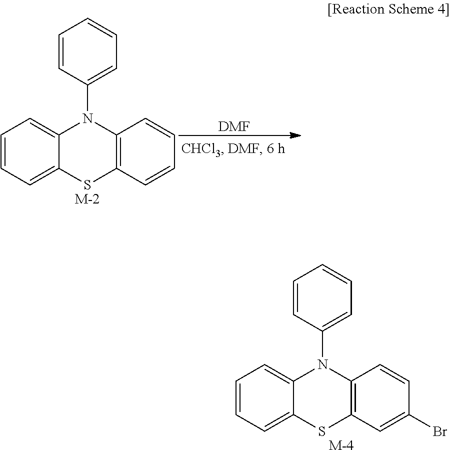

60 g (217.9 mmol) of the intermediate M-2 was dissolved in 600 ml of chloroform, and a solution prepared by dissolving 38.8 g (38.8 mmol) of N-bromosuccinimide in 180 ml of dimethylformamide was slowly added thereto for 4 hours, while the former solution was agitated at 0° C. The reactant was agitated at room temperature for 2 hours and extracted with distilled water and dichloromethane. An organic layer obtained therefrom was dried with potassium carbonate and filtered, and the filtered solution was concentrated under a reduced pressure. The concentrated product was purified with n-hexane through silica gel column chromatography, obtaining 48.6 g of a white solid compound, an intermediate M-4 (63% of a yield).

LC-Mass (calcd.: 352 g/mol, measured.: M+1=355 g/mol)

Synthesis of Intermediate M-5

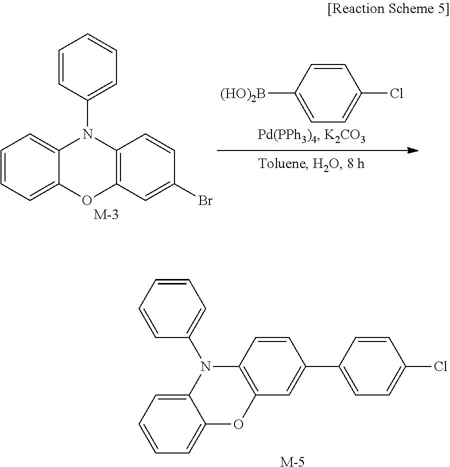

20 g (59.1 mmol) of the intermediate M-3, 9.2 g (59.1 mmol) of 4-chlorophenylboronic acid, and 0.68 g (0.59 mmol) of tetrakistriphenylphosphine palladium dissolved in 200 ml of toluene under a nitrogen atmosphere in a flask and, 100 ml of an aqueous solution in which 13 g (88.7 mmol) of potassium carbonate was dissolved was added thereto, and the mixture was agitated for 8 hours while being refluxed. When the reaction was complete, the resultant was extracted with ethyl acetate, the extracted solution was dried with magnesium sulfate and filtered, and the filtered solution was concentrated under a reduced pressure. The concentrated product was purified with n-hexane/dichloromethane (8:2 of a volume ratio) through silica gel column chromatography, obtaining 19.2 g of a white solid compound, an intermediate M-5 (88% of a yield).

LC-Mass (calcd.: 369.00 g/mol, measured.: M+1=370 g/mol)

Synthesis of Intermediate M-6

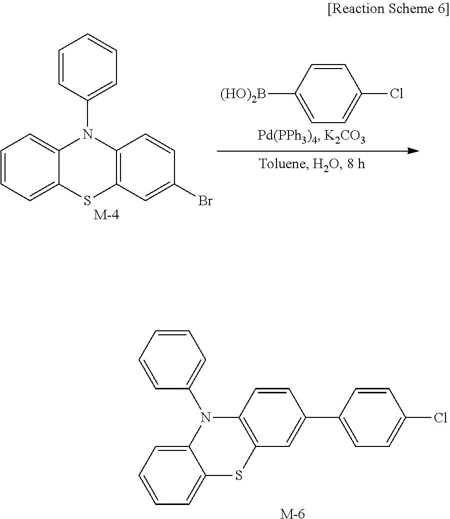

20.9 g (59.1 mmol) of the intermediate M-4, 9.2 g (59.1 mmol) of 4-chlorophenylboronic acid, and 0.68 g (0.59 mmol) of tetrakistriphenylphosphine palladium were dissolved in 200 ml of toluene under a nitrogen atmosphere in a flask, 100 ml of an aqueous solution in which 13 g (88.7 mmol) of potassium carbonate was dissolved was added thereto, and the mixture was agitated for 8 hours while being refluxed. When the reaction was complete, the resultant was extracted with ethyl acetate, an extracted solution was dried with magnesium sulfate and filtered, and the filtered solution was concentrated under a reduced pressure. The concentrated product was purified with n-hexane/dichloromethane (8:2 of a volume ratio) through silica gel column chromatography, obtaining 20.5 g of a white solid compound, an intermediate M-6 (90% of a yield).

LC-Mass (calcd.: 386.00 g/mol, measured.: M+1=387 g/mol)

Synthesis of Intermediate M-7

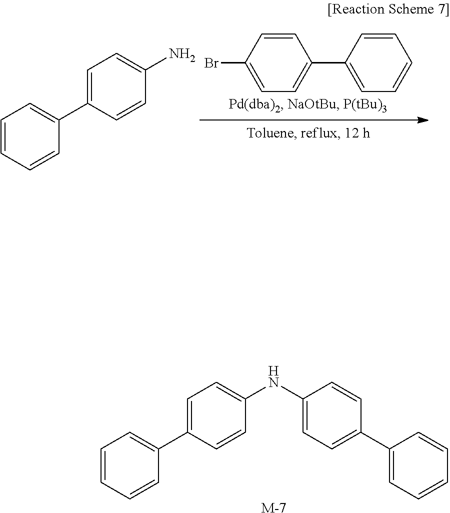

20 g (118.2 mmol) of 4-aminobiphenyl, 24.8 g (106.4 mmol) of 4-bromobiphenyl, 15.3 g (159.6 mmol) of sodium t-butoxide, and 0.65 g (3.19 mmol) of tri-tert-butylphosphine were dissolved in 590 ml of toluene, 0.61 g (1.06 mmol) of Pd(dba)₂ was added thereto, and the mixture was agitated under a nitrogen atmosphere for 6 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 26 g of a white solid compound, an intermediate M-7 (76% of a yield).

LC-Mass (calcd.: 321.00 g/mol, measured.: M+1=321.41 g/mol)

Synthesis of Intermediate M-8

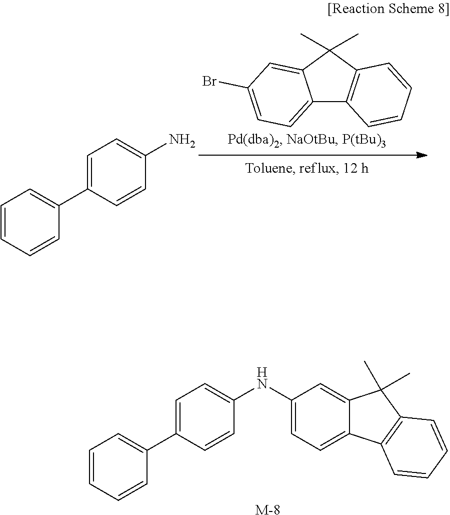 [SMILES: CC1(C)c2ccccc2-c2ccc(Br)cc21 ; Nc1ccc(-c2ccccc2)cc1 ; CC1(C)c2ccccc2-c2ccc(Nc3ccc(-c4ccccc4)cc3)cc21 ; "M-8"]

20 g (118.2 mmol) of 4-aminobiphenyl, 29.1 g (106.4 mmol) of 2-bromo-9,9-dimethylfluorene, 15.3 g (159.6 mmol) of sodium t-butoxide, and 0.65 g (3.19 mmol) of tri-tert-butylphosphine were dissolved in 590 ml of toluene, 0.61 g (1.06 mmol) of Pd(dba)₂ was added thereto, and the mixture was agitated for 6 hours under a nitrogen atmosphere while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 28.5 g of a white solid compound, an intermediate M-8 (74% of a yield).

LC-Mass (calcd.: 361.00 g/mol, measured.: M+1=362.00 g/mol)

Synthesis of Intermediate M-9

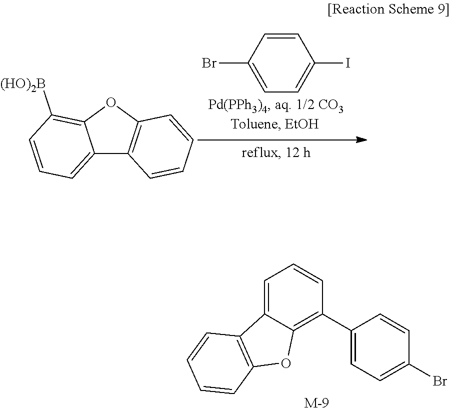 [SMILES: OB(O)c1cccc2c1oc1ccccc12 ; Brc1ccc(I)cc1 ; Brc1ccc(-c2cccc3c2oc2ccccc23)cc1 ; "M-9"]

20 g (94.4 mmol) of 4-dibenzofuranboronic acid, 28 g (99.2 mmol) of 1-bromo-4-iodobenzene, and 1.08 g (0.94 mmol) of tetrakistriphenylphosphine palladium were dissolved in 240 ml of toluene and 120 ml of ethanol under a nitrogen atmosphere in a flask, 120 ml of an aqueous solution in which 28 g (188.8 mmol) of potassium carbonate was dissolved was added thereto, and the mixture was agitated for 12 hours while being refluxed. When the reaction was complete, the resultant was extracted with ethyl acetate, the extracted solution was dried with magnesium sulfite and filtered, and the filtered solution was concentrated under a reduced pressure. The concentrated product was purified with n-hexane/dichloromethane (9:1 of a volume ratio) through silica gel column chromatography, obtaining 27 g of a white solid compound, an intermediate M-9 (89% of a yield).

LC-Mass (calcd.: 322.00 g/mol, measured.: M+1=323 g/mol)

Synthesis of Intermediate M-10

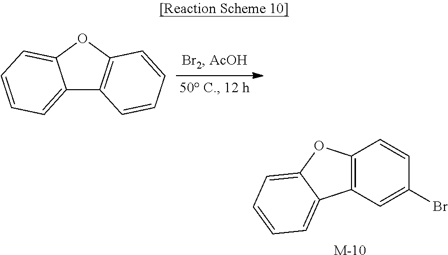

30 g (178.4 mmol) of dibenzofuran was dissolved in 270 g of acetic acid in a round-bottomed flask, and a solution prepared by dissolving 29 g (181.5 mmol) of bromine in 6 g of acetic acid was slowly added thereto at 50° C. for 4 hours. The reaction solution was additionally agitated at 50° C. for 8 hours, cooled down, and added to distilled water. An orange solid was dissolved in dichloromethane, the solution was cleaned with a sodium thiosulfite aqueous solution, an organic layer obtained therefrom was dried with magnesium sulfite and filtered, and the filtered solution was concentrated under a reduced pressure. The concentrated product was recrystallized with dichloromethane/n-hexane, obtaining 10.1 g of a white solid compound, an intermediate M-10 (23% of a yield).

GC-Mass (calcd.: 245.97 g/mol, measured.: M+1=246 g/mol)

Synthesis of Intermediate M-11

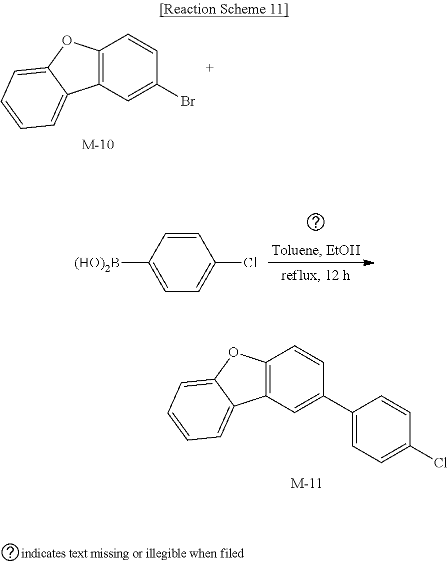

20 g (127.9 mmol) of 4-chlorophenylboronic acid, 30.0 g (121.5 mmol) of the intermediate M-10, and 1.48 g (1.28 mmol) of tetrakistriphenylphosphine palladium were dissolved in 320 ml of toluene and 160 ml of ethanol in a flask under a nitrogen atmosphere, 160 ml of an aqueous solution in which 37.7 g (255.8 mmol) of potassium carbonate was dissolved was added thereto, and the mixture was agitated for 12 hours while being refluxed. When the reaction was complete, the resultant was extracted with ethyl acetate, the extracted solution was dried with magnesium sulfite and filtered, and the filtered solution was concentrated under a reduced pressure. The concentrated product was purified with n-hexane/dichloromethane (9:1 volume ratio) through silica gel column chromatography, obtaining 28.1 g of a white solid compound, an intermediate M-11 (83% of a yield).

LC-Mass (calcd.: 278.05 g/mol, measured.: M+1=279 g/mol)

Synthesis of Intermediate M-12

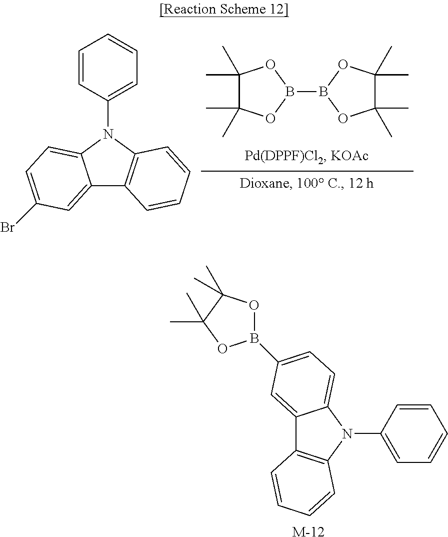

50 g (155.18 mmol) of 3-bromo-9-phenyl-9H-carbazole, 3.41 g (4.65 mmol) of Pd(dip)Cl₂, 51.32 g (201.8 mmol) of bis(pinacolato)diboron, and 45.8 g (465.5 mmol) of potassium acetate were dissolved in 520 ml of 1,4-dioxane. The reactant was reflux-agitated under a nitrogen atmosphere for 12 hours and then three times extracted with dichloromethane and distilled water. The extracted solution was dried with magnesium sulfite and filtered, and the filtered solution was concentrated under a reduced pressure. The concentrated product was purified with n-hexane/dichloromethane (7:3 of a volume ratio) through silica gel column chromatography, obtaining 43 g of a white solid compound, an intermediate M-12 (75% of a yield).

LC-Mass (calcd.: 369.19 g/mol, measured.: M+1=370 g/mol)

Synthesis of Intermediate M-13

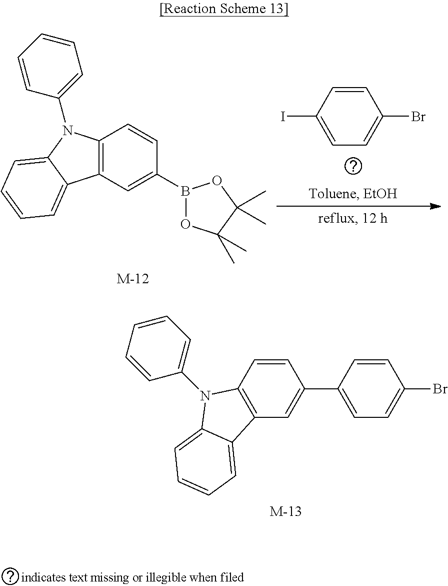 [SMILES: CC1(C)OB(c2ccc3c(c2)c2ccccc2n3-c2ccccc2)OC1(C)C ; Brc1ccc(I)cc1 ; "M-12" ; Brc1ccc(-c2ccc3c(c2)c2ccccc2n3-c2ccccc2)cc1 ; "M-13"]

40 g (108.3 mmol) of the intermediate M-12, 30.6 g (108.3 mmol) of 1-bromo-4-iodobenzene, and 1.25 g (1.08 mmol) of tetrakistriphenylphosphine palladium were dissolved in 270 ml of toluene and 135 ml of ethanol in a flask under a nitrogen atmosphere. Then, 135 ml of an aqueous solution in which 31.9 g (58.9 mmol) of potassium carbonate was added to the solution, and the mixture was agitated for 12 hours while being refluxed. When the reaction was complete, the resultant was extracted with ethyl acetate, the extracted solution was dried with magnesium sulfite and filtered, and the filtered solution was concentrated under a reduced pressure. The concentrated product was purified with n-hexane/dichloromethane (7:3 of a volume ratio) through silica gel column chromatography, obtaining 35 g of a white solid compound, an intermediate M-13 (81% of a yield).

LC-Mass (calcd.: 398.29 g/mol, measured.: M+1=399 g/mol)

Synthesis of Intermediate M-14

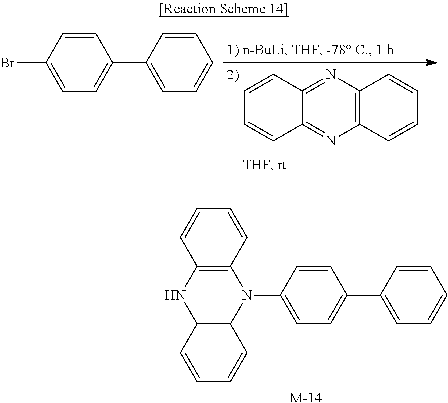

10 g (42.9 mmol) of 4-bromobiphenyl was dissolved in 143 ml of anhydrous tetrahydrofuran in a round-bottomed flask under a nitrogen atmosphere. The solution was cooled down to −78° C. and agitated, 27 ml (42.9 mmol) of a 1.6 M n-butyl lithium hexane solution was slowly added thereto, and the mixture was reacted at −78° C. for 1 hour. 8.5 g (47.2 mmol) of phenazine was dissolved in 143 ml of anhydrous tetrahydrofuran in a round-bottomed flask under a nitrogen atmosphere. The solution was cooled down to −78° C. and agitated, a 4-biphenyl lithium solution was slowly added thereto, and the mixture was heated up to room temperature and reacted for 12 hours. Then, distilled water was added to the resultant to complete the reaction, the reaction solution was concentrated under a reduced pressure to remove tetrahydrofuran and then extracted with toluene/distilled water, an organic layer obtained therefrom was dried with sodium sulfate and filtered, and the filtered solution was concentrated under a reduced pressure. The concentrated product was recrystallized under nitrogen and then purified with toluene/ethanol, obtaining 7.2 g of a desired compound, an intermediate M-14 (50% of a yield). The obtained product was refrigerated under nitrogen.

LC-Mass (calcd.: 336.00 g/mol, measured.: M+1=337.00 g/mol)

Synthesis of Intermediate M-15

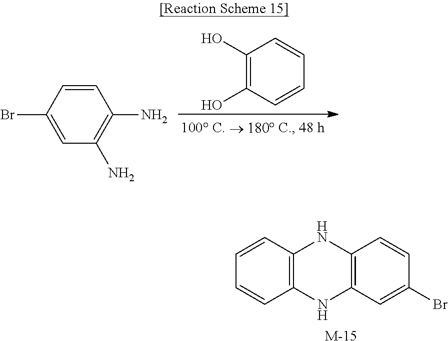

18.7 g (100 mmol) of 4-bromo-1,2-diaminobenzene and 22 g (200 mmol) of catechol were heated to 100° C. and agitated under nitrogen atmosphere in a round-bottomed flask until completely dissolved, and the solution was heated up to 180° C. and then heated and agitated for 48 hours. The resultant was cooled down to 80° C., toluene and distilled water were added thereto, and the mixture was agitated for 1 hour under a nitrogen atmosphere. The resultant was extracted with toluene and distilled water, an organic layer obtained therefrom was dried with sodium sulfate and filtered, and the filtered solution was concentrated under a reduced pressure. The concentrated product was recrystallized and purified with toluene/ethanol under nitrogen, obtaining 15.9 g of a compound, an intermediate M-15 (61% of a yield). The obtained product was refrigerated under nitrogen.

LC-Mass (calcd.: 260.00 g/mol, measured.: M+1=261.00 g/mol)

Synthesis of Intermediate M-16

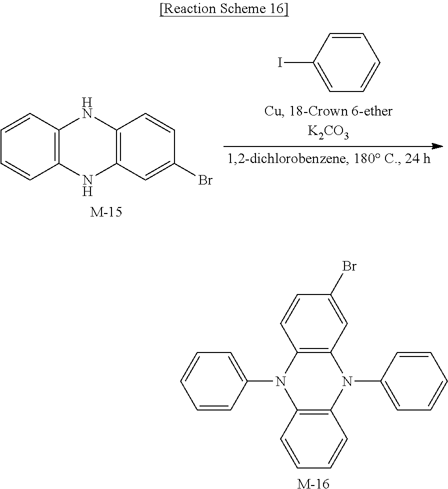

10 g (38.3 mmol) of the intermediate M-15, 46.9 g (229.8 mmol) of iodobenzene, and 21.1 g (153.2 mmol) of potassium carbonate were dissolved in 130 ml of 1,2-dichlorobenzene, 0.49 g (7.66 mmol) of copper powder and 2.02 g (7.66 mmol) of 18-crown-6-ether were added thereto, and the mixture was agitated at 180° C. for 24 hours under a nitrogen atmosphere. When the reaction was complete, the resultant was extracted with dichloromethane and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 13.5 g of a compound, an intermediate M-16 (85% of a yield).

LC-Mass (calcd.: 412.00 g/mol, measured.: M+1=413.00 g/mol)

### Example 1

### Preparation of Compound Represented by Chemical Formula A-140

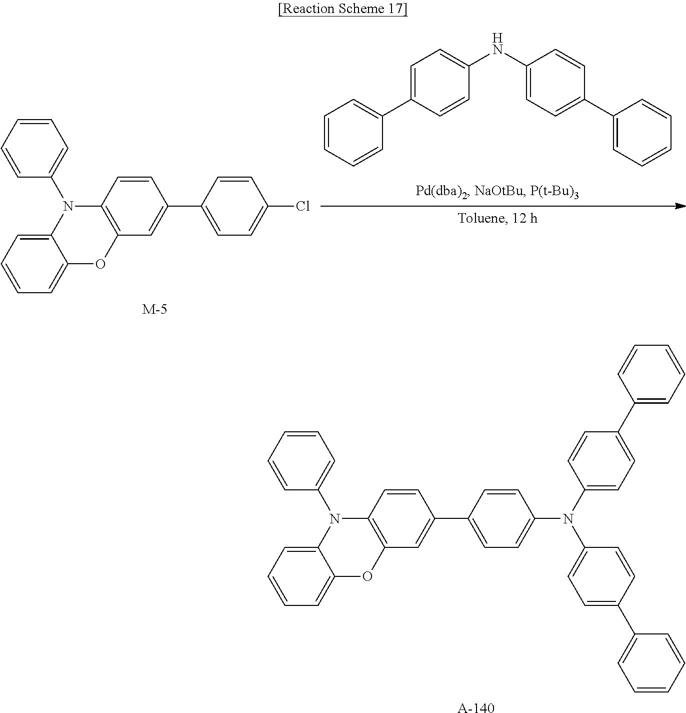 [SMILES: Clc1ccc(-c2ccc3c(c2)Oc2ccccc2N3c2ccccc2)cc1 ; c1ccc(-c2ccc(Nc3ccc(-c4ccccc4)cc3)cc2)cc1 ; "M-5" ; c1ccc(-c2ccc(N(c3ccc(-c4ccccc4)cc3)c3ccc(-c4ccc5c(c4)Oc4ccccc4N5c4ccccc4)cc3)cc2)cc1 ; "A-140"]

10 g (27.0 mmol) of the intermediate M-5, 8.7 g (27.0 mmol) of the intermediate M-7, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 15.7 g of a white solid compound, an intermediate A-140 (89% of a yield).

LC-Mass (calcd.: 654.00 g/mol, measured.: M+1=655.00 g/mol)

### Example 2

### Preparation of Compound Represented by Chemical Formula A-142

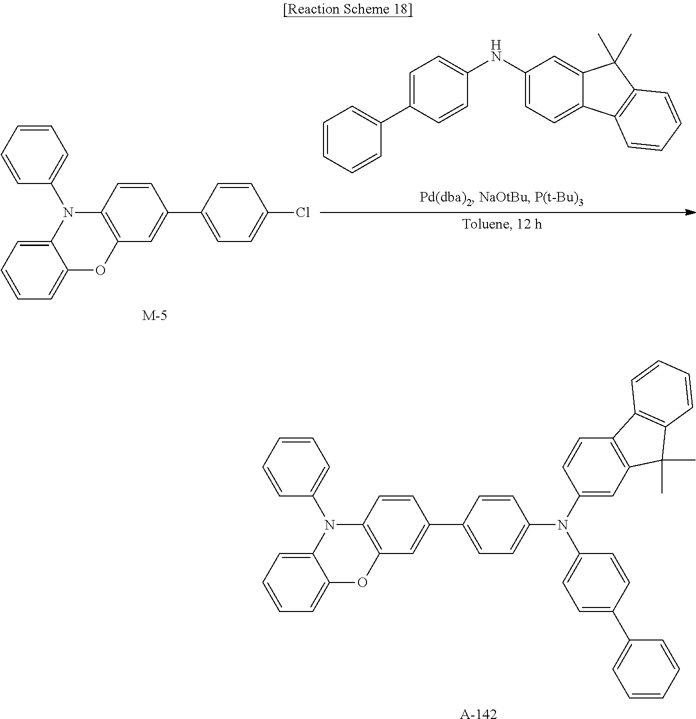 [SMILES: Clc1ccc(-c2ccc3c(c2)Oc2ccccc2N3c2ccccc2)cc1 ; CC1(C)c2ccccc2-c2ccc(Nc3ccc(-c4ccccc4)cc3)cc21 ; "M-5" ; CC1(C)c2ccccc2-c2ccc(N(c3ccc(-c4ccccc4)cc3)c3ccc(-c4ccc5c(c4)Oc4ccccc4N5c4ccccc4)cc3)cc21 ; "A-142"]

10 g (27.0 mmol) of the intermediate M-5, 9.8 g (27.0 mmol) of the intermediate M-8, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 17.1 g of a white solid compound, an intermediate A-142 (91% of a yield).

LC-Mass (calcd.: 694.00 g/mol, measured.: M+1=695.00 g/mol)

### Example 3

### Preparation of Compound Represented by Chemical Formula A-216

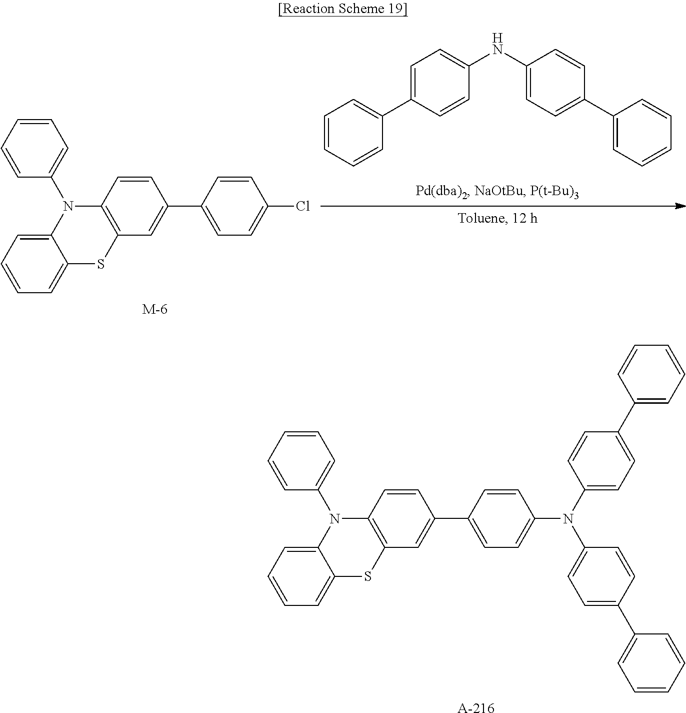 [SMILES: Clc1ccc(-c2ccc3c(c2)Sc2ccccc2N3c2ccccc2)cc1 ; c1ccc(-c2ccc(Nc3ccc(-c4ccccc4)cc3)cc2)cc1 ; "M-6" ; c1ccc(-c2ccc(N(c3ccc(-c4ccccc4)cc3)c3ccc(-c4ccc5c(c4)Sc4ccccc4N5c4ccccc4)cc3)cc2)cc1 ; "A-216"]

10.4 g (27.0 mmol) of the intermediate M-6, 8.7 g (27.0 mmol) of the intermediate M-7, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 16.5 g of a white solid compound, an intermediate A-216 (91% of a yield).

LC-Mass (calcd.: 670.00 g/mol, measured.: M+1=671.00 g/mol)

### Example 4

### Preparation of Compound Represented by Chemical Formula A-217

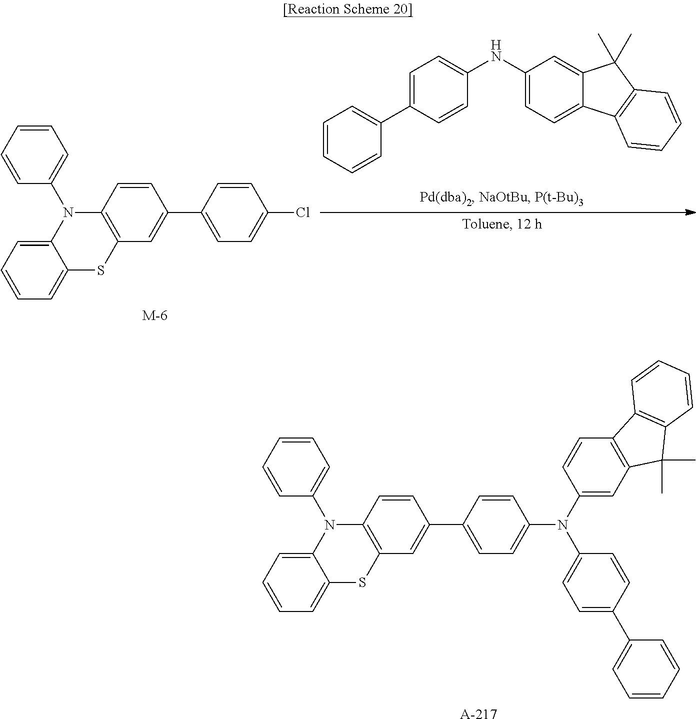 [SMILES: Clc1ccc(-c2ccc3c(c2)Sc2ccccc2N3c2ccccc2)cc1 ; CC1(C)c2ccccc2-c2ccc(Nc3ccc(-c4ccccc4)cc3)cc21 ; "M-6" ; CC1(C)c2ccccc2-c2ccc(N(c3ccc(-c4ccccc4)cc3)c3ccc(-c4ccc5c(c4)Sc4ccccc4N5c4ccccc4)cc3)cc21 ; "A-217"]

10.4 g (27.0 mmol) of the intermediate M-6, 9.8 g (27.0 mmol) of the intermediate M-8, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 16.9 g of a white solid compound, an intermediate A-217 (88% of a yield).

LC-Mass (calcd.: 710.00 g/mol, measured.: M+1=711.00 g/mol)

### Example 5

### Preparation of Compound Represented by Chemical Formula B-1

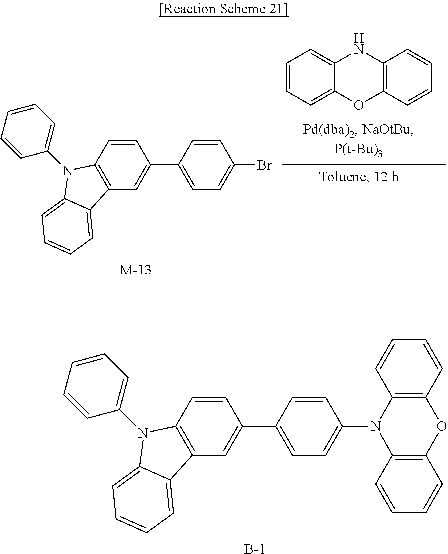

10.8 g (27.0 mmol) of the intermediate M-13, 5 g (27.0 mmol) of phenoxazine, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 12.4 g of a white solid compound, an intermediate B-1 (92% of a yield).

LC-Mass (calcd.: 500.00 g/mol, measured.: M+1=501.00 g/mol)

### Example 6

### Preparation of Compound Represented by Chemical Formula B-35

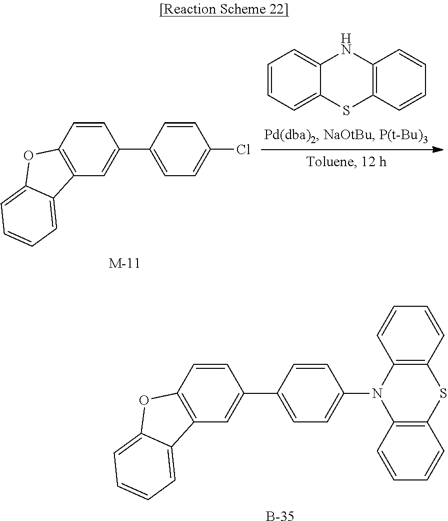

7.5 g (27.0 mmol) of the intermediate M-11, 5.4 g (27.0 mmol) of phenothiazine, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 10.8 g of a white solid compound, an intermediate B-35 (91% of a yield).

LC-Mass (calcd.: 441.00 g/mol, measured.: M+1=442.00 g/mol)

### Example 7

### Preparation of Compound Represented by Chemical Formula C-35

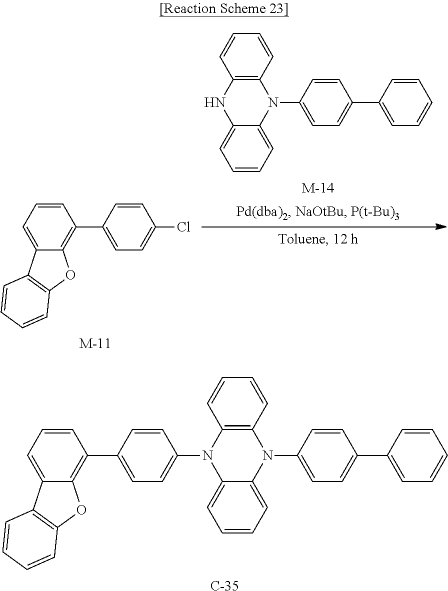

7.5 g (27.0 mmol) of the intermediate M-11, 9.1 g (27.0 mmol) of the intermediate M-14, 3.9 g (40.5 mmol) of sodium t-butoxide, and 0.16 g (0.81 mmol) of tri-tert-butylphosphine were dissolved in 270 ml of toluene, 0.15 g (0.27 mmol) of Pd(dba)₂ was added thereto, and the mixture was agitated under a nitrogen atmosphere for 12 hours while being refluxed. When the reaction was complete, the resultant was extracted with ethyl acetate and distilled water, an organic layer obtained therefrom was dried with magnesium sulfate and filtered, and the filtered solution was concentrated under a reduced pressure. The concentrated product was purified with n-hexane/dichloromethane (7:3 of a volume ratio) through silica gel column chromatography, obtaining 14 g of a white solid compound, an intermediate C-35 (90% of a yield).

LC-Mass (calcd.: 576.00 g/mol, measured.: M+1=577.00 g/mol)

### Example 8

### Preparation of Compound Represented by Chemical Formula A-237

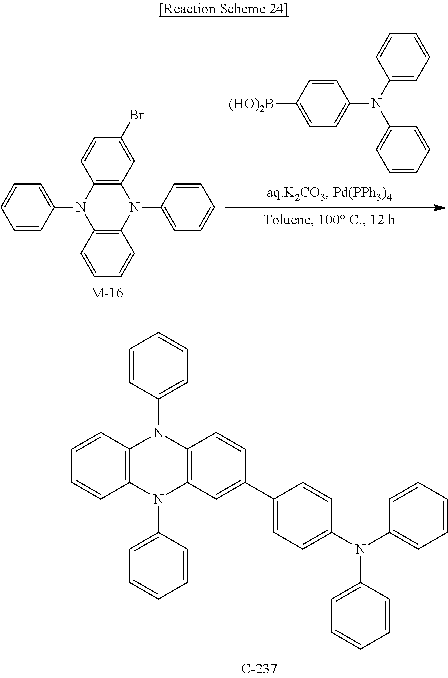

9.0 g (21.6 mmol) of the intermediate M-16, 6.2 g (21.6 mmol) of triphenylamine-4-boronic acid, and 0.26 g (0.108 mmol) of tetrakistriphenylphosphine palladium were dissolved in 216 ml of toluene under a nitrogen atmosphere in a flask. Subsequently, 150 ml of an aqueous solution in which 6.4 g (11.8 mmol) of potassium carbonate was dissolved was added to the solution, and the mixture was agitated for 12 hours while being refluxed. When the reaction was complete, the resultant was extracted with toluene, the extracted solution was dried with magnesium sulfate and filtered, and the filtered solution was concentrated under a reduced pressure. The concentrated product was purified with n-hexane/dichloromethane (7:3 of a volume ratio) through silica gel column chromatography, obtaining 10.6 g of a white solid compound A-237 (85% of a yield).

LC-Mass (calcd.: 577.00 g/mol, measured.: M+1=578.00 g/mol)

### Manufacture of Organic Light Emitting Diode

### Example 9

A glass substrate coated with ITO (Indium tin oxide) to form a 1500 Å-thick thin film was cleaned with a distilled water ultrasonic wave. After cleaning with distilled water, the glass substrate was ultra sonic wave-cleaned with a solvent such as isopropyl alcohol, acetone, methanol, and the like and moved to a plasma cleaner and then cleaned by using oxygen plasma for 5 minutes and moved to a vacuum-depositor. This ITO transparent electrode was used as an anode, 4,4′-bis[N-[4-{N,N-bis(3-methylphenyl)amino}-phenyl]-N-phenylamino]biphenyl (DNTPD) was vacuum-deposited on the ITO substrate to form a 600 Å-thick hole injection layer (HIL). Subsequently, the compound according to Example 1 was vacuum-deposited to form a 300 Å-thick hole transport layer (HTL). On the hole transport layer (HTL), a 250 Å-thick emission layer was vacuum-deposited by doping 9,10-di-(2-naphthyl)anthracene (ADN) as a host with 3 wt % of 2,5,8,11-tetra(tert-butyl)perylene (TBPe) as a dopant.

Subsequently, Alq3 was vacuum-deposited to form a 250 Å-thick electron transport layer (ETL) on the emission layer. On the electron transport layer (ETL), 10 Å-thick LiF and 1000 Å-thick Al were sequentially vacuum-deposited to form a cathode, manufacturing an organic light emitting diode.

The organic light emitting diode has a structure of five organic thin layers and specifically, a structure of:
1000 Å Al/10 Å LiF/250 Å Alq3/250 Å EML[ADN:TBPe=97:3]/300 Å HTL/600 Å DNTPD/1500 Å ITO.

### Example 10

An organic light emitting diode was manufactured according to the same method as Example 9 except for using the compound according to Example 2 instead of the compound according to Example 1.

### Example 11

An organic light emitting diode was manufactured according to the same method as Example 9 except for using the compound according to Example 3 instead of the compound according to Example 1.

### Example 12

An organic light emitting diode was manufactured according to the same method as Example 9 except for using the compound according to Example 4 instead of the compound according to Example 1.

### Example 13

An organic light emitting diode was manufactured according to the same method as Example 9 except for using the compound according to Example 5 instead of the compound according to Example 1.

### Example 14

An organic light emitting diode was manufactured according to the same method as Example 9 except for using the compound according to Example 6 instead of the compound according to Example 1.

### Example 15

An organic light emitting diode was manufactured according to the same method as Example 9 except for using the compound according to Example 7 instead of the compound according to Example 1.

### Example 16

An organic light emitting diode was manufactured according to the same method as Example 9 except for using the compound according to Example 8 instead of the compound according to Example 1.

### Comparative Example 1

An organic light emitting diode was manufactured according to the same method as Example 9 except for using NPB instead of the compound according to Example 1. The NPB has a structure shown below.

### Comparative Example 2

An organic light emitting diode was manufactured according to the same method as Example 9 except for using HT1 instead of the compound according to Example 1. The HT1 has a structure shown below.

### Comparative Example 3

An organic light emitting diode was manufactured according to the same method as Example 9 except for using HT2 instead of the compound according to Example 1. The HT1 has a structure shown below.

### Comparative Example 4

An organic light emitting diode was manufactured according to the same method as Example 9 except for using HT3 instead of the compound according to Example 1. The HT3 has a structure shown below.

The DNTPD, ADN, TBPe, NPB, HT1, HT2, and HT3 used for an organic light emitting diode respectively have a structure shown below.

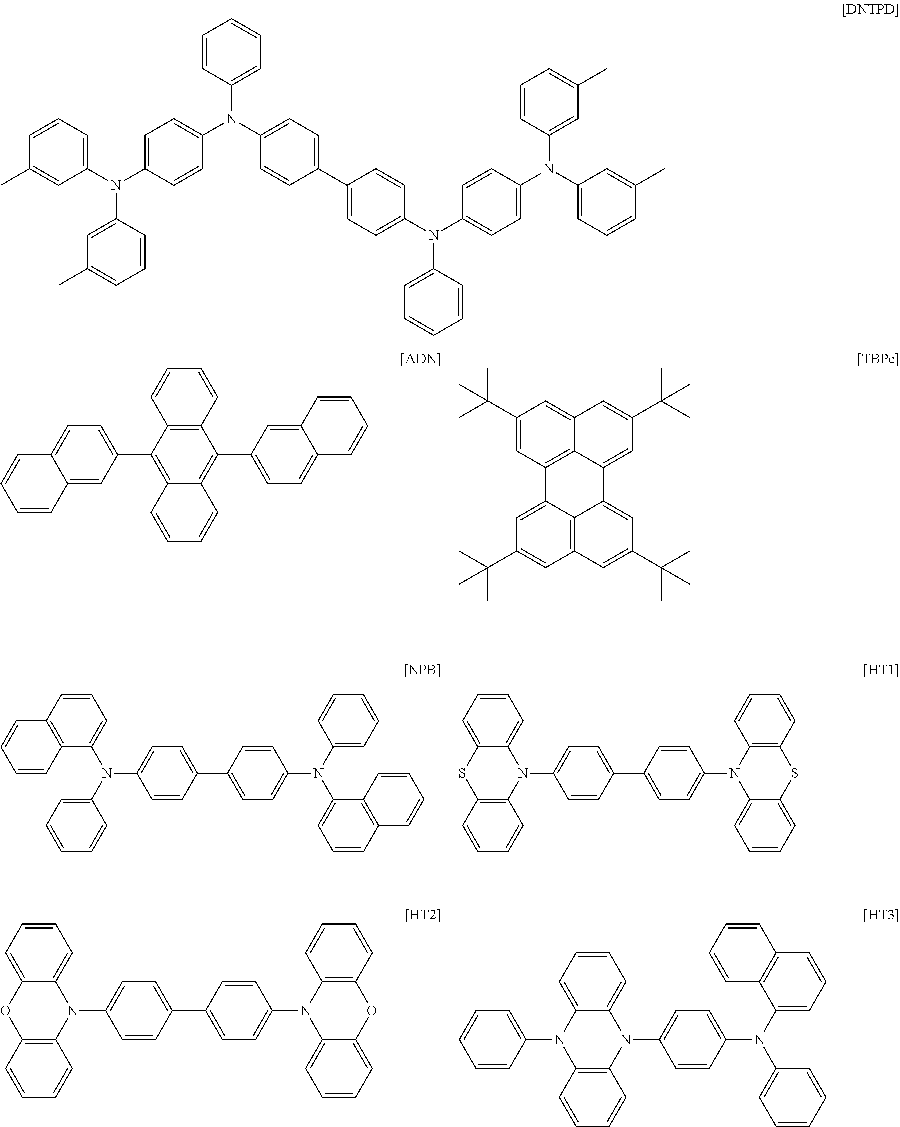

(Analysis and Characteristics Measurement of Compound)

¹H-NMR Result Analysis

The molecular weights of the intermediates M-1 to M-8 and the compounds according to Examples 1 to 2 were measured by using LC-MS for a structure analysis, and ¹H-NMR thereof was measured by using a 300 MHz NMR equipment after dissolved in a CD₂Cl₂ solvent.

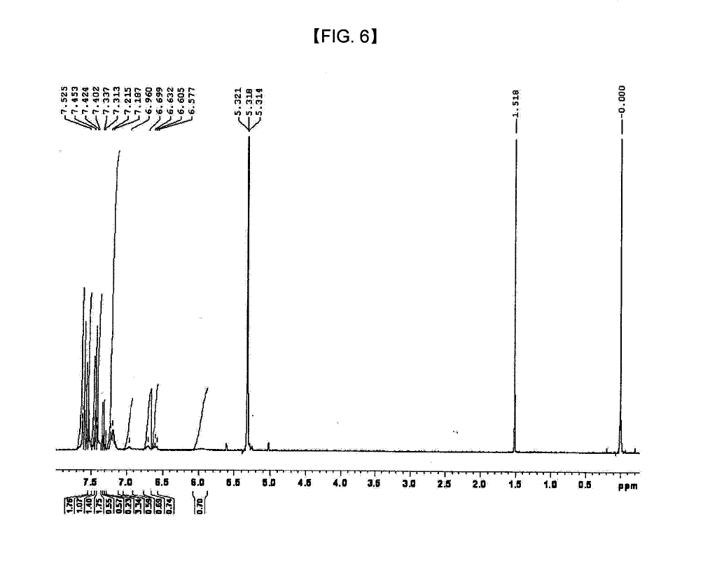

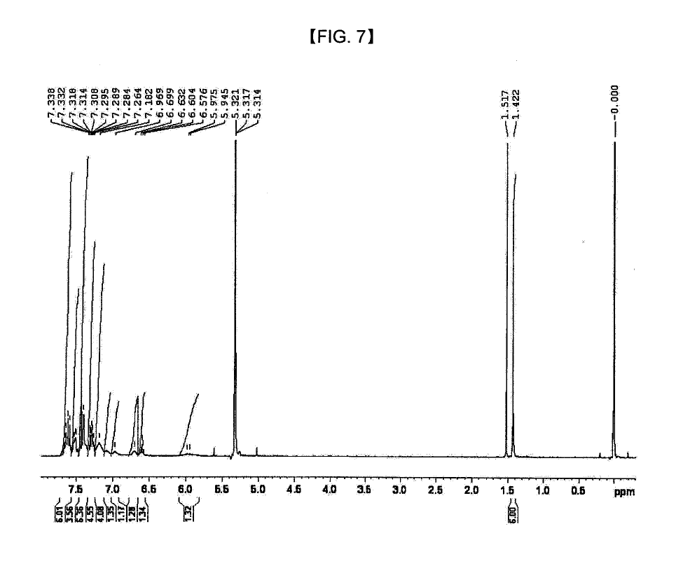

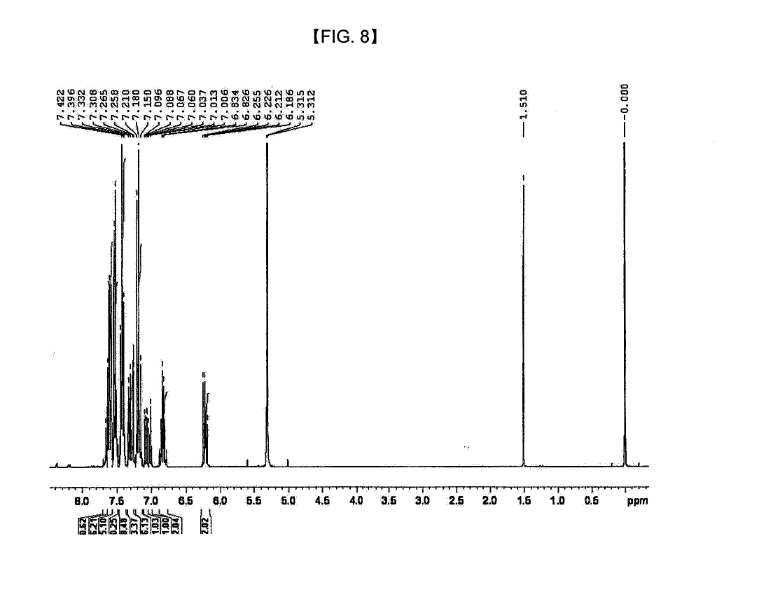

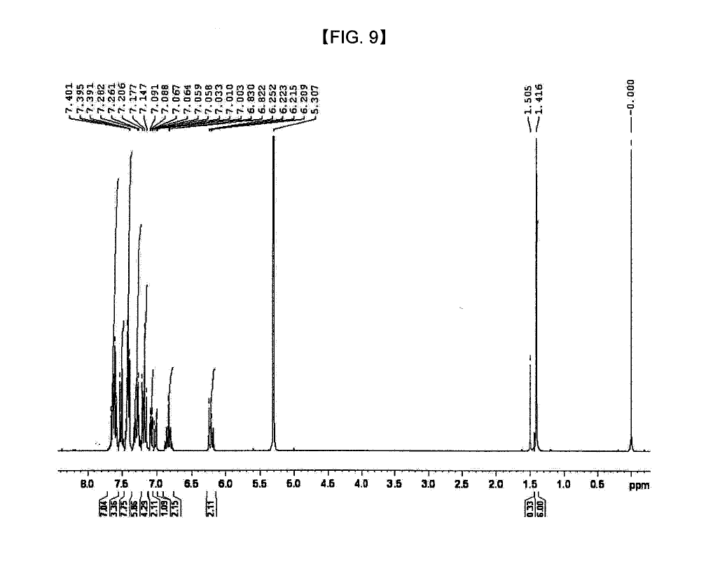

FIG. 6 shows ¹H-NMR data of the compound A-140 according to Example 1, FIG. 7 shows ¹H-NMR data of the compound A-142 according to Example 2, FIG. 8 shows ¹H-NMR data of the compound A-216 according to Example 3, and FIG. 9 shows ¹H-NMR data of the compound A-217 according to Example 4.

Referring to FIGS. 6, 7, 8, and 9, desired compounds were synthesized.

(Performance Measurement of Organic Light Emitting Diode)

Current density and luminance changes depending on voltage and luminous efficiency of each organic light emitting diode according to Examples 9 to 16 and Comparative Examples 1 to 4 were measured. The measurements were specifically performed in the following method. The results were provided in the following Table 1.

(1) Measurement of Current Density Change Depending on Voltage Change

The manufactured organic light emitting diodes were measured for current value flowing in the unit device, while increasing the voltage from 0V to 10V using a current-voltage meter (Keithley 2400), and the measured current value was divided by an area to provide the result.

(2) Measurement of Luminance Change Depending on Voltage Change

The organic light emitting diodes were measured for luminance, while increasing the voltage faint 0V to 10V using a luminance meter (Minolta Cs-1000A).

(3) Measurement of Luminous Efficiency

Current efficiency (cd/A) and electric power efficiency (lm/W) at the same current density (10 mA/cm²) were calculated by using the luminance, current density, and voltages from the items (1) and (2).

TABLE 1

| | Compound used | Volt- | Color | Effi- | Half-life |
|---|---|---|---|---|---|
| | in hole transport | age | (EL | ciency | life-span (h) |
| Devices | layer (HTL) | (V) | color) | (cd/A) | at 1000 cd/m² |
| Example 9 | A-140 | 6.2 | Blue | 5.7 | 1,510 |
| Example 10 | A-142 | 6.2 | Blue | 5.8 | 1,490 |
| Example 11 | A-216 | 6.3 | Blue | 5.6 | 1,360 |
| Example 12 | A-217 | 6.3 | Blue | 5.8 | 1,340 |
| Example 13 | B-1 | 6.5 | Blue | 4.9 | 1,250 |
| Example 14 | B-35 | 6.6 | Blue | 5.0 | 1,140 |
| Example 15 | C-35 | 6.6 | Blue | 5.0 | 1,210 |
| Example 16 | C-237 | 6.4 | Blue | 5.5 | 1,290 |
| Comparative | NPB | 7.1 | Blue | 4.9 | 1,250 |
| Example 1 | | | | | |
| Comparative | HT1 | 7.0 | Blue | 4.1 | 1,080 |
| Example 2 | | | | | |
| Comparative | HT2 | 6.8 | Blue | 4.4 | 1,210 |
| Example 3 | | | | | |
| Comparative | HT3 | 6.6 | Blue | 4.1 | 1,050 |
| Example 4 | | | | | |

Current Density: 10 mA/cm²

From the results of the Table 1, the organic light emitting diodes according to Example 9 to 16 showed low driving voltages and improved efficiency.

In addition, the organic light emitting diodes according to Examples 9 to 11 and 16 showed improved half-life life-spans compared with the organic light emitting diodes according to Comparative Examples 1 to 4 and, particularly, the organic light emitting diode according to Example 9 showed a half-life life-span of 1,380 hours (h), which was greater than or equal to 20% improved half-life life-span compared with 1,250 hours of the organic light emitting diode according to Comparative Example 1. Considering that life-span of a device is important for commercial availability, the half-life life-span improvement of the devices according to the Examples indicates suitability for commercial application.

By way of summation and review, examples of an organic optoelectronic device include an organic photoelectric device, an organic light emitting diode, an organic solar cell, an organic photo conductor drum, an organic transistor, and the like, Such devices may use a hole injecting or transport material, an electron injecting or transport material, and/or a light emitting material.

An organic light emitting diode (OLED) has drawn attention due to a demand for flat panel displays. In general, organic light emission refers to conversion of electrical energy into photo-energy.

Such an organic light emitting diode converts electrical energy into light by applying current to an organic light emitting material. It has a structure in which a functional organic material layer is interposed between an anode and a cathode. The organic material layer may include a multi-layer including different materials, for example a hole injection layer (HIL), a hole transport layer (HTL), an emission layer, an electron transport layer (ETL), and an electron injection layer (EIL), which may improve efficiency and stability of an organic photoelectric device.

In such an organic light emitting diode, when a voltage is applied between an anode and a cathode, holes from the anode and electrons from the cathode are injected to an organic material layer and recombined to generate excitons having high energy. The generated excitons generate light having certain wavelengths while shifting to a ground state.

A phosphorescent light emitting material may be used for a light emitting material of an organic photoelectric device in addition to the fluorescent light emitting material. Such a phosphorescent material emits lights by transporting the electrons from a ground state to an exited state, non-radiance transiting of a singlet exciton to a triplet exciton through intersystem crossing, and transiting a triplet exciton to a ground state to emit light.

As described above, in an organic light emitting diode, an organic material layer may include a light emitting material and a charge transport material, for example a hole injection material, a hole transport material, an electron transport material, an electron injection material, or the like.

The light emitting material may be classified as blue, green, and red light emitting materials according to emitted colors, and yellow and orange light emitting materials to emit colors approaching natural colors.

When one material is used as a light emitting material, a maximum light emitting wavelength may be shifted to a long wavelength or color purity may decrease because of interactions between molecules, or device efficiency may decrease because of a light emitting quenching effect. Therefore, a host/dopant system may be used as a light emitting material in order to improve color purity, and increase luminous efficiency and stability through energy transfer.

In an organic light emitting diode, a material constituting an organic material layer, for example a hole injection material, a hole transport material, a light emitting material, an electron transport material, an electron injection material, or a light emitting material such as a host and/or a dopant, are desirably stable and have good efficiency. This material development is also required for other organic optoelectronic devices.

A low molecular weight organic light emitting diode may be manufactured as a thin film in a vacuum deposition method and may have good efficiency and life-span performance. A polymer organic light emitting diode may be manufactured in an inkjet or spin coating method, and may have an advantage of low initial cost and being applicable to a large-sized apparatus.

Both low molecular weight organic light emitting and polymer organic light emitting diodes have an advantage of self-light emitting, high speed response, wide viewing angle, ultra-thin, high image quality, durability, large driving temperature range, and the like. In particular, they may have good visibility due to self-light emitting characteristics compared with a conventional LCD (liquid crystal display), and may have an advantage of decreasing thickness and weight of LCD up to a third, because they do not need a backlight.

In addition, they may have a response speed 1000 times faster microsecond unit than LCD, and they may realize a high quality motion picture without after-image. Based on these advantages, they have been remarkably developed to have 80 times efficiency and more than 100 times life-span since they come out for the first time in the late 1980s. They keep being made larger, such as a 40-inch organic light emitting diode panel.

It is desired that they simultaneously have improved luminous efficiency and life-span in order to be larger. Luminous efficiency may be improved by smooth combination between holes and electrons in an emission layer. An organic material in general may have slower electron mobility than hole mobility, which may lead to inefficient combination between holes and electrons. Accordingly, increasing electron injection and mobility from a cathode and simultaneously preventing movement of holes is desired.

Preventing a material crystallization caused by Joule heat generated during device operation may improve life-span. Accordingly, it is desired that an organic compound have excellent electron injection and mobility, and high electrochemical stability.

As described above, embodiments may provide a compound for an organic optoelectronic device that may act as light emission, or electron injection and transport material, and also act as a light emitting host along with an appropriate dopant. Embodiments may also provide an organic optoelectronic device having excellent life-span, efficiency, driving voltage, electrochemical stability, and thermal stability. Embodiments may provide a compound for an organic optoelectronic device that may exhibit excellent life-span, efficiency, electrochemical stability, and thermal stability, an organic light emitting diode including the compound, and a display device including the organic light emitting diode. Embodiments may also provide an organic optoelectronic device having excellent electrochemical and thermal stability and life-span characteristics, and high luminous efficiency at a low driving voltage.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A compound for an organic optoelectronic device, the compound being represented by the following Chemical Formula 1: 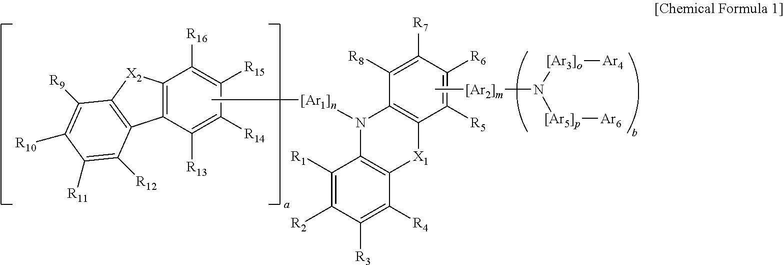
wherein, in the above Chemical Formula 1,
R₁ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
one of R₁ to R₈ links to Ar₂ when Ar₂ is present,
one of R₉ to R₁₆ links to Ar₁ when Ar₁ is present,
X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₁, Ar₂, Ar₃, and Ar₅ are the same or different, and are independently a substituted or unsubstituted C6 to C30 arylene group or a substituted or unsubstituted C2 to C30 heteroarylene group,
Ar₄ and Ar₆ are the same or different, and are independently a substituted or unsubstituted C6 to C30 aryl group or a substituted or unsubstituted C3 to C30 heteroaryl group,
n, m, o, and p are the same or different, and are independently integers ranging from 0 to 4,
a and b are the same or different, and are independently integers of 0 or 1, provided that at least one of a or b is 1.

2. The compound for an organic optoelectronic device as claimed in claim 1, wherein the compound is represented by the following Chemical Formula 2: 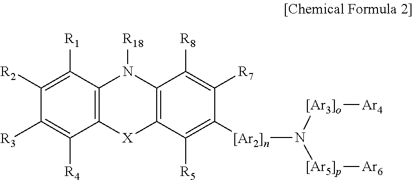
wherein, in the above Chemical Formula 2,
R₁ to R₅, R₇, R₈, and R₁₈ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
X is NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₂ is a substituted or unsubstituted C6 to C30 arylene group or a substituted or unsubstituted C2 to C30 heteroarylene group,
Ar₃ and Ar₅ are the same or different, and are independently a substituted or unsubstituted C6 to C30 arylene group or a substituted or unsubstituted C2 to C30 heteroarylene group,
Ar₄ and Ar₆ are the same or different, and are independently a substituted or unsubstituted C6 to C30 aryl group or a substituted or unsubstituted C3 to C30 heteroaryl group, and
n, o, and p are the same or different, and are independently integers ranging from 0 to 4.

3. The compound for an organic optoelectronic device as claimed in claim 1, wherein the compound is represented by the following Chemical Formula 3: 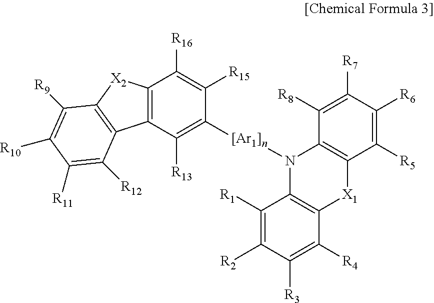
wherein, in the above Chemical Formula 3,
R₁ to R₁₃, R₁₅, and R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
X₁ and X₂ are the same or different, and are independently NR₁₇, O, S, SO₂(O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₁ is a substituted or unsubstituted C6 to C30 arylene group or a substituted or unsubstituted C2 to C30 heteroarylene group, and
n is an integer ranging from 0 to 4.

4. The compound for an organic optoelectronic device of claim 1, wherein the compound is represented by the following Chemical Formula 4: 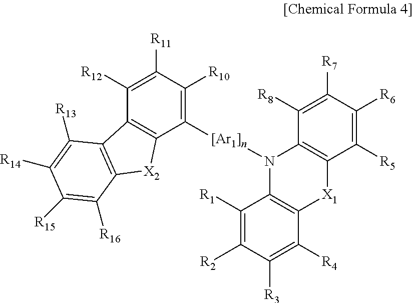
wherein, in the above Chemical Formula 4,
R₁ to R₈ and R₁₀ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₁ is a substituted or unsubstituted C6 to C30 arylene group or a substituted or unsubstituted C2 to C30 heteroarylene group, and
n is an integer ranging from 0 to 4.

5. The compound for an organic optoelectronic device as claimed in claim 1, wherein the compound is represented by the following Chemical Formula 5: 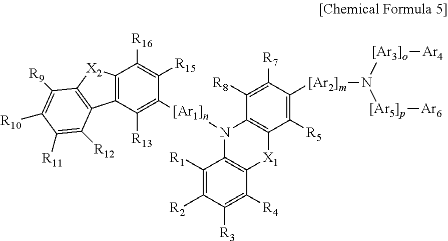
wherein, in the above Chemical Formula 5,
R₁ to R₅, R₇ to R₁₃, R₁₅, and R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₁, Ar₂, Ar₃, and Ar₅ are the same or different, and are independently a substituted or unsubstituted C6 to C30 arylene group or a substituted or unsubstituted C2 to C30 heteroarylene group,
Ar₄ and Ar₆ are the same or different, and are independently a substituted or unsubstituted C6 to C30 aryl group or a substituted or unsubstituted C3 to C30 heteroaryl group, and
n, m, o, and p are the same or different, and are independently integers ranging from 0 to 4.

6. The compound for an organic optoelectronic device as claimed in claim 1, wherein the compound is represented by the following Chemical Formula 6: 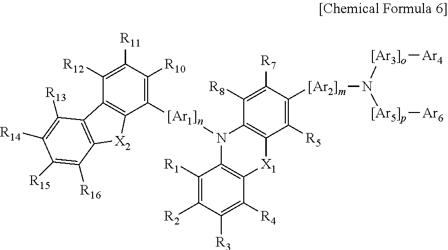
wherein in the above Chemical Formula 6,
R₁ to R₅, R₇, R₈, and R₁₀ to R₁₆ are the same or different, and are independently selected from hydrogen, deuterium, a halogen, a cyano group, a hydroxyl group, an amino group, a substituted or unsubstituted C1 to C20 amine group, a nitro group, a carboxyl group, a ferrocenyl group, a substituted or unsubstituted C1 to C20 alkyl group, a substituted or unsubstituted C6 to C30 aryl group, a substituted or unsubstituted C2 to C30 heteroaryl group, a substituted or unsubstituted C1 to C20 alkoxy group, a substituted or unsubstituted C6 to C20 aryloxy group, a substituted or unsubstituted C3 to C40 silyloxy group, a substituted or unsubstituted C1 to C20 acyl group, a substituted or unsubstituted C2 to C20 alkoxycarbonyl group, a substituted or unsubstituted C2 to C20 acyloxy group, a substituted or unsubstituted C2 to C20 acylamino group, a substituted or unsubstituted C2 to C20 alkoxycarbonylamino group, a substituted or unsubstituted C7 to C20 aryloxycarbonylamino group, a substituted or unsubstituted C1 to C20 sulfamoylamino group, a substituted or unsubstituted C1 to C20 sulfonyl group, a substituted or unsubstituted C1 to C20 alkylthiol group, a substituted or unsubstituted C6 to C20 arylthiol group, a substituted or unsubstituted C1 to C20 heterocyclothiol group, a substituted or unsubstituted C1 to C20 ureide group, and a substituted or unsubstituted C3 to C40 silyl group,
X₁ and X₂ are the same or different, and are independently NR₁₇, O, S, SO₂ (O═S═O), or PR₁₇, wherein R₁₇ is selected from a substituted or unsubstituted C1 to C20 alkyl group, a substituted or unsubstituted C6 to C30 aryl group, and a substituted or unsubstituted C2 to C30 heteroaryl group,
Ar₁, Ar₂, Ar₃, and Ar₅ are the same or different, and are independently a substituted or unsubstituted C6 to C30 arylene group or a substituted or unsubstituted C2 to C30 heteroarylene group,
Ar₄ and Ar₆ are the same or different, and are independently a substituted or unsubstituted C6 to C30 aryl group or a substituted or unsubstituted C3 to C30 heteroaryl group, and
n, m, o, and p are the same or different, and are independently integers ranging from 0 to 4.

7. The compound for an organic optoelectronic device as claimed in claim 1, wherein the compound is represented by one of the following Chemical Formulae A-1 to A-21 and A-23 to A-290:

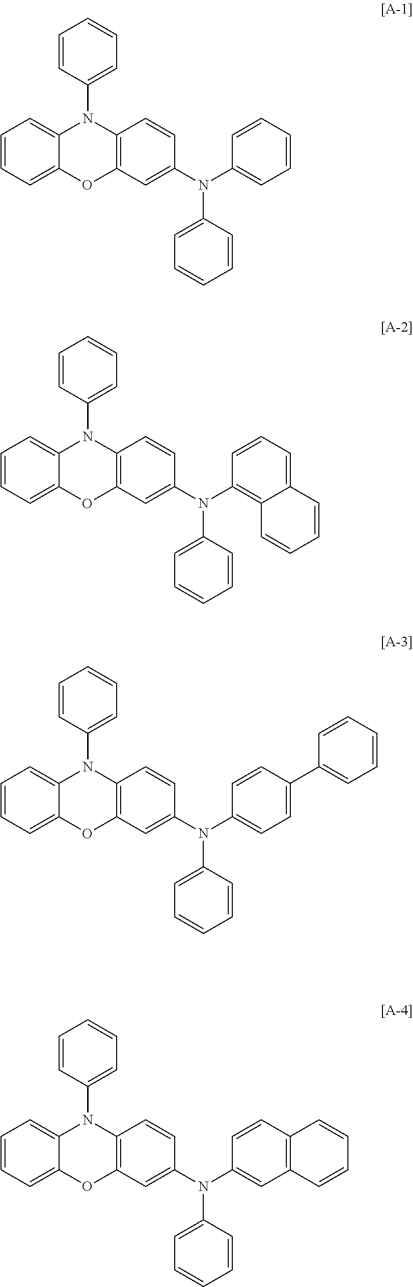 [SMILES: c1ccc(N(c2ccccc2)c2ccc3c(c2)Oc2ccccc2N3c2ccccc2)cc1 ; c1ccc(N2c3ccccc3Oc3cc(N(c4ccccc4)c4cccc5ccccc45)ccc32)cc1 ; c1ccc(-c2ccc(N(c3ccccc3)c3ccc4c(c3)Oc3ccccc3N4c3ccccc3)cc2)cc1 ; c1ccc(N(c2ccc3c(c2)Oc2ccccc2N3c2ccccc2)c2ccc3ccccc3c2)cc1]

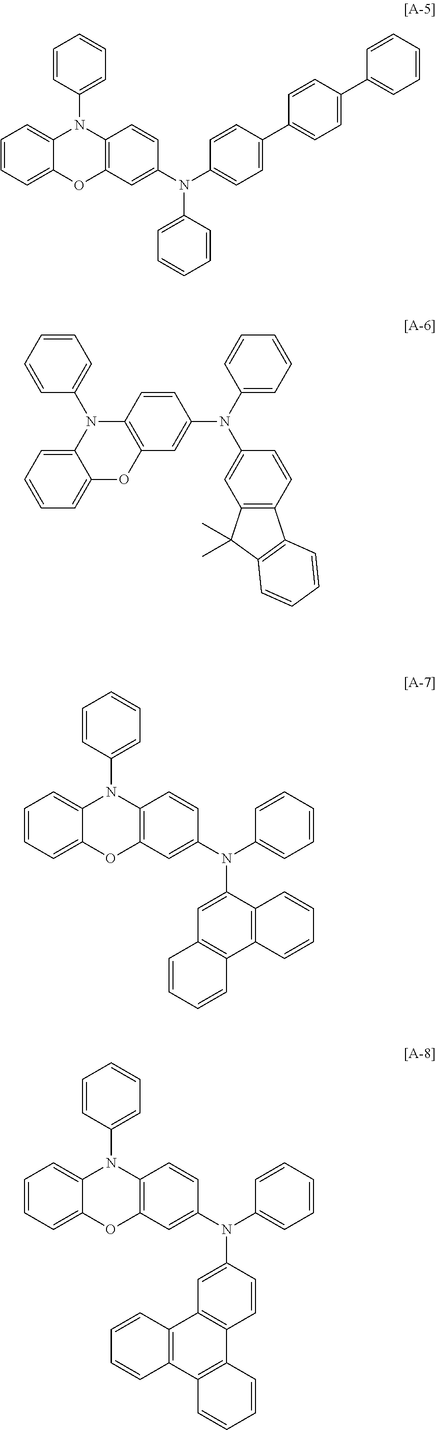 [SMILES: c1ccc(-c2ccc(-c3ccc(N(c4ccccc4)c4ccc5c(c4)Oc4ccccc4N5c4ccccc4)cc3)cc2)cc1 ; CC1(C)c2ccccc2-c2ccc(N(c3ccccc3)c3ccc4c(c3)Oc3ccccc3N4c3ccccc3)cc21 ; c1ccc(N2c3ccccc3Oc3cc(N(c4ccccc4)c4cc5ccccc5c5ccccc45)ccc32)cc1 ; c1ccc(N(c2ccc3c(c2)Oc2ccccc2N3c2ccccc2)c2ccc3c4ccccc4c4ccccc4c3c2)cc1]

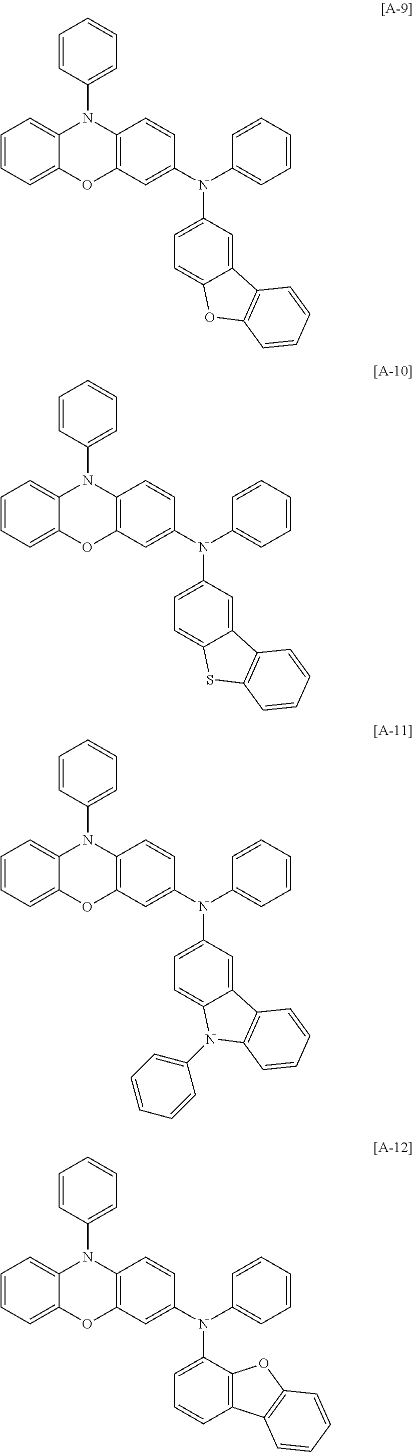 [SMILES: c1ccc(N(c2ccc3c(c2)Oc2ccccc2N3c2ccccc2)c2ccc3oc4ccccc4c3c2)cc1 ; c1ccc(N(c2ccc3c(c2)Oc2ccccc2N3c2ccccc2)c2ccc3sc4ccccc4c3c2)cc1 ; c1ccc(N(c2ccc3c(c2)Oc2ccccc2N3c2ccccc2)c2ccc3c(c2)c2ccccc2n3-c2ccccc2)cc1 ; c1ccc(N2c3ccccc3Oc3cc(N(c4ccccc4)c4cccc5c4oc4ccccc45)ccc32)cc1]

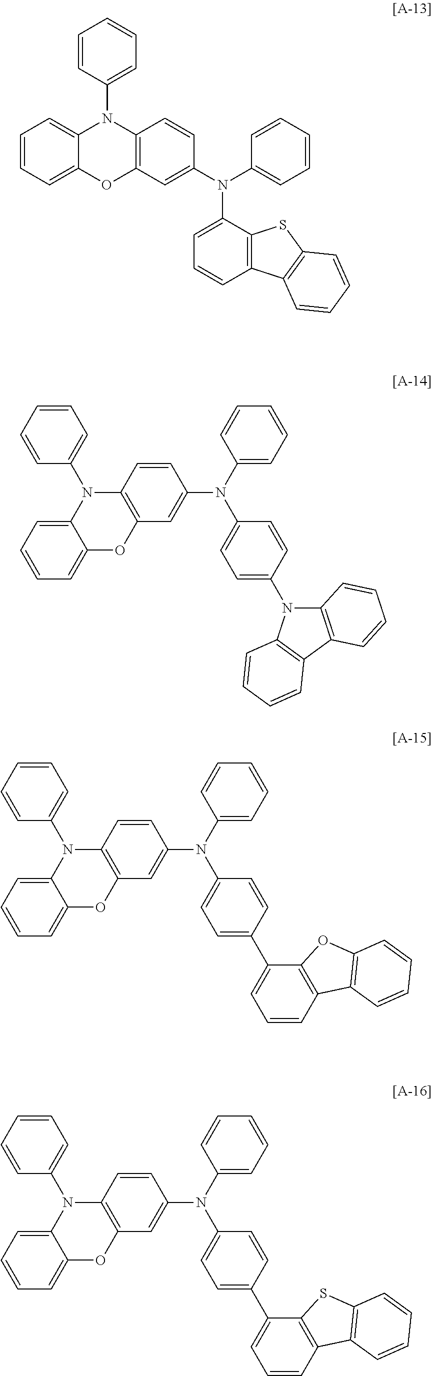 [SMILES: c1ccc(N2c3ccccc3Oc3cc(N(c4ccccc4)c4cccc5c4sc4ccccc45)ccc32)cc1 ; c1ccc(N(c2ccc(-n3c4ccccc4c4ccccc43)cc2)c2ccc3c(c2)Oc2ccccc2N3c2ccccc2)cc1 ; c1ccc(N(c2ccc(-c3cccc4c3oc3ccccc34)cc2)c2ccc3c(c2)Oc2ccccc2N3c2ccccc2)cc1 ; c1ccc(N(c2ccc(-c3cccc4c3sc3ccccc34)cc2)c2ccc3c(c2)Oc2ccccc2N3c2ccccc2)cc1]

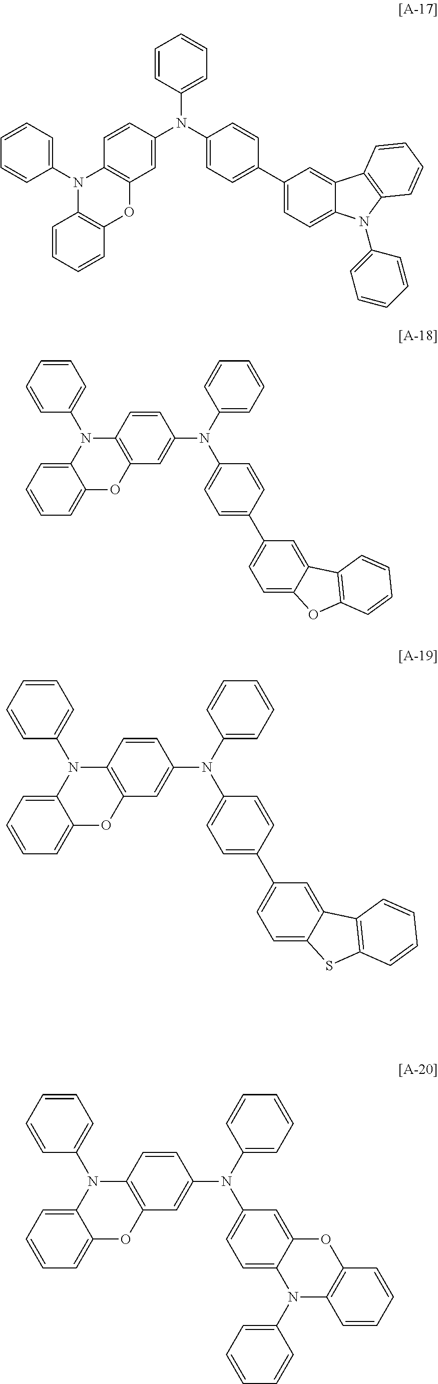 [SMILES: c1ccc(N(c2ccc(-c3ccc4c(c3)c3ccccc3n4-c3ccccc3)cc2)c2ccc3c(c2)Oc2ccccc2N3c2ccccc2)cc1 ; c1ccc(N(c2ccc(-c3ccc4oc5ccccc5c4c3)cc2)c2ccc3c(c2)Oc2ccccc2N3c2ccccc2)cc1 ; c1ccc(N(c2ccc(-c3ccc4sc5ccccc5c4c3)cc2)c2ccc3c(c2)Oc2ccccc2N3c2ccccc2)cc1 ; c1ccc(N(c2ccc3c(c2)Oc2ccccc2N3c2ccccc2)c2ccc3c(c2)Oc2ccccc2N3c2ccccc2)cc1]

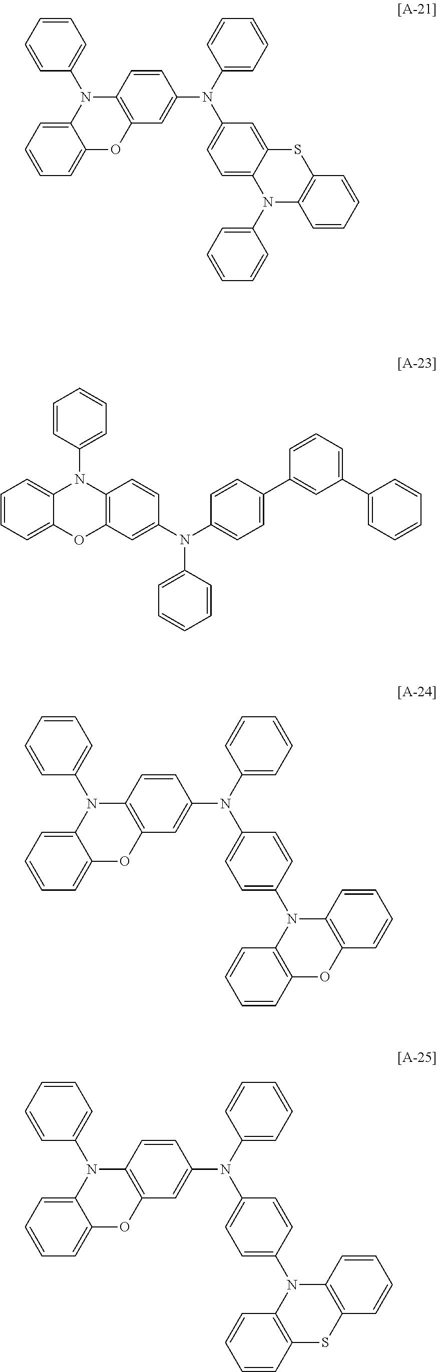 [SMILES: c1ccc(N(c2ccc3c(c2)Oc2ccccc2N3c2ccccc2)c2ccc3c(c2)Sc2ccccc2N3c2ccccc2)cc1 ; c1ccc(-c2cccc(-c3ccc(N(c4ccccc4)c4ccc5c(c4)Oc4ccccc4N5c4ccccc4)cc3)c2)cc1 ; c1ccc(N(c2ccc(N3c4ccccc4Oc4ccccc43)cc2)c2ccc3c(c2)Oc2ccccc2N3c2ccccc2)cc1 ; c1ccc(N(c2ccc(N3c4ccccc4Sc4ccccc43)cc2)c2ccc3c(c2)Oc2ccccc2N3c2ccccc2)cc1]

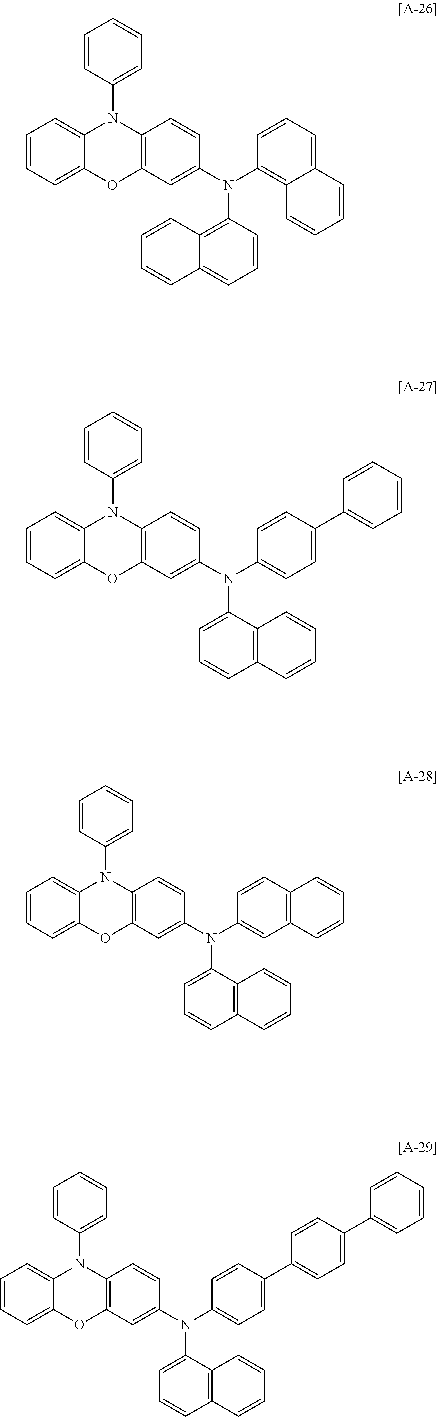 [SMILES: c1ccc(N2c3ccccc3Oc3cc(N(c4cccc5ccccc45)c4cccc5ccccc45)ccc32)cc1 ; c1ccc(-c2ccc(N(c3ccc4c(c3)Oc3ccccc3N4c3ccccc3)c3cccc4ccccc34)cc2)cc1 ; c1ccc(N2c3ccccc3Oc3cc(N(c4ccc5ccccc5c4)c4cccc5ccccc45)ccc32)cc1 ; c1ccc(-c2ccc(-c3ccc(N(c4ccc5c(c4)Oc4ccccc4N5c4ccccc4)c4cccc5ccccc45)cc3)cc2)cc1]

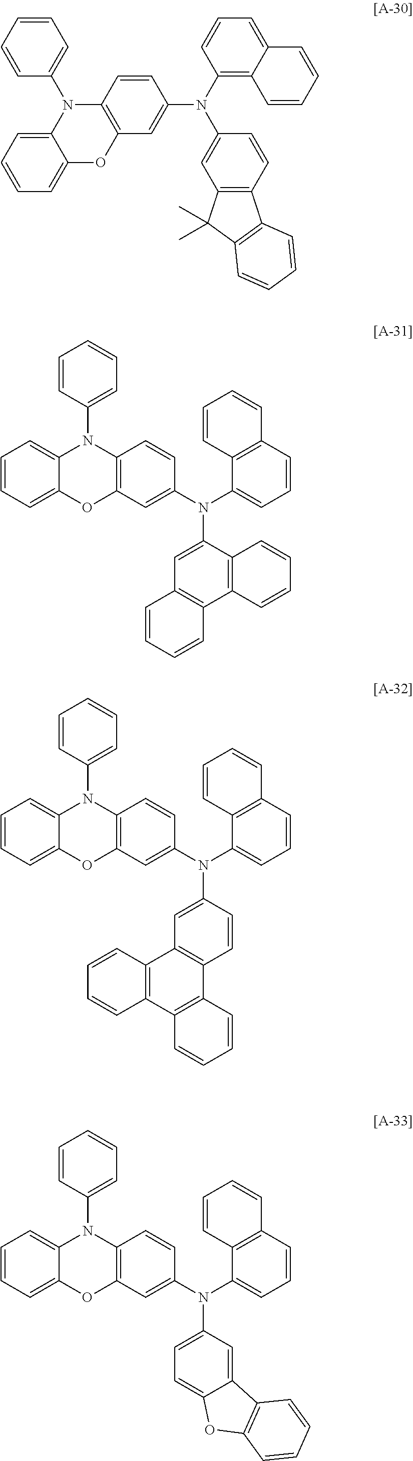 [SMILES: CC1(C)c2ccccc2-c2ccc(N(c3ccc4c(c3)Oc3ccccc3N4c3ccccc3)c3cccc4ccccc34)cc21 ; c1ccc(N2c3ccccc3Oc3cc(N(c4cccc5ccccc45)c4cc5ccccc5c5ccccc45)ccc32)cc1 ; c1ccc(N2c3ccccc3Oc3cc(N(c4ccc5c6ccccc6c6ccccc6c5c4)c4cccc5ccccc45)ccc32)cc1 ; c1ccc(N2c3ccccc3Oc3cc(N(c4ccc5oc6ccccc6c5c4)c4cccc5ccccc45)ccc32)cc1]

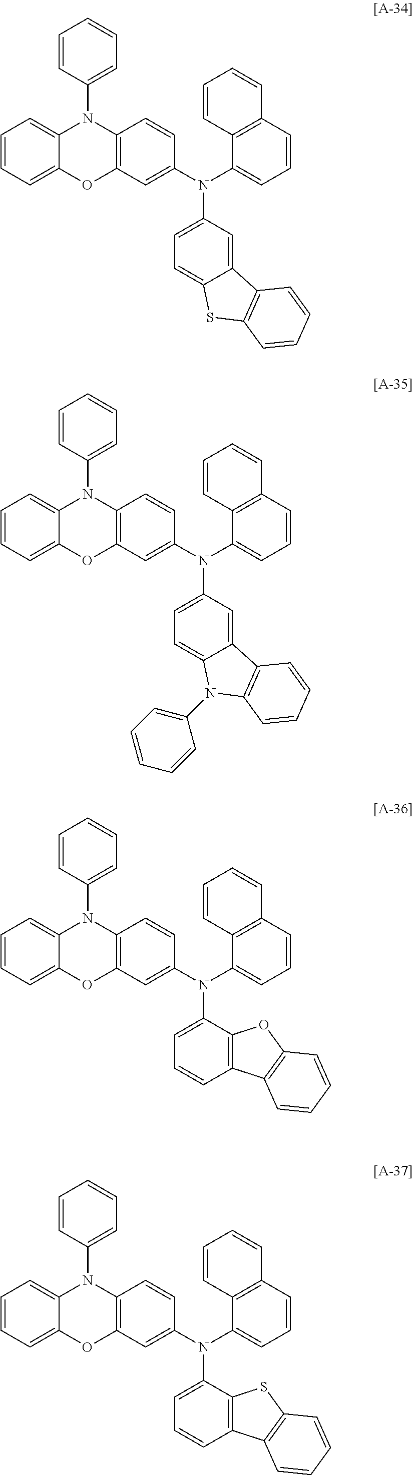 [SMILES: c1ccc(N2c3ccccc3Oc3cc(N(c4ccc5sc6ccccc6c5c4)c4cccc5ccccc45)ccc32)cc1 ; c1ccc(N2c3ccccc3Oc3cc(N(c4ccc5c(c4)c4ccccc4n5-c4ccccc4)c4cccc5ccccc45)ccc32)cc1 ; c1ccc(N2c3ccccc3Oc3cc(N(c4cccc5ccccc45)c4cccc5c4oc4ccccc45)ccc32)cc1 ; c1ccc(N2c3ccccc3Oc3cc(N(c4cccc5ccccc45)c4cccc5c4sc4ccccc45)ccc32)cc1]

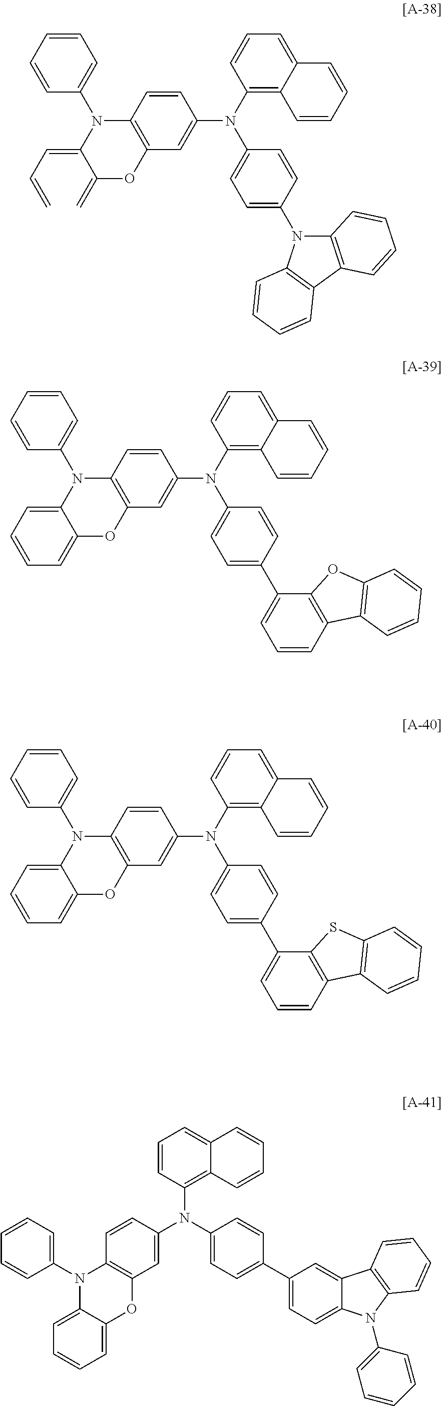 [SMILES: C=C/C=C1\C(=C)Oc2cc(N(c3ccc(-n4c5ccccc5c5ccccc54)cc3)c3cccc4ccccc34)ccc2N1c1ccccc1 ; c1ccc(N2c3ccccc3Oc3cc(N(c4ccc(-c5cccc6c5oc5ccccc56)cc4)c4cccc5ccccc45)ccc32)cc1 ; c1ccc(N2c3ccccc3Oc3cc(N(c4ccc(-c5cccc6c5sc5ccccc56)cc4)c4cccc5ccccc45)ccc32)cc1 ; c1ccc(N2c3ccccc3Oc3cc(N(c4ccc(-c5ccc6c(c5)c5ccccc5n6-c5ccccc5)cc4)c4cccc5ccccc45)ccc32)cc1]

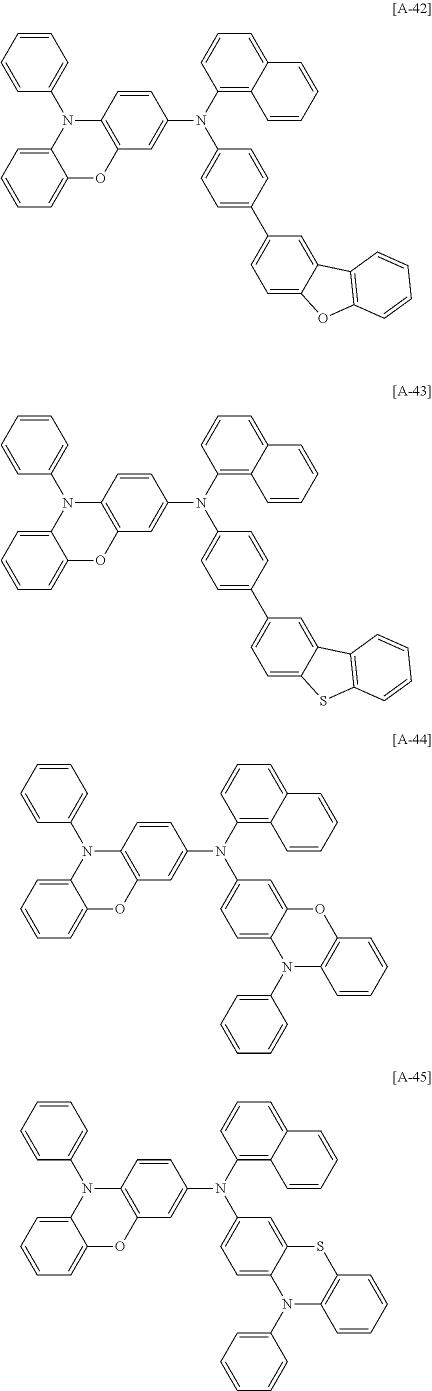 [SMILES: c1ccc(N2c3ccccc3Oc3cc(N(c4ccc(-c5ccc6oc7ccccc7c6c5)cc4)c4cccc5ccccc45)ccc32)cc1 ; c1ccc(N2c3ccccc3Oc3cc(N(c4ccc(-c5ccc6sc7ccccc7c6c5)cc4)c4cccc5ccccc45)ccc32)cc1 ; c1ccc(N2c3ccccc3Oc3cc(N(c4ccc5c(c4)Oc4ccccc4N5c4ccccc4)c4cccc5ccccc45)ccc32)cc1 ; c1ccc(N2c3ccccc3Oc3cc(N(c4ccc5c(c4)Sc4ccccc4N5c4ccccc4)c4cccc5ccccc45)ccc32)cc1]

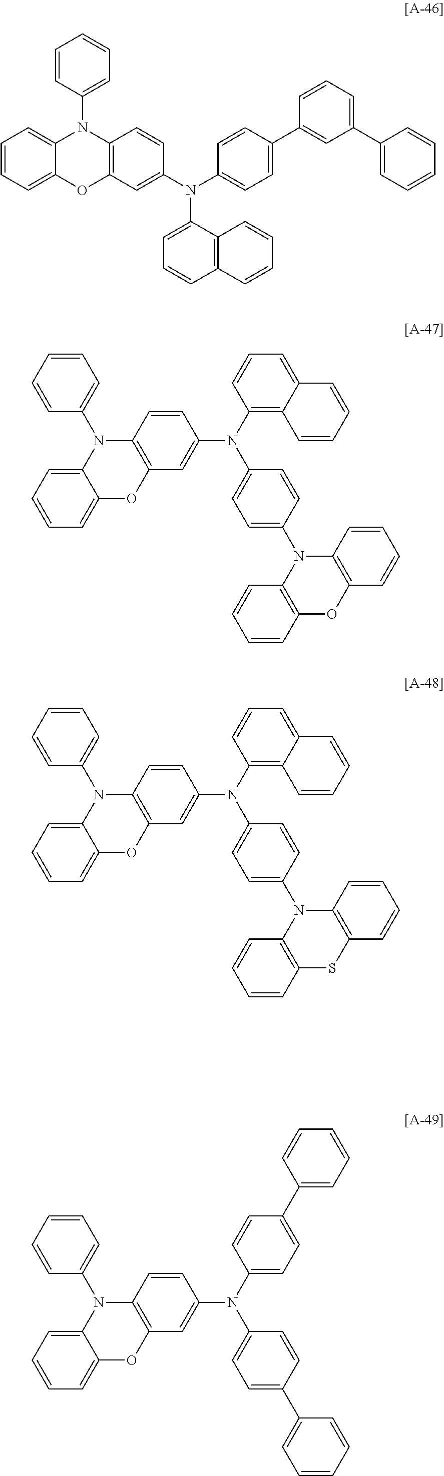 [SMILES: c1ccc(-c2cccc(-c3ccc(N(c4ccc5c(c4)Oc4ccccc4N5c4ccccc4)c4cccc5ccccc45)cc3)c2)cc1 ; c1ccc(N2c3ccccc3Oc3cc(N(c4ccc(N5c6ccccc6Oc6ccccc65)cc4)c4cccc5ccccc45)ccc32)cc1 ; c1ccc(N2c3ccccc3Oc3cc(N(c4ccc(N5c6ccccc6Sc6ccccc65)cc4)c4cccc5ccccc45)ccc32)cc1 ; c1ccc(-c2ccc(N(c3ccc(-c4ccccc4)cc3)c3ccc4c(c3)Oc3ccccc3N4c3ccccc3)cc2)cc1]

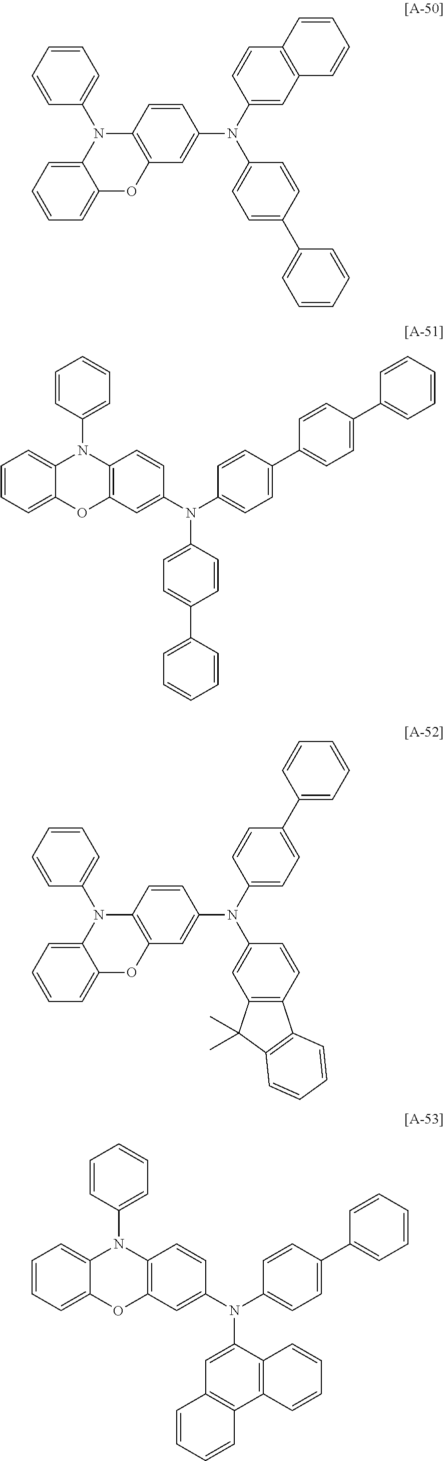 [SMILES: c1ccc(-c2ccc(N(c3ccc4c(c3)Oc3ccccc3N4c3ccccc3)c3ccc4ccccc4c3)cc2)cc1 ; c1ccc(-c2ccc(-c3ccc(N(c4ccc(-c5ccccc5)cc4)c4ccc5c(c4)Oc4ccccc4N5c4ccccc4)cc3)cc2)cc1 ; CC1(C)c2ccccc2-c2ccc(N(c3ccc(-c4ccccc4)cc3)c3ccc4c(c3)Oc3ccccc3N4c3ccccc3)cc21 ; c1ccc(-c2ccc(N(c3ccc4c(c3)Oc3ccccc3N4c3ccccc3)c3cc4ccccc4c4ccccc34)cc2)cc1]

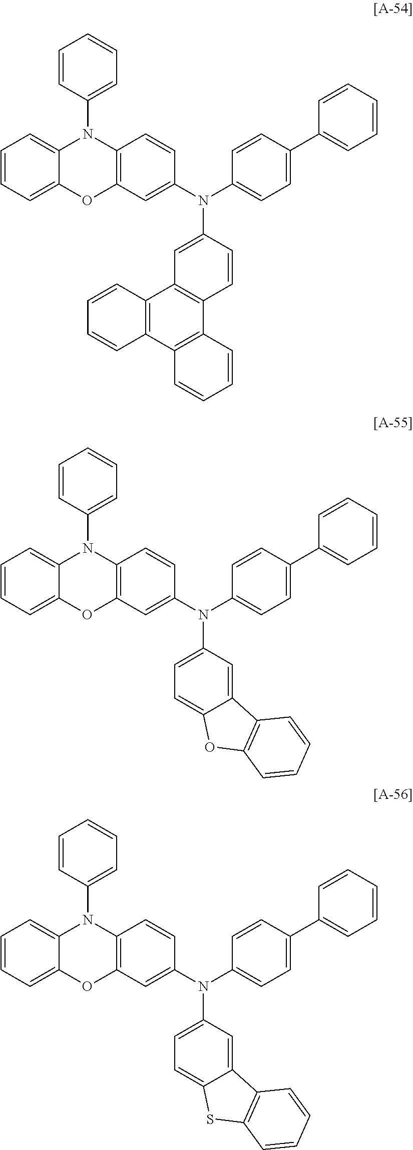 [SMILES: c1ccc(-c2ccc(N(c3ccc4c(c3)Oc3ccccc3N4c3ccccc3)c3ccc4c5ccccc5c5ccccc5c4c3)cc2)cc1 ; c1ccc(-c2ccc(N(c3ccc4c(c3)Oc3ccccc3N4c3ccccc3)c3ccc4oc5ccccc5c4c3)cc2)cc1 ; c1ccc(-c2ccc(N(c3ccc4c(c3)Oc3ccccc3N4c3ccccc3)c3ccc4sc5ccccc5c4c3)cc2)cc1]

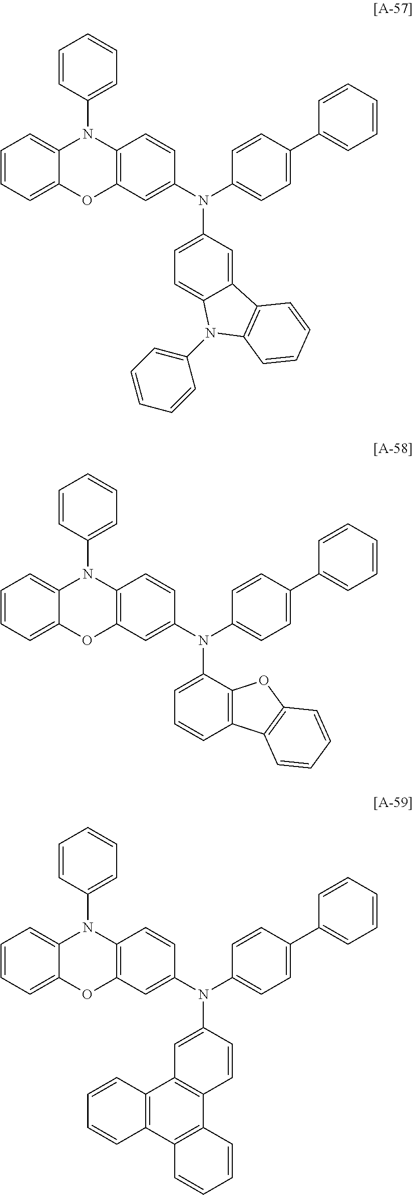 [SMILES: c1ccc(-c2ccc(N(c3ccc4c(c3)Oc3ccccc3N4c3ccccc3)c3ccc4c(c3)c3ccccc3n4-c3ccccc3)cc2)cc1 ; c1ccc(-c2ccc(N(c3ccc4c(c3)Oc3ccccc3N4c3ccccc3)c3cccc4c3oc3ccccc34)cc2)cc1 ; c1ccc(-c2ccc(N(c3ccc4c(c3)Oc3ccccc3N4c3ccccc3)c3ccc4c5ccccc5c5ccccc5c4c3)cc2)cc1]

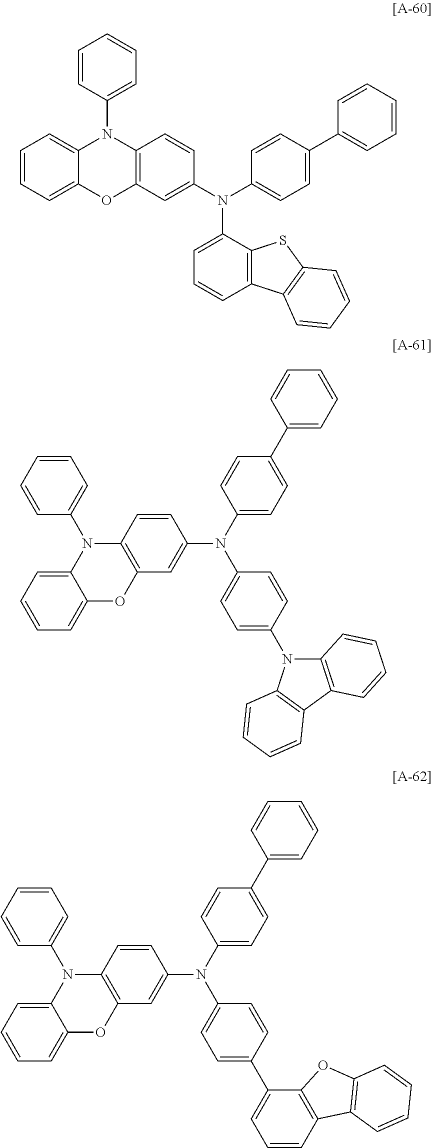

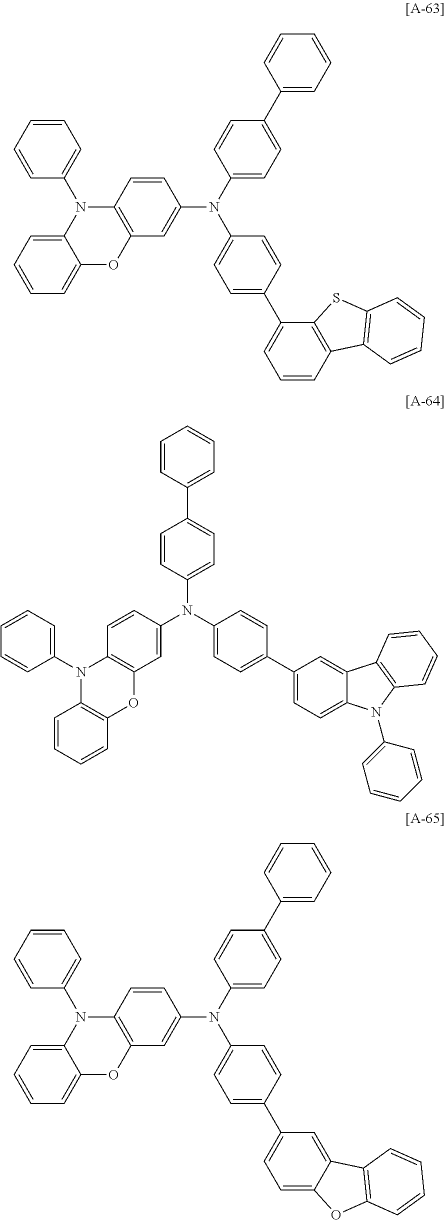 [SMILES: c1ccc(-c2ccc(N(c3ccc(-c4cccc5c4sc4ccccc45)cc3)c3ccc4c(c3)Oc3ccccc3N4c3ccccc3)cc2)cc1 ; c1ccc(-c2ccc(N(c3ccc(-c4ccc5c(c4)c4ccccc4n5-c4ccccc4)cc3)c3ccc4c(c3)Oc3ccccc3N4c3ccccc3)cc2)cc1 ; c1ccc(-c2ccc(N(c3ccc(-c4ccc5oc6ccccc6c5c4)cc3)c3ccc4c(c3)Oc3ccccc3N4c3ccccc3)cc2)cc1]

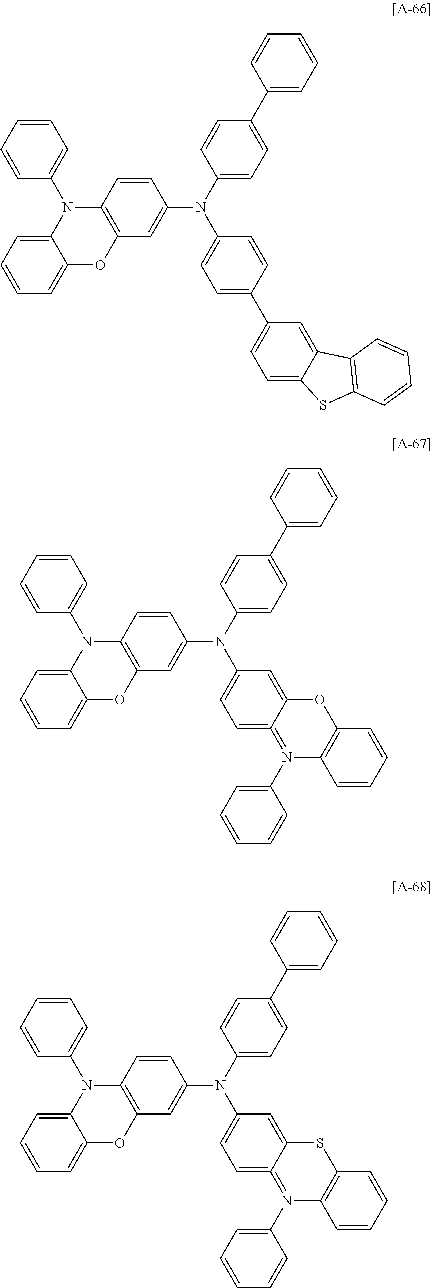

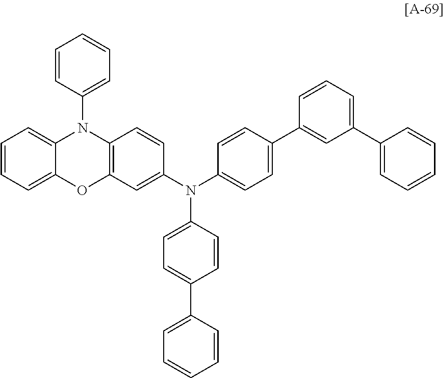 [SMILES: c1ccc(-c2ccc(N(c3ccc(-c4cccc(-c5ccccc5)c4)cc3)c3ccc4c(c3)Oc3ccccc3N4c3ccccc3)cc2)cc1]

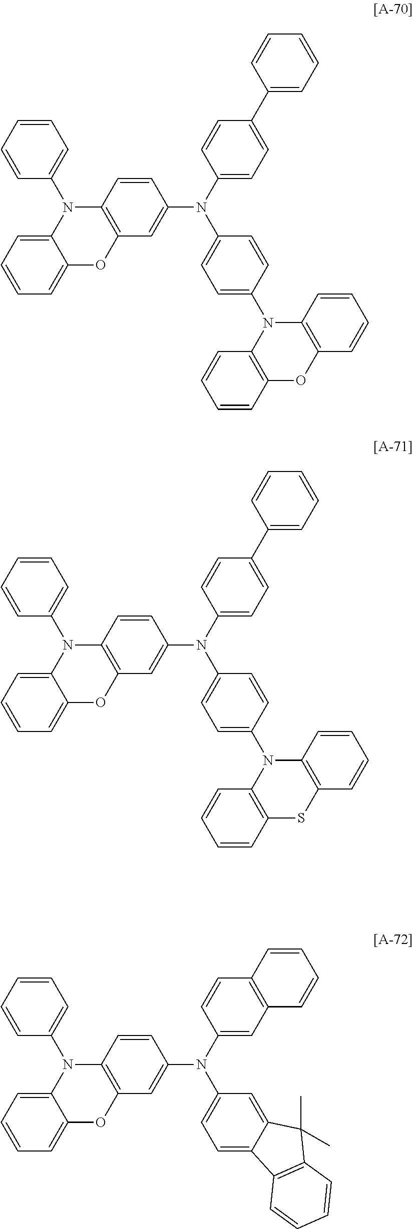 [SMILES: c1ccc(-c2ccc(N(c3ccc(N4c5ccccc5Oc5ccccc54)cc3)c3ccc4c(c3)Oc3ccccc3N4c3ccccc3)cc2)cc1 ; c1ccc(-c2ccc(N(c3ccc(N4c5ccccc5Sc5ccccc54)cc3)c3ccc4c(c3)Oc3ccccc3N4c3ccccc3)cc2)cc1 ; CC1(C)c2ccccc2-c2ccc(N(c3ccc4c(c3)Oc3ccccc3N4c3ccccc3)c3ccc4ccccc4c3)cc21]

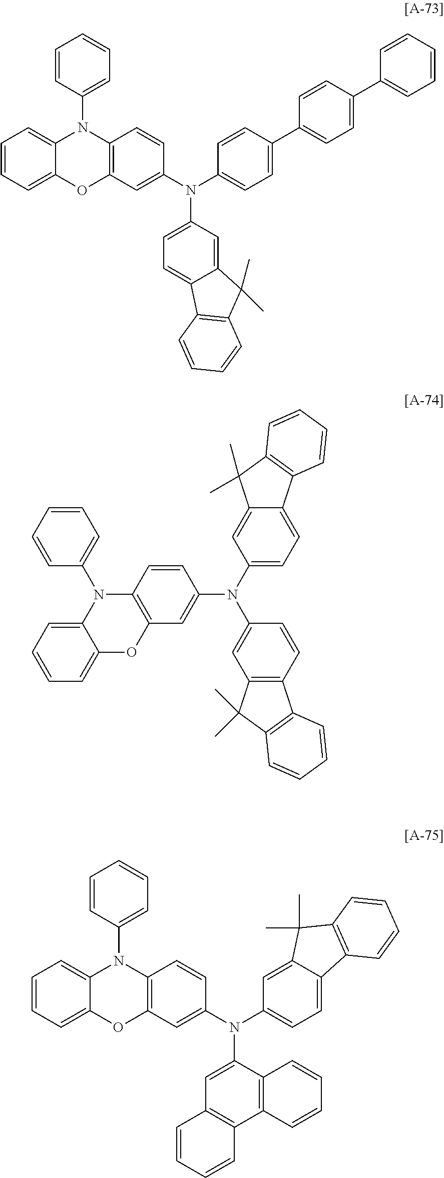 [SMILES: CC1(C)c2ccccc2-c2ccc(N(c3ccc(-c4ccc(-c5ccccc5)cc4)cc3)c3ccc4c(c3)Oc3ccccc3N4c3ccccc3)cc21 ; CC1(C)c2ccccc2-c2ccc(N(c3ccc4c(c3)Oc3ccccc3N4c3ccccc3)c3ccc4c(c3)C(C)(C)c3ccccc3-4)cc21 ; CC1(C)c2ccccc2-c2ccc(N(c3ccc4c(c3)Oc3ccccc3N4c3ccccc3)c3cc4ccccc4c4ccccc34)cc21]

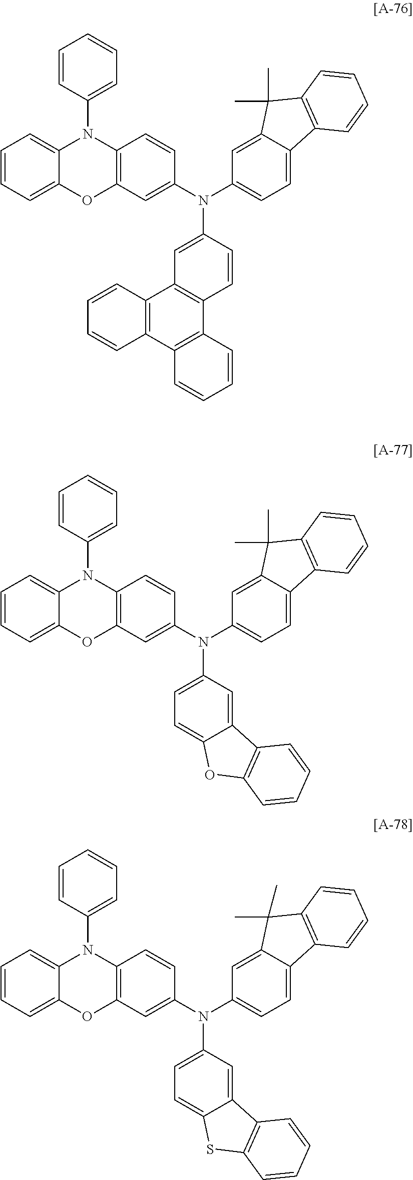 [SMILES: CC1(C)c2ccccc2-c2ccc(N(c3ccc4c(c3)Oc3ccccc3N4c3ccccc3)c3ccc4c5ccccc5c5ccccc5c4c3)cc21 ; CC1(C)c2ccccc2-c2ccc(N(c3ccc4c(c3)Oc3ccccc3N4c3ccccc3)c3ccc4oc5ccccc5c4c3)cc21 ; CC1(C)c2ccccc2-c2ccc(N(c3ccc4c(c3)Oc3ccccc3N4c3ccccc3)c3ccc4sc5ccccc5c4c3)cc21]

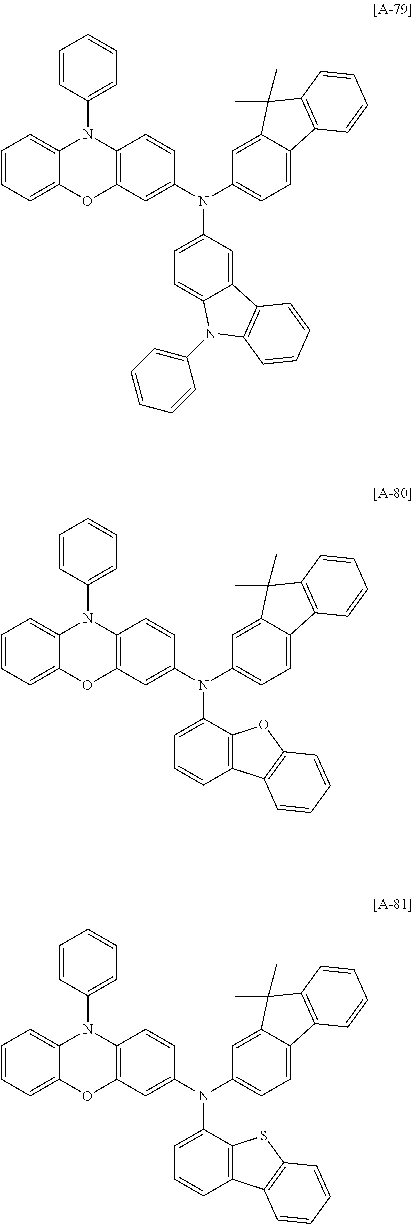 [SMILES: CC1(C)c2ccccc2-c2ccc(N(c3ccc4c(c3)Oc3ccccc3N4c3ccccc3)c3ccc4c(c3)c3ccccc3n4-c3ccccc3)cc21 ; CC1(C)c2ccccc2-c2ccc(N(c3ccc4c(c3)Oc3ccccc3N4c3ccccc3)c3cccc4c3oc3ccccc34)cc21 ; CC1(C)c2ccccc2-c2ccc(N(c3ccc4c(c3)Oc3ccccc3N4c3ccccc3)c3cccc4c3sc3ccccc34)cc21]

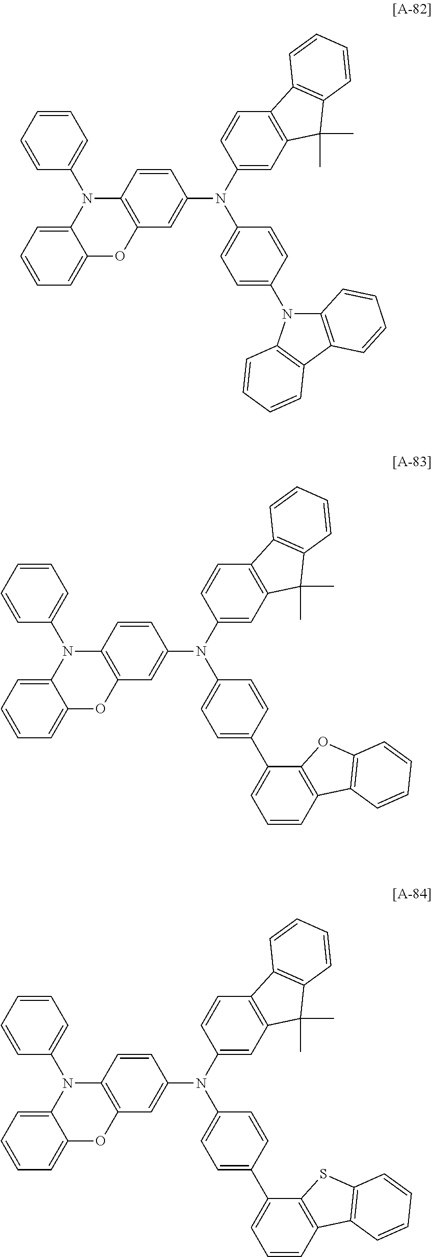 [SMILES: CC1(C)c2ccccc2-c2ccc(N(c3ccc(-n4c5ccccc5c5ccccc54)cc3)c3ccc4c(c3)Oc3ccccc3N4c3ccccc3)cc21 ; CC1(C)c2ccccc2-c2ccc(N(c3ccc(-c4cccc5c4oc4ccccc45)cc3)c3ccc4c(c3)Oc3ccccc3N4c3ccccc3)cc21 ; CC1(C)c2ccccc2-c2ccc(N(c3ccc(-c4cccc5c4sc4ccccc45)cc3)c3ccc4c(c3)Oc3ccccc3N4c3ccccc3)cc21]

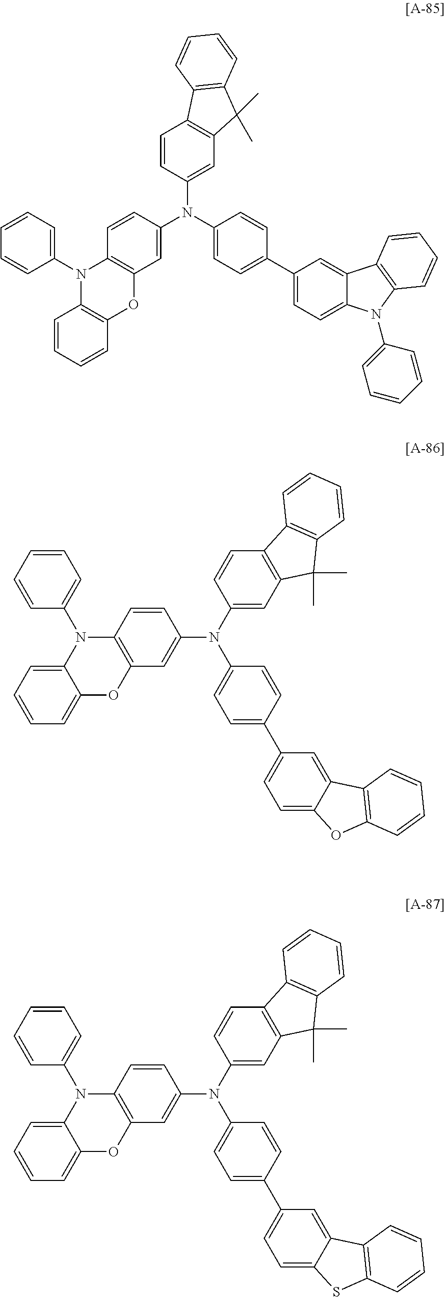 [SMILES: CC1(C)c2ccccc2-c2ccc(N(c3ccc(-c4ccc5c(c4)c4ccccc4n5-c4ccccc4)cc3)c3ccc4c(c3)Oc3ccccc3N4c3ccccc3)cc21 ; CC1(C)c2ccccc2-c2ccc(N(c3ccc(-c4ccc5oc6ccccc6c5c4)cc3)c3ccc4c(c3)Oc3ccccc3N4c3ccccc3)cc21 ; CC1(C)c2ccccc2-c2ccc(N(c3ccc(-c4ccc5sc6ccccc6c5c4)cc3)c3ccc4c(c3)Oc3ccccc3N4c3ccccc3)cc21]

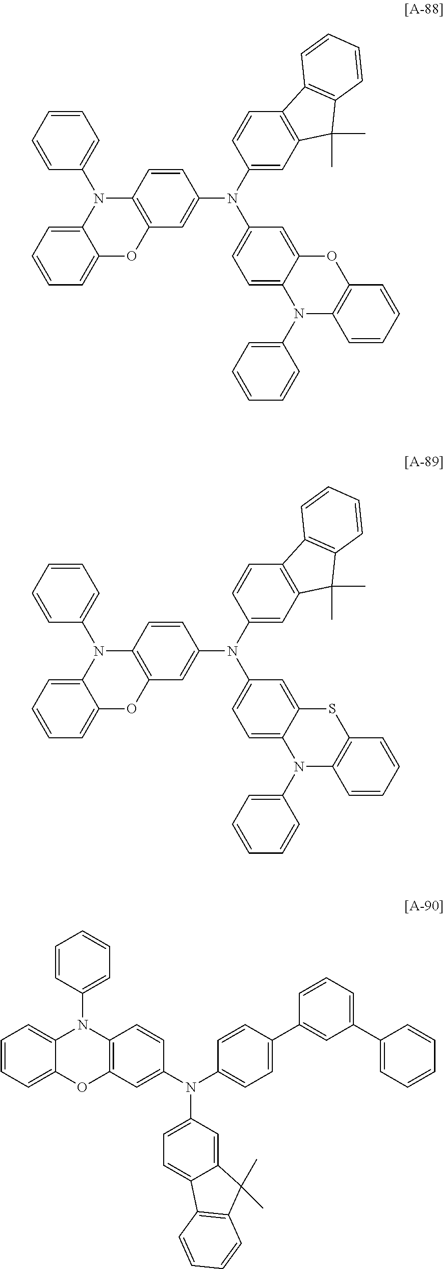 [SMILES: CC1(C)c2ccccc2-c2ccc(N(c3ccc4c(c3)Oc3ccccc3N4c3ccccc3)c3ccc4c(c3)Oc3ccccc3N4c3ccccc3)cc21 ; CC1(C)c2ccccc2-c2ccc(N(c3ccc4c(c3)Oc3ccccc3N4c3ccccc3)c3ccc4c(c3)Sc3ccccc3N4c3ccccc3)cc21 ; CC1(C)c2ccccc2-c2ccc(N(c3ccc(-c4cccc(-c5ccccc5)c4)cc3)c3ccc4c(c3)Oc3ccccc3N4c3ccccc3)cc21]

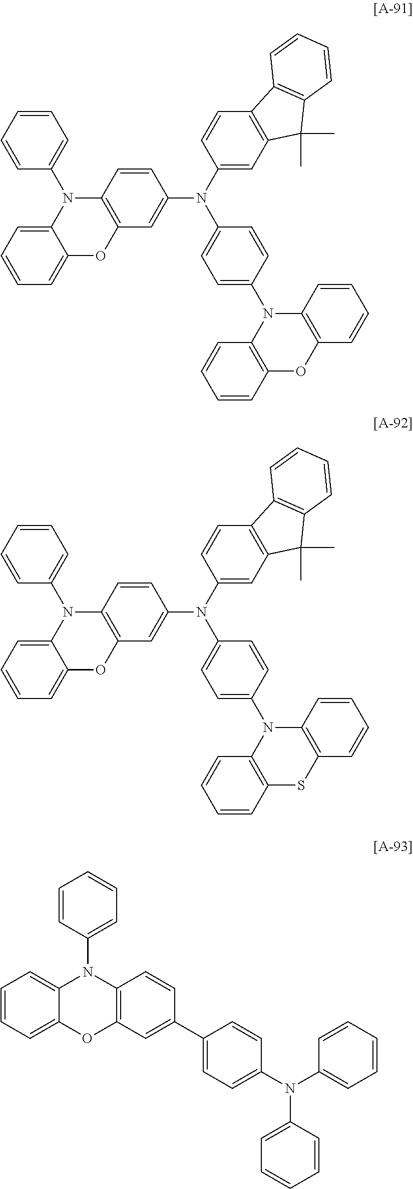 [SMILES: CC1(C)c2ccccc2-c2ccc(N(c3ccc(N4c5ccccc5Oc5ccccc54)cc3)c3ccc4c(c3)Oc3ccccc3N4c3ccccc3)cc21 ; CC1(C)c2ccccc2-c2ccc(N(c3ccc(N4c5ccccc5Sc5ccccc54)cc3)c3ccc4c(c3)Oc3ccccc3N4c3ccccc3)cc21 ; c1ccc(N(c2ccccc2)c2ccc(-c3ccc4c(c3)Oc3ccccc3N4c3ccccc3)cc2)cc1]

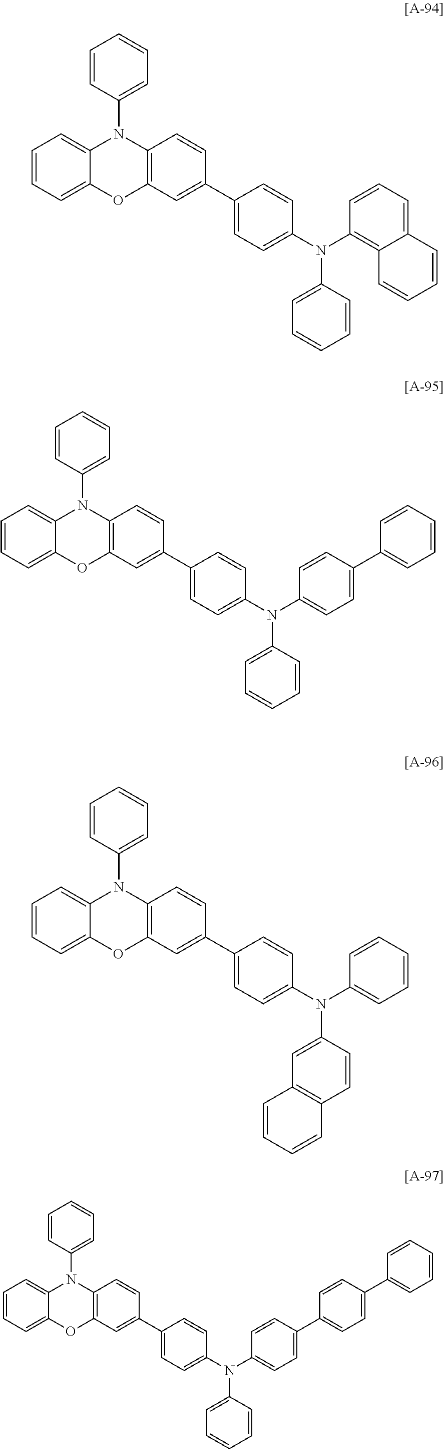 [SMILES: c1ccc(N2c3ccccc3Oc3cc(-c4ccc(N(c5ccccc5)c5cccc6ccccc56)cc4)ccc32)cc1 ; c1ccc(-c2ccc(N(c3ccccc3)c3ccc(-c4ccc5c(c4)Oc4ccccc4N5c4ccccc4)cc3)cc2)cc1 ; c1ccc(N(c2ccc(-c3ccc4c(c3)Oc3ccccc3N4c3ccccc3)cc2)c2ccc3ccccc3c2)cc1 ; c1ccc(-c2ccc(-c3ccc(N(c4ccccc4)c4ccc(-c5ccc6c(c5)Oc5ccccc5N6c5ccccc5)cc4)cc3)cc2)cc1]

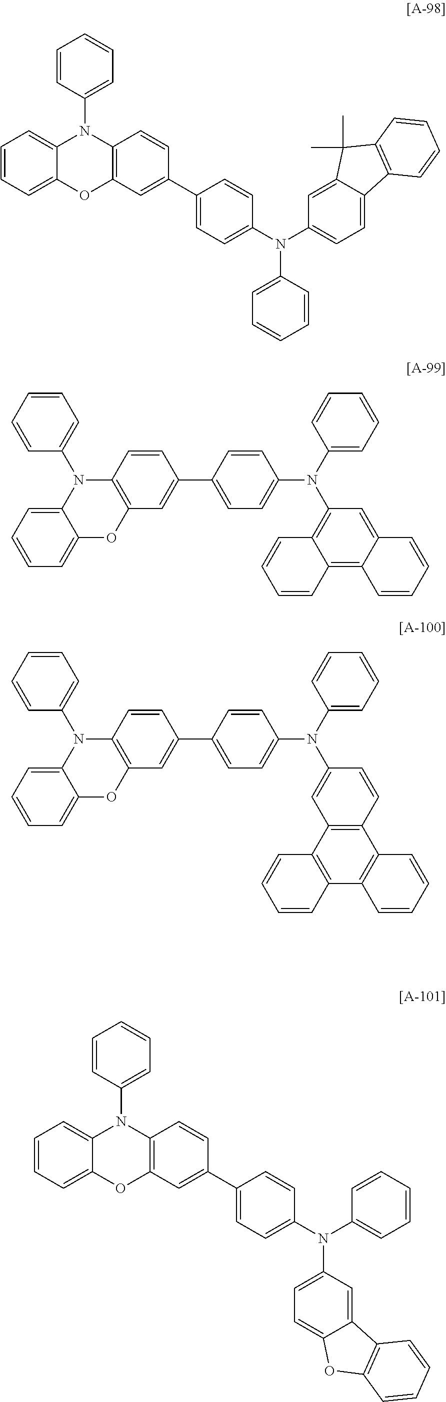 [SMILES: CC1(C)c2ccccc2-c2ccc(N(c3ccccc3)c3ccc(-c4ccc5c(c4)Oc4ccccc4N5c4ccccc4)cc3)cc21 ; c1ccc(N2c3ccccc3Oc3cc(-c4ccc(N(c5ccccc5)c5cc6ccccc6c6ccccc56)cc4)ccc32)cc1 ; c1ccc(N(c2ccc(-c3ccc4c(c3)Oc3ccccc3N4c3ccccc3)cc2)c2ccc3c4ccccc4c4ccccc4c3c2)cc1 ; c1ccc(N(c2ccc(-c3ccc4c(c3)Oc3ccccc3N4c3ccccc3)cc2)c2ccc3oc4ccccc4c3c2)cc1]

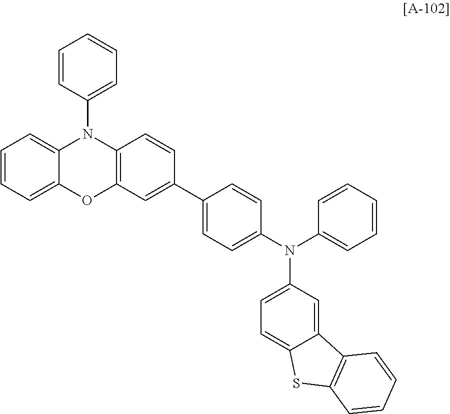 [SMILES: c1ccc(N(c2ccc(-c3ccc4c(c3)Oc3ccccc3N4c3ccccc3)cc2)c2ccc3sc4ccccc4c3c2)cc1]

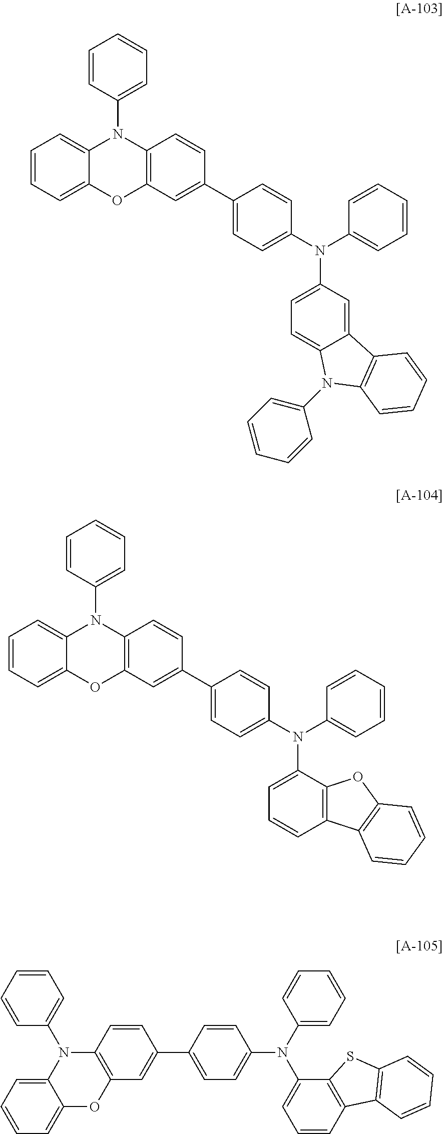 [SMILES: c1ccc(N(c2ccc(-c3ccc4c(c3)Oc3ccccc3N4c3ccccc3)cc2)c2ccc3c(c2)c2ccccc2n3-c2ccccc2)cc1 ; c1ccc(N2c3ccccc3Oc3cc(-c4ccc(N(c5ccccc5)c5cccc6c5oc5ccccc56)cc4)ccc32)cc1 ; c1ccc(N2c3ccccc3Oc3cc(-c4ccc(N(c5ccccc5)c5cccc6c5sc5ccccc56)cc4)ccc32)cc1]

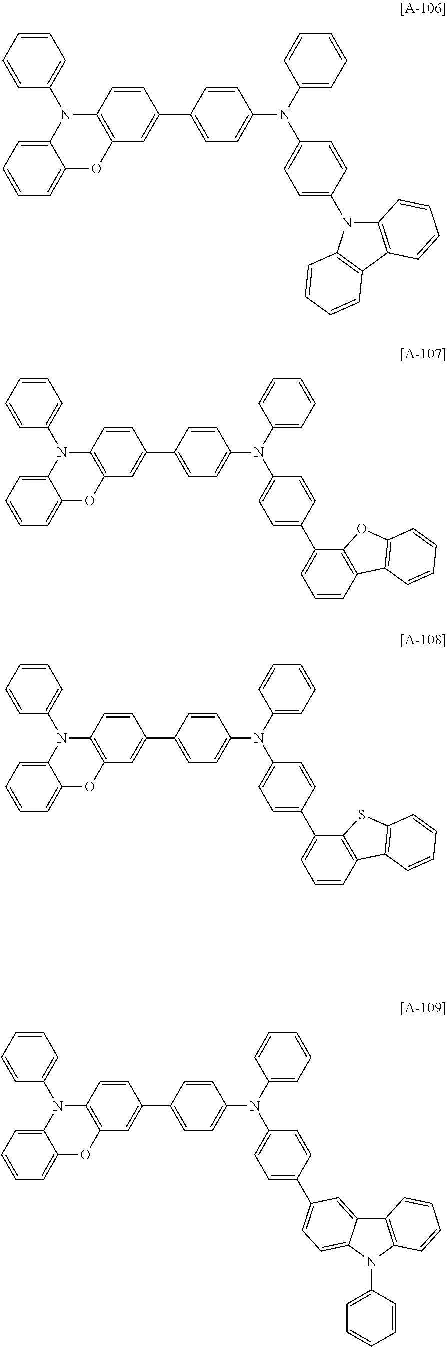 [SMILES: c1ccc(N(c2ccc(-c3ccc4c(c3)Oc3ccccc3N4c3ccccc3)cc2)c2ccc(-n3c4ccccc4c4ccccc43)cc2)cc1 ; c1ccc(N(c2ccc(-c3ccc4c(c3)Oc3ccccc3N4c3ccccc3)cc2)c2ccc(-c3cccc4c3oc3ccccc34)cc2)cc1 ; c1ccc(N(c2ccc(-c3ccc4c(c3)Oc3ccccc3N4c3ccccc3)cc2)c2ccc(-c3cccc4c3sc3ccccc34)cc2)cc1 ; c1ccc(N(c2ccc(-c3ccc4c(c3)Oc3ccccc3N4c3ccccc3)cc2)c2ccc(-c3ccc4c(c3)c3ccccc3n4-c3ccccc3)cc2)cc1]

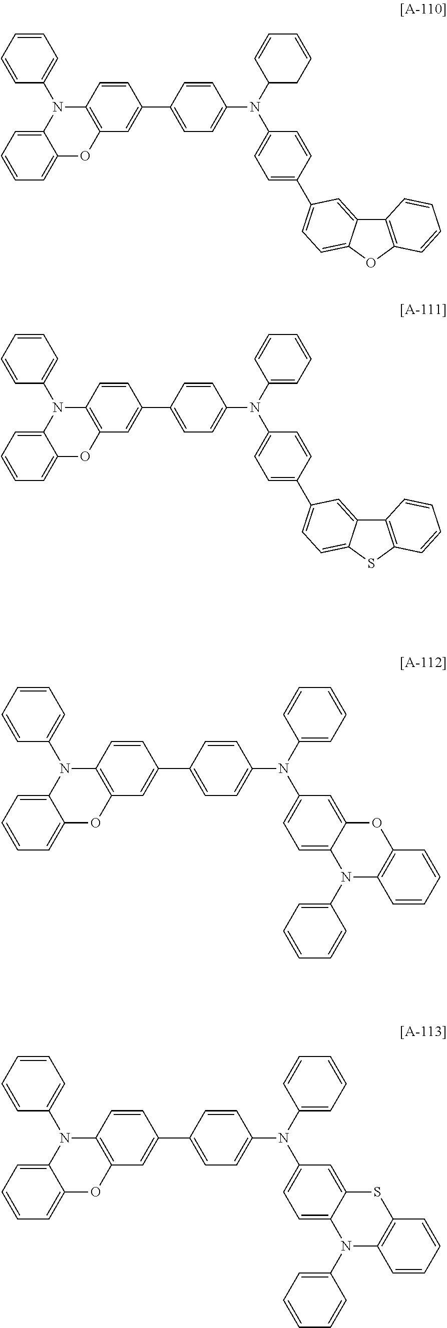 [SMILES: C1=CCC(N(c2ccc(-c3ccc4c(c3)Oc3ccccc3N4c3ccccc3)cc2)c2ccc(-c3ccc4oc5ccccc5c4c3)cc2)C=C1 ; c1ccc(N(c2ccc(-c3ccc4c(c3)Oc3ccccc3N4c3ccccc3)cc2)c2ccc(-c3ccc4sc5ccccc5c4c3)cc2)cc1 ; c1ccc(N(c2ccc(-c3ccc4c(c3)Oc3ccccc3N4c3ccccc3)cc2)c2ccc3c(c2)Oc2ccccc2N3c2ccccc2)cc1 ; c1ccc(N(c2ccc(-c3ccc4c(c3)Oc3ccccc3N4c3ccccc3)cc2)c2ccc3c(c2)Sc2ccccc2N3c2ccccc2)cc1]

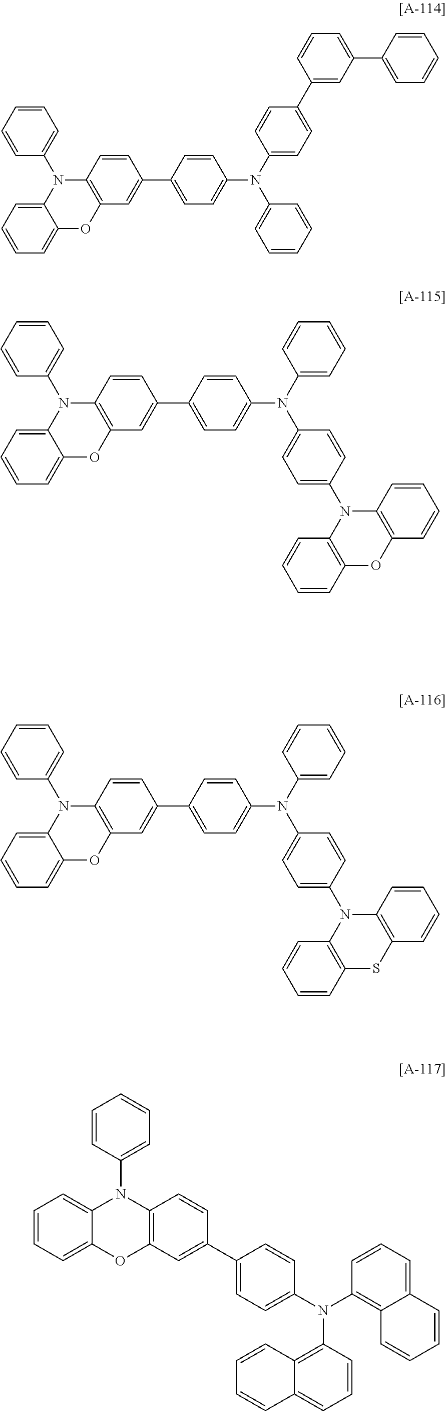 [SMILES: c1ccc(-c2cccc(-c3ccc(N(c4ccccc4)c4ccc(-c5ccc6c(c5)Oc5ccccc5N6c5ccccc5)cc4)cc3)c2)cc1 ; c1ccc(N(c2ccc(-c3ccc4c(c3)Oc3ccccc3N4c3ccccc3)cc2)c2ccc(N3c4ccccc4Oc4ccccc43)cc2)cc1 ; c1ccc(N(c2ccc(-c3ccc4c(c3)Oc3ccccc3N4c3ccccc3)cc2)c2ccc(N3c4ccccc4Sc4ccccc43)cc2)cc1 ; c1ccc(N2c3ccccc3Oc3cc(-c4ccc(N(c5cccc6ccccc56)c5cccc6ccccc56)cc4)ccc32)cc1]

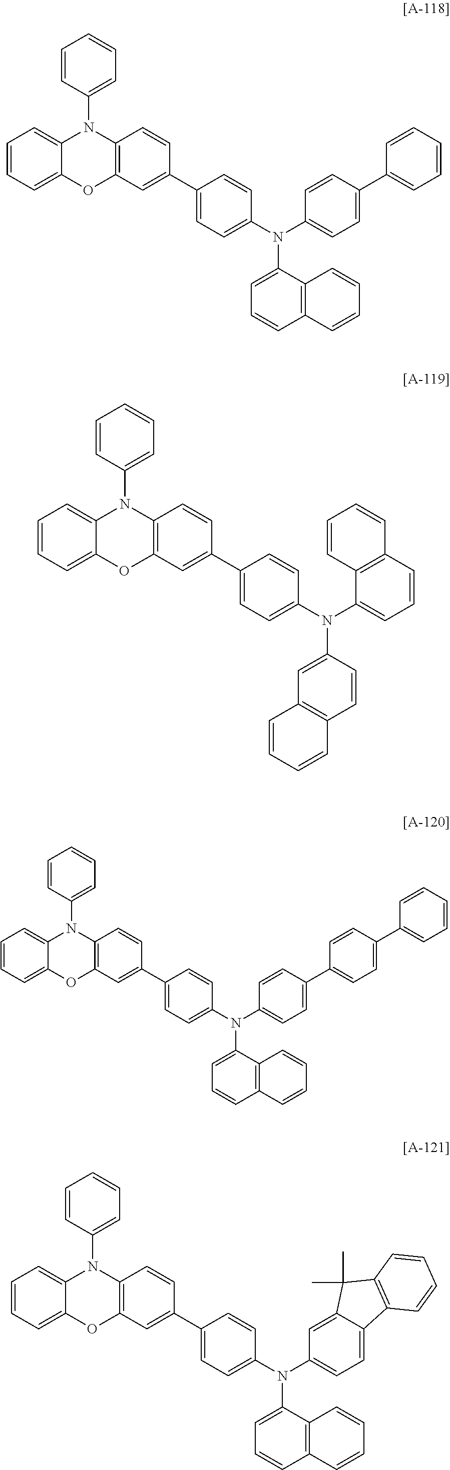 [SMILES: c1ccc(-c2ccc(N(c3ccc(-c4ccc5c(c4)Oc4ccccc4N5c4ccccc4)cc3)c3cccc4ccccc34)cc2)cc1 ; c1ccc(N2c3ccccc3Oc3cc(-c4ccc(N(c5ccc6ccccc6c5)c5cccc6ccccc56)cc4)ccc32)cc1 ; c1ccc(-c2ccc(-c3ccc(N(c4ccc(-c5ccc6c(c5)Oc5ccccc5N6c5ccccc5)cc4)c4cccc5ccccc45)cc3)cc2)cc1 ; CC1(C)c2ccccc2-c2ccc(N(c3ccc(-c4ccc5c(c4)Oc4ccccc4N5c4ccccc4)cc3)c3cccc4ccccc34)cc21]

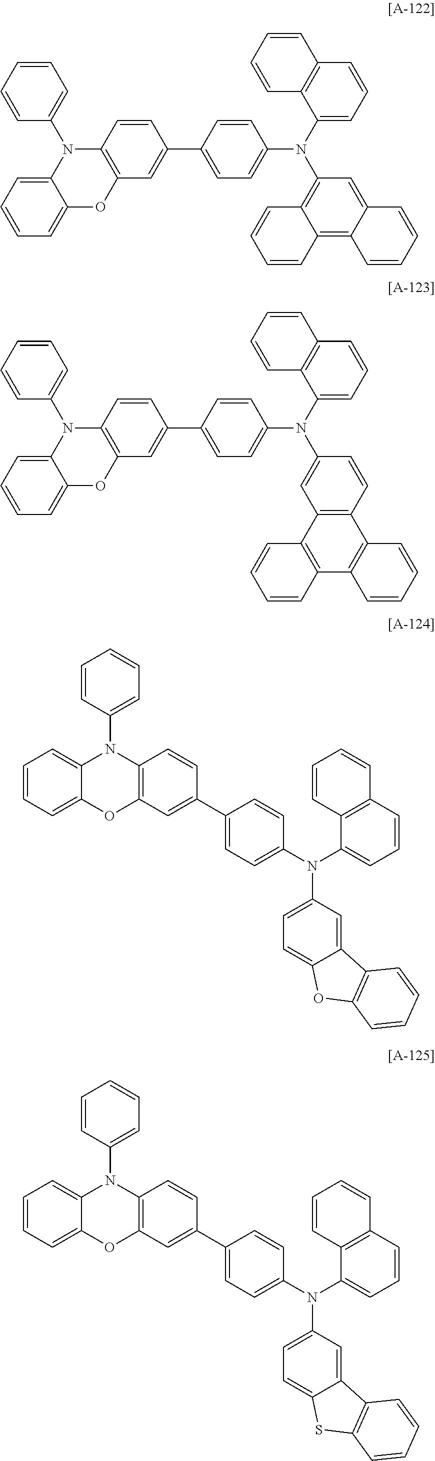 [SMILES: c1ccc(N2c3ccccc3Oc3cc(-c4ccc(N(c5cccc6ccccc56)c5cc6ccccc6c6ccccc56)cc4)ccc32)cc1 ; c1ccc(N2c3ccccc3Oc3cc(-c4ccc(N(c5ccc6c7ccccc7c7ccccc7c6c5)c5cccc6ccccc56)cc4)ccc32)cc1 ; c1ccc(N2c3ccccc3Oc3cc(-c4ccc(N(c5ccc6oc7ccccc7c6c5)c5cccc6ccccc56)cc4)ccc32)cc1 ; c1ccc(N2c3ccccc3Oc3cc(-c4ccc(N(c5ccc6sc7ccccc7c6c5)c5cccc6ccccc56)cc4)ccc32)cc1]

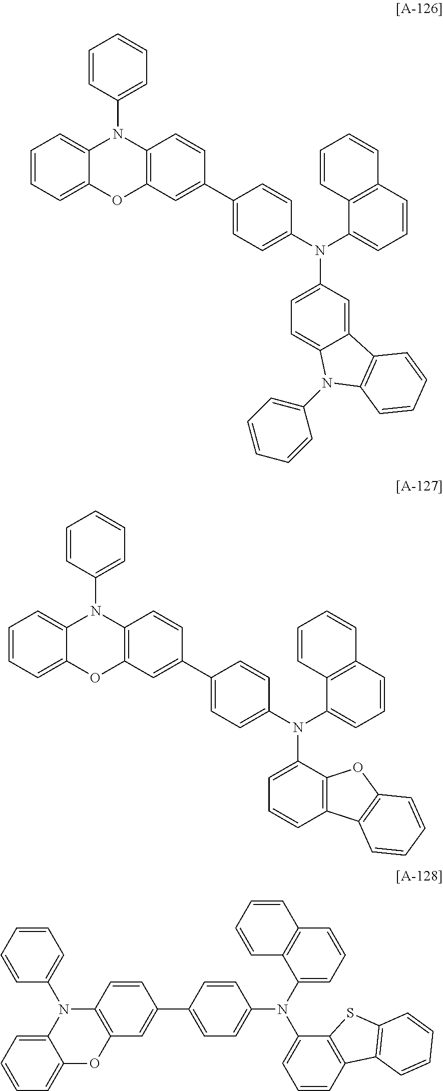 [SMILES: c1ccc(N2c3ccccc3Oc3cc(-c4ccc(N(c5ccc6c(c5)c5ccccc5n6-c5ccccc5)c5cccc6ccccc56)cc4)ccc32)cc1 ; c1ccc(N2c3ccccc3Oc3cc(-c4ccc(N(c5cccc6ccccc56)c5cccc6c5oc5ccccc56)cc4)ccc32)cc1 ; c1ccc(N2c3ccccc3Oc3cc(-c4ccc(N(c5cccc6ccccc56)c5cccc6c5sc5ccccc56)cc4)ccc32)cc1]

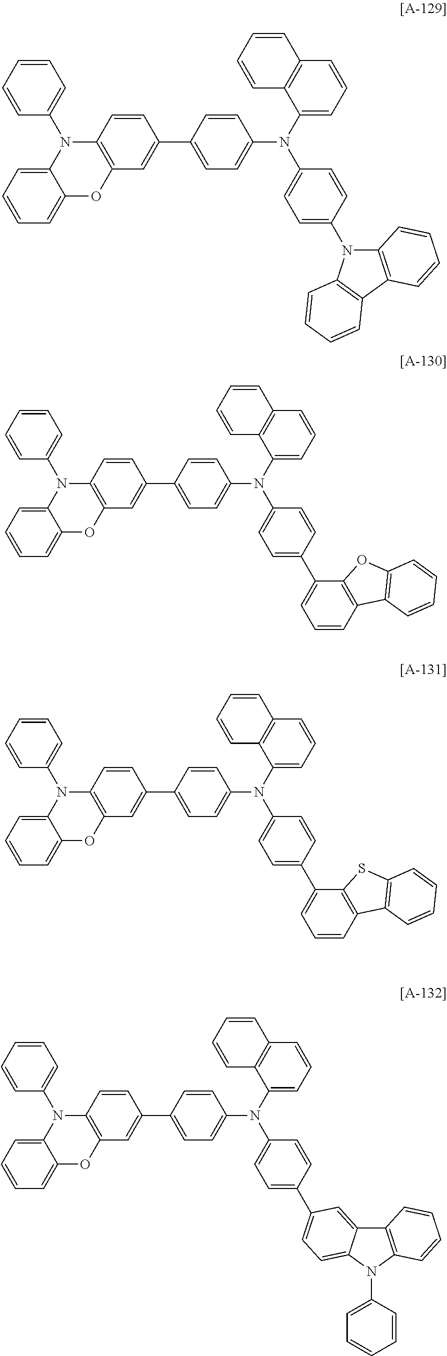 [SMILES: c1ccc(N2c3ccccc3Oc3cc(-c4ccc(N(c5ccc(-n6c7ccccc7c7ccccc76)cc5)c5cccc6ccccc56)cc4)ccc32)cc1 ; c1ccc(N2c3ccccc3Oc3cc(-c4ccc(N(c5ccc(-c6cccc7c6oc6ccccc67)cc5)c5cccc6ccccc56)cc4)ccc32)cc1 ; c1ccc(N2c3ccccc3Oc3cc(-c4ccc(N(c5ccc(-c6cccc7c6sc6ccccc67)cc5)c5cccc6ccccc56)cc4)ccc32)cc1 ; c1ccc(N2c3ccccc3Oc3cc(-c4ccc(N(c5ccc(-c6ccc7c(c6)c6ccccc6n7-c6ccccc6)cc5)c5cccc6ccccc56)cc4)ccc32)cc1]

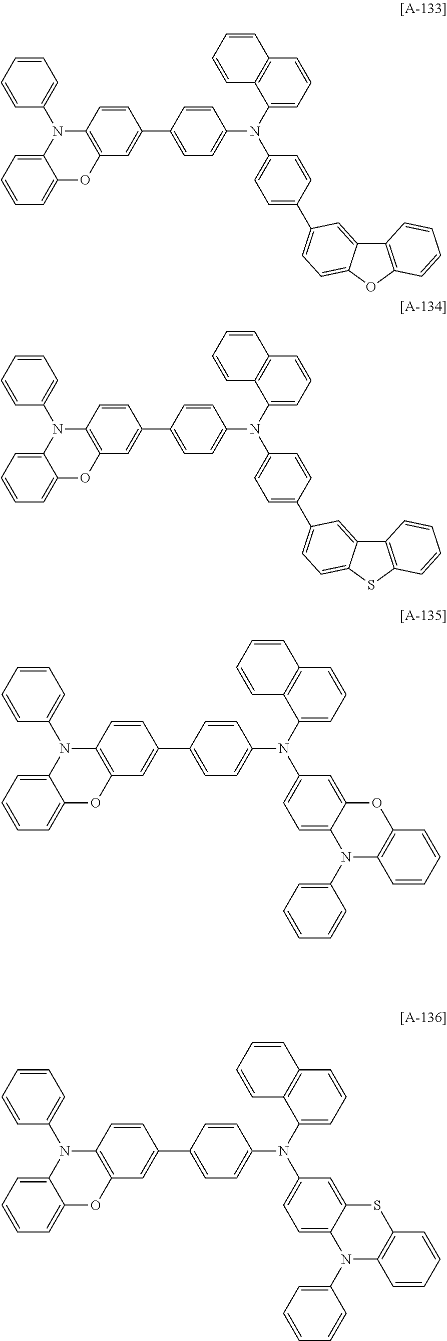 [SMILES: c1ccc(N2c3ccccc3Oc3cc(-c4ccc(N(c5ccc(-c6ccc7oc8ccccc8c7c6)cc5)c5cccc6ccccc56)cc4)ccc32)cc1 ; c1ccc(N2c3ccccc3Oc3cc(-c4ccc(N(c5ccc(-c6ccc7sc8ccccc8c7c6)cc5)c5cccc6ccccc56)cc4)ccc32)cc1 ; c1ccc(N2c3ccccc3Oc3cc(-c4ccc(N(c5ccc6c(c5)Oc5ccccc5N6c5ccccc5)c5cccc6ccccc56)cc4)ccc32)cc1 ; c1ccc(N2c3ccccc3Oc3cc(-c4ccc(N(c5ccc6c(c5)Sc5ccccc5N6c5ccccc5)c5cccc6ccccc56)cc4)ccc32)cc1]

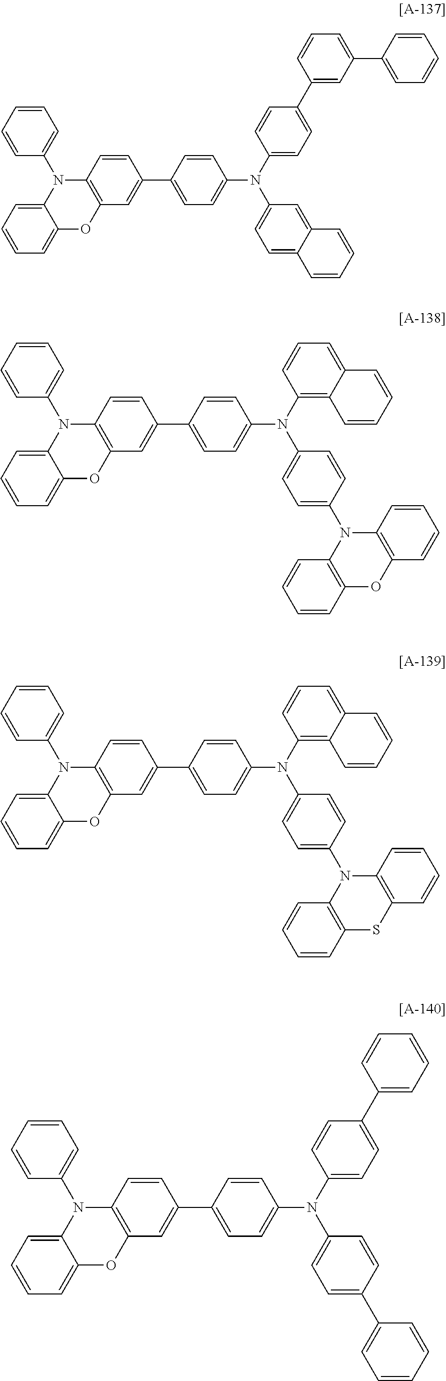 [SMILES: c1ccc(-c2cccc(-c3ccc(N(c4ccc(-c5ccc6c(c5)Oc5ccccc5N6c5ccccc5)cc4)c4ccc5ccccc5c4)cc3)c2)cc1 ; c1ccc(N2c3ccccc3Oc3cc(-c4ccc(N(c5ccc(N6c7ccccc7Oc7ccccc76)cc5)c5cccc6ccccc56)cc4)ccc32)cc1 ; c1ccc(N2c3ccccc3Oc3cc(-c4ccc(N(c5ccc(N6c7ccccc7Sc7ccccc76)cc5)c5cccc6ccccc56)cc4)ccc32)cc1 ; c1ccc(-c2ccc(N(c3ccc(-c4ccccc4)cc3)c3ccc(-c4ccc5c(c4)Oc4ccccc4N5c4ccccc4)cc3)cc2)cc1]

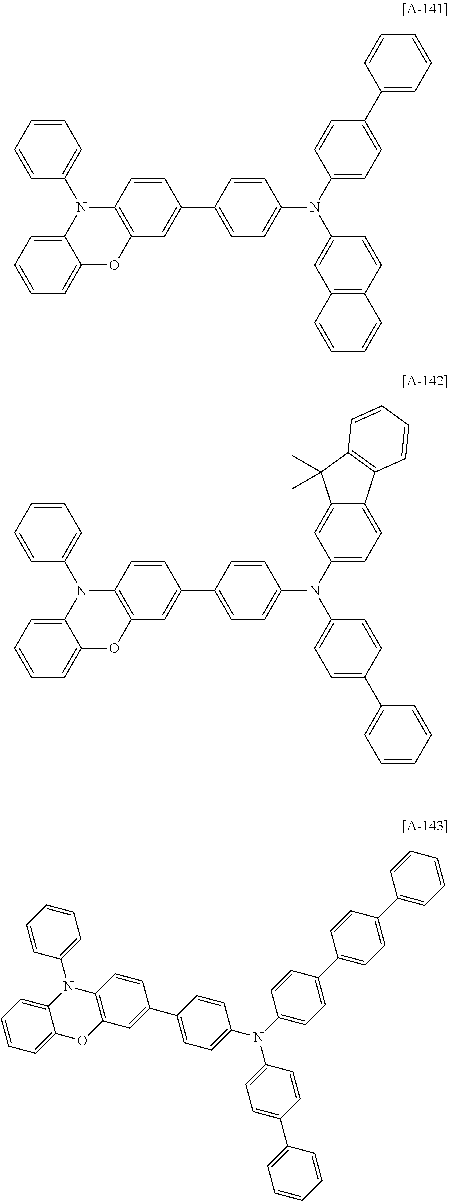 [SMILES: c1ccc(-c2ccc(N(c3ccc(-c4ccc5c(c4)Oc4ccccc4N5c4ccccc4)cc3)c3ccc4ccccc4c3)cc2)cc1 ; CC1(C)c2ccccc2-c2ccc(N(c3ccc(-c4ccccc4)cc3)c3ccc(-c4ccc5c(c4)Oc4ccccc4N5c4ccccc4)cc3)cc21 ; c1ccc(-c2ccc(-c3ccc(N(c4ccc(-c5ccccc5)cc4)c4ccc(-c5ccc6c(c5)Oc5ccccc5N6c5ccccc5)cc4)cc3)cc2)cc1]

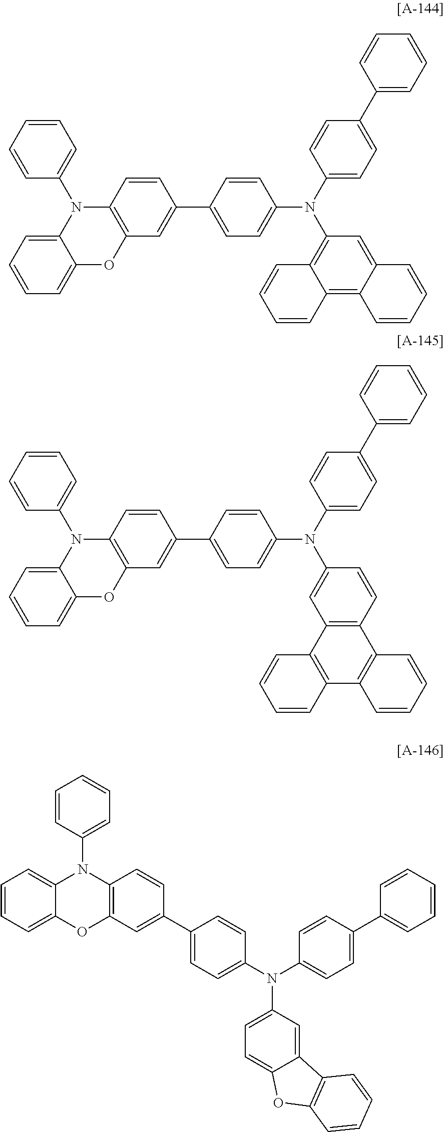

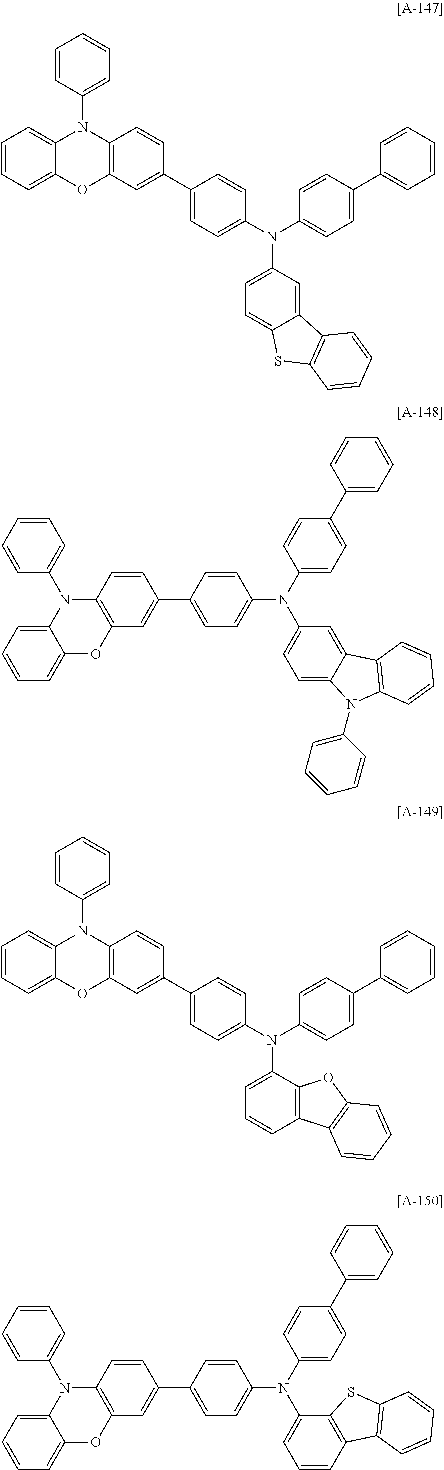 [SMILES: c1ccc(-c2ccc(N(c3ccc(-c4ccc5c(c4)Oc4ccccc4N5c4ccccc4)cc3)c3ccc4sc5ccccc5c4c3)cc2)cc1 ; c1ccc(-c2ccc(N(c3ccc(-c4ccc5c(c4)Oc4ccccc4N5c4ccccc4)cc3)c3ccc4c(c3)c3ccccc3n4-c3ccccc3)cc2)cc1 ; c1ccc(-c2ccc(N(c3ccc(-c4ccc5c(c4)Oc4ccccc4N5c4ccccc4)cc3)c3cccc4c3oc3ccccc34)cc2)cc1 ; c1ccc(-c2ccc(N(c3ccc(-c4ccc5c(c4)Oc4ccccc4N5c4ccccc4)cc3)c3cccc4c3sc3ccccc34)cc2)cc1]

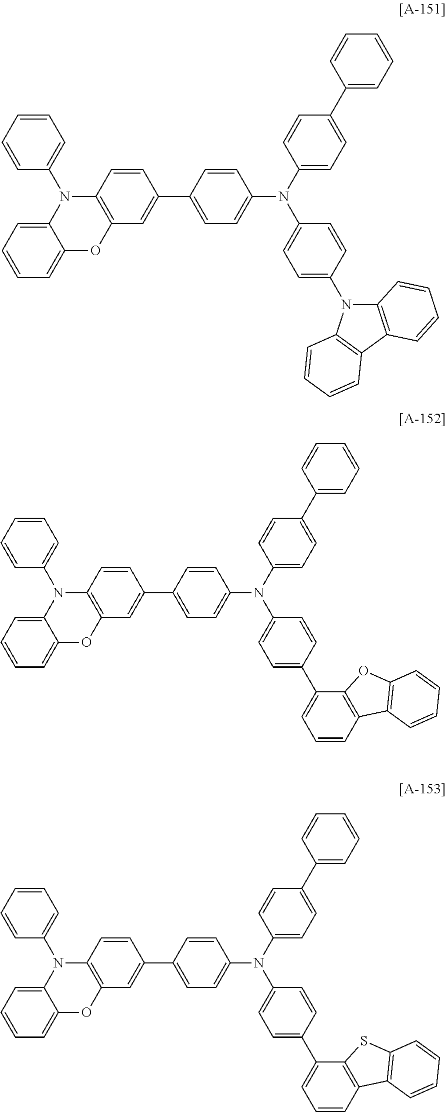 [SMILES: c1ccc(-c2ccc(N(c3ccc(-c4ccc5c(c4)Oc4ccccc4N5c4ccccc4)cc3)c3ccc(-n4c5ccccc5c5ccccc54)cc3)cc2)cc1 ; c1ccc(-c2ccc(N(c3ccc(-c4ccc5c(c4)Oc4ccccc4N5c4ccccc4)cc3)c3ccc(-c4cccc5c4oc4ccccc45)cc3)cc2)cc1 ; c1ccc(-c2ccc(N(c3ccc(-c4ccc5c(c4)Oc4ccccc4N5c4ccccc4)cc3)c3ccc(-c4cccc5c4sc4ccccc45)cc3)cc2)cc1]

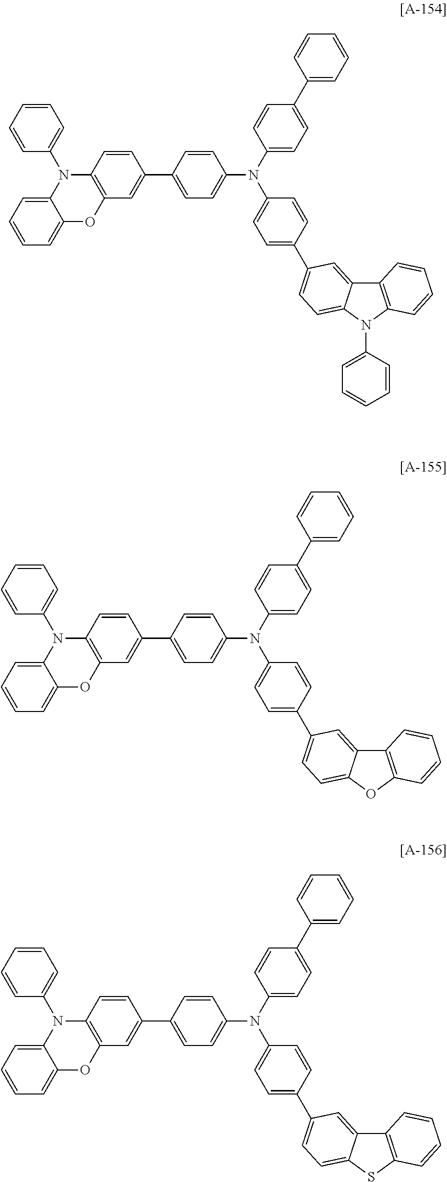 [SMILES: c1ccc(-c2ccc(N(c3ccc(-c4ccc5c(c4)Oc4ccccc4N5c4ccccc4)cc3)c3ccc(-c4ccc5c(c4)c4ccccc4n5-c4ccccc4)cc3)cc2)cc1 ; c1ccc(-c2ccc(N(c3ccc(-c4ccc5c(c4)Oc4ccccc4N5c4ccccc4)cc3)c3ccc(-c4ccc5oc6ccccc6c5c4)cc3)cc2)cc1 ; c1ccc(-c2ccc(N(c3ccc(-c4ccc5c(c4)Oc4ccccc4N5c4ccccc4)cc3)c3ccc(-c4ccc5sc6ccccc6c5c4)cc3)cc2)cc1]

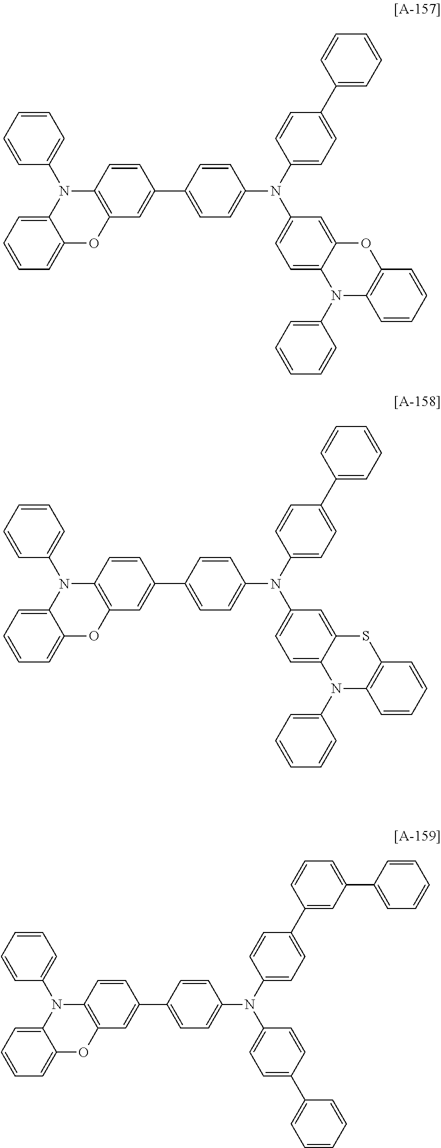 [SMILES: c1ccc(-c2ccc(N(c3ccc(-c4ccc5c(c4)Oc4ccccc4N5c4ccccc4)cc3)c3ccc4c(c3)Oc3ccccc3N4c3ccccc3)cc2)cc1 ; c1ccc(-c2ccc(N(c3ccc(-c4ccc5c(c4)Oc4ccccc4N5c4ccccc4)cc3)c3ccc4c(c3)Sc3ccccc3N4c3ccccc3)cc2)cc1 ; c1ccc(-c2ccc(N(c3ccc(-c4cccc(-c5ccccc5)c4)cc3)c3ccc(-c4ccc5c(c4)Oc4ccccc4N5c4ccccc4)cc3)cc2)cc1]

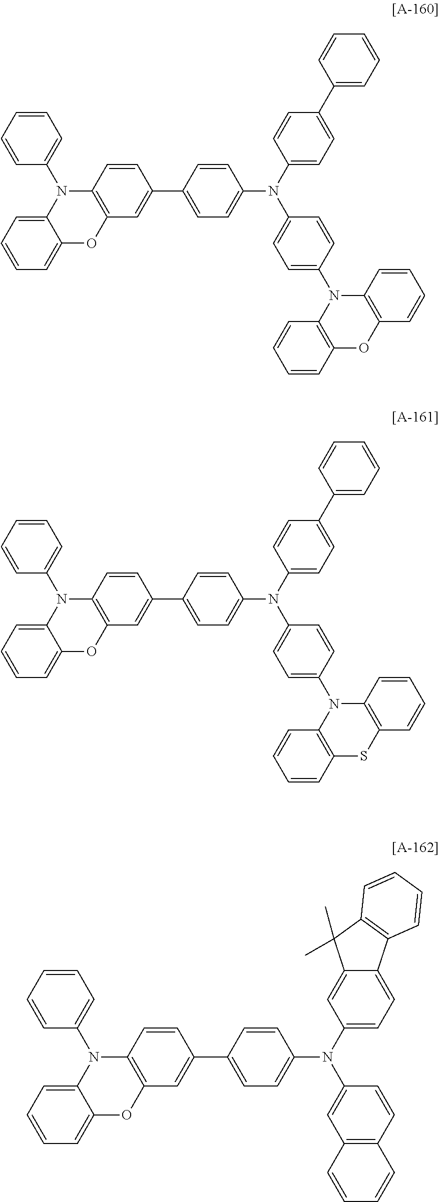 [SMILES: c1ccc(-c2ccc(N(c3ccc(-c4ccc5c(c4)Oc4ccccc4N5c4ccccc4)cc3)c3ccc(N4c5ccccc5Oc5ccccc54)cc3)cc2)cc1 ; c1ccc(-c2ccc(N(c3ccc(-c4ccc5c(c4)Oc4ccccc4N5c4ccccc4)cc3)c3ccc(N4c5ccccc5Sc5ccccc54)cc3)cc2)cc1 ; CC1(C)c2ccccc2-c2ccc(N(c3ccc(-c4ccc5c(c4)Oc4ccccc4N5c4ccccc4)cc3)c3ccc4ccccc4c3)cc21]

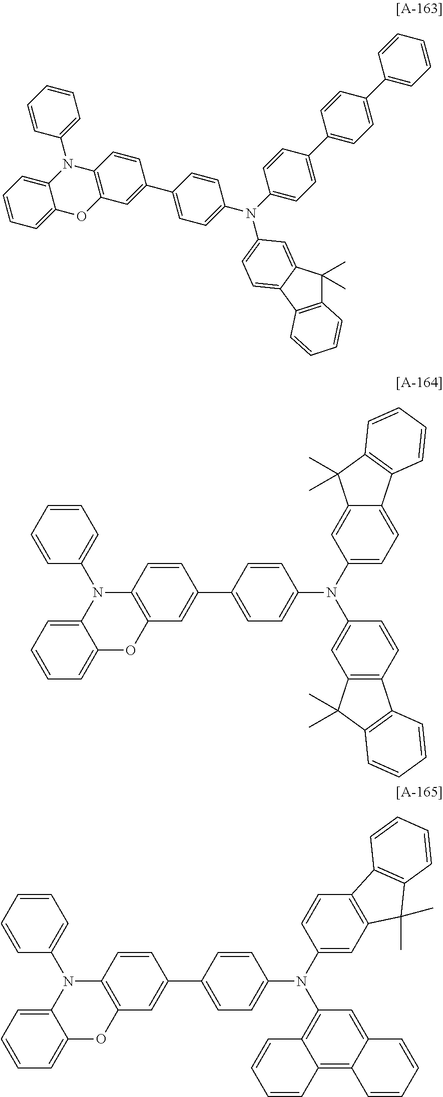

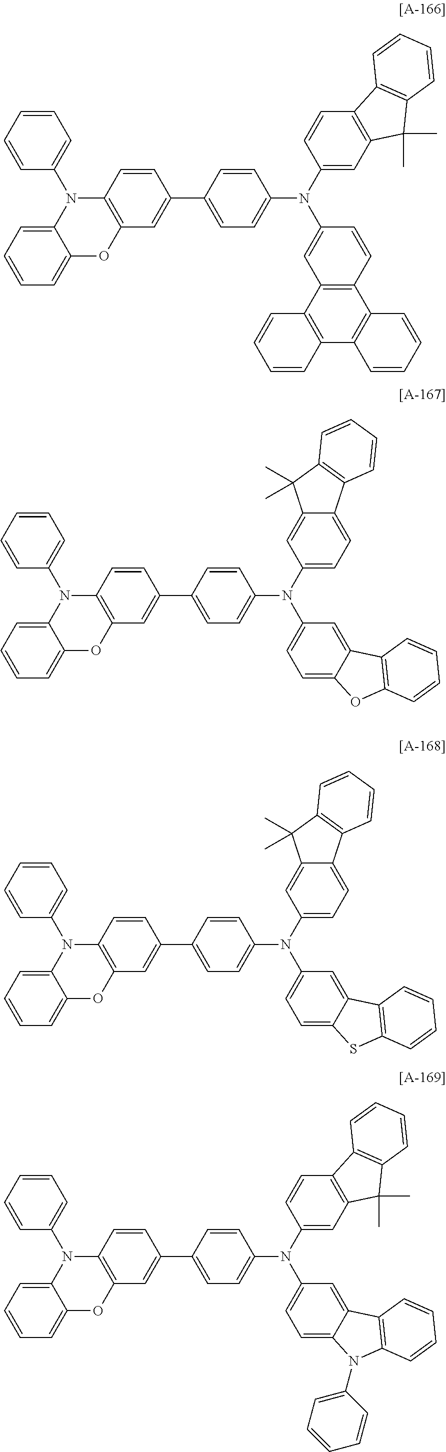 [SMILES: CC1(C)c2ccccc2-c2ccc(N(c3ccc(-c4ccc5c(c4)Oc4ccccc4N5c4ccccc4)cc3)c3ccc4c5ccccc5c5ccccc5c4c3)cc21 ; CC1(C)c2ccccc2-c2ccc(N(c3ccc(-c4ccc5c(c4)Oc4ccccc4N5c4ccccc4)cc3)c3ccc4oc5ccccc5c4c3)cc21 ; CC1(C)c2ccccc2-c2ccc(N(c3ccc(-c4ccc5c(c4)Oc4ccccc4N5c4ccccc4)cc3)c3ccc4sc5ccccc5c4c3)cc21 ; CC1(C)c2ccccc2-c2ccc(N(c3ccc(-c4ccc5c(c4)Oc4ccccc4N5c4ccccc4)cc3)c3ccc4c(c3)c3ccccc3n4-c3ccccc3)cc21]

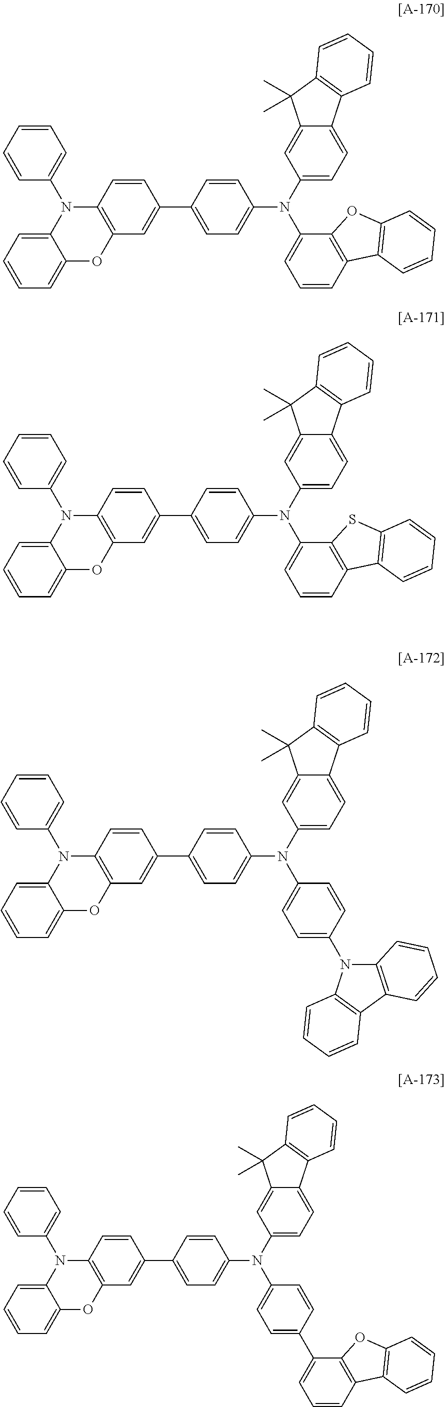 [SMILES: CC1(C)c2ccccc2-c2ccc(N(c3ccc(-c4ccc5c(c4)Oc4ccccc4N5c4ccccc4)cc3)c3cccc4c3oc3ccccc34)cc21 ; CC1(C)c2ccccc2-c2ccc(N(c3ccc(-c4ccc5c(c4)Oc4ccccc4N5c4ccccc4)cc3)c3cccc4c3sc3ccccc34)cc21 ; CC1(C)c2ccccc2-c2ccc(N(c3ccc(-c4ccc5c(c4)Oc4ccccc4N5c4ccccc4)cc3)c3ccc(-n4c5ccccc5c5ccccc54)cc3)cc21 ; CC1(C)c2ccccc2-c2ccc(N(c3ccc(-c4ccc5c(c4)Oc4ccccc4N5c4ccccc4)cc3)c3ccc(-c4cccc5c4oc4ccccc45)cc3)cc21]

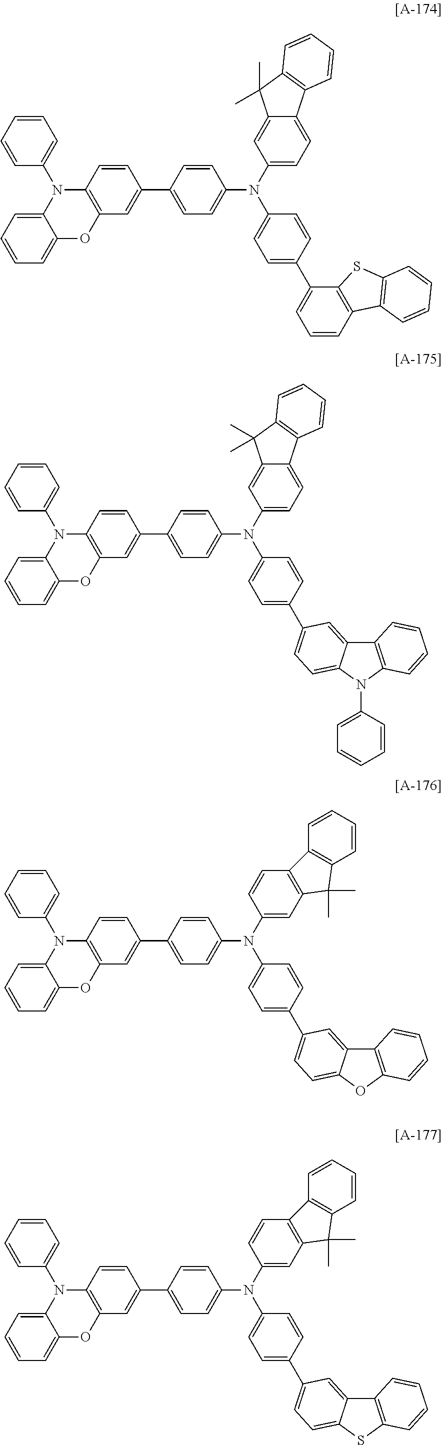 [SMILES: CC1(C)c2ccccc2-c2ccc(N(c3ccc(-c4ccc5c(c4)Oc4ccccc4N5c4ccccc4)cc3)c3ccc(-c4cccc5c4sc4ccccc45)cc3)cc21 ; CC1(C)c2ccccc2-c2ccc(N(c3ccc(-c4ccc5c(c4)Oc4ccccc4N5c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)Oc4ccccc4N5c4ccccc4)cc3)c3ccc(-c4ccc5oc6ccccc6c5c4)cc3)cc21 ; CC1(C)c2ccccc2-c2ccc(N(c3ccc(-c4ccc5c(c4)Oc4ccccc4N5c4ccccc4)cc3)c3ccc(-c4ccc5sc6ccccc6c5c4)cc3)cc21]

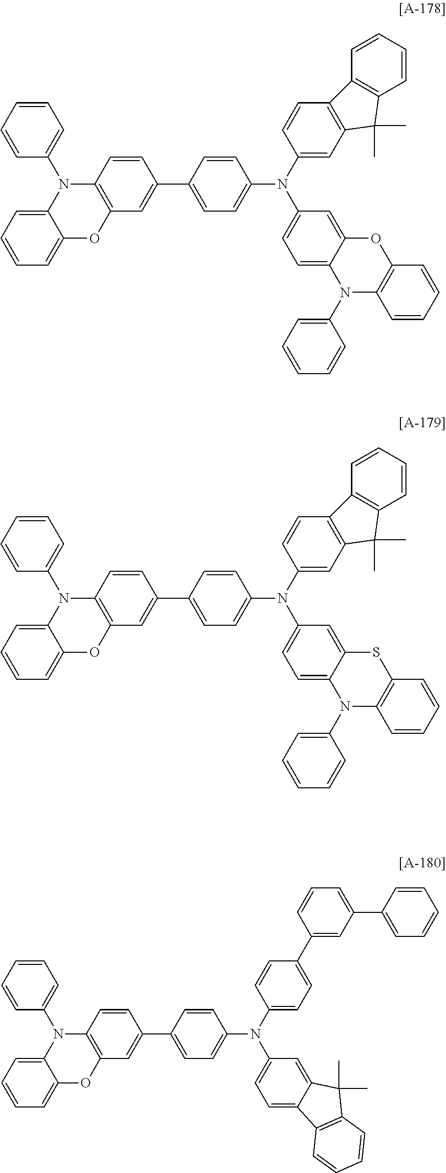 [SMILES: CC1(C)c2ccccc2-c2ccc(N(c3ccc(-c4ccc5c(c4)Oc4ccccc4N5c4ccccc4)cc3)c3ccc4c(c3)Oc3ccccc3N4c3ccccc3)cc21 ; CC1(C)c2ccccc2-c2ccc(N(c3ccc(-c4ccc5c(c4)Oc4ccccc4N5c4ccccc4)cc3)c3ccc4c(c3)Sc3ccccc3N4c3ccccc3)cc21 ; CC1(C)c2ccccc2-c2ccc(N(c3ccc(-c4cccc(-c5ccccc5)c4)cc3)c3ccc(-c4ccc5c(c4)Oc4ccccc4N5c4ccccc4)cc3)cc21]

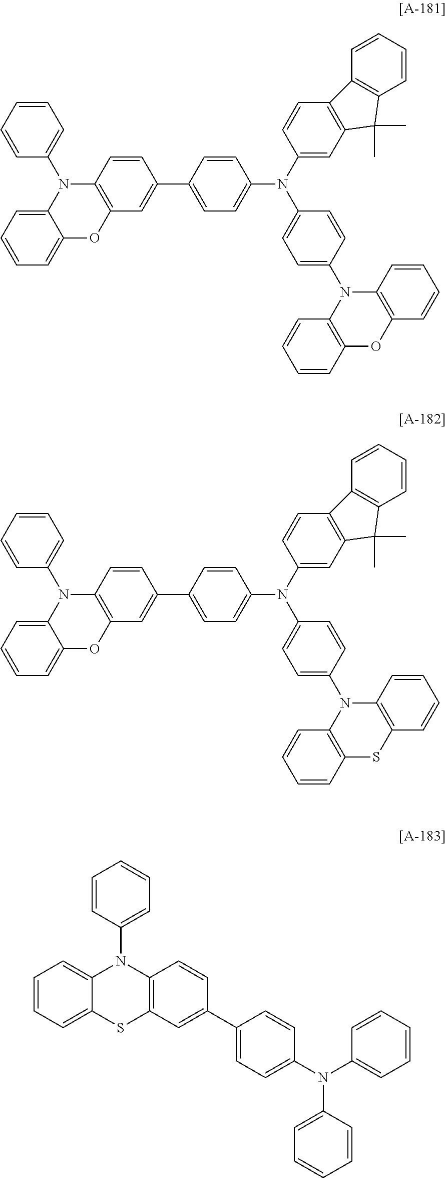 [SMILES: CC1(C)c2ccccc2-c2ccc(N(c3ccc(-c4ccc5c(c4)Oc4ccccc4N5c4ccccc4)cc3)c3ccc(N4c5ccccc5Oc5ccccc54)cc3)cc21 ; CC1(C)c2ccccc2-c2ccc(N(c3ccc(-c4ccc5c(c4)Oc4ccccc4N5c4ccccc4)cc3)c3ccc(N4c5ccccc5Sc5ccccc54)cc3)cc21 ; c1ccc(N(c2ccccc2)c2ccc(-c3ccc4c(c3)Sc3ccccc3N4c3ccccc3)cc2)cc1]

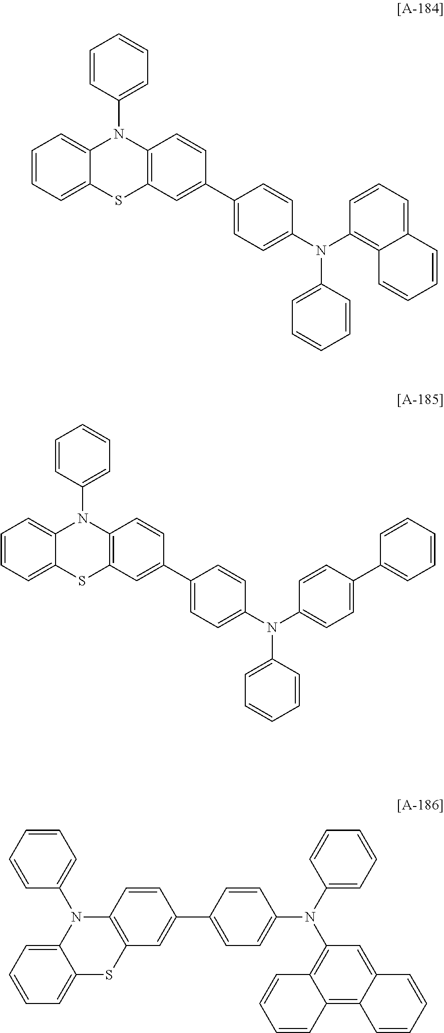 [SMILES: c1ccc(N2c3ccccc3Sc3cc(-c4ccc(N(c5ccccc5)c5cccc6ccccc56)cc4)ccc32)cc1 ; c1ccc(-c2ccc(N(c3ccccc3)c3ccc(-c4ccc5c(c4)Sc4ccccc4N5c4ccccc4)cc3)cc2)cc1 ; c1ccc(N2c3ccccc3Sc3cc(-c4ccc(N(c5ccccc5)c5cc6ccccc6c6ccccc56)cc4)ccc32)cc1]

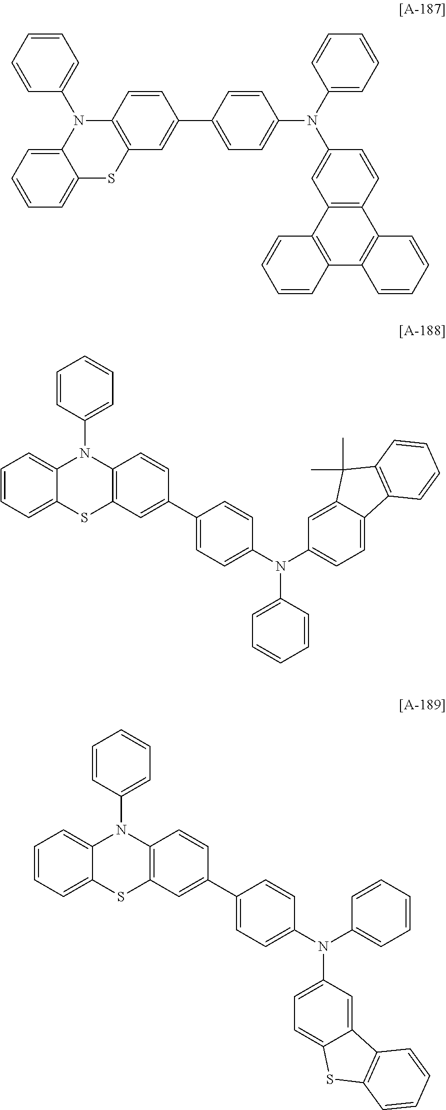 [SMILES: c1ccc(N(c2ccc(-c3ccc4c(c3)Sc3ccccc3N4c3ccccc3)cc2)c2ccc3c4ccccc4c4ccccc4c3c2)cc1 ; CC1(C)c2ccccc2-c2ccc(N(c3ccccc3)c3ccc(-c4ccc5c(c4)Sc4ccccc4N5c4ccccc4)cc3)cc21 ; c1ccc(N(c2ccc(-c3ccc4c(c3)Sc3ccccc3N4c3ccccc3)cc2)c2ccc3sc4ccccc4c3c2)cc1]

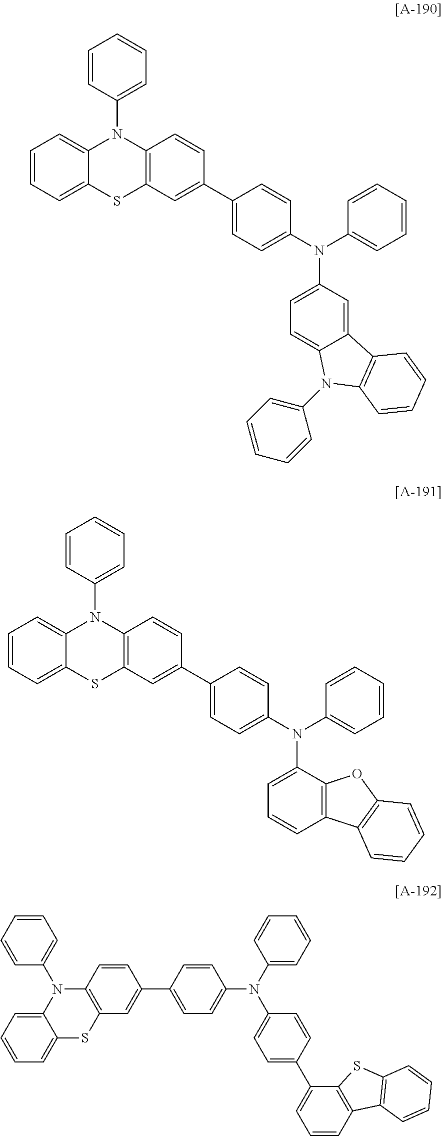 [SMILES: c1ccc(N(c2ccc(-c3ccc4c(c3)Sc3ccccc3N4c3ccccc3)cc2)c2ccc3c(c2)c2ccccc2n3-c2ccccc2)cc1 ; c1ccc(N2c3ccccc3Sc3cc(-c4ccc(N(c5ccccc5)c5cccc6c5oc5ccccc56)cc4)ccc32)cc1 ; c1ccc(N(c2ccc(-c3ccc4c(c3)Sc3ccccc3N4c3ccccc3)cc2)c2ccc(-c3cccc4c3sc3ccccc34)cc2)cc1]

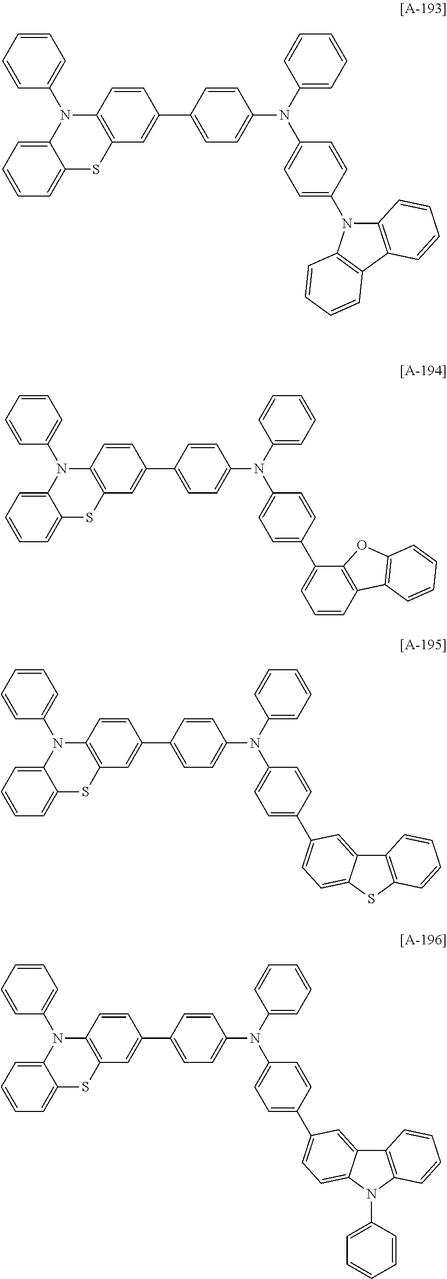 [SMILES: c1ccc(N(c2ccc(-c3ccc4c(c3)Sc3ccccc3N4c3ccccc3)cc2)c2ccc(-n3c4ccccc4c4ccccc43)cc2)cc1 ; c1ccc(N(c2ccc(-c3ccc4c(c3)Sc3ccccc3N4c3ccccc3)cc2)c2ccc(-c3cccc4c3oc3ccccc34)cc2)cc1 ; c1ccc(N(c2ccc(-c3ccc4c(c3)Sc3ccccc3N4c3ccccc3)cc2)c2ccc(-c3ccc4sc5ccccc5c4c3)cc2)cc1 ; c1ccc(N(c2ccc(-c3ccc4c(c3)Sc3ccccc3N4c3ccccc3)cc2)c2ccc(-c3ccc4c(c3)c3ccccc3n4-c3ccccc3)cc2)cc1]

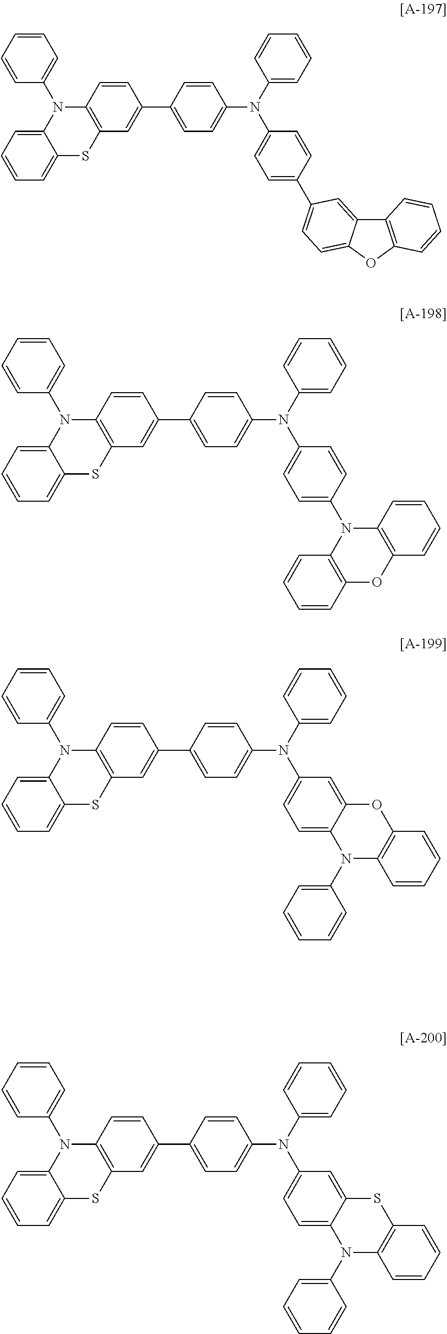 [SMILES: c1ccc(N(c2ccc(-c3ccc4c(c3)Sc3ccccc3N4c3ccccc3)cc2)c2ccc(-c3ccc4oc5ccccc5c4c3)cc2)cc1 ; c1ccc(N(c2ccc(-c3ccc4c(c3)Sc3ccccc3N4c3ccccc3)cc2)c2ccc(N3c4ccccc4Oc4ccccc43)cc2)cc1 ; c1ccc(N(c2ccc(-c3ccc4c(c3)Sc3ccccc3N4c3ccccc3)cc2)c2ccc3c(c2)Oc2ccccc2N3c2ccccc2)cc1 ; c1ccc(N(c2ccc(-c3ccc4c(c3)Sc3ccccc3N4c3ccccc3)cc2)c2ccc3c(c2)Sc2ccccc2N3c2ccccc2)cc1]

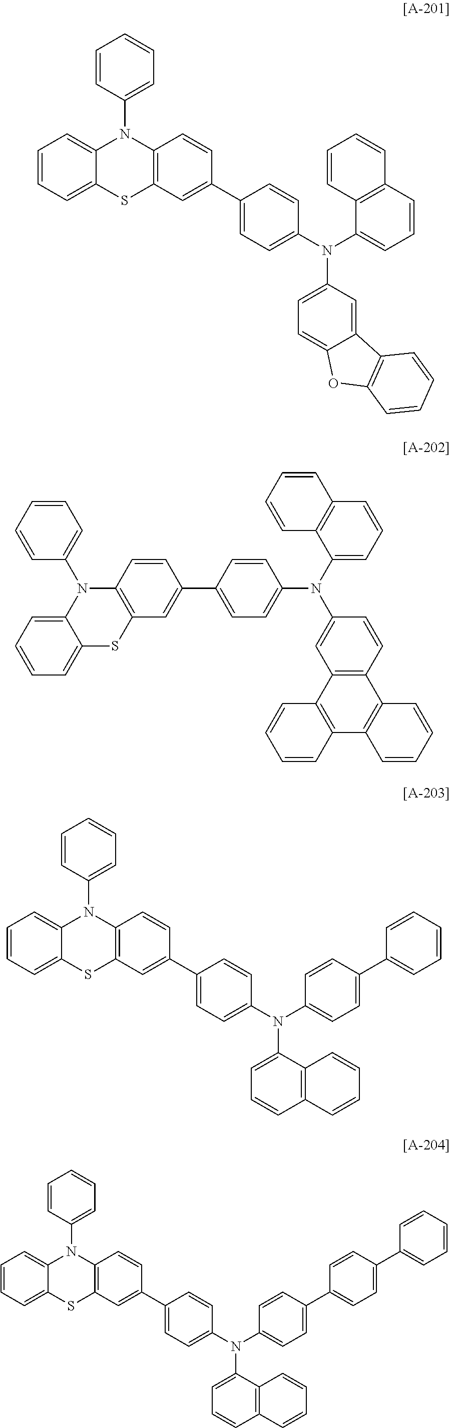 [SMILES: c1ccc(N2c3ccccc3Sc3cc(-c4ccc(N(c5ccc6oc7ccccc7c6c5)c5cccc6ccccc56)cc4)ccc32)cc1 ; c1ccc(N2c3ccccc3Sc3cc(-c4ccc(N(c5ccc6c7ccccc7c7ccccc7c6c5)c5cccc6ccccc56)cc4)ccc32)cc1 ; c1ccc(-c2ccc(N(c3ccc(-c4ccc5c(c4)Sc4ccccc4N5c4ccccc4)cc3)c3cccc4ccccc34)cc2)cc1 ; c1ccc(-c2ccc(-c3ccc(N(c4ccc(-c5ccc6c(c5)Sc5ccccc5N6c5ccccc5)cc4)c4cccc5ccccc45)cc3)cc2)cc1]

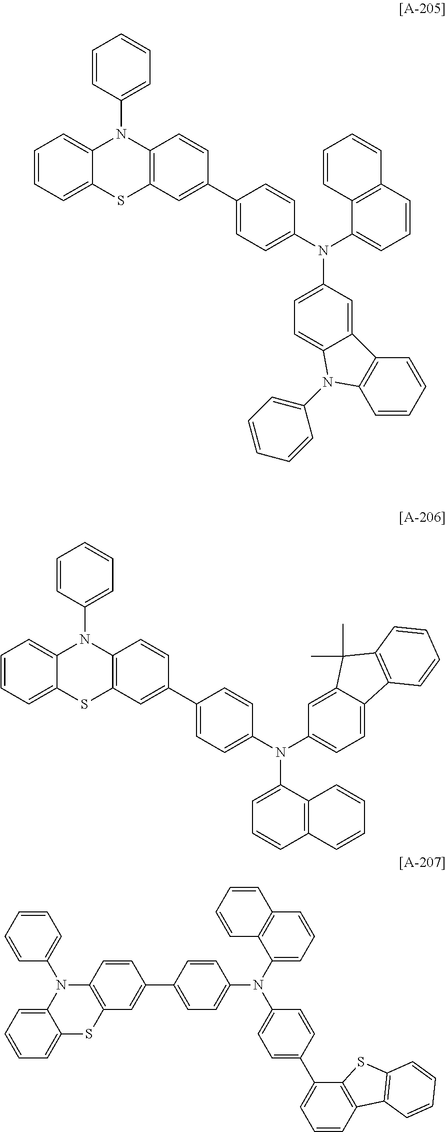

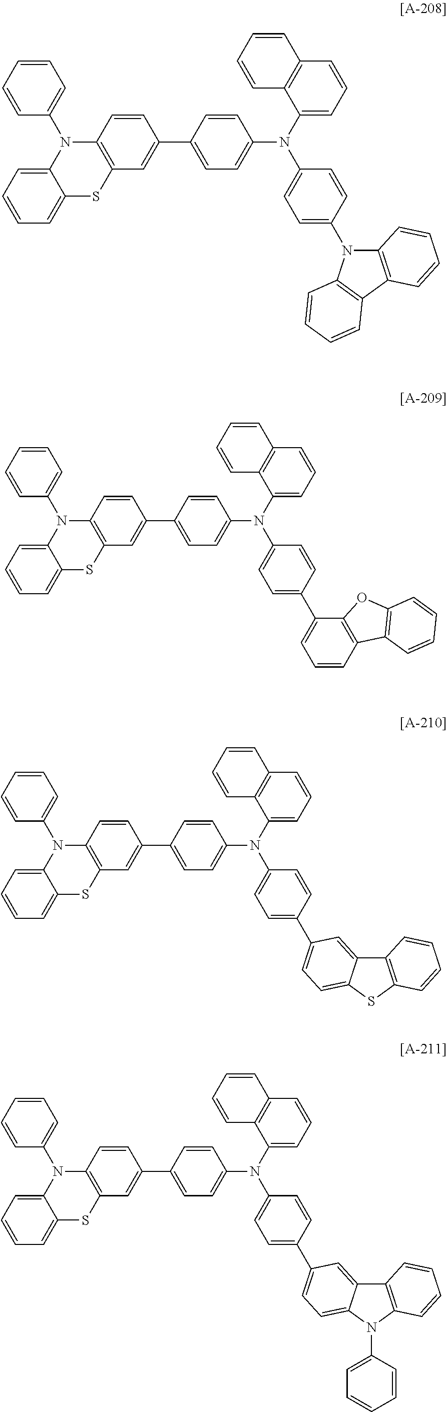 [SMILES: c1ccc(N2c3ccccc3Sc3cc(-c4ccc(N(c5ccc(-n6c7ccccc7c7ccccc76)cc5)c5cccc6ccccc56)cc4)ccc32)cc1 ; c1ccc(N2c3ccccc3Sc3cc(-c4ccc(N(c5ccc(-c6cccc7c6oc6ccccc67)cc5)c5cccc6ccccc56)cc4)ccc32)cc1 ; c1ccc(N2c3ccccc3Sc3cc(-c4ccc(N(c5ccc(-c6ccc7sc8ccccc8c7c6)cc5)c5cccc6ccccc56)cc4)ccc32)cc1 ; c1ccc(N2c3ccccc3Sc3cc(-c4ccc(N(c5ccc(-c6ccc7c(c6)c6ccccc6n7-c6ccccc6)cc5)c5cccc6ccccc56)cc4)ccc32)cc1]

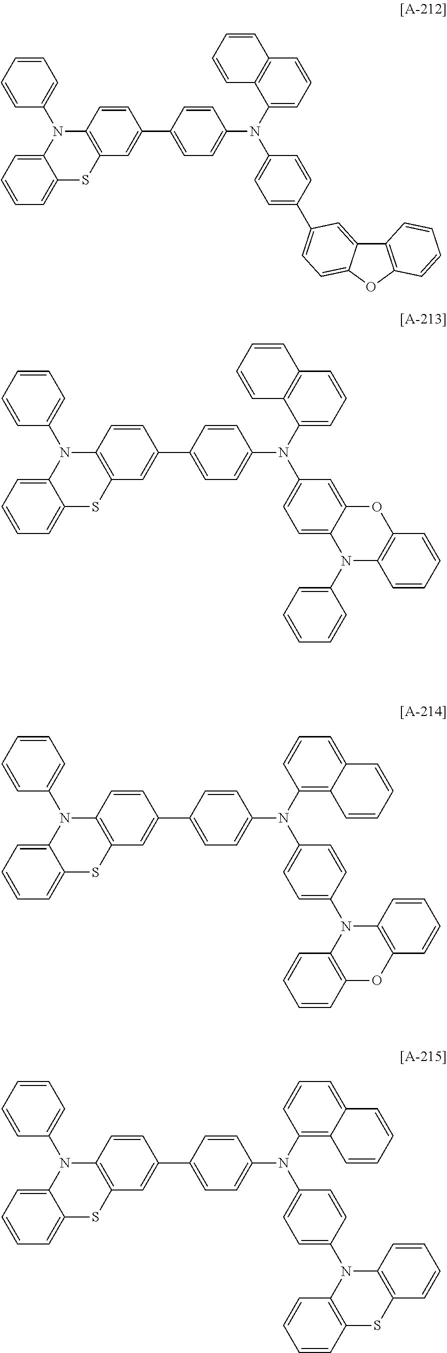 [SMILES: c1ccc(N2c3ccccc3Sc3cc(-c4ccc(N(c5ccc(-c6ccc7oc8ccccc8c7c6)cc5)c5cccc6ccccc56)cc4)ccc32)cc1 ; c1ccc(N2c3ccccc3Oc3cc(N(c4ccc(-c5ccc6c(c5)Sc5ccccc5N6c5ccccc5)cc4)c4cccc5ccccc45)ccc32)cc1 ; c1ccc(N2c3ccccc3Sc3cc(-c4ccc(N(c5ccc(N6c7ccccc7Oc7ccccc76)cc5)c5cccc6ccccc56)cc4)ccc32)cc1 ; c1ccc(N2c3ccccc3Sc3cc(-c4ccc(N(c5ccc(N6c7ccccc7Sc7ccccc76)cc5)c5cccc6ccccc56)cc4)ccc32)cc1]

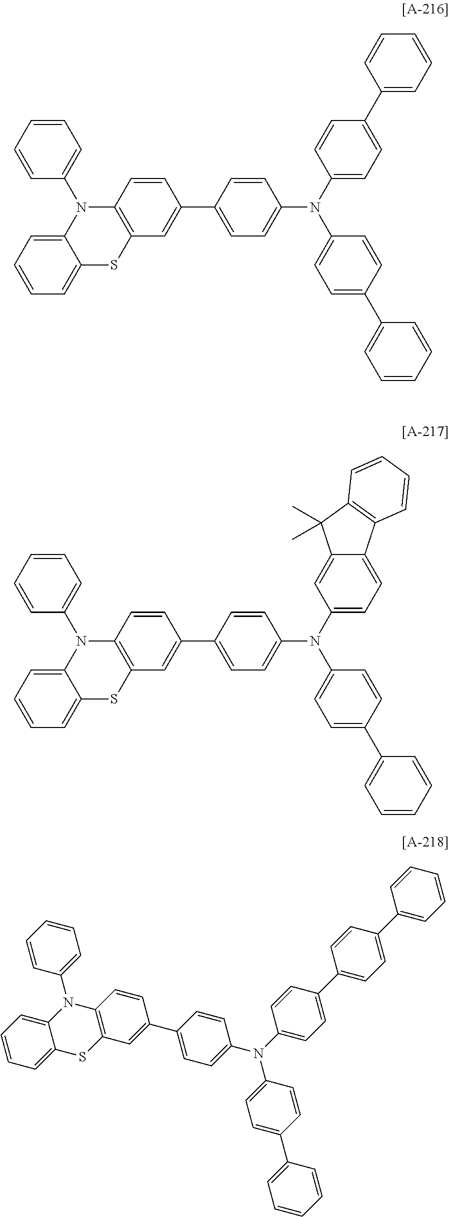 [SMILES: c1ccc(-c2ccc(N(c3ccc(-c4ccccc4)cc3)c3ccc(-c4ccc5c(c4)Sc4ccccc4N5c4ccccc4)cc3)cc2)cc1 ; CC1(C)c2ccccc2-c2ccc(N(c3ccc(-c4ccccc4)cc3)c3ccc(-c4ccc5c(c4)Sc4ccccc4N5c4ccccc4)cc3)cc21 ; c1ccc(-c2ccc(-c3ccc(N(c4ccc(-c5ccccc5)cc4)c4ccc(-c5ccc6c(c5)Sc5ccccc5N6c5ccccc5)cc4)cc3)cc2)cc1]

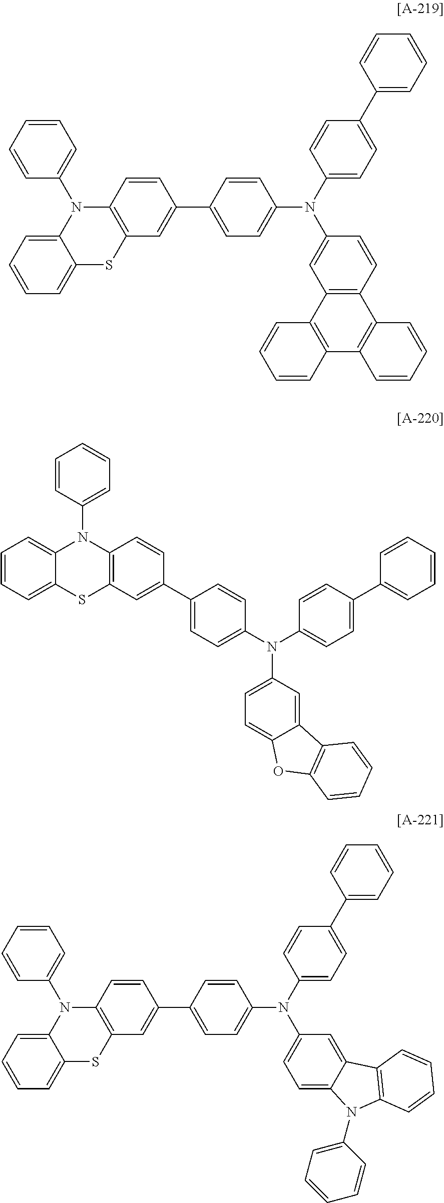 [SMILES: c1ccc(-c2ccc(N(c3ccc(-c4ccc5c(c4)Sc4ccccc4N5c4ccccc4)cc3)c3ccc4c5ccccc5c5ccccc5c4c3)cc2)cc1 ; c1ccc(-c2ccc(N(c3ccc(-c4ccc5c(c4)Sc4ccccc4N5c4ccccc4)cc3)c3ccc4oc5ccccc5c4c3)cc2)cc1 ; c1ccc(-c2ccc(N(c3ccc(-c4ccc5c(c4)Sc4ccccc4N5c4ccccc4)cc3)c3ccc4c(c3)c3ccccc3n4-c3ccccc3)cc2)cc1]

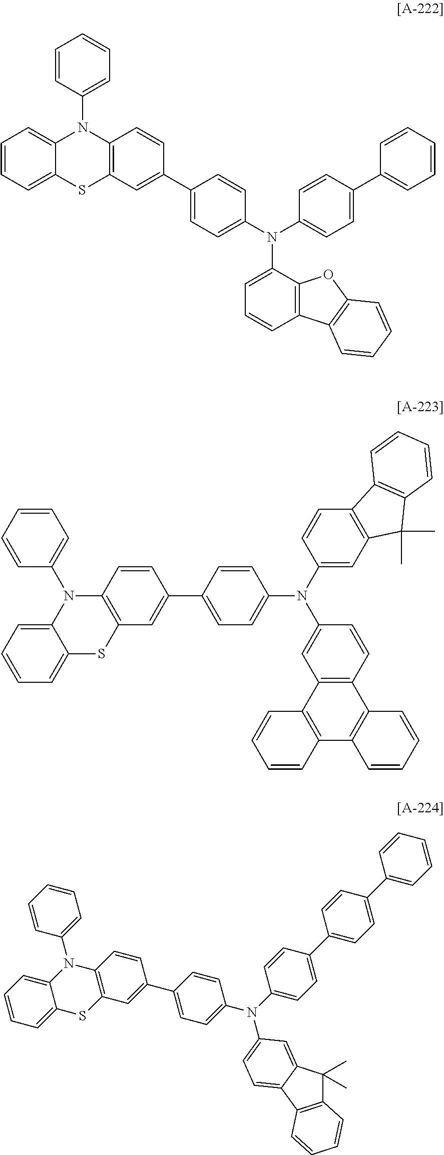 [SMILES: c1ccc(-c2ccc(N(c3ccc(-c4ccc5c(c4)Sc4ccccc4N5c4ccccc4)cc3)c3cccc4c3oc3ccccc34)cc2)cc1 ; CC1(C)c2ccccc2-c2ccc(N(c3ccc(-c4ccc5c(c4)Sc4ccccc4N5c4ccccc4)cc3)c3ccc4c5ccccc5c5ccccc5c4c3)cc21 ; CC1(C)c2ccccc2-c2ccc(N(c3ccc(-c4ccc(-c5ccccc5)cc4)cc3)c3ccc(-c4ccc5c(c4)Sc4ccccc4N5c4ccccc4)cc3)cc21]

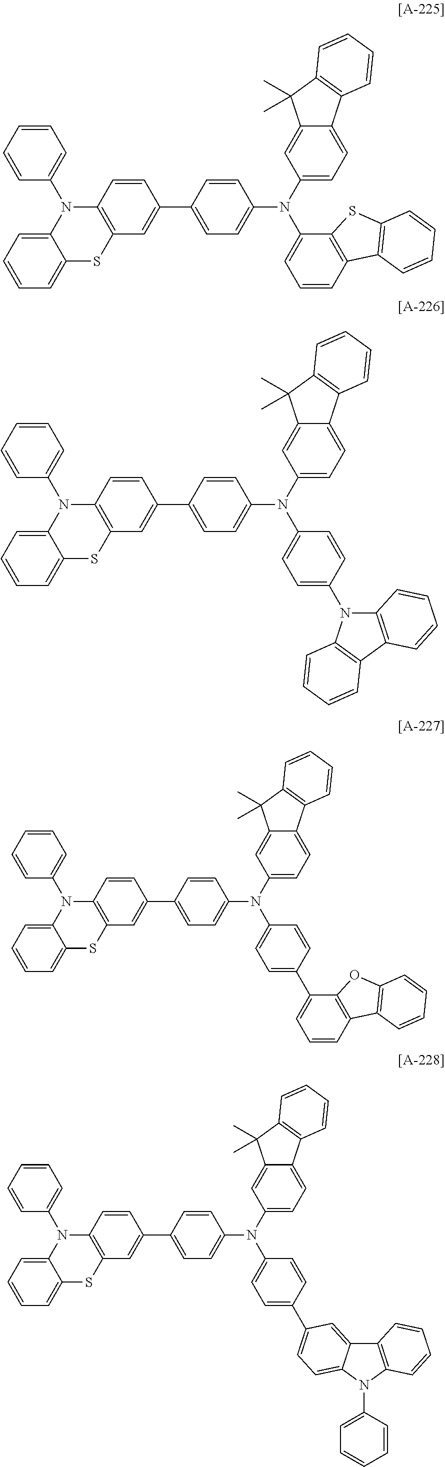 [SMILES: CC1(C)c2ccccc2-c2ccc(N(c3ccc(-c4ccc5c(c4)Sc4ccccc4N5c4ccccc4)cc3)c3cccc4c3sc3ccccc34)cc21 ; CC1(C)c2ccccc2-c2ccc(N(c3ccc(-c4ccc5c(c4)Sc4ccccc4N5c4ccccc4)cc3)c3ccc(-n4c5ccccc5c5ccccc54)cc3)cc21 ; CC1(C)c2ccccc2-c2ccc(N(c3ccc(-c4ccc5c(c4)Sc4ccccc4N5c4ccccc4)cc3)c3ccc(-c4cccc5c4oc4ccccc45)cc3)cc21 ; CC1(C)c2ccccc2-c2ccc(N(c3ccc(-c4ccc5c(c4)Sc4ccccc4N5c4ccccc4)cc3)c3ccc(-c4ccc5c(c4)c4ccccc4n5-c4ccccc4)cc3)cc21]

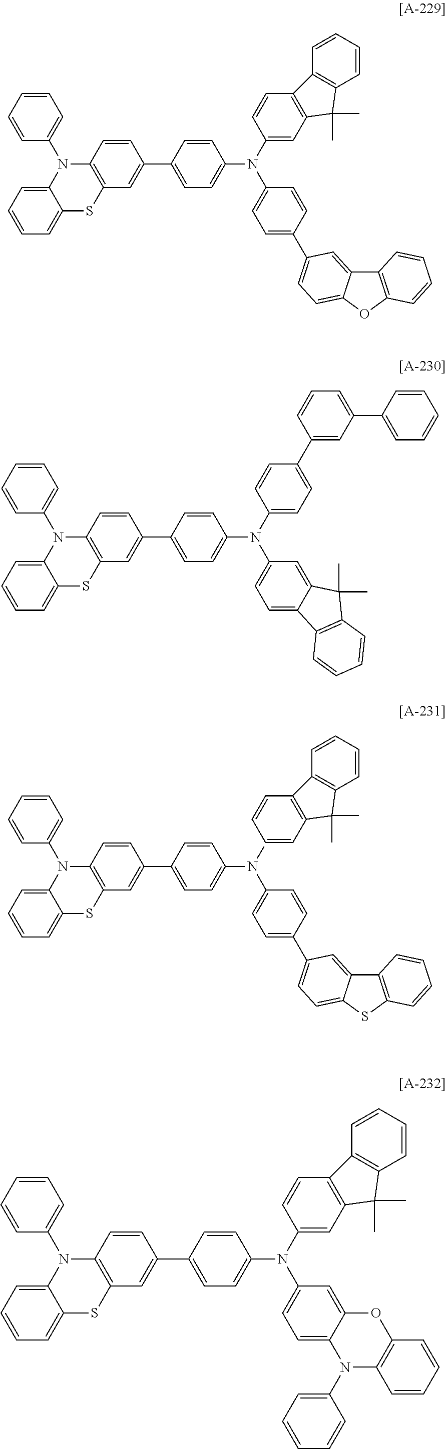

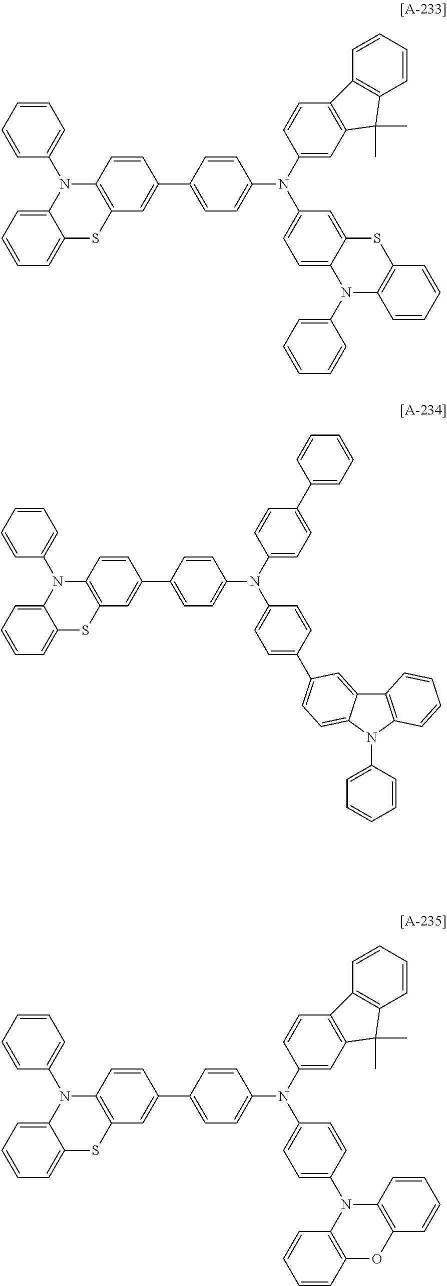 [SMILES: CC1(C)c2ccccc2-c2ccc(N(c3ccc(-c4ccc5c(c4)Sc4ccccc4N5c4ccccc4)cc3)c3ccc4c(c3)Sc3ccccc3N4c3ccccc3)cc21 ; c1ccc(-c2ccc(N(c3ccc(-c4ccc5c(c4)Sc4ccccc4N5c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccc5c(c4)Sc4ccccc4N5c4ccccc4)cc3)c3ccc(N4c5ccccc5Oc5ccccc54)cc3)cc21]

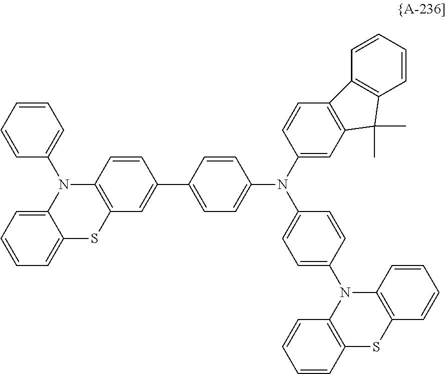 [SMILES: CC1(C)c2ccccc2-c2ccc(N(c3ccc(-c4ccc5c(c4)Sc4ccccc4N5c4ccccc4)cc3)c3ccc(N4c5ccccc5Sc5ccccc54)cc3)cc21]

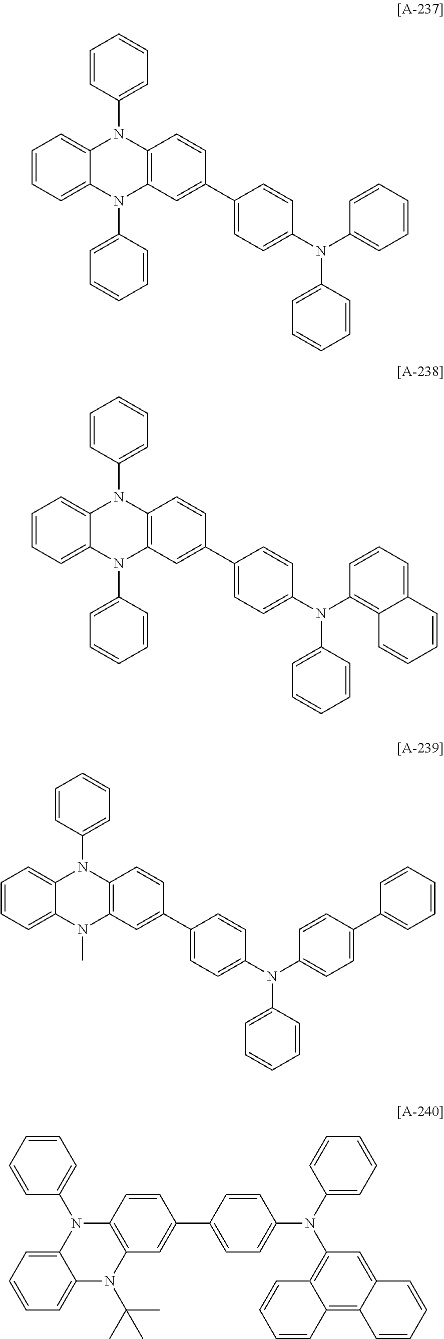 [SMILES: c1ccc(N(c2ccccc2)c2ccc(-c3ccc4c(c3)N(c3ccccc3)c3ccccc3N4c3ccccc3)cc2)cc1 ; c1ccc(N2c3ccccc3N(c3ccccc3)c3cc(-c4ccc(N(c5ccccc5)c5cccc6ccccc56)cc4)ccc32)cc1 ; CN1c2ccccc2N(c2ccccc2)c2ccc(-c3ccc(N(c4ccccc4)c4ccc(-c5ccccc5)cc4)cc3)cc21 ; CC(C)(C)N1c2ccccc2N(c2ccccc2)c2ccc(-c3ccc(N(c4ccccc4)c4cc5ccccc5c5ccccc45)cc3)cc21]

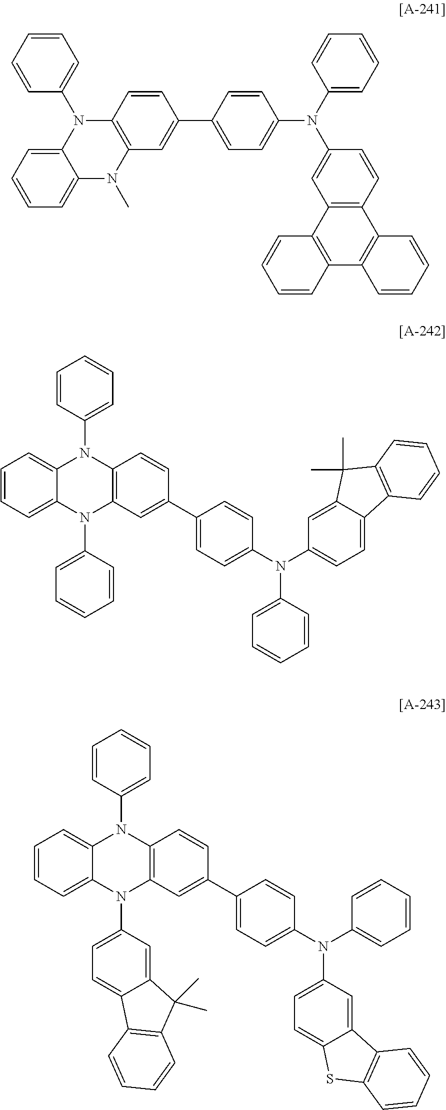 [SMILES: CN1c2ccccc2N(c2ccccc2)c2ccc(-c3ccc(N(c4ccccc4)c4ccc5c6ccccc6c6ccccc6c5c4)cc3)cc21 ; CC1(C)c2ccccc2-c2ccc(N(c3ccccc3)c3ccc(-c4ccc5c(c4)N(c4ccccc4)c4ccccc4N5c4ccccc4)cc3)cc21 ; CC1(C)c2ccccc2-c2ccc(N3c4ccccc4N(c4ccccc4)c4ccc(-c5ccc(N(c6ccccc6)c6ccc7sc8ccccc8c7c6)cc5)cc43)cc21]

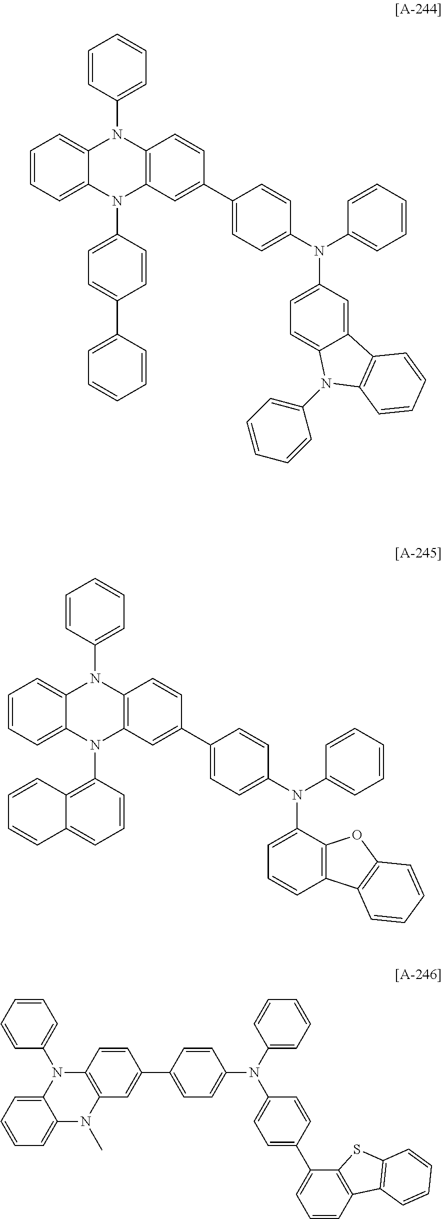 [SMILES: c1ccc(-c2ccc(N3c4ccccc4N(c4ccccc4)c4ccc(-c5ccc(N(c6ccccc6)c6ccc7c(c6)c6ccccc6n7-c6ccccc6)cc5)cc43)cc2)cc1 ; c1ccc(N2c3ccccc3N(c3cccc4ccccc34)c3cc(-c4ccc(N(c5ccccc5)c5cccc6c5oc5ccccc56)cc4)ccc32)cc1 ; CN1c2ccccc2N(c2ccccc2)c2ccc(-c3ccc(N(c4ccccc4)c4ccc(-c5cccc6c5sc5ccccc56)cc4)cc3)cc21]

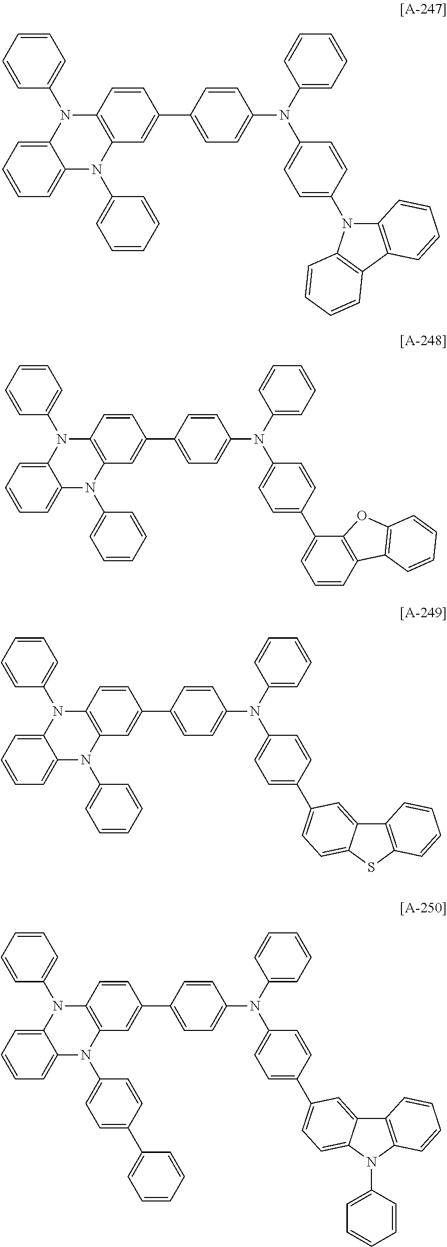 [SMILES: c1ccc(N(c2ccc(-c3ccc4c(c3)N(c3ccccc3)c3ccccc3N4c3ccccc3)cc2)c2ccc(-n3c4ccccc4c4ccccc43)cc2)cc1 ; c1ccc(N(c2ccc(-c3ccc4c(c3)N(c3ccccc3)c3ccccc3N4c3ccccc3)cc2)c2ccc(-c3cccc4c3oc3ccccc34)cc2)cc1 ; c1ccc(N(c2ccc(-c3ccc4c(c3)N(c3ccccc3)c3ccccc3N4c3ccccc3)cc2)c2ccc(-c3ccc4sc5ccccc5c4c3)cc2)cc1 ; c1ccc(-c2ccc(N3c4ccccc4N(c4ccccc4)c4ccc(-c5ccc(N(c6ccccc6)c6ccc(-c7ccc8c(c7)c7ccccc7n8-c7ccccc7)cc6)cc5)cc43)cc2)cc1]

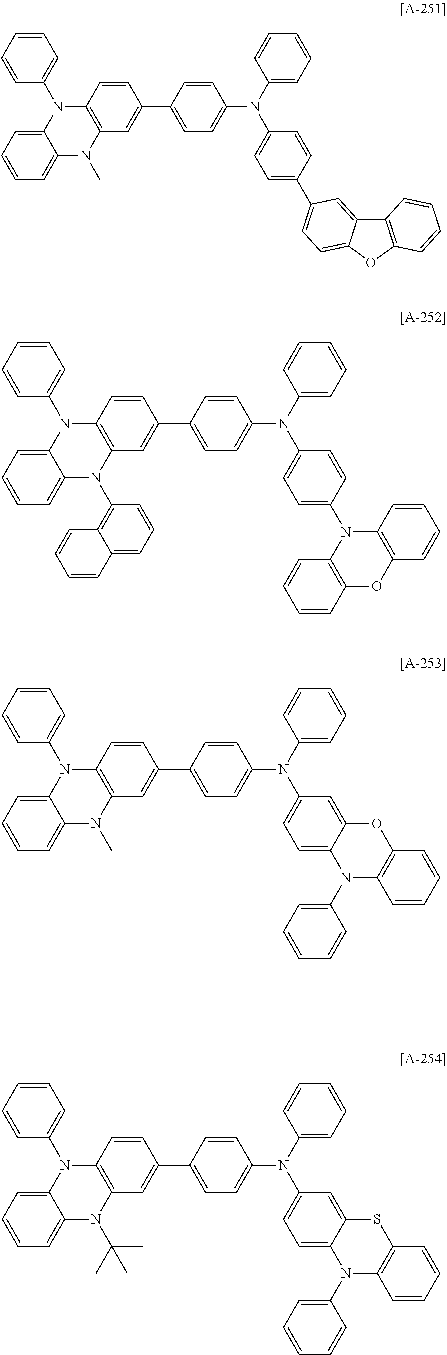 [SMILES: CN1c2ccccc2N(c2ccccc2)c2ccc(-c3ccc(N(c4ccccc4)c4ccc(-c5ccc6oc7ccccc7c6c5)cc4)cc3)cc21 ; c1ccc(N(c2ccc(-c3ccc4c(c3)N(c3cccc5ccccc35)c3ccccc3N4c3ccccc3)cc2)c2ccc(N3c4ccccc4Oc4ccccc43)cc2)cc1 ; CN1c2ccccc2N(c2ccccc2)c2ccc(-c3ccc(N(c4ccccc4)c4ccc5c(c4)Oc4ccccc4N5c4ccccc4)cc3)cc21 ; CC(C)(C)N1c2ccccc2N(c2ccccc2)c2ccc(-c3ccc(N(c4ccccc4)c4ccc5c(c4)Sc4ccccc4N5c4ccccc4)cc3)cc21]

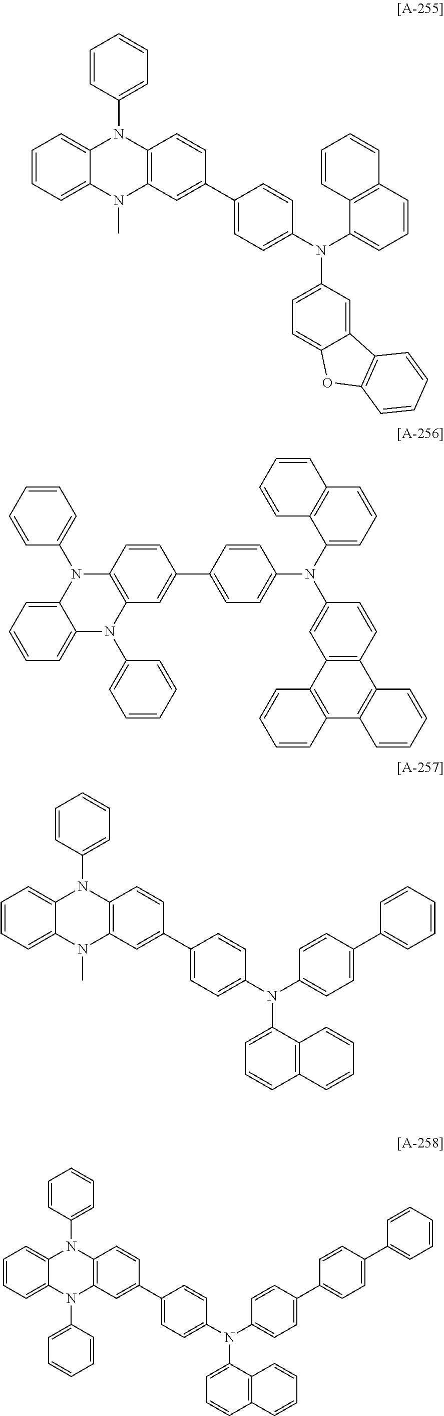 [SMILES: CN1c2ccccc2N(c2ccccc2)c2ccc(-c3ccc(N(c4ccc5oc6ccccc6c5c4)c4cccc5ccccc45)cc3)cc21 ; c1ccc(N2c3ccccc3N(c3ccccc3)c3cc(-c4ccc(N(c5ccc6c7ccccc7c7ccccc7c6c5)c5cccc6ccccc56)cc4)ccc32)cc1 ; CN1c2ccccc2N(c2ccccc2)c2ccc(-c3ccc(N(c4ccc(-c5ccccc5)cc4)c4cccc5ccccc45)cc3)cc21 ; c1ccc(-c2ccc(-c3ccc(N(c4ccc(-c5ccc6c(c5)N(c5ccccc5)c5ccccc5N6c5ccccc5)cc4)c4cccc5ccccc45)cc3)cc2)cc1]

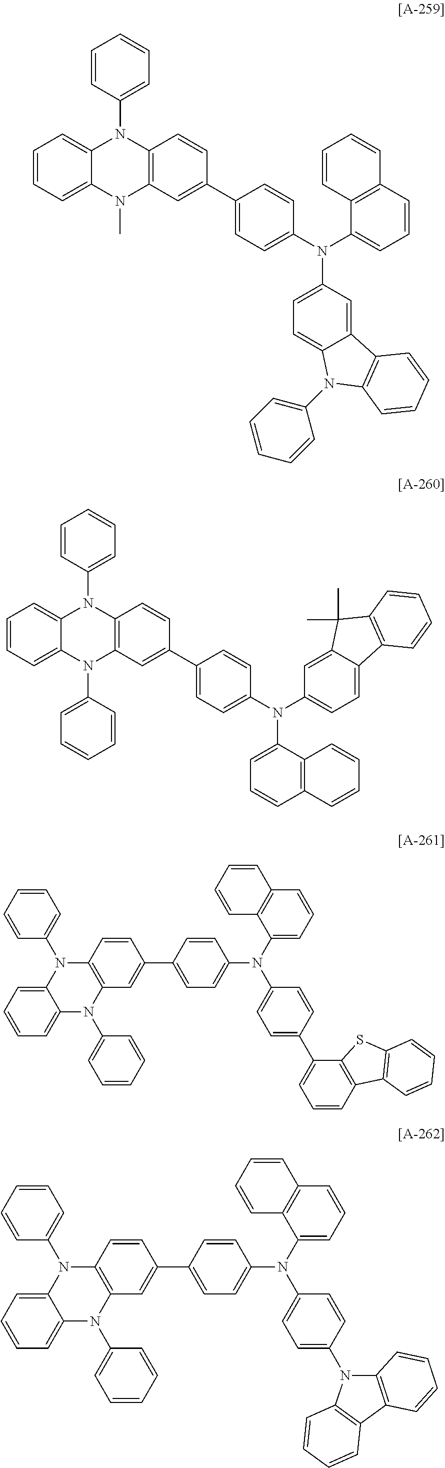 [SMILES: CN1c2ccccc2N(c2ccccc2)c2ccc(-c3ccc(N(c4ccc5c(c4)c4ccccc4n5-c4ccccc4)c4cccc5ccccc45)cc3)cc21 ; CC1(C)c2ccccc2-c2ccc(N(c3ccc(-c4ccc5c(c4)N(c4ccccc4)c4ccccc4N5c4ccccc4)cc3)c3cccc4ccccc34)cc21 ; c1ccc(N2c3ccccc3N(c3ccccc3)c3cc(-c4ccc(N(c5ccc(-c6cccc7c6sc6ccccc67)cc5)c5cccc6ccccc56)cc4)ccc32)cc1 ; c1ccc(N2c3ccccc3N(c3ccccc3)c3cc(-c4ccc(N(c5ccc(-n6c7ccccc7c7ccccc76)cc5)c5cccc6ccccc56)cc4)ccc32)cc1]

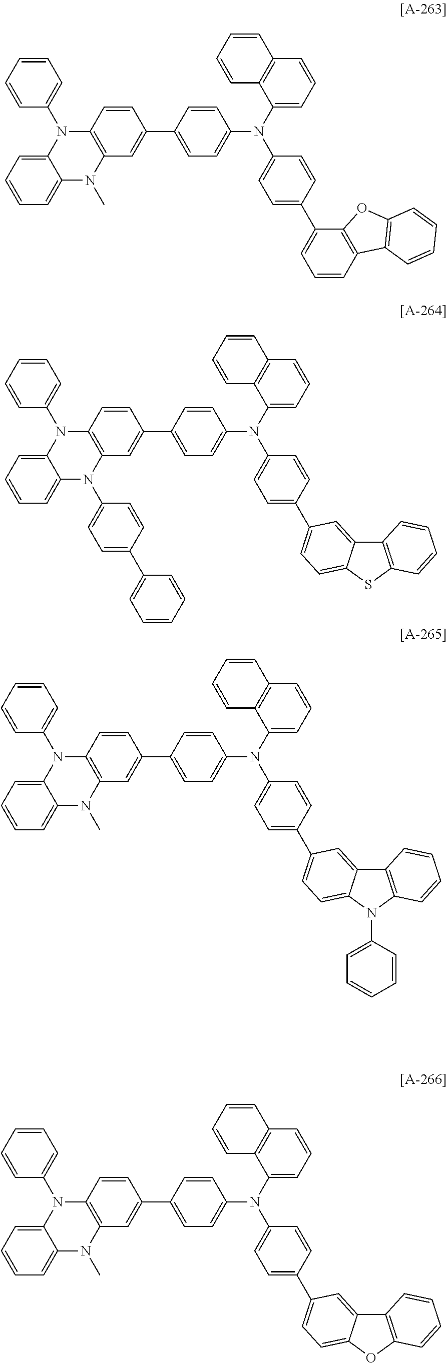 [SMILES: CN1c2ccccc2N(c2ccccc2)c2ccc(-c3ccc(N(c4ccc(-c5cccc6c5oc5ccccc56)cc4)c4cccc5ccccc45)cc3)cc21 ; c1ccc(-c2ccc(N3c4ccccc4N(c4ccccc4)c4ccc(-c5ccc(N(c6ccc(-c7ccc8sc9ccccc9c8c7)cc6)c6cccc7ccccc67)cc5)cc43)cc2)cc1 ; CN1c2ccccc2N(c2ccccc2)c2ccc(-c3ccc(N(c4ccc(-c5ccc6c(c5)c5ccccc5n6-c5ccccc5)cc4)c4cccc5ccccc45)cc3)cc21 ; CN1c2ccccc2N(c2ccccc2)c2ccc(-c3ccc(N(c4ccc(-c5ccc6oc7ccccc7c6c5)cc4)c4cccc5ccccc45)cc3)cc21]

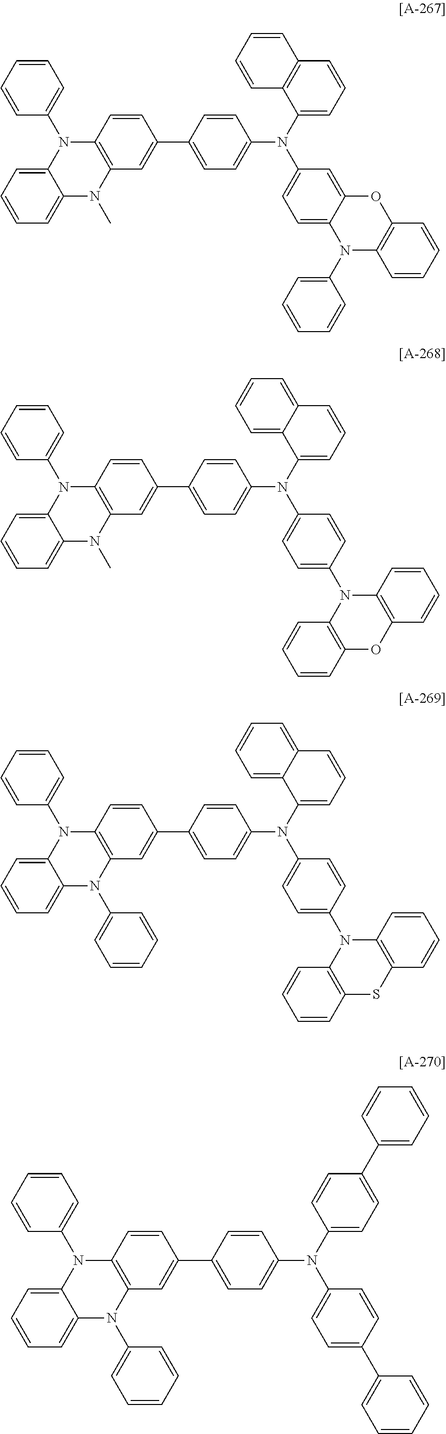 [SMILES: CN1c2ccccc2N(c2ccccc2)c2ccc(-c3ccc(N(c4ccc5c(c4)Oc4ccccc4N5c4ccccc4)c4cccc5ccccc45)cc3)cc21 ; CN1c2ccccc2N(c2ccccc2)c2ccc(-c3ccc(N(c4ccc(N5c6ccccc6Oc6ccccc65)cc4)c4cccc5ccccc45)cc3)cc21 ; c1ccc(N2c3ccccc3N(c3ccccc3)c3cc(-c4ccc(N(c5ccc(N6c7ccccc7Sc7ccccc76)cc5)c5cccc6ccccc56)cc4)ccc32)cc1 ; c1ccc(-c2ccc(N(c3ccc(-c4ccccc4)cc3)c3ccc(-c4ccc5c(c4)N(c4ccccc4)c4ccccc4N5c4ccccc4)cc3)cc2)cc1]

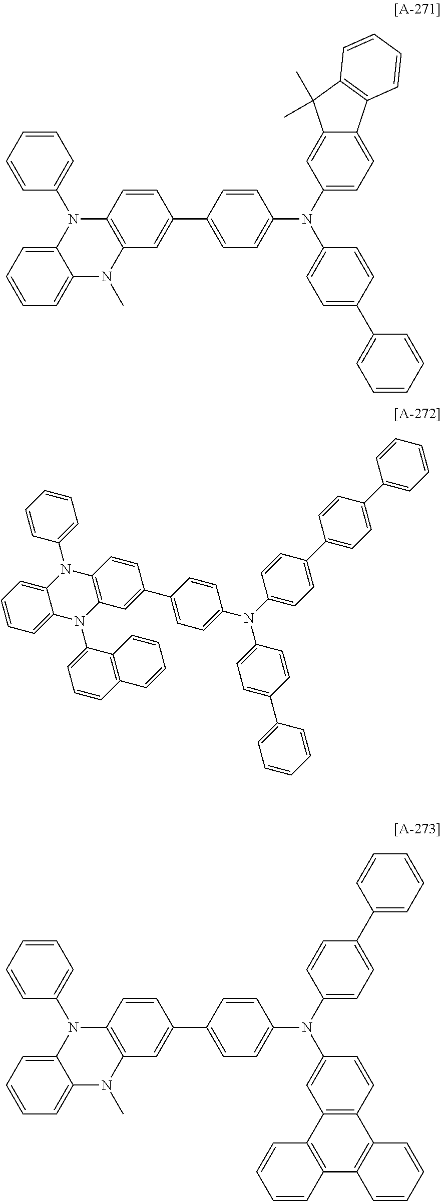 [SMILES: CN1c2ccccc2N(c2ccccc2)c2ccc(-c3ccc(N(c4ccc(-c5ccccc5)cc4)c4ccc5c(c4)C(C)(C)c4ccccc4-5)cc3)cc21 ; c1ccc(-c2ccc(-c3ccc(N(c4ccc(-c5ccccc5)cc4)c4ccc(-c5ccc6c(c5)N(c5cccc7ccccc57)c5ccccc5N6c5ccccc5)cc4)cc3)cc2)cc1 ; CN1c2ccccc2N(c2ccccc2)c2ccc(-c3ccc(N(c4ccc(-c5ccccc5)cc4)c4ccc5c6ccccc6c6ccccc6c5c4)cc3)cc21]

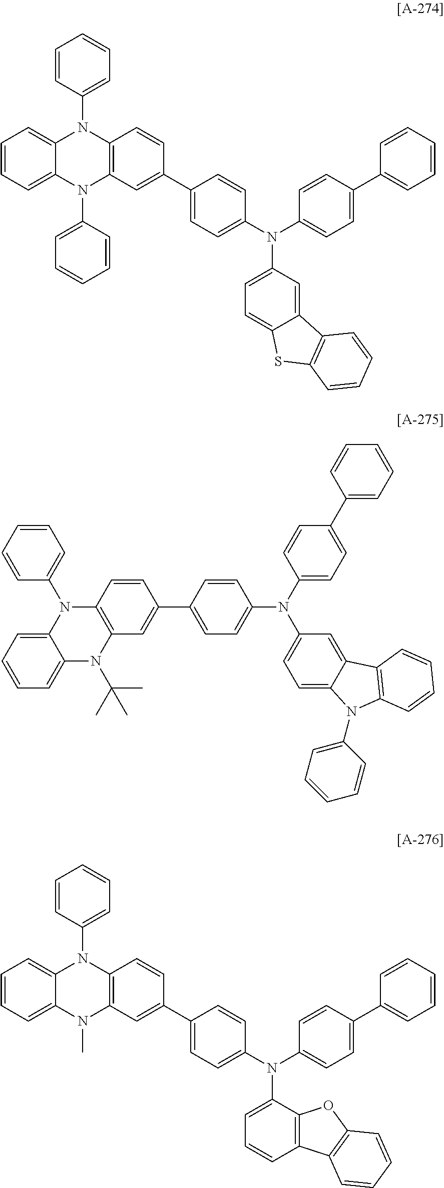 [SMILES: c1ccc(-c2ccc(N(c3ccc(-c4ccc5c(c4)N(c4ccccc4)c4ccccc4N5c4ccccc4)cc3)c3ccc4sc5ccccc5c4c3)cc2)cc1 ; CC(C)(C)N1c2ccccc2N(c2ccccc2)c2ccc(-c3ccc(N(c4ccc(-c5ccccc5)cc4)c4ccc5c(c4)c4ccccc4n5-c4ccccc4)cc3)cc21 ; CN1c2ccccc2N(c2ccccc2)c2ccc(-c3ccc(N(c4ccc(-c5ccccc5)cc4)c4cccc5c4oc4ccccc45)cc3)cc21]

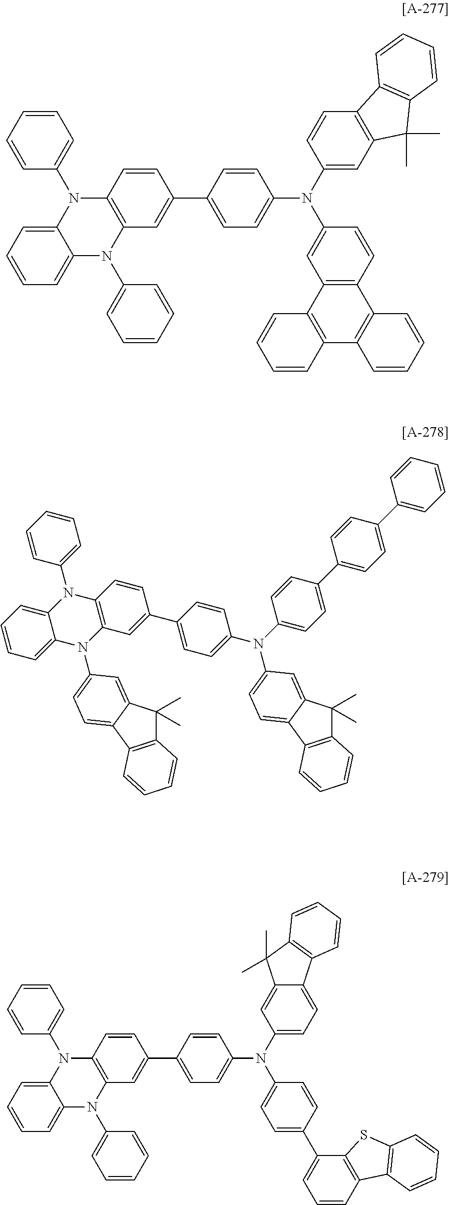 [SMILES: CC1(C)c2ccccc2-c2ccc(N(c3ccc(-c4ccc5c(c4)N(c4ccccc4)c4ccccc4N5c4ccccc4)cc3)c3ccc4c5ccccc5c5ccccc5c4c3)cc21 ; CC1(C)c2ccccc2-c2ccc(N(c3ccc(-c4ccc(-c5ccccc5)cc4)cc3)c3ccc(-c4ccc5c(c4)N(c4ccc6c(c4)C(C)(C)c4ccccc4-6)c4ccccc4N5c4ccccc4)cc3)cc21 ; CC1(C)c2ccccc2-c2ccc(N(c3ccc(-c4ccc5c(c4)N(c4ccccc4)c4ccccc4N5c4ccccc4)cc3)c3ccc(-c4cccc5c4sc4ccccc45)cc3)cc21]

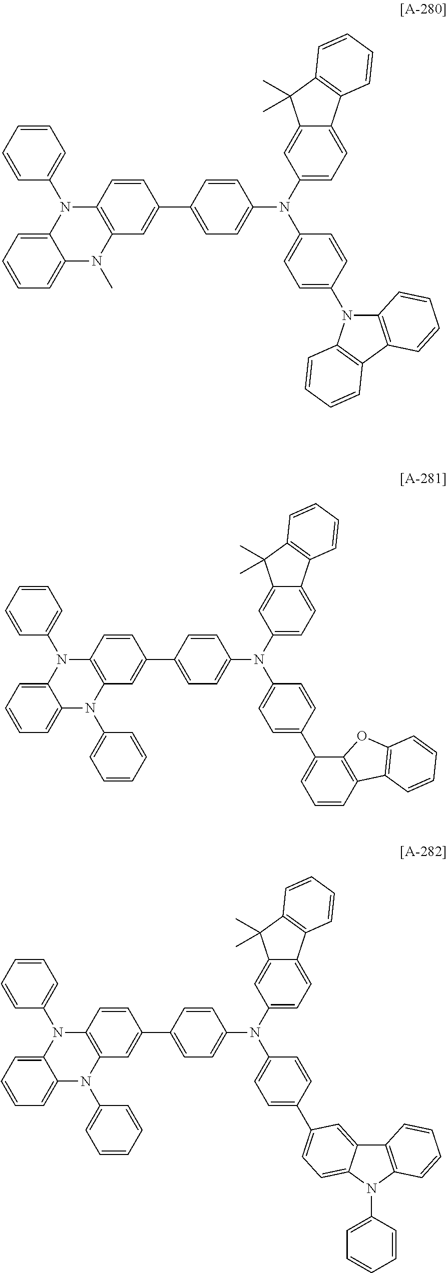 [SMILES: CN1c2ccccc2N(c2ccccc2)c2ccc(-c3ccc(N(c4ccc(-n5c6ccccc6c6ccccc65)cc4)c4ccc5c(c4)C(C)(C)c4ccccc4-5)cc3)cc21 ; CC1(C)c2ccccc2-c2ccc(N(c3ccc(-c4ccc5c(c4)N(c4ccccc4)c4ccccc4N5c4ccccc4)cc3)c3ccc(-c4cccc5c4oc4ccccc45)cc3)cc21 ; CC1(C)c2ccccc2-c2ccc(N(c3ccc(-c4ccc5c(c4)N(c4ccccc4)c4ccccc4N5c4ccccc4)cc3)c3ccc(-c4ccc5c(c4)c4ccccc4n5-c4ccccc4)cc3)cc21]

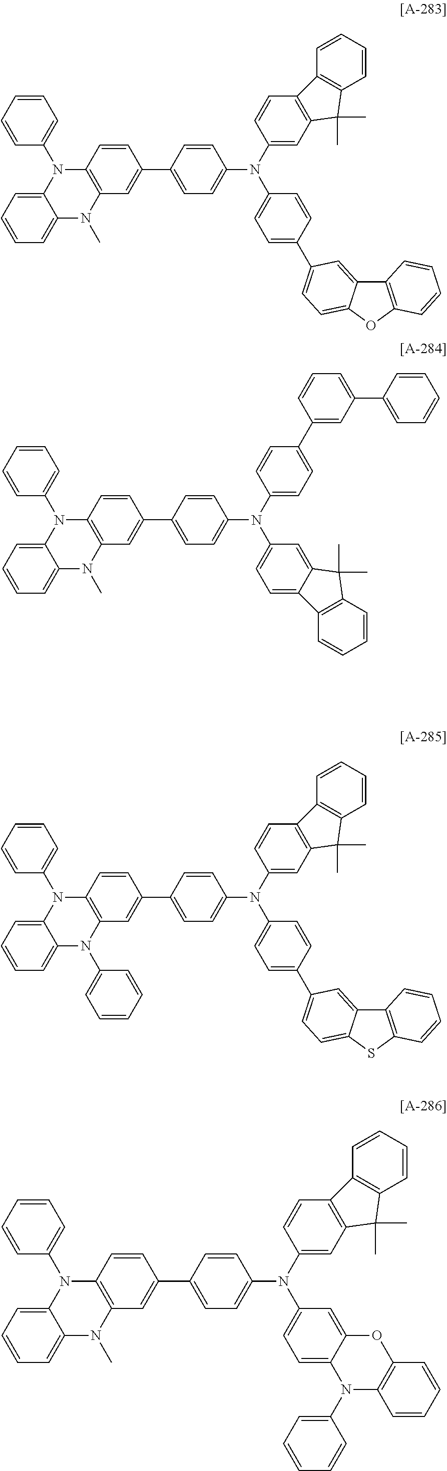 [SMILES: CN1c2ccccc2N(c2ccccc2)c2ccc(-c3ccc(N(c4ccc(-c5ccc6oc7ccccc7c6c5)cc4)c4ccc5c(c4)C(C)(C)c4ccccc4-5)cc3)cc21 ; CN1c2ccccc2N(c2ccccc2)c2ccc(-c3ccc(N(c4ccc(-c5cccc(-c6ccccc6)c5)cc4)c4ccc5c(c4)C(C)(C)c4ccccc4-5)cc3)cc21 ; CC1(C)c2ccccc2-c2ccc(N(c3ccc(-c4ccc5c(c4)N(c4ccccc4)c4ccccc4N5c4ccccc4)cc3)c3ccc(-c4ccc5sc6ccccc6c5c4)cc3)cc21 ; CN1c2ccccc2N(c2ccccc2)c2ccc(-c3ccc(N(c4ccc5c(c4)Oc4ccccc4N5c4ccccc4)c4ccc5c(c4)C(C)(C)c4ccccc4-5)cc3)cc21]

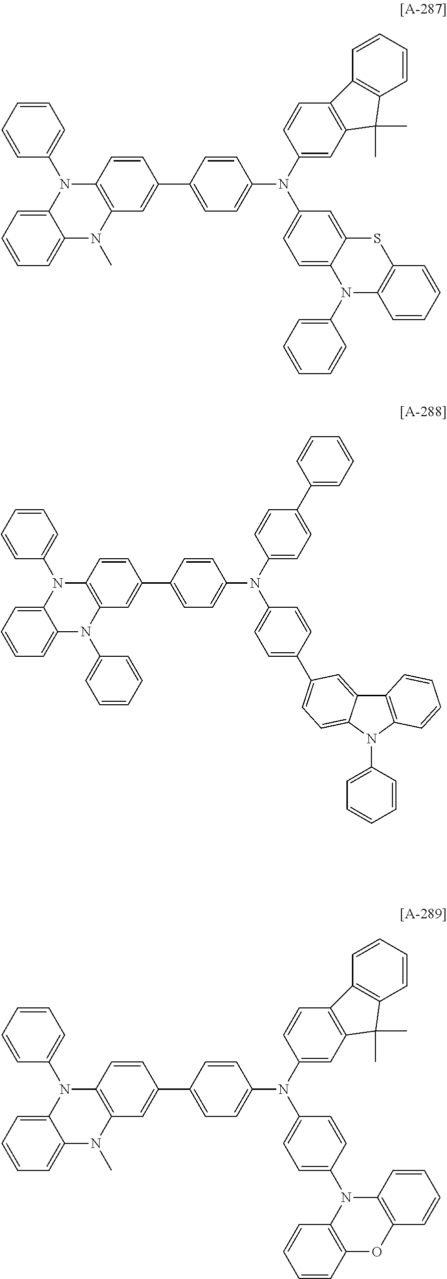 [SMILES: CN1c2ccccc2N(c2ccccc2)c2ccc(-c3ccc(N(c4ccc5c(c4)Sc4ccccc4N5c4ccccc4)c4ccc5c(c4)C(C)(C)c4ccccc4-5)cc3)cc21 ; c1ccc(-c2ccc(N(c3ccc(-c4ccc5c(c4)N(c4ccccc4)c4ccccc4N5c4ccccc4)cc3)c3ccc(-c4ccc5c(c4)c4ccccc4n5-c4ccccc4)cc3)cc2)cc1 ; CN1c2ccccc2N(c2ccccc2)c2ccc(-c3ccc(N(c4ccc(N5c6ccccc6Oc6ccccc65)cc4)c4ccc5c(c4)C(C)(C)c4ccccc4-5)cc3)cc21]

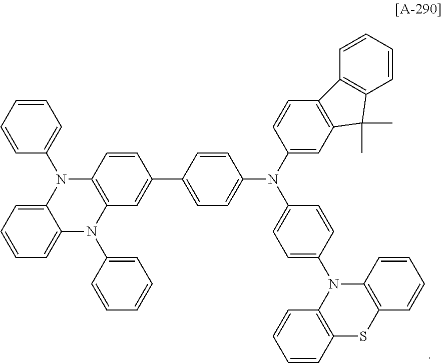 [SMILES: CC1(C)c2ccccc2-c2ccc(N(c3ccc(-c4ccc5c(c4)N(c4ccccc4)c4ccccc4N5c4ccccc4)cc3)c3ccc(N4c5ccccc5Sc5ccccc54)cc3)cc21]

8. The compound for an organic optoelectronic device as claimed in claim 1, wherein the compound is represented by one of the following Chemical Formulae B-1 to B-81:

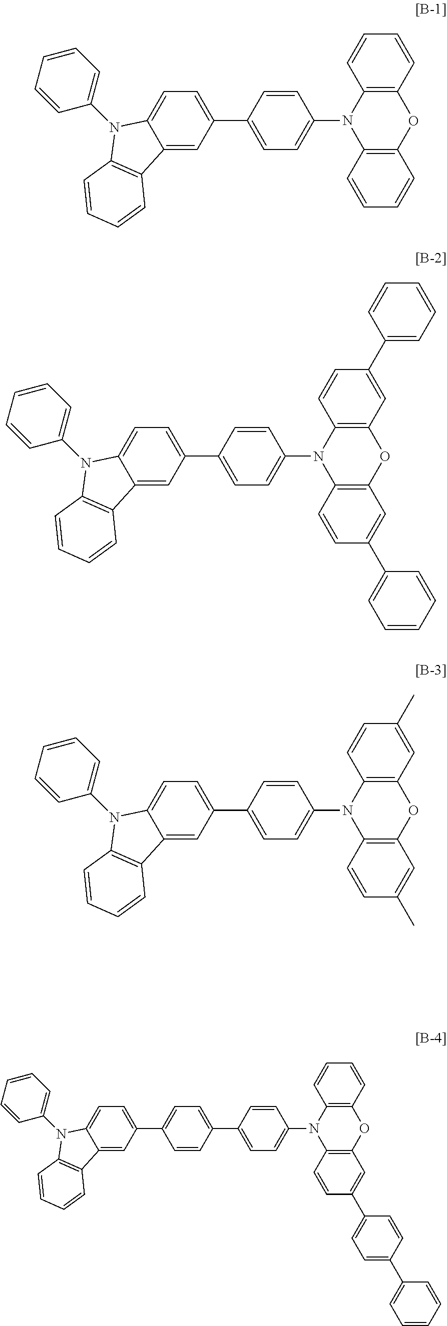 [SMILES: c1ccc(-n2c3ccccc3c3cc(-c4ccc(N5c6ccccc6Oc6ccccc65)cc4)ccc32)cc1 ; c1ccc(-c2ccc3c(c2)Oc2cc(-c4ccccc4)ccc2N3c2ccc(-c3ccc4c(c3)c3ccccc3n4-c3ccccc3)cc2)cc1 ; Cc1ccc2c(c1)Oc1cc(C)ccc1N2c1ccc(-c2ccc3c(c2)c2ccccc2n3-c2ccccc2)cc1 ; c1ccc(-c2ccc(-c3ccc4c(c3)Oc3ccccc3N4c3ccc(-c4ccc(-c5ccc6c(c5)c5ccccc5n6-c5ccccc5)cc4)cc3)cc2)cc1]

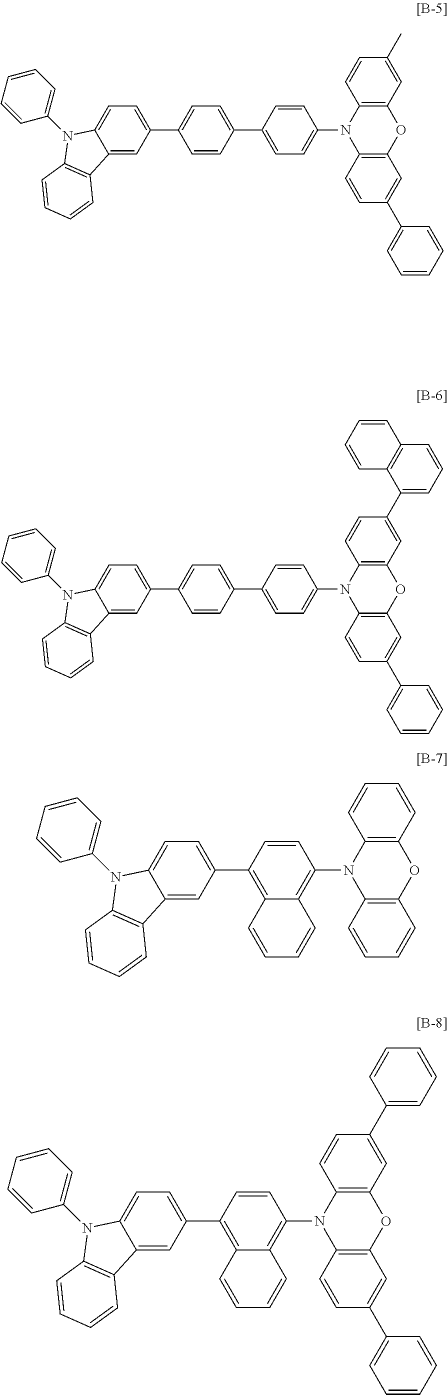 [SMILES: Cc1ccc2c(c1)Oc1cc(-c3ccccc3)ccc1N2c1ccc(-c2ccc(-c3ccc4c(c3)c3ccccc3n4-c3ccccc3)cc2)cc1 ; c1ccc(-c2ccc3c(c2)Oc2cc(-c4cccc5ccccc45)ccc2N3c2ccc(-c3ccc(-c4ccc5c(c4)c4ccccc4n5-c4ccccc4)cc3)cc2)cc1 ; c1ccc(-n2c3ccccc3c3cc(-c4ccc(N5c6ccccc6Oc6ccccc65)c5ccccc45)ccc32)cc1 ; c1ccc(-c2ccc3c(c2)Oc2cc(-c4ccccc4)ccc2N3c2ccc(-c3ccc4c(c3)c3ccccc3n4-c3ccccc3)c3ccccc23)cc1]

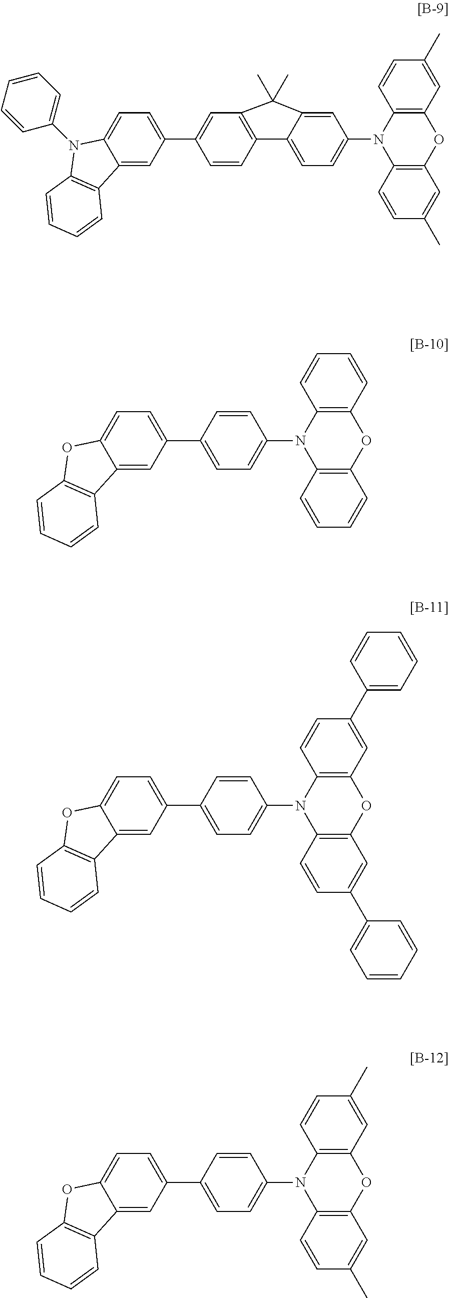 [SMILES: Cc1ccc2c(c1)Oc1cc(C)ccc1N2c1ccc2c(c1)C(C)(C)c1cc(-c3ccc4c(c3)c3ccccc3n4-c3ccccc3)ccc1-2 ; c1ccc2c(c1)Oc1ccccc1N2c1ccc(-c2ccc3oc4ccccc4c3c2)cc1 ; c1ccc(-c2ccc3c(c2)Oc2cc(-c4ccccc4)ccc2N3c2ccc(-c3ccc4oc5ccccc5c4c3)cc2)cc1 ; Cc1ccc2c(c1)Oc1cc(C)ccc1N2c1ccc(-c2ccc3oc4ccccc4c3c2)cc1]

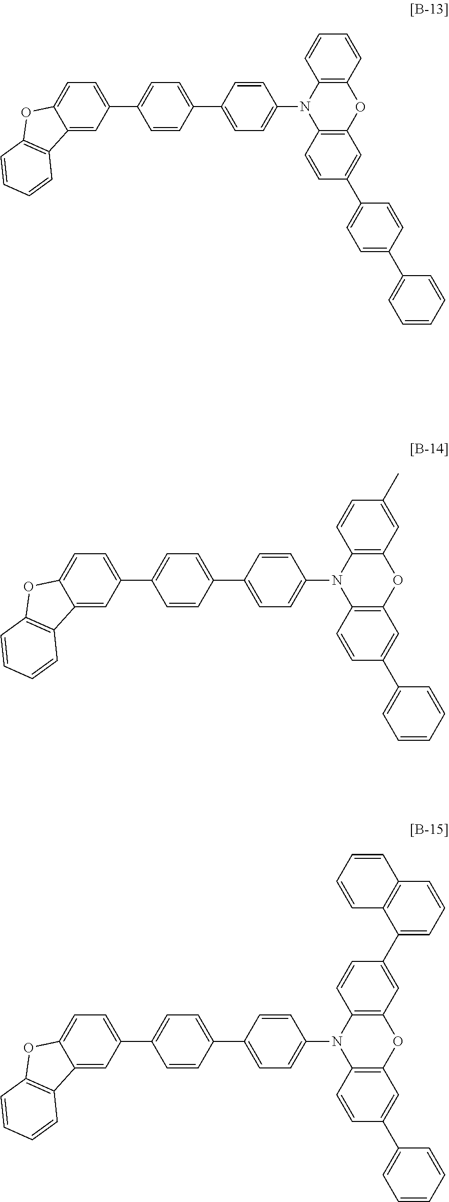 [SMILES: c1ccc(-c2ccc(-c3ccc4c(c3)Oc3ccccc3N4c3ccc(-c4ccc(-c5ccc6oc7ccccc7c6c5)cc4)cc3)cc2)cc1 ; Cc1ccc2c(c1)Oc1cc(-c3ccccc3)ccc1N2c1ccc(-c2ccc(-c3ccc4oc5ccccc5c4c3)cc2)cc1 ; c1ccc(-c2ccc3c(c2)Oc2cc(-c4cccc5ccccc45)ccc2N3c2ccc(-c3ccc(-c4ccc5oc6ccccc6c5c4)cc3)cc2)cc1]

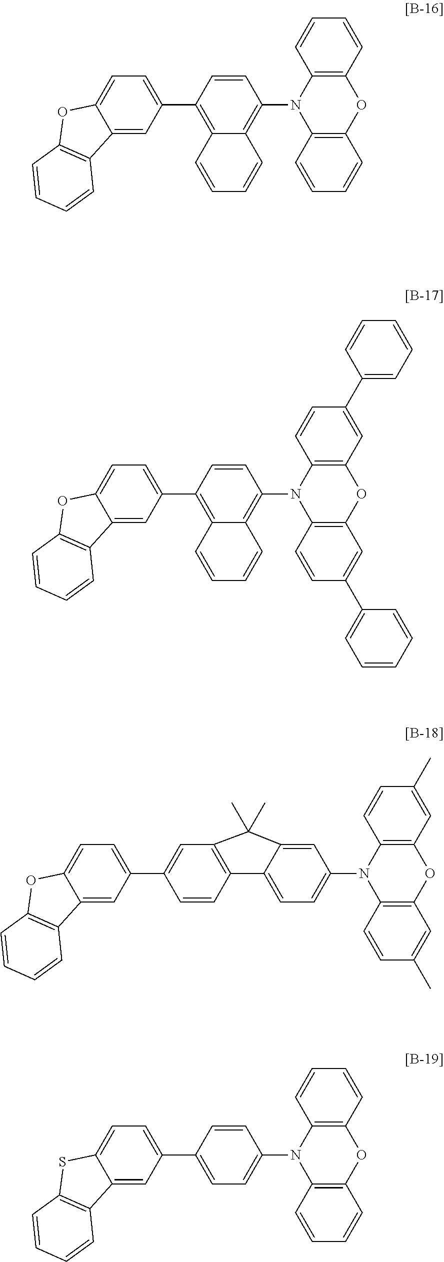 [SMILES: c1ccc2c(c1)Oc1ccccc1N2c1ccc(-c2ccc3oc4ccccc4c3c2)c2ccccc12 ; c1ccc(-c2ccc3c(c2)Oc2cc(-c4ccccc4)ccc2N3c2ccc(-c3ccc4oc5ccccc5c4c3)c3ccccc23)cc1 ; Cc1ccc2c(c1)Oc1cc(C)ccc1N2c1ccc2c(c1)C(C)(C)c1cc(-c3ccc4oc5ccccc5c4c3)ccc1-2 ; c1ccc2c(c1)Oc1ccccc1N2c1ccc(-c2ccc3sc4ccccc4c3c2)cc1]

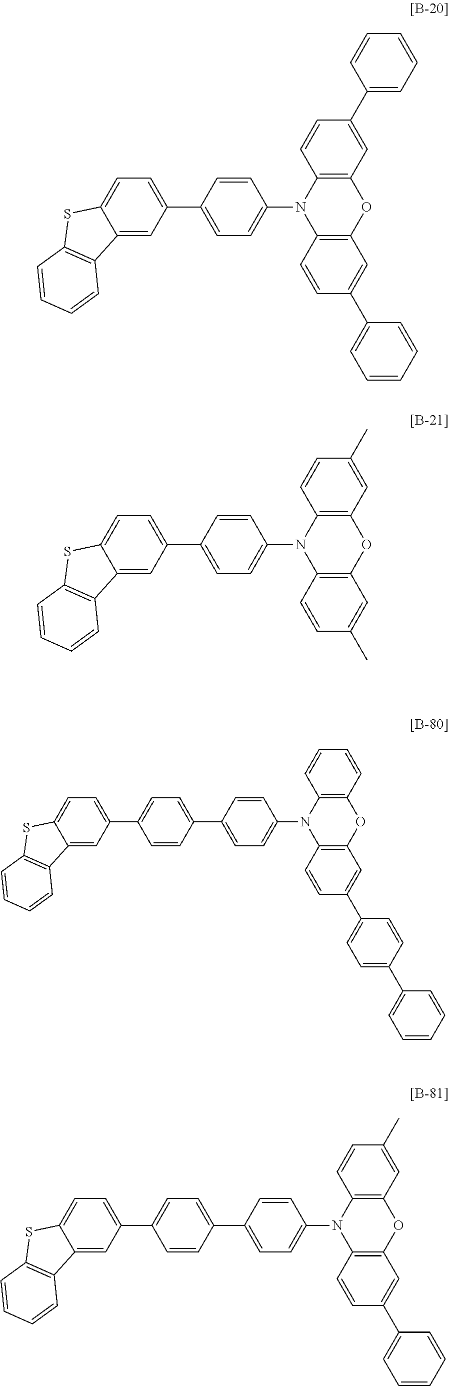 [SMILES: c1ccc(-c2ccc3c(c2)Oc2cc(-c4ccccc4)ccc2N3c2ccc(-c3ccc4sc5ccccc5c4c3)cc2)cc1 ; Cc1ccc2c(c1)Oc1cc(C)ccc1N2c1ccc(-c2ccc3sc4ccccc4c3c2)cc1 ; c1ccc(-c2ccc(-c3ccc4c(c3)Oc3ccccc3N4c3ccc(-c4ccc(-c5ccc6sc7ccccc7c6c5)cc4)cc3)cc2)cc1 ; Cc1ccc2c(c1)Oc1cc(-c3ccccc3)ccc1N2c1ccc(-c2ccc(-c3ccc4sc5ccccc5c4c3)cc2)cc1]

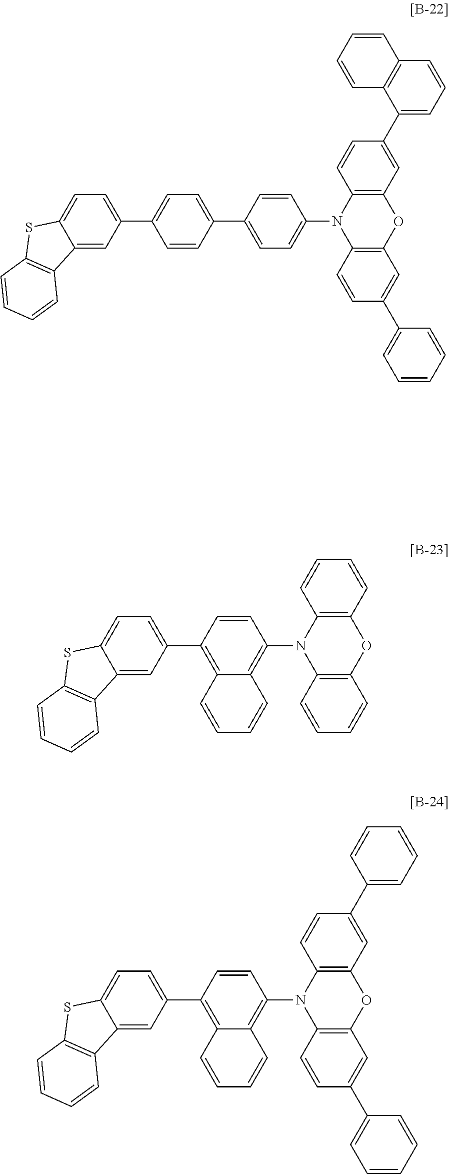 [SMILES: c1ccc(-c2ccc3c(c2)Oc2cc(-c4cccc5ccccc45)ccc2N3c2ccc(-c3ccc(-c4ccc5sc6ccccc6c5c4)cc3)cc2)cc1 ; c1ccc2c(c1)Oc1ccccc1N2c1ccc(-c2ccc3sc4ccccc4c3c2)c2ccccc12 ; c1ccc(-c2ccc3c(c2)Oc2cc(-c4ccccc4)ccc2N3c2ccc(-c3ccc4sc5ccccc5c4c3)c3ccccc23)cc1]

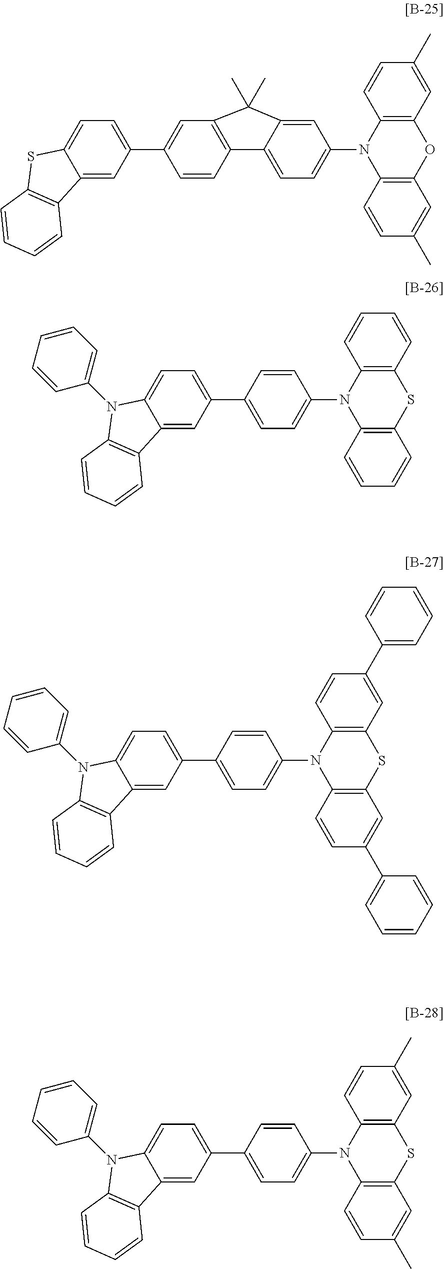 [SMILES: Cc1ccc2c(c1)Oc1cc(C)ccc1N2c1ccc2c(c1)C(C)(C)c1cc(-c3ccc4sc5ccccc5c4c3)ccc1-2 ; c1ccc(-n2c3ccccc3c3cc(-c4ccc(N5c6ccccc6Sc6ccccc65)cc4)ccc32)cc1 ; c1ccc(-c2ccc3c(c2)Sc2cc(-c4ccccc4)ccc2N3c2ccc(-c3ccc4c(c3)c3ccccc3n4-c3ccccc3)cc2)cc1 ; Cc1ccc2c(c1)Sc1cc(C)ccc1N2c1ccc(-c2ccc3c(c2)c2ccccc2n3-c2ccccc2)cc1]

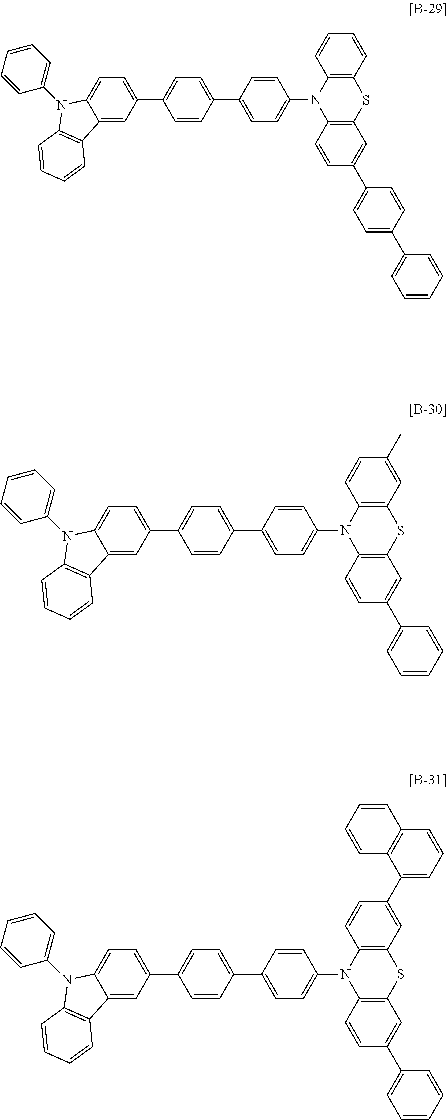 [SMILES: c1ccc(-c2ccc(-c3ccc4c(c3)Sc3ccccc3N4c3ccc(-c4ccc(-c5ccc6c(c5)c5ccccc5n6-c5ccccc5)cc4)cc3)cc2)cc1 ; Cc1ccc2c(c1)Sc1cc(-c3ccccc3)ccc1N2c1ccc(-c2ccc(-c3ccc4c(c3)c3ccccc3n4-c3ccccc3)cc2)cc1 ; c1ccc(-c2ccc3c(c2)Sc2cc(-c4cccc5ccccc45)ccc2N3c2ccc(-c3ccc(-c4ccc5c(c4)c4ccccc4n5-c4ccccc4)cc3)cc2)cc1]

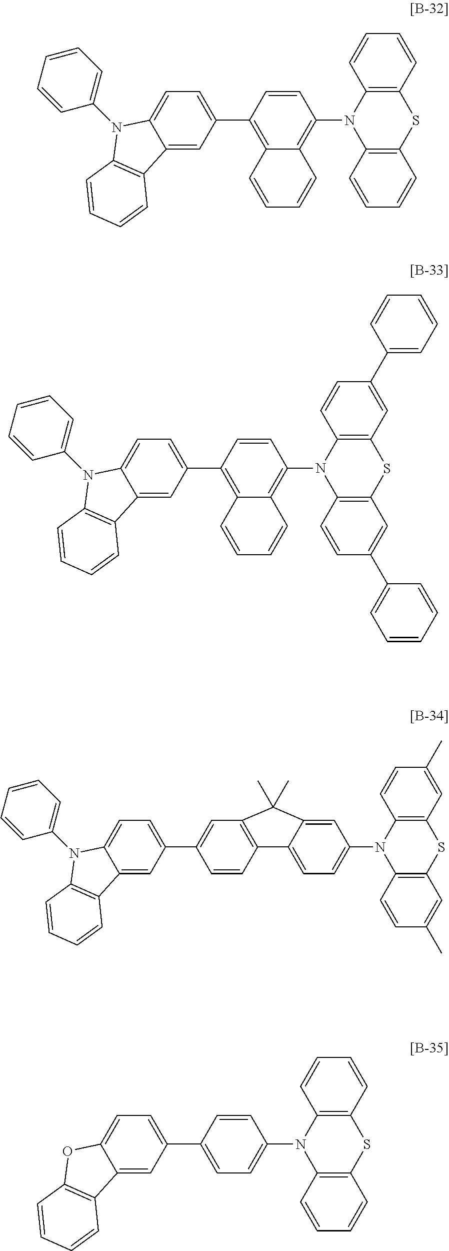 [SMILES: c1ccc(-n2c3ccccc3c3cc(-c4ccc(N5c6ccccc6Sc6ccccc65)c5ccccc45)ccc32)cc1 ; c1ccc(-c2ccc3c(c2)Sc2cc(-c4ccccc4)ccc2N3c2ccc(-c3ccc4c(c3)c3ccccc3n4-c3ccccc3)c3ccccc23)cc1 ; Cc1ccc2c(c1)Sc1cc(C)ccc1N2c1ccc2c(c1)C(C)(C)c1cc(-c3ccc4c(c3)c3ccccc3n4-c3ccccc3)ccc1-2 ; c1ccc2c(c1)Sc1ccccc1N2c1ccc(-c2ccc3oc4ccccc4c3c2)cc1]

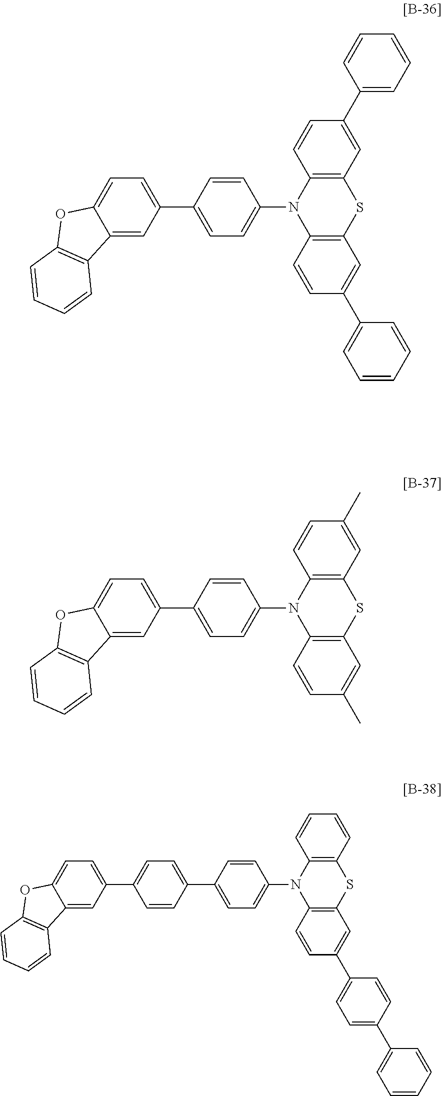 [SMILES: c1ccc(-c2ccc3c(c2)Sc2cc(-c4ccccc4)ccc2N3c2ccc(-c3ccc4oc5ccccc5c4c3)cc2)cc1 ; Cc1ccc2c(c1)Sc1cc(C)ccc1N2c1ccc(-c2ccc3oc4ccccc4c3c2)cc1 ; c1ccc(-c2ccc(-c3ccc4c(c3)Sc3ccccc3N4c3ccc(-c4ccc(-c5ccc6oc7ccccc7c6c5)cc4)cc3)cc2)cc1]

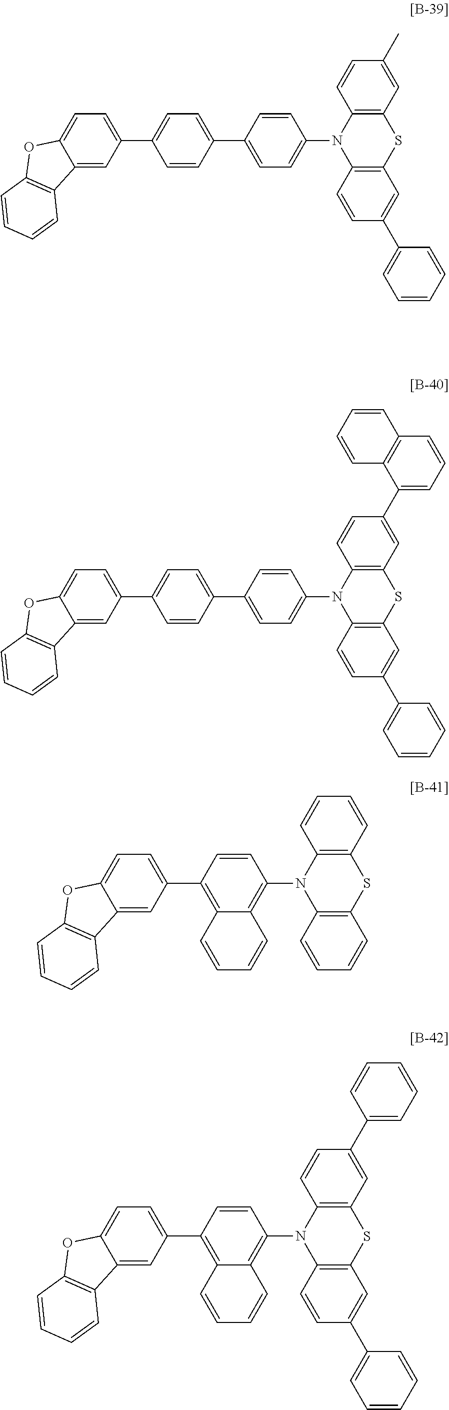 [SMILES: Cc1ccc2c(c1)Sc1cc(-c3ccccc3)ccc1N2c1ccc(-c2ccc(-c3ccc4oc5ccccc5c4c3)cc2)cc1 ; c1ccc(-c2ccc3c(c2)Sc2cc(-c4cccc5ccccc45)ccc2N3c2ccc(-c3ccc(-c4ccc5oc6ccccc6c5c4)cc3)cc2)cc1 ; c1ccc2c(c1)Sc1ccccc1N2c1ccc(-c2ccc3oc4ccccc4c3c2)c2ccccc12 ; c1ccc(-c2ccc3c(c2)Sc2cc(-c4ccccc4)ccc2N3c2ccc(-c3ccc4oc5ccccc5c4c3)c3ccccc23)cc1]

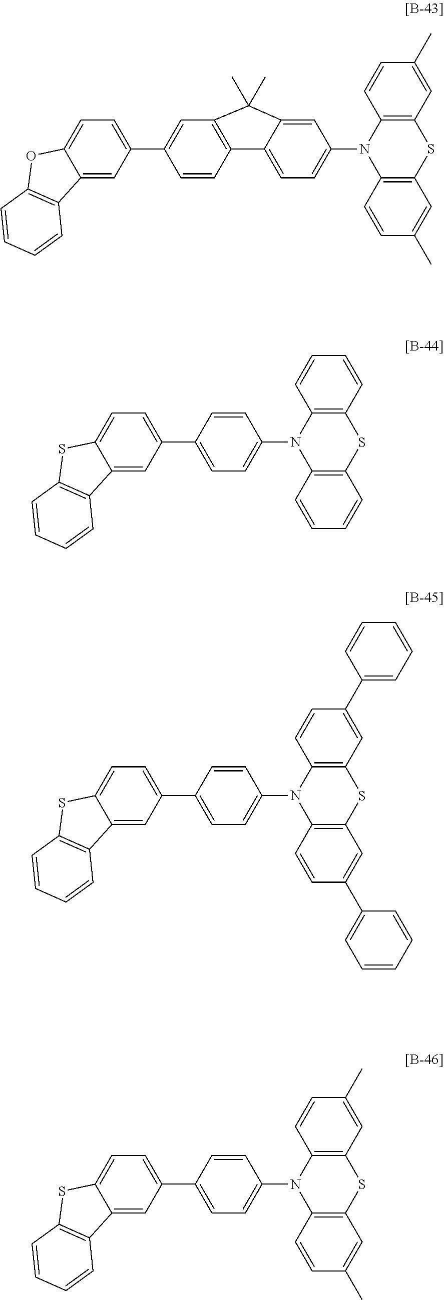 [SMILES: Cc1ccc2c(c1)Sc1cc(C)ccc1N2c1ccc2c(c1)C(C)(C)c1cc(-c3ccc4oc5ccccc5c4c3)ccc1-2 ; c1ccc2c(c1)Sc1ccccc1N2c1ccc(-c2ccc3sc4ccccc4c3c2)cc1 ; c1ccc(-c2ccc3c(c2)Sc2cc(-c4ccccc4)ccc2N3c2ccc(-c3ccc4sc5ccccc5c4c3)cc2)cc1 ; Cc1ccc2c(c1)Sc1cc(C)ccc1N2c1ccc(-c2ccc3sc4ccccc4c3c2)cc1]

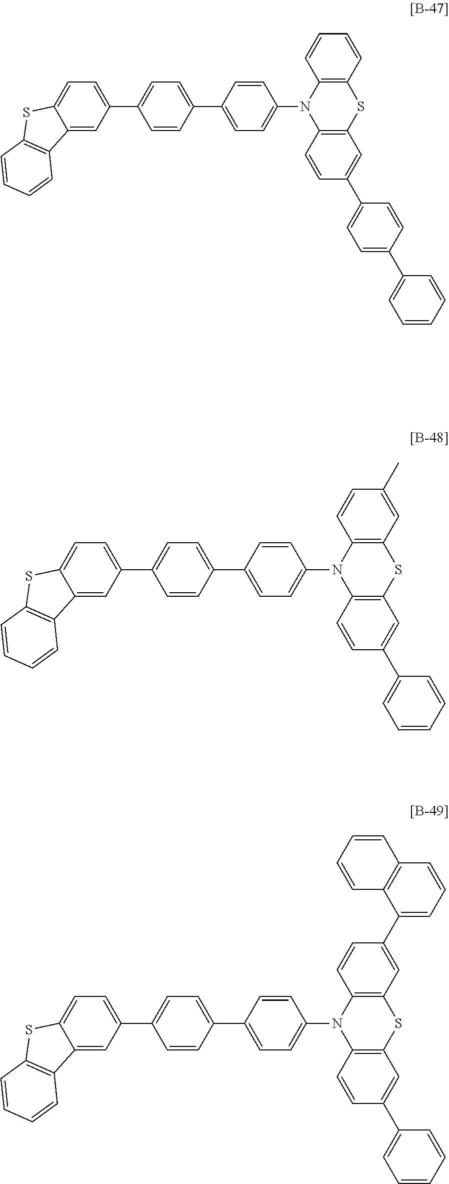 [SMILES: c1ccc(-c2ccc(-c3ccc4c(c3)Sc3ccccc3N4c3ccc(-c4ccc(-c5ccc6sc7ccccc7c6c5)cc4)cc3)cc2)cc1 ; Cc1ccc2c(c1)Sc1cc(-c3ccccc3)ccc1N2c1ccc(-c2ccc(-c3ccc4sc5ccccc5c4c3)cc2)cc1 ; c1ccc(-c2ccc3c(c2)Sc2cc(-c4cccc5ccccc45)ccc2N3c2ccc(-c3ccc(-c4ccc5sc6ccccc6c5c4)cc3)cc2)cc1]

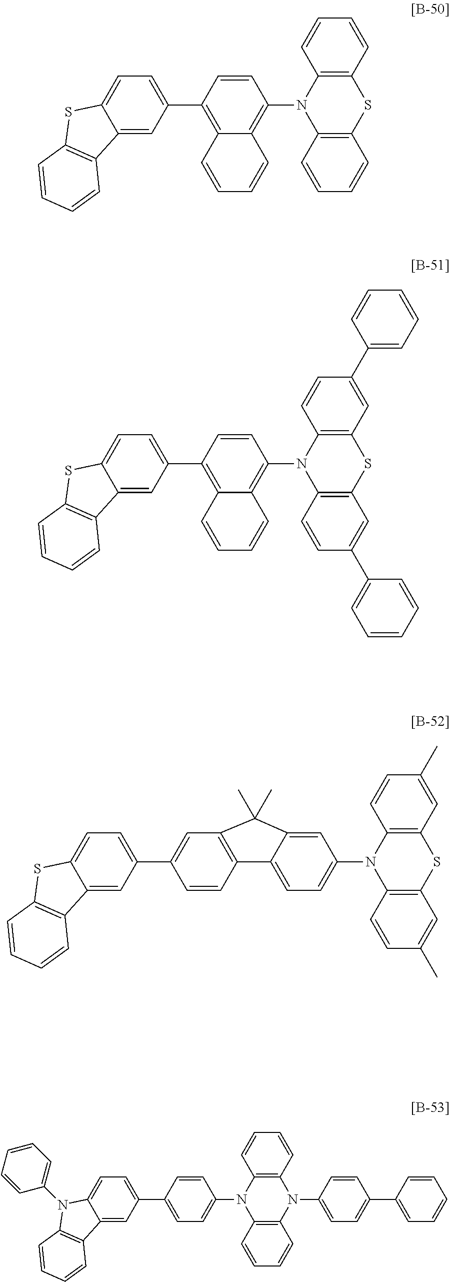 [SMILES: c1ccc2c(c1)Sc1ccccc1N2c1ccc(-c2ccc3sc4ccccc4c3c2)c2ccccc12 ; c1ccc(-c2ccc3c(c2)Sc2cc(-c4ccccc4)ccc2N3c2ccc(-c3ccc4sc5ccccc5c4c3)c3ccccc23)cc1 ; Cc1ccc2c(c1)Sc1cc(C)ccc1N2c1ccc2c(c1)C(C)(C)c1cc(-c3ccc4sc5ccccc5c4c3)ccc1-2 ; c1ccc(-c2ccc(N3c4ccccc4N(c4ccc(-c5ccc6c(c5)c5ccccc5n6-c5ccccc5)cc4)c4ccccc43)cc2)cc1]

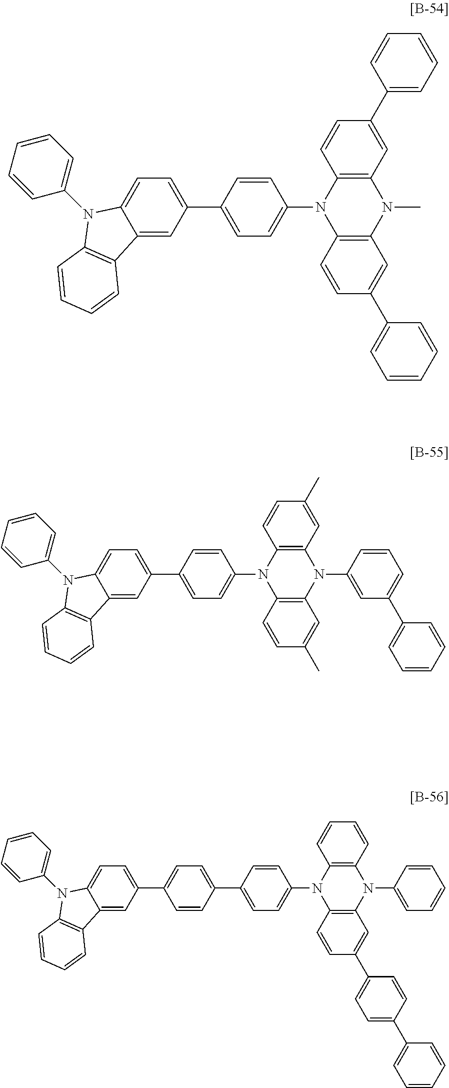 [SMILES: CN1c2cc(-c3ccccc3)ccc2N(c2ccc(-c3ccc4c(c3)c3ccccc3n4-c3ccccc3)cc2)c2ccc(-c3ccccc3)cc21 ; Cc1ccc2c(c1)N(c1cccc(-c3ccccc3)c1)c1cc(C)ccc1N2c1ccc(-c2ccc3c(c2)c2ccccc2n3-c2ccccc2)cc1 ; c1ccc(-c2ccc(-c3ccc4c(c3)N(c3ccccc3)c3ccccc3N4c3ccc(-c4ccc(-c5ccc6c(c5)c5ccccc5n6-c5ccccc5)cc4)cc3)cc2)cc1]

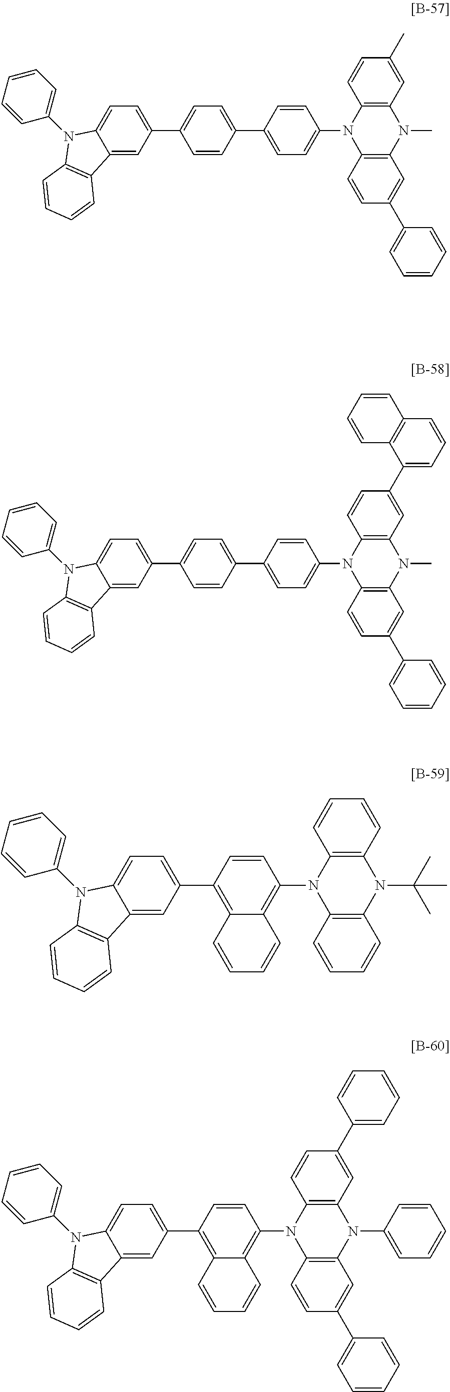 [SMILES: Cc1ccc2c(c1)N(C)c1cc(-c3ccccc3)ccc1N2c1ccc(-c2ccc(-c3ccc4c(c3)c3ccccc3n4-c3ccccc3)cc2)cc1 ; CN1c2cc(-c3ccccc3)ccc2N(c2ccc(-c3ccc(-c4ccc5c(c4)c4ccccc4n5-c4ccccc4)cc3)cc2)c2ccc(-c3cccc4ccccc34)cc21 ; CC(C)(C)N1c2ccccc2N(c2ccc(-c3ccc4c(c3)c3ccccc3n4-c3ccccc3)c3ccccc23)c2ccccc21 ; c1ccc(-c2ccc3c(c2)N(c2ccccc2)c2cc(-c4ccccc4)ccc2N3c2ccc(-c3ccc4c(c3)c3ccccc3n4-c3ccccc3)c3ccccc23)cc1]

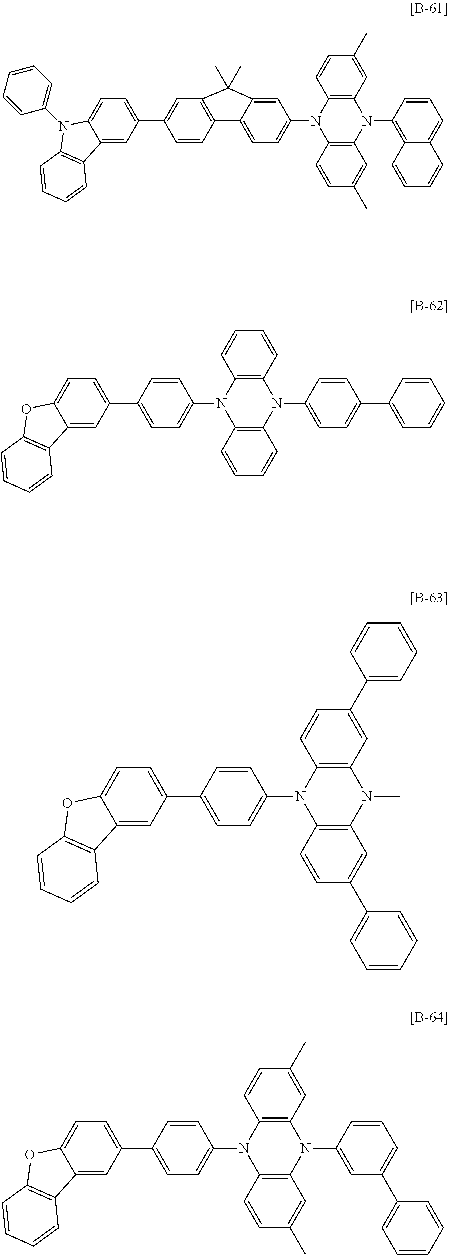 [SMILES: Cc1ccc2c(c1)N(c1cccc3ccccc13)c1cc(C)ccc1N2c1ccc2c(c1)C(C)(C)c1cc(-c3ccc4c(c3)c3ccccc3n4-c3ccccc3)ccc1-2 ; c1ccc(-c2ccc(N3c4ccccc4N(c4ccc(-c5ccc6oc7ccccc7c6c5)cc4)c4ccccc43)cc2)cc1 ; CN1c2cc(-c3ccccc3)ccc2N(c2ccc(-c3ccc4oc5ccccc5c4c3)cc2)c2ccc(-c3ccccc3)cc21 ; Cc1ccc2c(c1)N(c1cccc(-c3ccccc3)c1)c1cc(C)ccc1N2c1ccc(-c2ccc3oc4ccccc4c3c2)cc1]

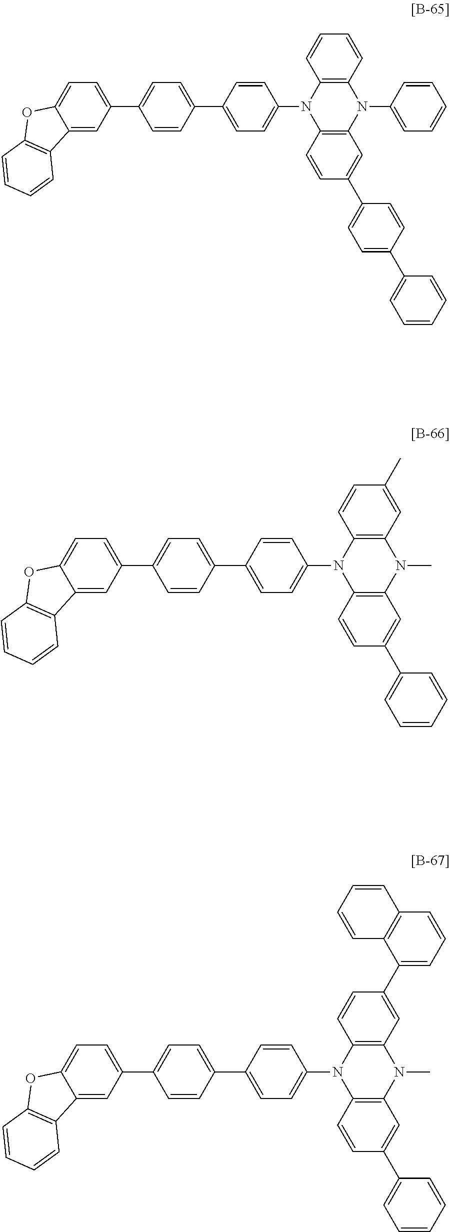 [SMILES: c1ccc(-c2ccc(-c3ccc4c(c3)N(c3ccccc3)c3ccccc3N4c3ccc(-c4ccc(-c5ccc6oc7ccccc7c6c5)cc4)cc3)cc2)cc1 ; Cc1ccc2c(c1)N(C)c1cc(-c3ccccc3)ccc1N2c1ccc(-c2ccc(-c3ccc4oc5ccccc5c4c3)cc2)cc1 ; CN1c2cc(-c3ccccc3)ccc2N(c2ccc(-c3ccc(-c4ccc5oc6ccccc6c5c4)cc3)cc2)c2ccc(-c3cccc4ccccc34)cc21]

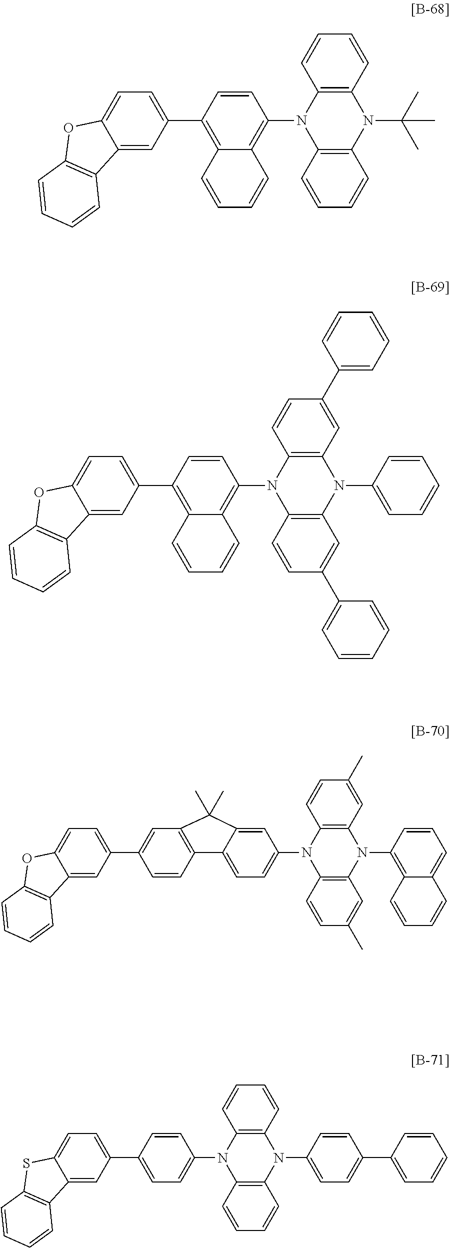 [SMILES: CC(C)(C)N1c2ccccc2N(c2ccc(-c3ccc4oc5ccccc5c4c3)c3ccccc23)c2ccccc21 ; c1ccc(-c2ccc3c(c2)N(c2ccccc2)c2cc(-c4ccccc4)ccc2N3c2ccc(-c3ccc4oc5ccccc5c4c3)c3ccccc23)cc1 ; Cc1ccc2c(c1)N(c1cccc3ccccc13)c1cc(C)ccc1N2c1ccc2c(c1)C(C)(C)c1cc(-c3ccc4oc5ccccc5c4c3)ccc1-2 ; c1ccc(-c2ccc(N3c4ccccc4N(c4ccc(-c5ccc6sc7ccccc7c6c5)cc4)c4ccccc43)cc2)cc1]

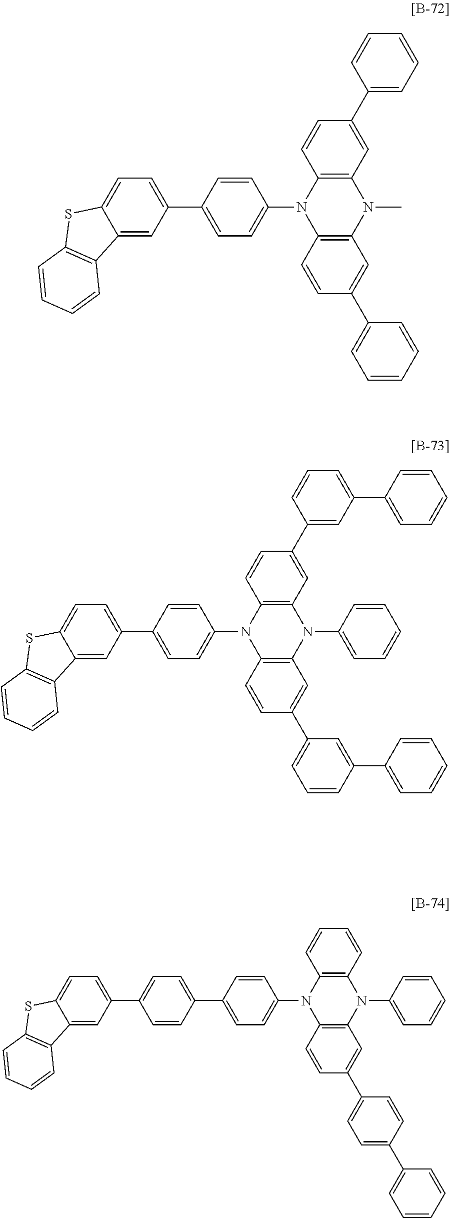 [SMILES: CN1c2cc(-c3ccccc3)ccc2N(c2ccc(-c3ccc4sc5ccccc5c4c3)cc2)c2ccc(-c3ccccc3)cc21 ; c1ccc(-c2cccc(-c3ccc4c(c3)N(c3ccccc3)c3cc(-c5cccc(-c6ccccc6)c5)ccc3N4c3ccc(-c4ccc5sc6ccccc6c5c4)cc3)c2)cc1 ; c1ccc(-c2ccc(-c3ccc4c(c3)N(c3ccccc3)c3ccccc3N4c3ccc(-c4ccc(-c5ccc6sc7ccccc7c6c5)cc4)cc3)cc2)cc1]

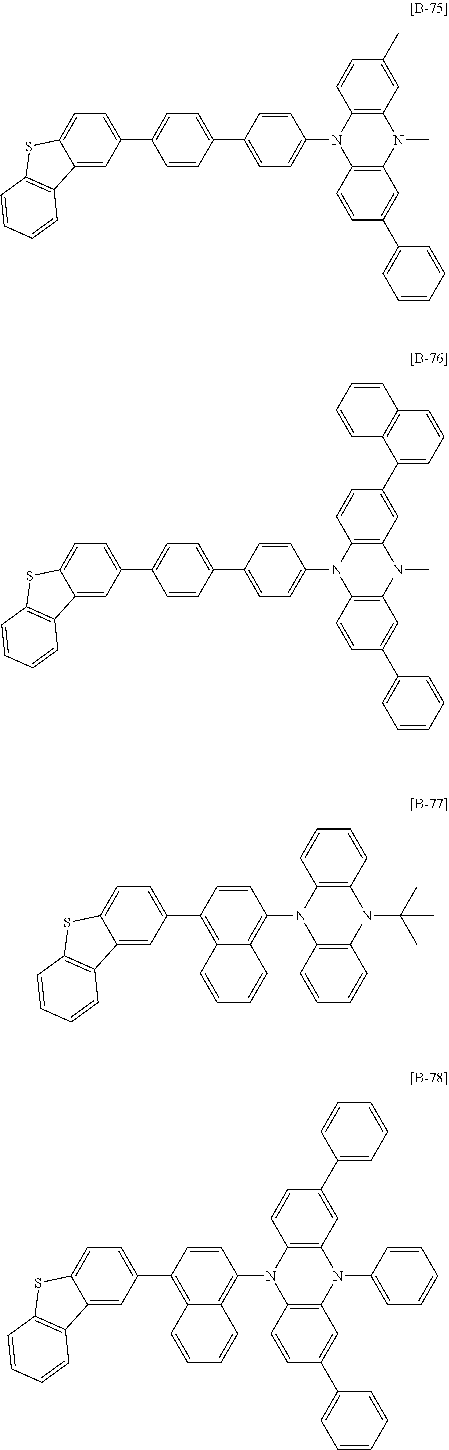 [SMILES: Cc1ccc2c(c1)N(C)c1cc(-c3ccccc3)ccc1N2c1ccc(-c2ccc(-c3ccc4sc5ccccc5c4c3)cc2)cc1 ; CN1c2cc(-c3ccccc3)ccc2N(c2ccc(-c3ccc(-c4ccc5sc6ccccc6c5c4)cc3)cc2)c2ccc(-c3cccc4ccccc34)cc21 ; CC(C)(C)N1c2ccccc2N(c2ccc(-c3ccc4sc5ccccc5c4c3)c3ccccc23)c2ccccc21 ; c1ccc(-c2ccc3c(c2)N(c2ccccc2)c2cc(-c4ccccc4)ccc2N3c2ccc(-c3ccc4sc5ccccc5c4c3)c3ccccc23)cc1]

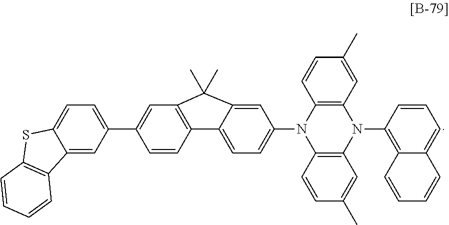 [SMILES: Cc1ccc2c(c1)N(c1cccc3ccccc13)c1cc(C)ccc1N2c1ccc2c(c1)C(C)(C)c1cc(-c3ccc4sc5ccccc5c4c3)ccc1-2]

9. The compound for an organic optoelectronic device as claimed in claim 1, wherein the compound is represented by one of the following Chemical Formulae C-1 to C-54.

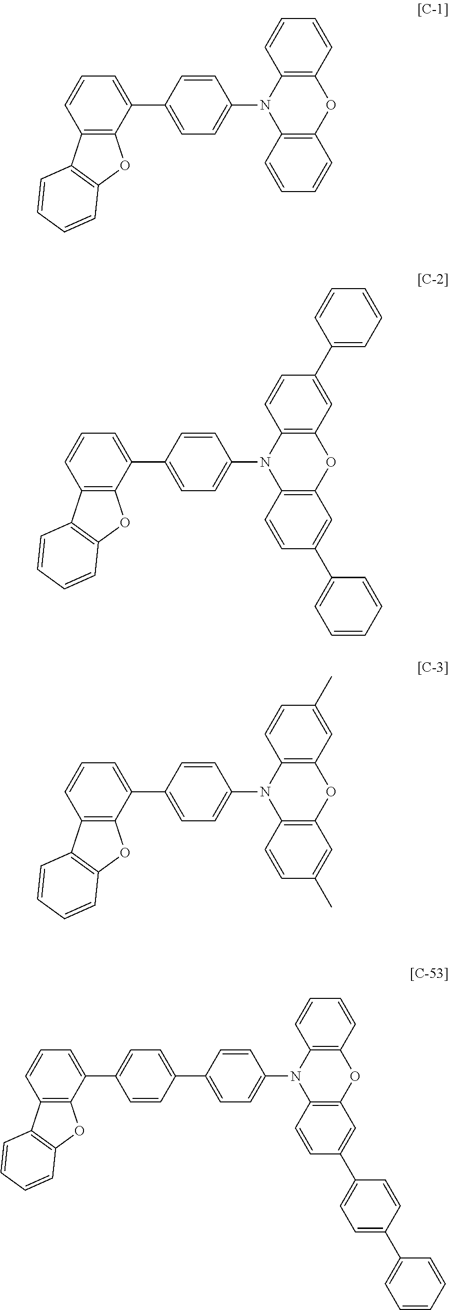

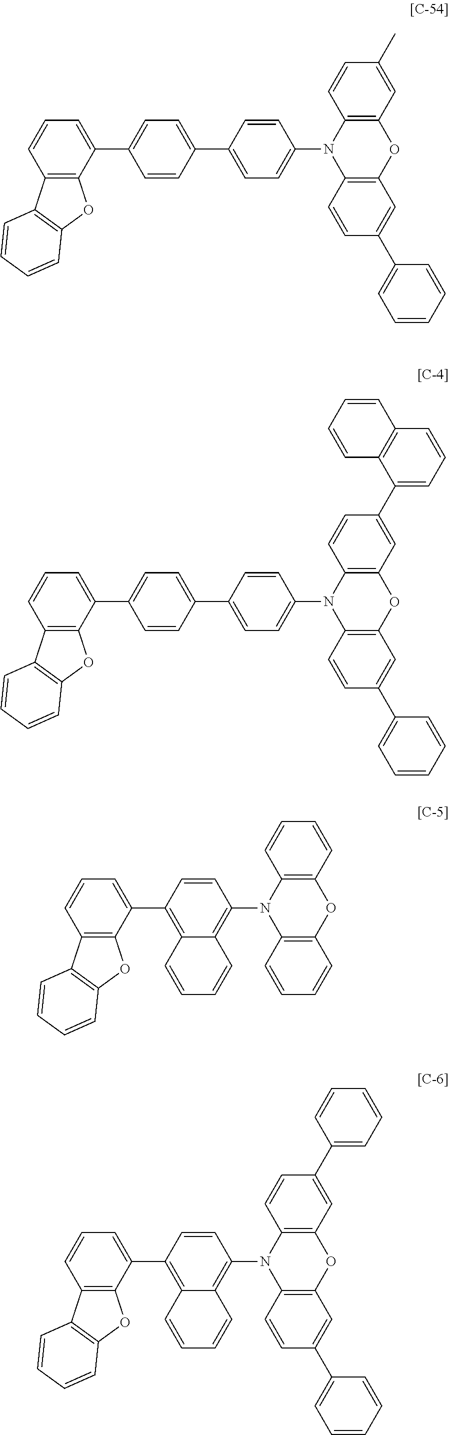 [SMILES: Cc1ccc2c(c1)Oc1cc(-c3ccccc3)ccc1N2c1ccc(-c2ccc(-c3cccc4c3oc3ccccc34)cc2)cc1 ; c1ccc(-c2ccc3c(c2)Oc2cc(-c4cccc5ccccc45)ccc2N3c2ccc(-c3ccc(-c4cccc5c4oc4ccccc45)cc3)cc2)cc1 ; c1ccc2c(c1)Oc1ccccc1N2c1ccc(-c2cccc3c2oc2ccccc23)c2ccccc12 ; c1ccc(-c2ccc3c(c2)Oc2cc(-c4ccccc4)ccc2N3c2ccc(-c3cccc4c3oc3ccccc34)c3ccccc23)cc1]

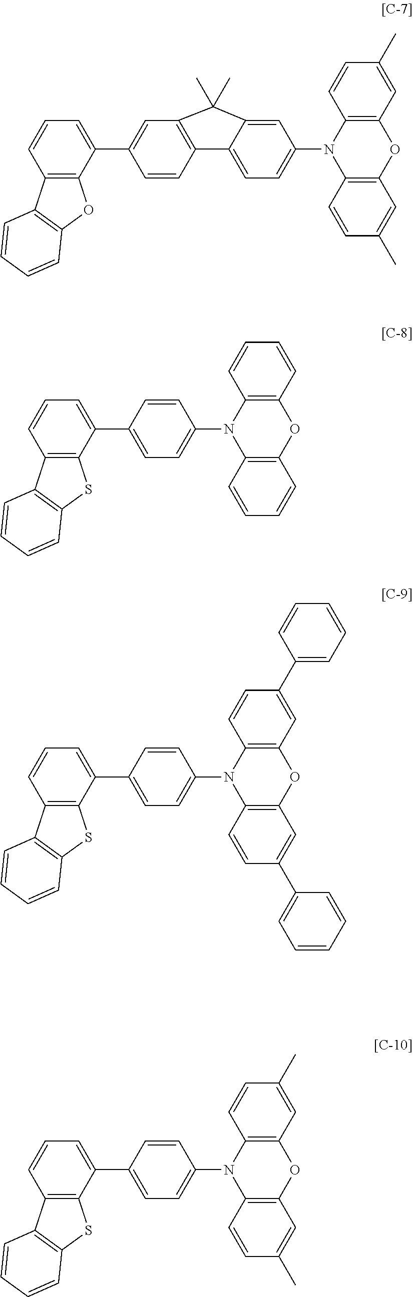 [SMILES: Cc1ccc2c(c1)Oc1cc(C)ccc1N2c1ccc2c(c1)C(C)(C)c1cc(-c3cccc4c3oc3ccccc34)ccc1-2 ; c1ccc2c(c1)Oc1ccccc1N2c1ccc(-c2cccc3c2sc2ccccc23)cc1 ; c1ccc(-c2ccc3c(c2)Oc2cc(-c4ccccc4)ccc2N3c2ccc(-c3cccc4c3sc3ccccc34)cc2)cc1 ; Cc1ccc2c(c1)Oc1cc(C)ccc1N2c1ccc(-c2cccc3c2sc2ccccc23)cc1]

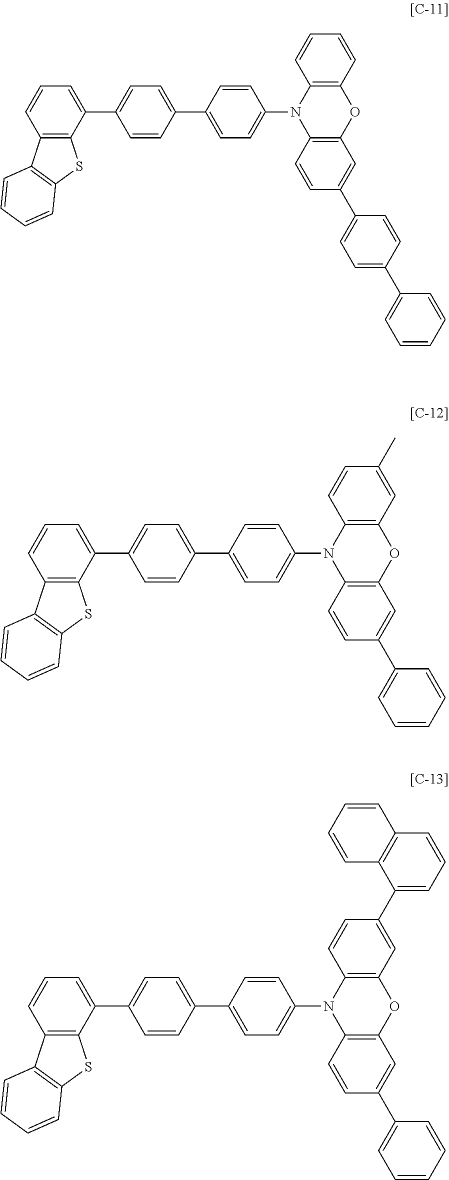 [SMILES: c1ccc(-c2ccc(-c3ccc4c(c3)Oc3ccccc3N4c3ccc(-c4ccc(-c5cccc6c5sc5ccccc56)cc4)cc3)cc2)cc1 ; Cc1ccc2c(c1)Oc1cc(-c3ccccc3)ccc1N2c1ccc(-c2ccc(-c3cccc4c3sc3ccccc34)cc2)cc1 ; c1ccc(-c2ccc3c(c2)Oc2cc(-c4cccc5ccccc45)ccc2N3c2ccc(-c3ccc(-c4cccc5c4sc4ccccc45)cc3)cc2)cc1]

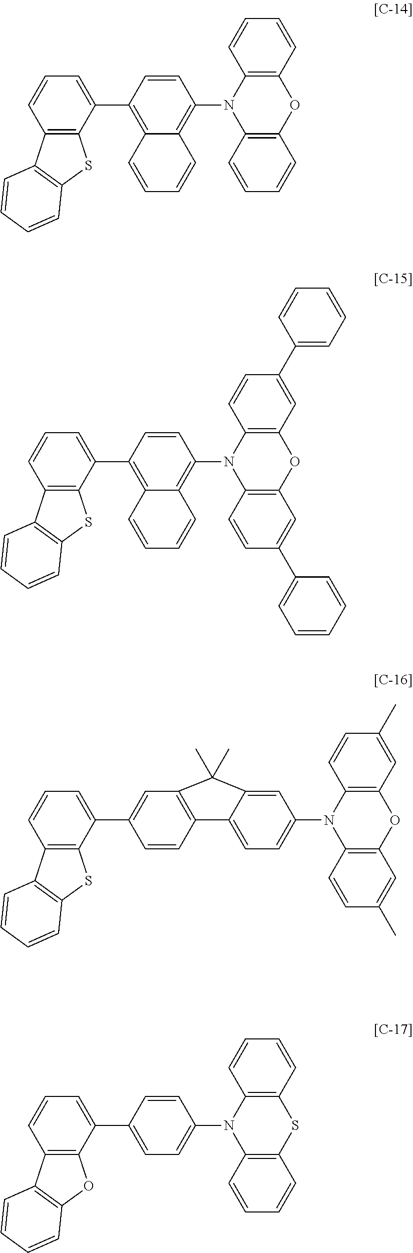 [SMILES: c1ccc2c(c1)Oc1ccccc1N2c1ccc(-c2cccc3c2sc2ccccc23)c2ccccc12 ; c1ccc(-c2ccc3c(c2)Oc2cc(-c4ccccc4)ccc2N3c2ccc(-c3cccc4c3sc3ccccc34)c3ccccc23)cc1 ; Cc1ccc2c(c1)Oc1cc(C)ccc1N2c1ccc2c(c1)C(C)(C)c1cc(-c3cccc4c3sc3ccccc34)ccc1-2 ; c1ccc2c(c1)Sc1ccccc1N2c1ccc(-c2cccc3c2oc2ccccc23)cc1]

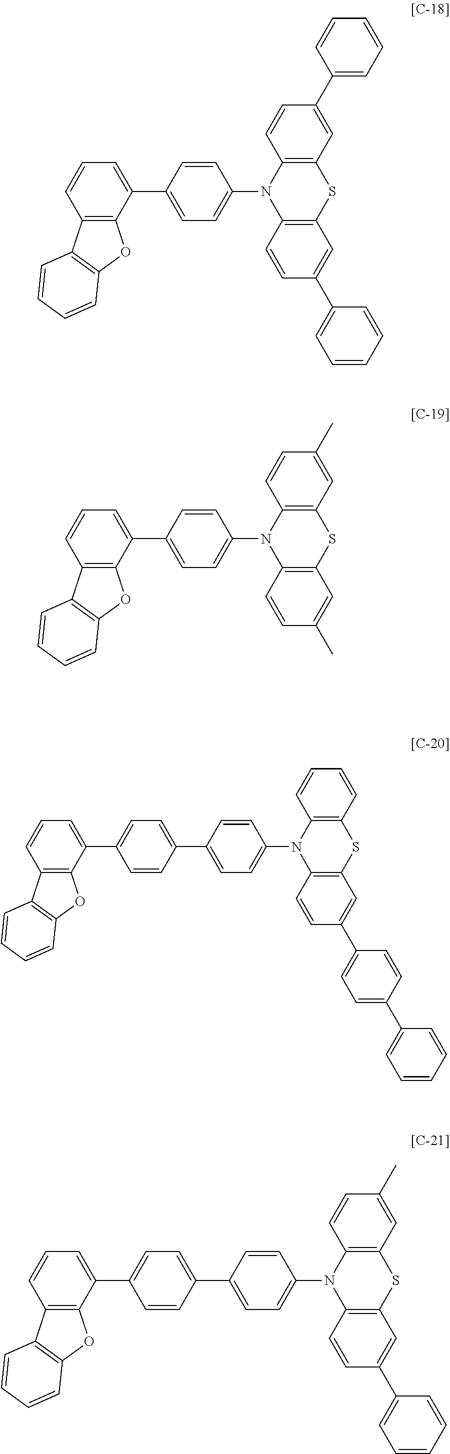 [SMILES: c1ccc(-c2ccc3c(c2)Sc2cc(-c4ccccc4)ccc2N3c2ccc(-c3cccc4c3oc3ccccc34)cc2)cc1 ; Cc1ccc2c(c1)Sc1cc(C)ccc1N2c1ccc(-c2cccc3c2oc2ccccc23)cc1 ; c1ccc(-c2ccc(-c3ccc4c(c3)Sc3ccccc3N4c3ccc(-c4ccc(-c5cccc6c5oc5ccccc56)cc4)cc3)cc2)cc1 ; Cc1ccc2c(c1)Sc1cc(-c3ccccc3)ccc1N2c1ccc(-c2ccc(-c3cccc4c3oc3ccccc34)cc2)cc1]

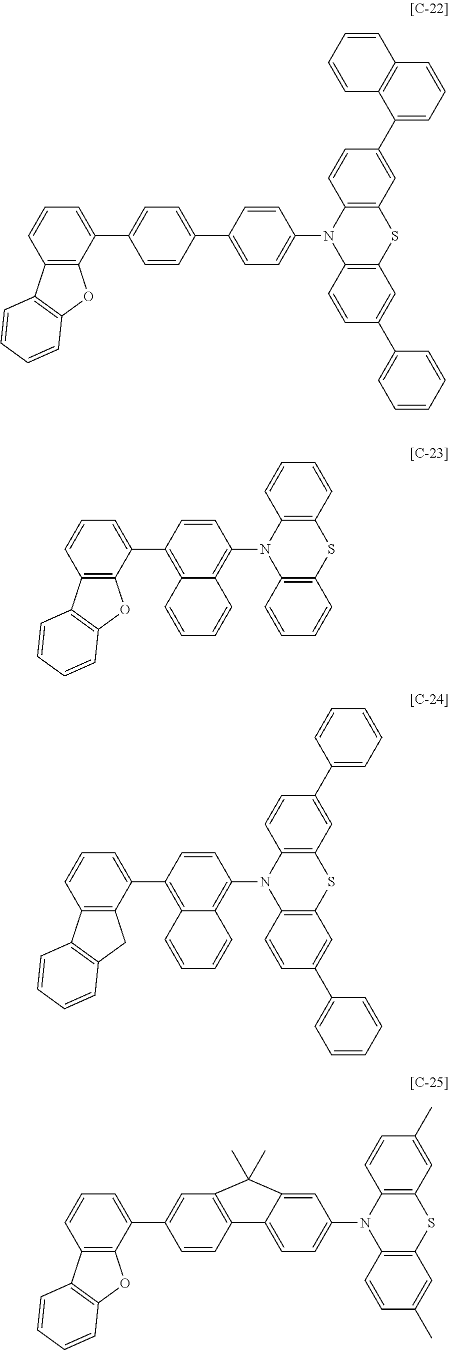 [SMILES: c1ccc(-c2ccc3c(c2)Sc2cc(-c4cccc5ccccc45)ccc2N3c2ccc(-c3ccc(-c4cccc5c4oc4ccccc45)cc3)cc2)cc1 ; c1ccc2c(c1)Sc1ccccc1N2c1ccc(-c2cccc3c2oc2ccccc23)c2ccccc12 ; c1ccc(-c2ccc3c(c2)Sc2cc(-c4ccccc4)ccc2N3c2ccc(-c3cccc4c3Cc3ccccc3-4)c3ccccc23)cc1 ; Cc1ccc2c(c1)Sc1cc(C)ccc1N2c1ccc2c(c1)C(C)(C)c1cc(-c3cccc4c3oc3ccccc34)ccc1-2]

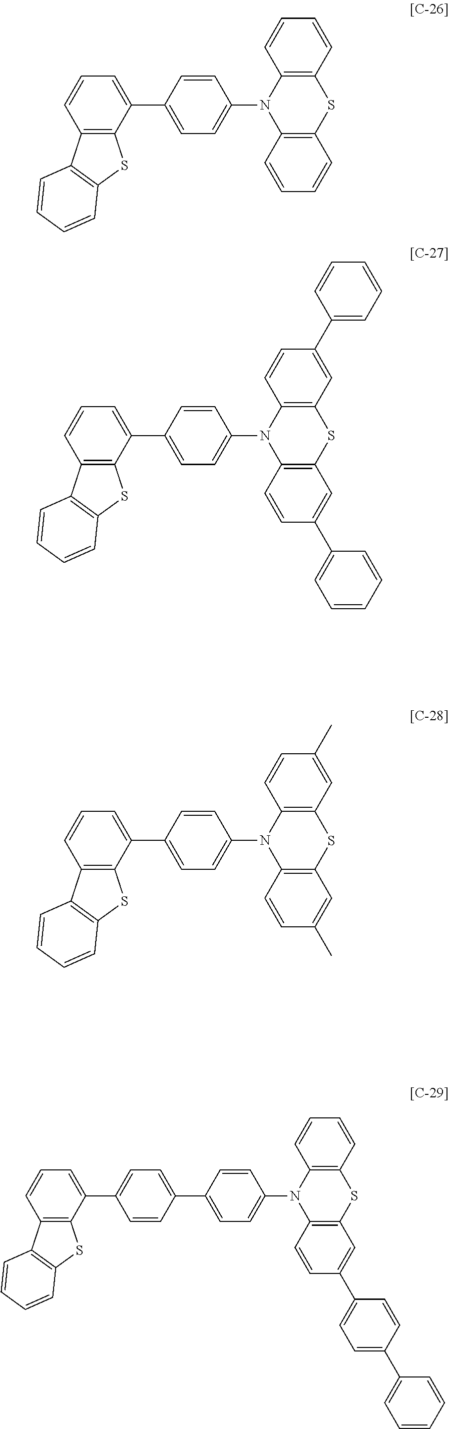 [SMILES: c1ccc2c(c1)Sc1ccccc1N2c1ccc(-c2cccc3c2sc2ccccc23)cc1 ; c1ccc(-c2ccc3c(c2)Sc2cc(-c4ccccc4)ccc2N3c2ccc(-c3cccc4c3sc3ccccc34)cc2)cc1 ; Cc1ccc2c(c1)Sc1cc(C)ccc1N2c1ccc(-c2cccc3c2sc2ccccc23)cc1 ; c1ccc(-c2ccc(-c3ccc4c(c3)Sc3ccccc3N4c3ccc(-c4ccc(-c5cccc6c5sc5ccccc56)cc4)cc3)cc2)cc1]

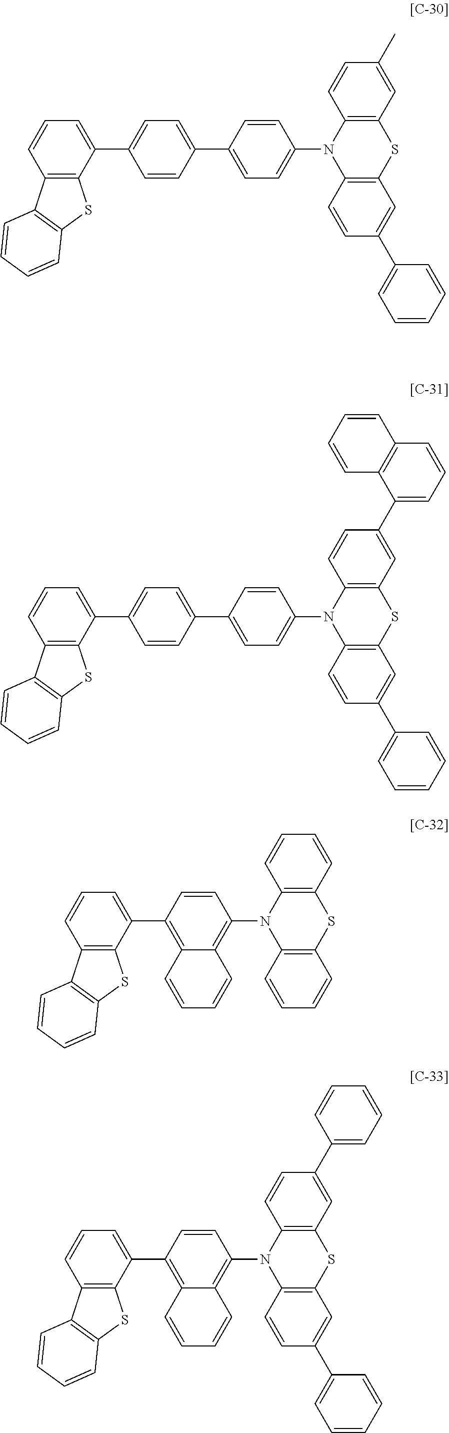 [SMILES: Cc1ccc2c(c1)Sc1cc(-c3ccccc3)ccc1N2c1ccc(-c2ccc(-c3cccc4c3sc3ccccc34)cc2)cc1 ; c1ccc(-c2ccc3c(c2)Sc2cc(-c4cccc5ccccc45)ccc2N3c2ccc(-c3ccc(-c4cccc5c4sc4ccccc45)cc3)cc2)cc1 ; c1ccc2c(c1)Sc1ccccc1N2c1ccc(-c2cccc3c2sc2ccccc23)c2ccccc12 ; c1ccc(-c2ccc3c(c2)Sc2cc(-c4ccccc4)ccc2N3c2ccc(-c3cccc4c3sc3ccccc34)c3ccccc23)cc1]

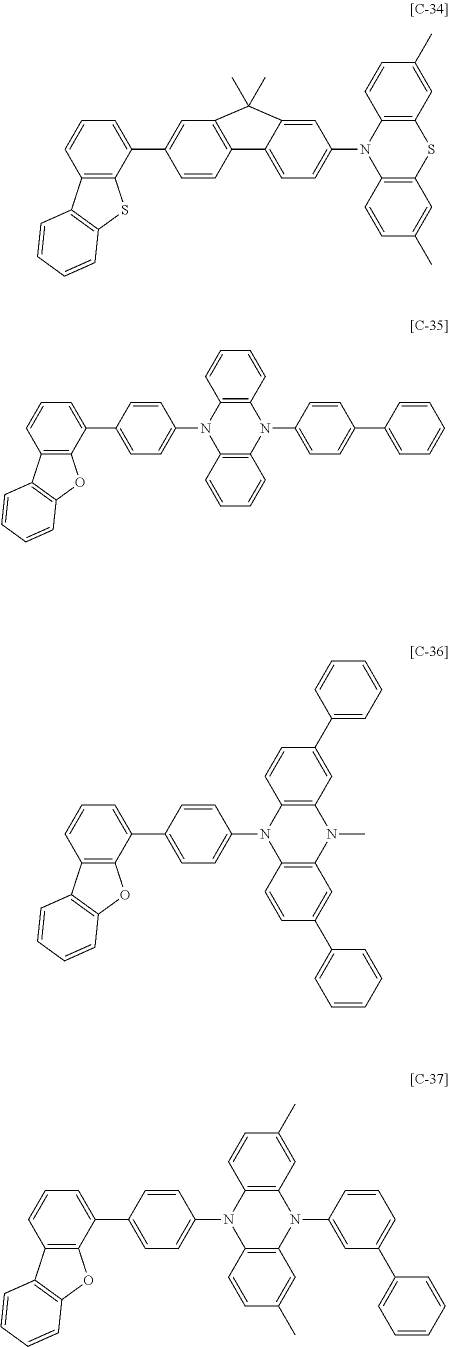 [SMILES: Cc1ccc2c(c1)Sc1cc(C)ccc1N2c1ccc2c(c1)C(C)(C)c1cc(-c3cccc4c3sc3ccccc34)ccc1-2 ; c1ccc(-c2ccc(N3c4ccccc4N(c4ccc(-c5cccc6c5oc5ccccc56)cc4)c4ccccc43)cc2)cc1 ; CN1c2cc(-c3ccccc3)ccc2N(c2ccc(-c3cccc4c3oc3ccccc34)cc2)c2ccc(-c3ccccc3)cc21 ; Cc1ccc2c(c1)N(c1cccc(-c3ccccc3)c1)c1cc(C)ccc1N2c1ccc(-c2cccc3c2oc2ccccc23)cc1]

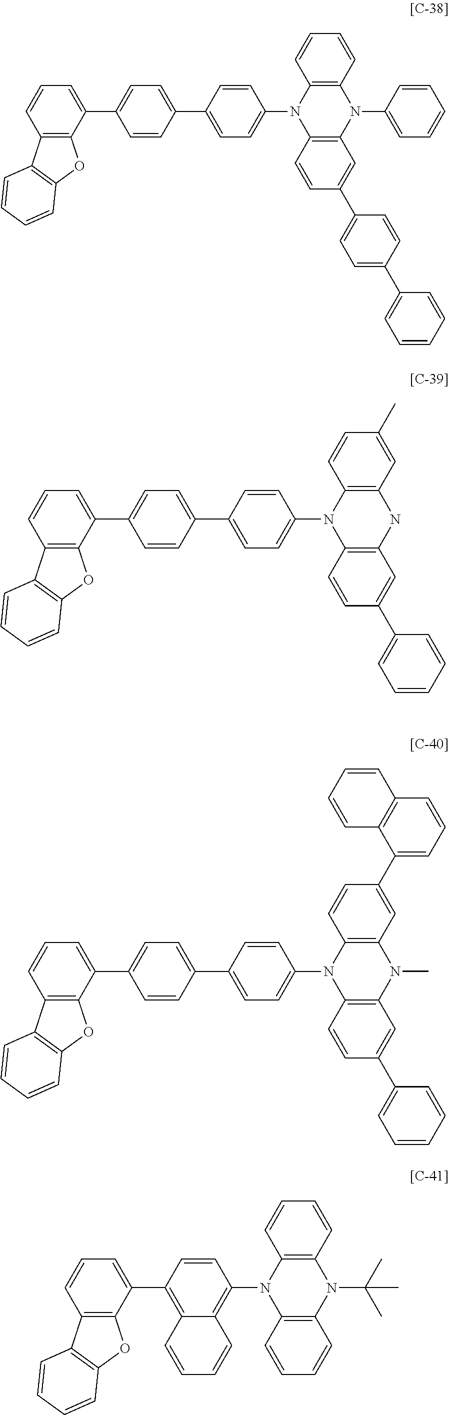 [SMILES: c1ccc(-c2ccc(-c3ccc4c(c3)N(c3ccccc3)c3ccccc3N4c3ccc(-c4ccc(-c5cccc6c5oc5ccccc56)cc4)cc3)cc2)cc1 ; Cc1ccc2c(c1)Nc1cc(-c3ccccc3)ccc1N2c1ccc(-c2ccc(-c3cccc4c3oc3ccccc34)cc2)cc1 ; CN1c2cc(-c3ccccc3)ccc2N(c2ccc(-c3ccc(-c4cccc5c4oc4ccccc45)cc3)cc2)c2ccc(-c3cccc4ccccc34)cc21 ; CC(C)(C)N1c2ccccc2N(c2ccc(-c3cccc4c3oc3ccccc34)c3ccccc23)c2ccccc21]

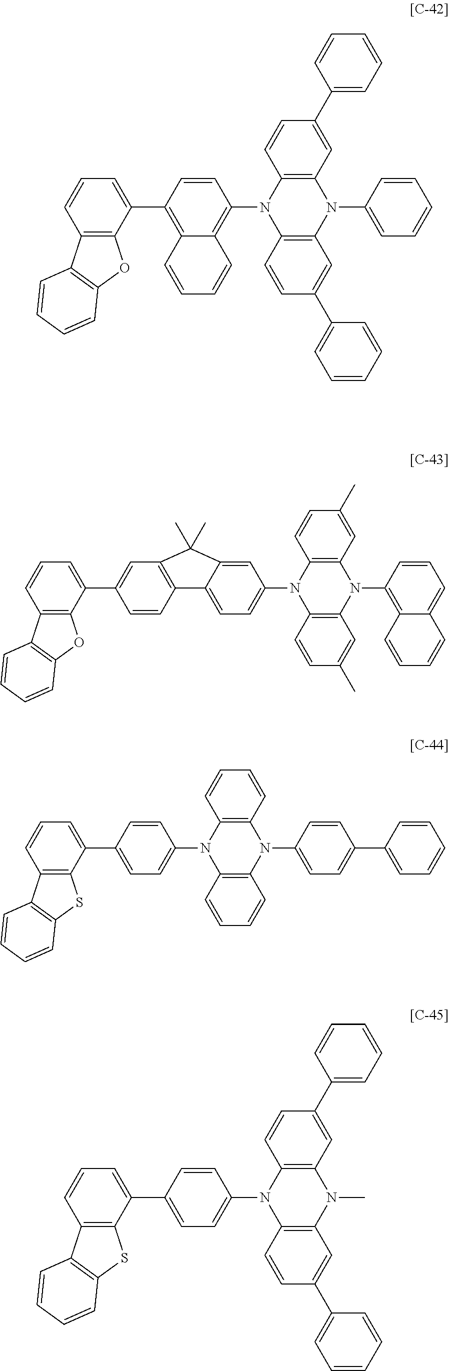 [SMILES: c1ccc(-c2ccc3c(c2)N(c2ccccc2)c2cc(-c4ccccc4)ccc2N3c2ccc(-c3cccc4c3oc3ccccc34)c3ccccc23)cc1 ; Cc1ccc2c(c1)N(c1cccc3ccccc13)c1cc(C)ccc1N2c1ccc2c(c1)C(C)(C)c1cc(-c3cccc4c3oc3ccccc34)ccc1-2 ; c1ccc(-c2ccc(N3c4ccccc4N(c4ccc(-c5cccc6c5sc5ccccc56)cc4)c4ccccc43)cc2)cc1 ; CN1c2cc(-c3ccccc3)ccc2N(c2ccc(-c3cccc4c3sc3ccccc34)cc2)c2ccc(-c3ccccc3)cc21]

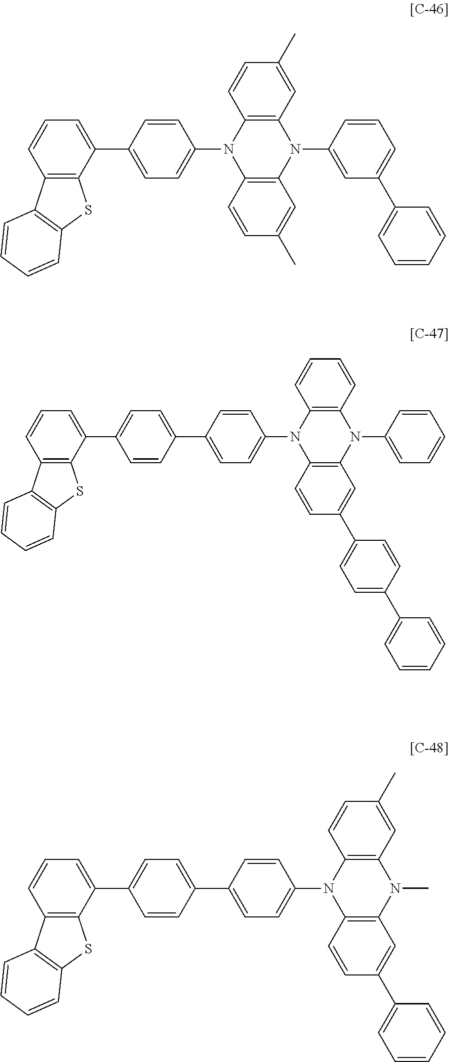 [SMILES: Cc1ccc2c(c1)N(c1cccc(-c3ccccc3)c1)c1cc(C)ccc1N2c1ccc(-c2cccc3c2sc2ccccc23)cc1 ; c1ccc(-c2ccc(-c3ccc4c(c3)N(c3ccccc3)c3ccccc3N4c3ccc(-c4ccc(-c5cccc6c5sc5ccccc56)cc4)cc3)cc2)cc1 ; Cc1ccc2c(c1)N(C)c1cc(-c3ccccc3)ccc1N2c1ccc(-c2ccc(-c3cccc4c3sc3ccccc34)cc2)cc1]

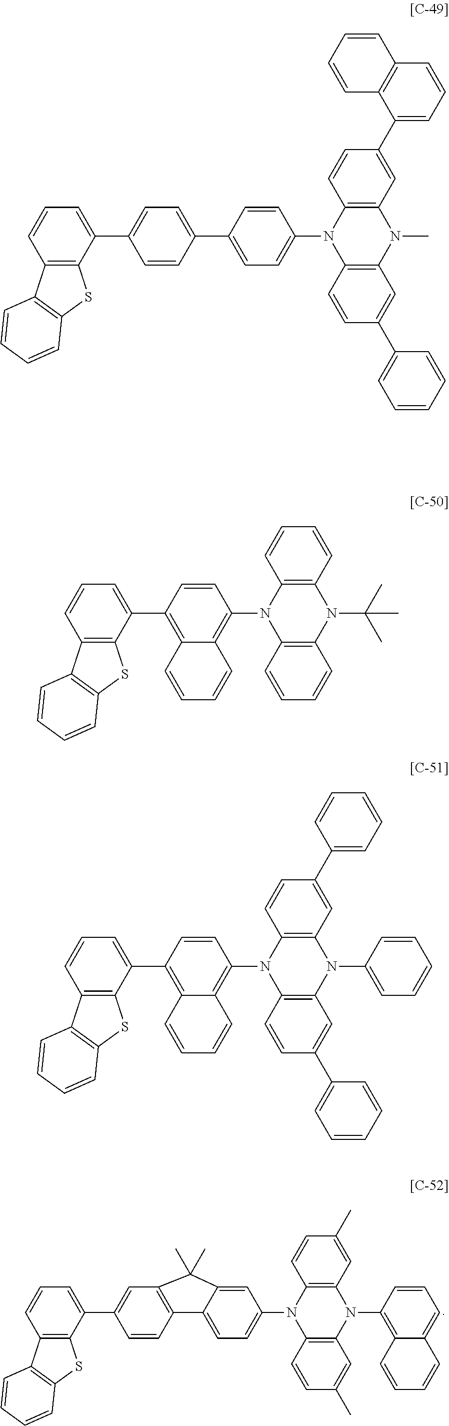 [SMILES: CN1c2cc(-c3ccccc3)ccc2N(c2ccc(-c3ccc(-c4cccc5c4sc4ccccc45)cc3)cc2)c2ccc(-c3cccc4ccccc34)cc21 ; CC(C)(C)N1c2ccccc2N(c2ccc(-c3cccc4c3sc3ccccc34)c3ccccc23)c2ccccc21 ; c1ccc(-c2ccc3c(c2)N(c2ccccc2)c2cc(-c4ccccc4)ccc2N3c2ccc(-c3cccc4c3sc3ccccc34)c3ccccc23)cc1 ; Cc1ccc2c(c1)N(c1cccc3ccccc13)c1cc(C)ccc1N2c1ccc2c(c1)C(C)(C)c1cc(-c3cccc4c3sc3ccccc34)ccc1-2]

10. The compound for an organic optoelectronic device as claimed in claim 1, the compound is represented by one of the following Chemical Formulae D-1 to D-36:

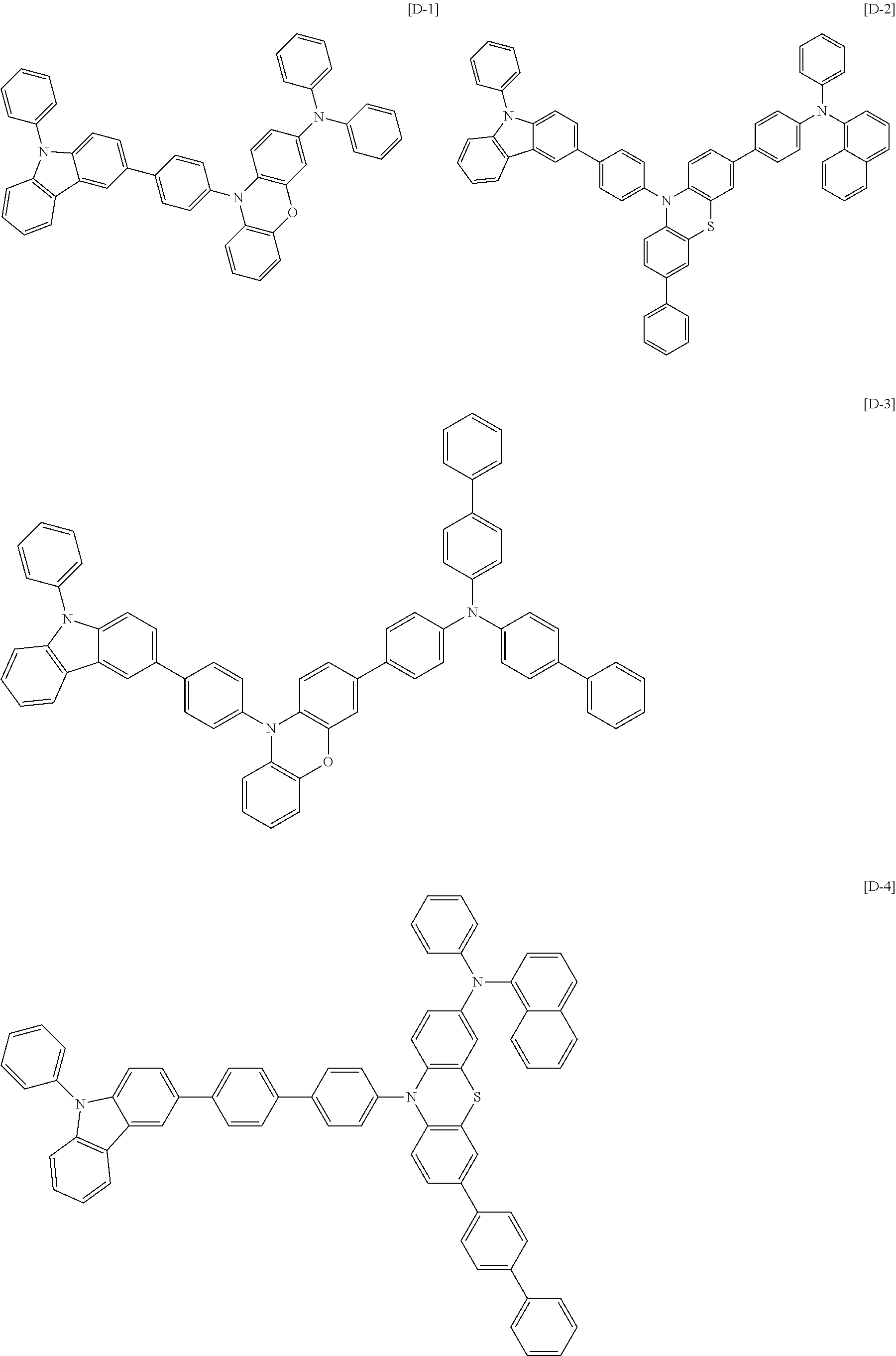 [SMILES: c1ccc(N(c2ccccc2)c2ccc3c(c2)Oc2ccccc2N3c2ccc(-c3ccc4c(c3)c3ccccc3n4-c3ccccc3)cc2)cc1 ; c1ccc(-c2ccc3c(c2)Sc2cc(-c4ccc(N(c5ccccc5)c5cccc6ccccc56)cc4)ccc2N3c2ccc(-c3ccc4c(c3)c3ccccc3n4-c3ccccc3)cc2)cc1 ; c1ccc(-c2ccc(N(c3ccc(-c4ccccc4)cc3)c3ccc(-c4ccc5c(c4)Oc4ccccc4N5c4ccc(-c5ccc6c(c5)c5ccccc5n6-c5ccccc5)cc4)cc3)cc2)cc1 ; c1ccc(-c2ccc(-c3ccc4c(c3)Sc3cc(N(c5ccccc5)c5cccc6ccccc56)ccc3N4c3ccc(-c4ccc(-c5ccc6c(c5)c5ccccc5n6-c5ccccc5)cc4)cc3)cc2)cc1]

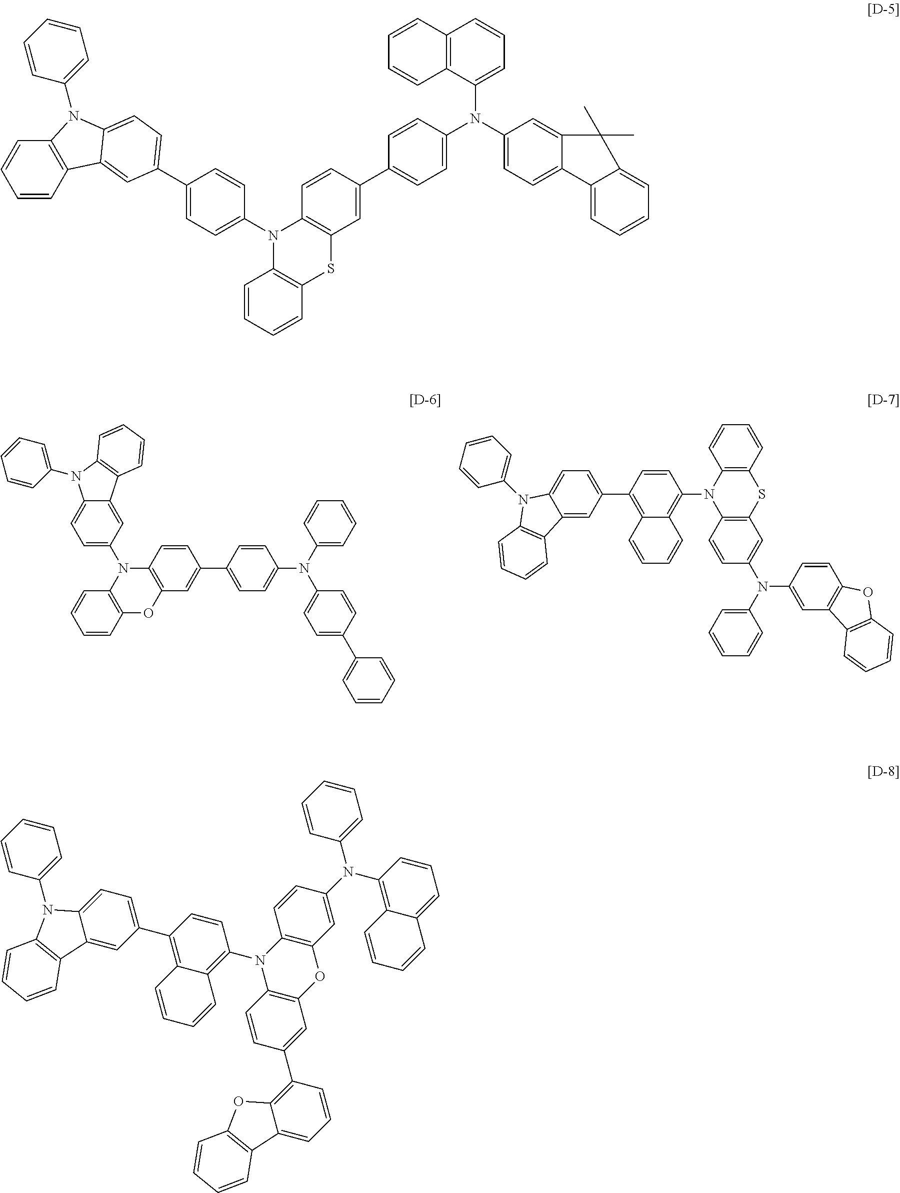 [SMILES: CC1(C)c2ccccc2-c2ccc(N(c3ccc(-c4ccc5c(c4)Sc4ccccc4N5c4ccc(-c5ccc6c(c5)c5ccccc5n6-c5ccccc5)cc4)cc3)c3cccc4ccccc34)cc21 ; c1ccc(-c2ccc(N(c3ccccc3)c3ccc(-c4ccc5c(c4)Oc4ccccc4N5c4ccc5c(c4)c4ccccc4n5-c4ccccc4)cc3)cc2)cc1 ; c1ccc(N(c2ccc3c(c2)Sc2ccccc2N3c2ccc(-c3ccc4c(c3)c3ccccc3n4-c3ccccc3)c3ccccc23)c2ccc3oc4ccccc4c3c2)cc1 ; c1ccc(N(c2ccc3c(c2)Oc2cc(-c4cccc5c4oc4ccccc45)ccc2N3c2ccc(-c3ccc4c(c3)c3ccccc3n4-c3ccccc3)c3ccccc23)c2cccc3ccccc23)cc1]

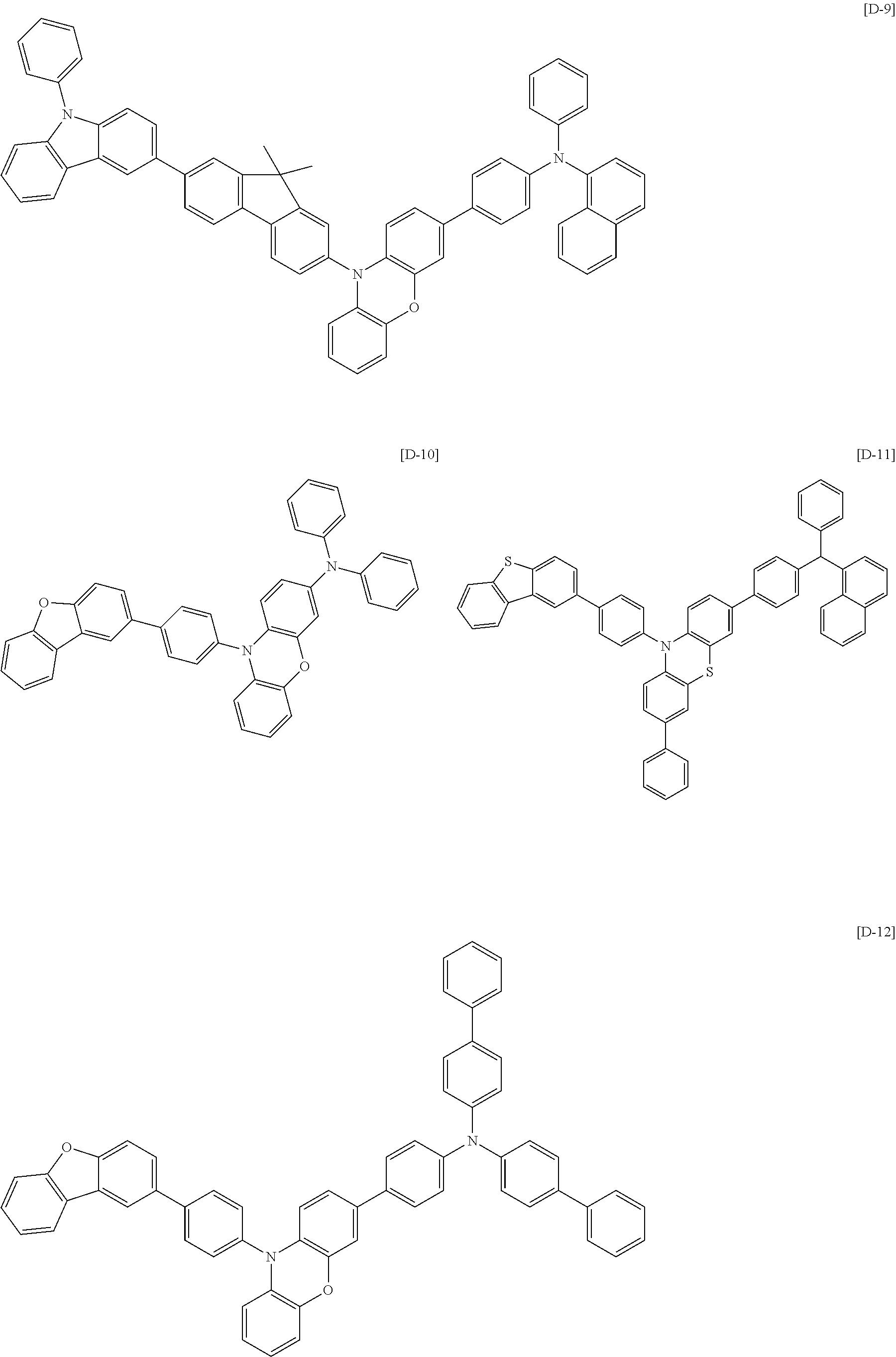

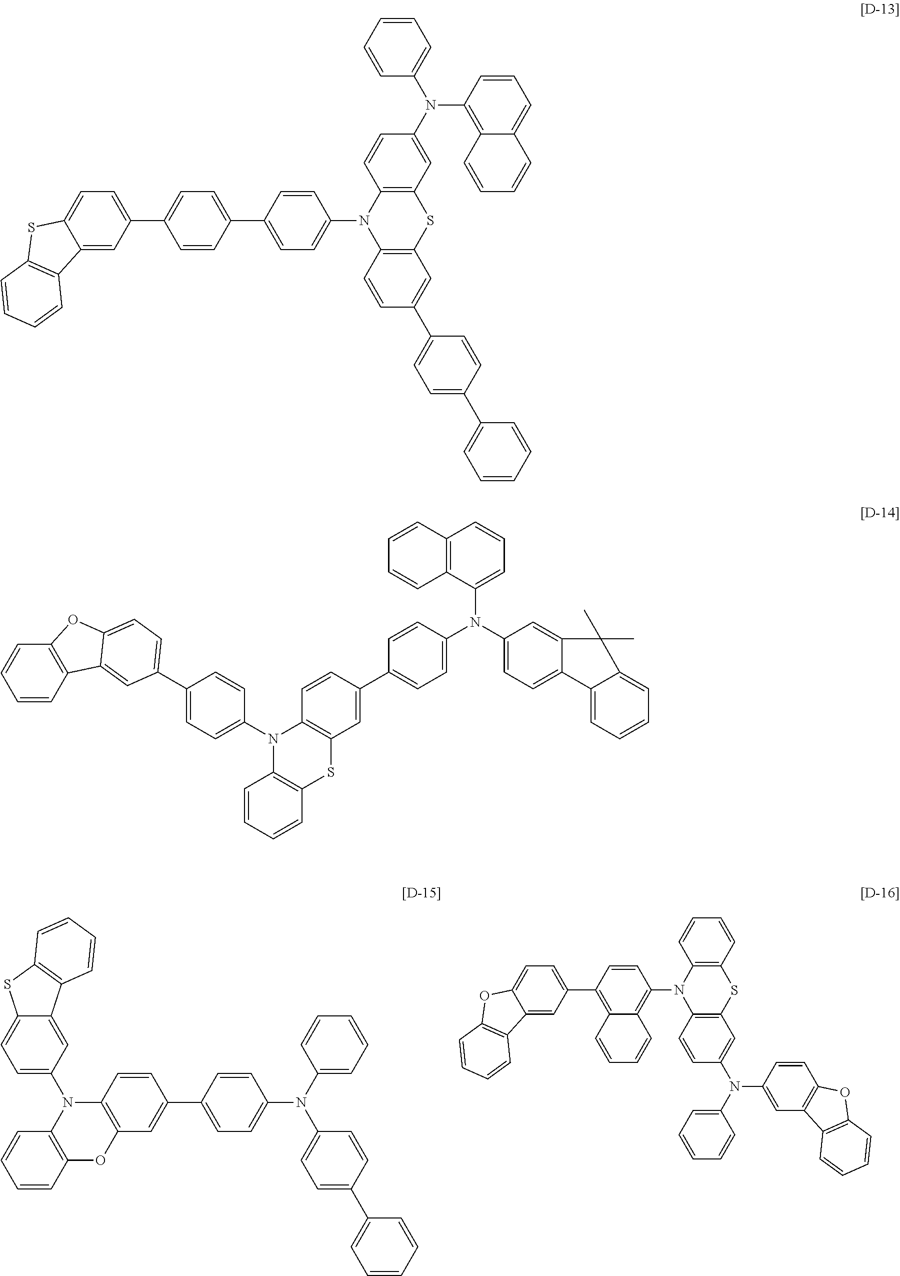

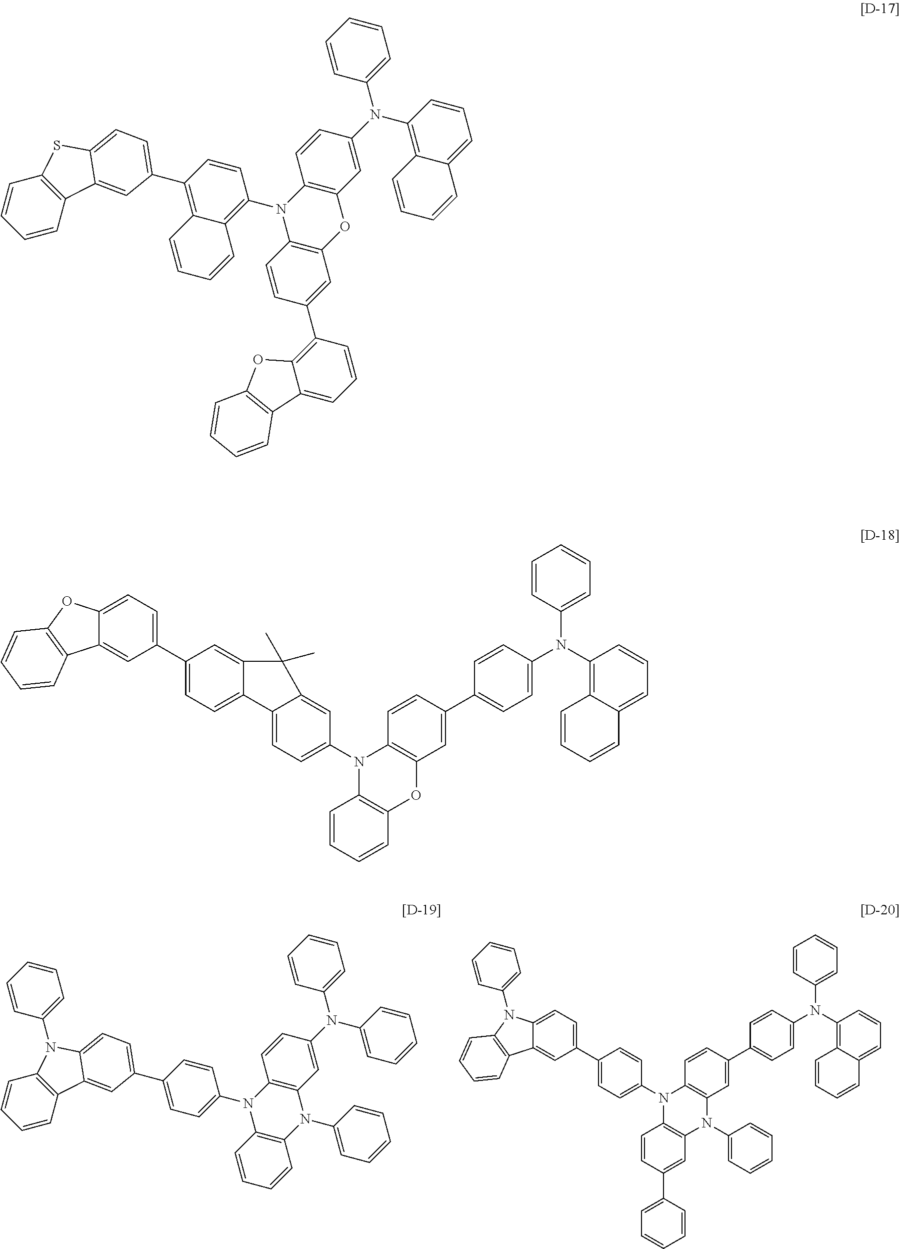

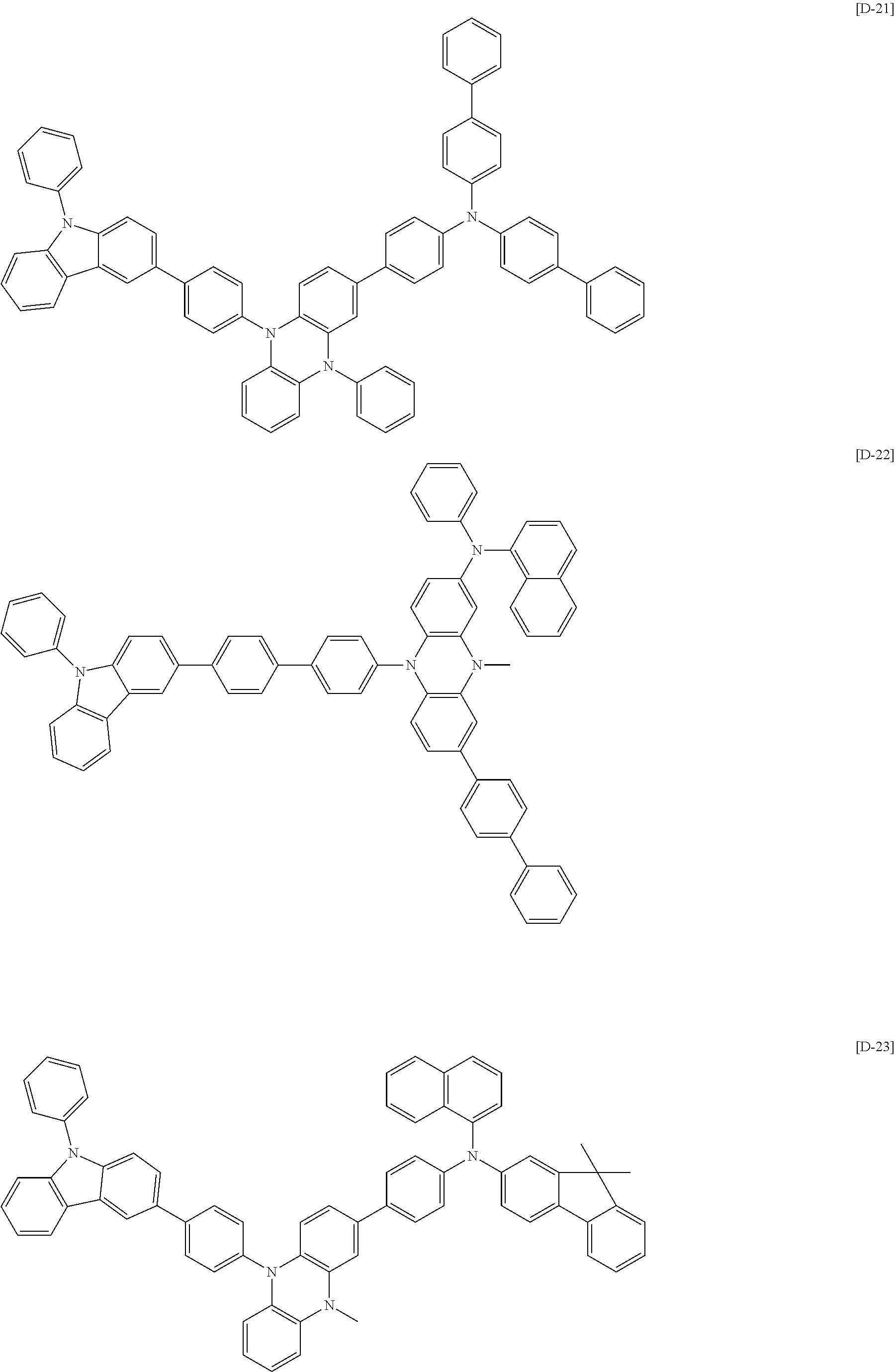 [SMILES: c1ccc(-c2ccc(N(c3ccc(-c4ccccc4)cc3)c3ccc(-c4ccc5c(c4)N(c4ccccc4)c4ccccc4N5c4ccc(-c5ccc6c(c5)c5ccccc5n6-c5ccccc5)cc4)cc3)cc2)cc1 ; CN1c2cc(-c3ccc(-c4ccccc4)cc3)ccc2N(c2ccc(-c3ccc(-c4ccc5c(c4)c4ccccc4n5-c4ccccc4)cc3)cc2)c2ccc(N(c3ccccc3)c3cccc4ccccc34)cc21 ; CN1c2ccccc2N(c2ccc(-c3ccc4c(c3)c3ccccc3n4-c3ccccc3)cc2)c2ccc(-c3ccc(N(c4ccc5c(c4)C(C)(C)c4ccccc4-5)c4cccc5ccccc45)cc3)cc21]

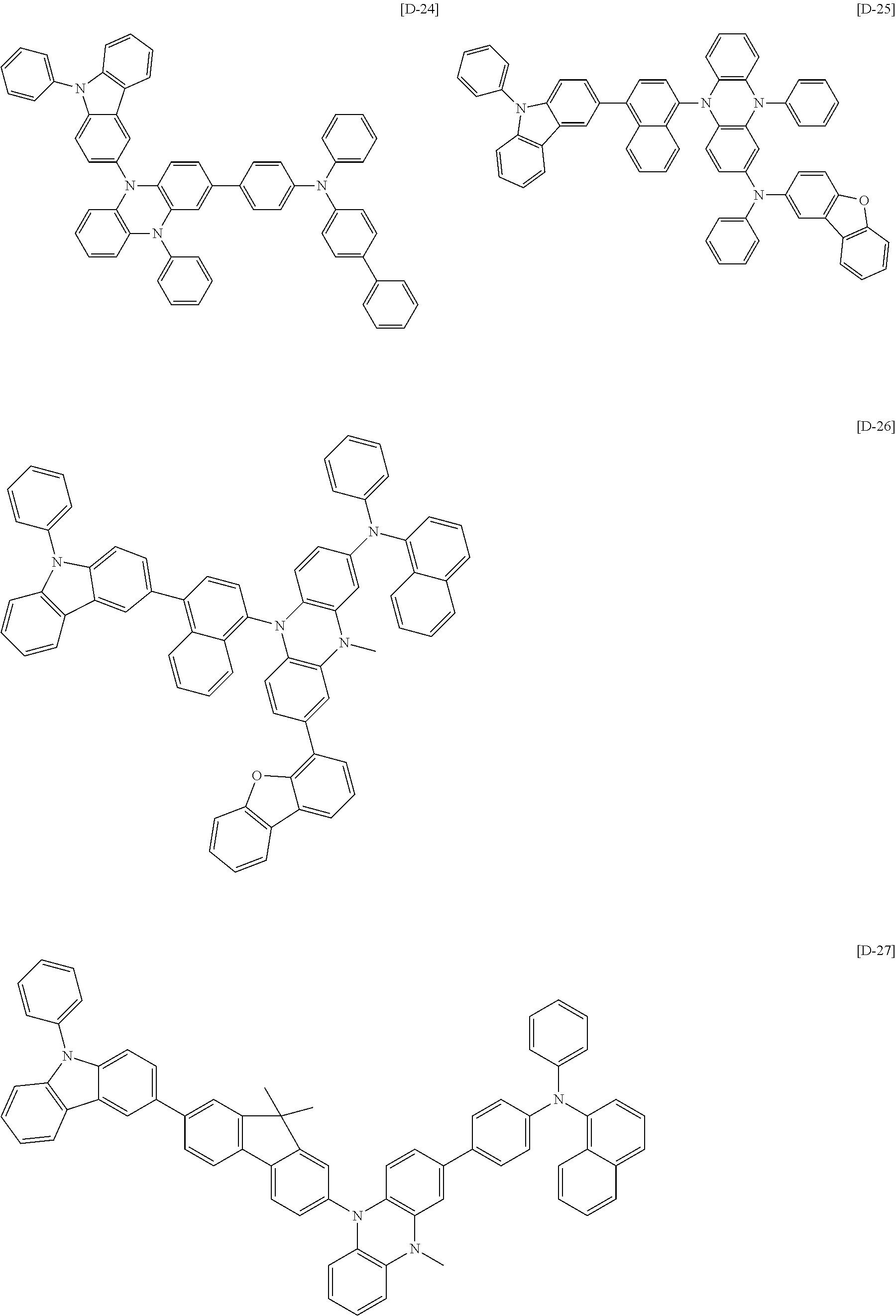 [SMILES: c1ccc(-c2ccc(N(c3ccccc3)c3ccc(-c4ccc5c(c4)N(c4ccccc4)c4ccccc4N5c4ccc5c(c4)c4ccccc4n5-c4ccccc4)cc3)cc2)cc1 ; c1ccc(N(c2ccc3c(c2)N(c2ccccc2)c2ccccc2N3c2ccc(-c3ccc4c(c3)c3ccccc3n4-c3ccccc3)c3ccccc23)c2ccc3oc4ccccc4c3c2)cc1 ; CN1c2cc(-c3cccc4c3oc3ccccc34)ccc2N(c2ccc(-c3ccc4c(c3)c3ccccc3n4-c3ccccc3)c3ccccc23)c2ccc(N(c3ccccc3)c3cccc4ccccc34)cc21 ; CN1c2ccccc2N(c2ccc3c(c2)C(C)(C)c2cc(-c4ccc5c(c4)c4ccccc4n5-c4ccccc4)ccc2-3)c2ccc(-c3ccc(N(c4ccccc4)c4cccc5ccccc45)cc3)cc21]

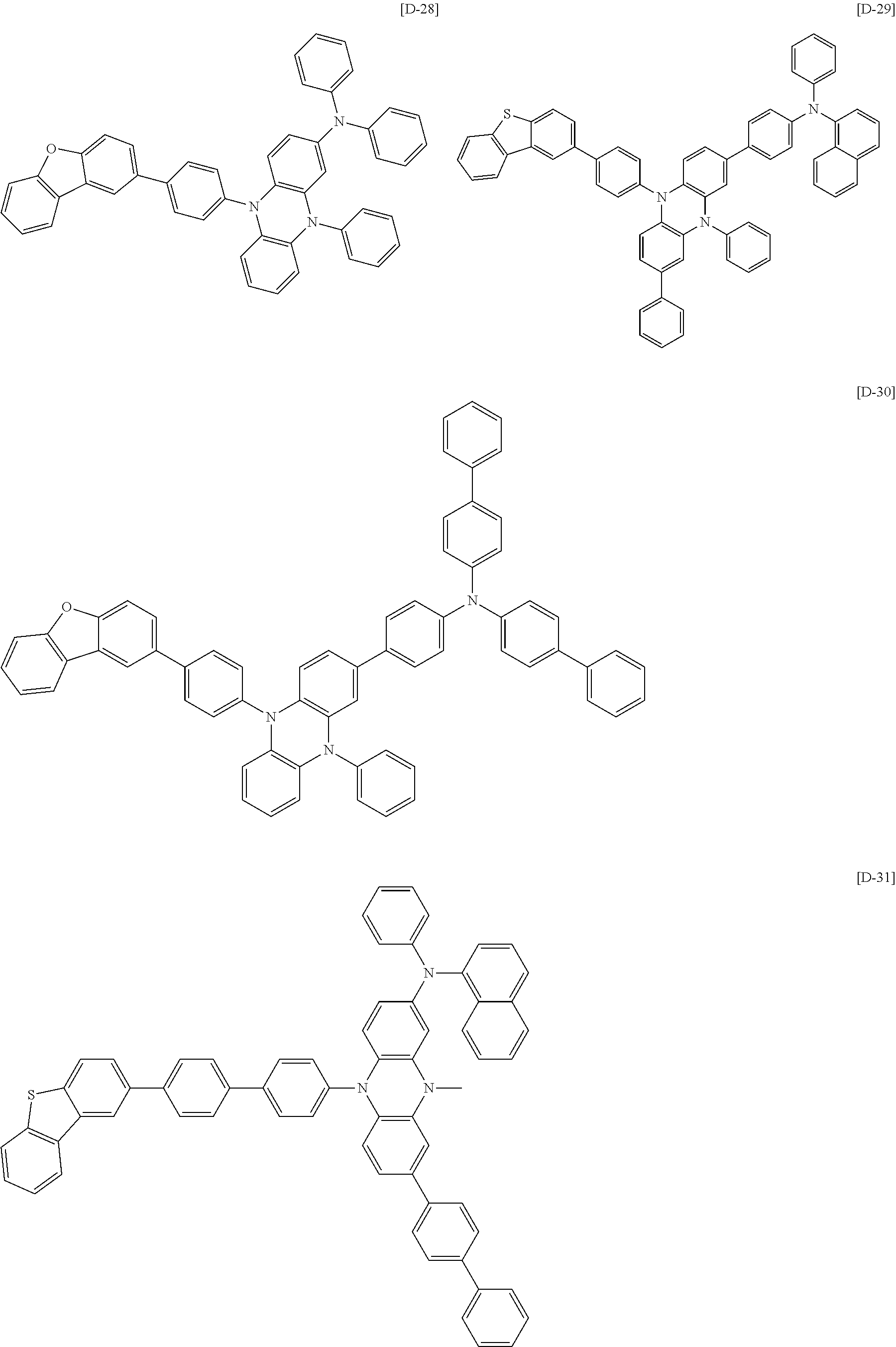

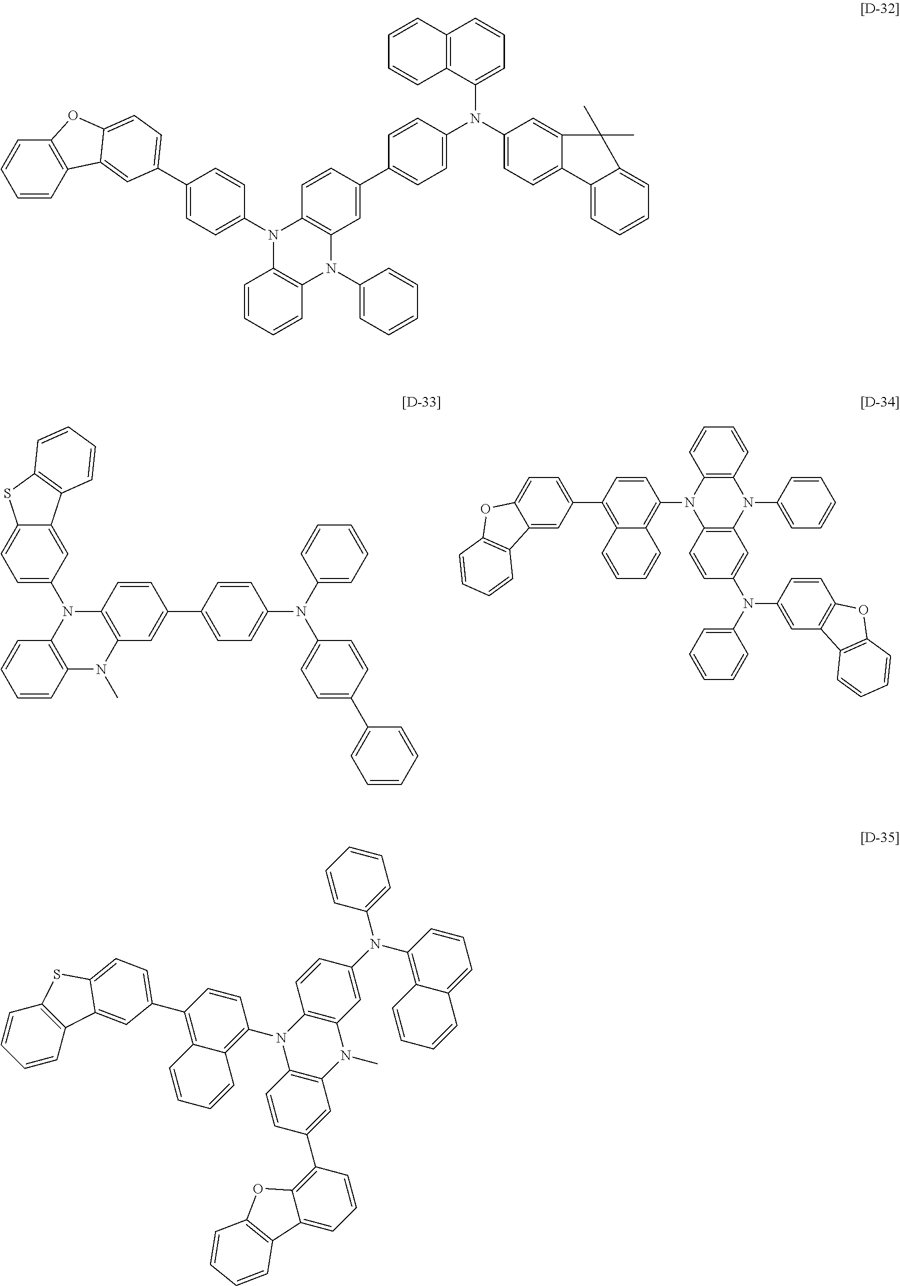 [SMILES: CC1(C)c2ccccc2-c2ccc(N(c3ccc(-c4ccc5c(c4)N(c4ccccc4)c4ccccc4N5c4ccc(-c5ccc6oc7ccccc7c6c5)cc4)cc3)c3cccc4ccccc34)cc21 ; CN1c2ccccc2N(c2ccc3sc4ccccc4c3c2)c2ccc(-c3ccc(N(c4ccccc4)c4ccc(-c5ccccc5)cc4)cc3)cc21 ; c1ccc(N(c2ccc3c(c2)N(c2ccccc2)c2ccccc2N3c2ccc(-c3ccc4oc5ccccc5c4c3)c3ccccc23)c2ccc3oc4ccccc4c3c2)cc1 ; CN1c2cc(-c3cccc4c3oc3ccccc34)ccc2N(c2ccc(-c3ccc4sc5ccccc5c4c3)c3ccccc23)c2ccc(N(c3ccccc3)c3cccc4ccccc34)cc21]

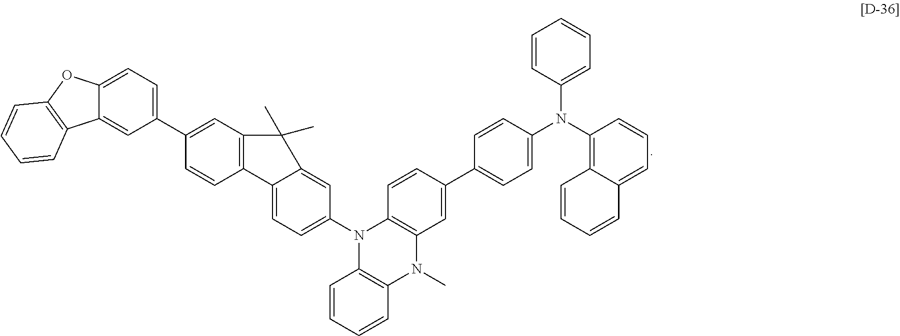 [SMILES: CN1c2ccccc2N(c2ccc3c(c2)C(C)(C)c2cc(-c4ccc5oc6ccccc6c5c4)ccc2-3)c2ccc(-c3ccc(N(c4ccccc4)c4cccc5ccccc45)cc3)cc21]

11. The compound for an organic optoelectronic device as claimed in claim 1, wherein the compound is represented by one of the following Chemical Formulae E-1 to E-18:

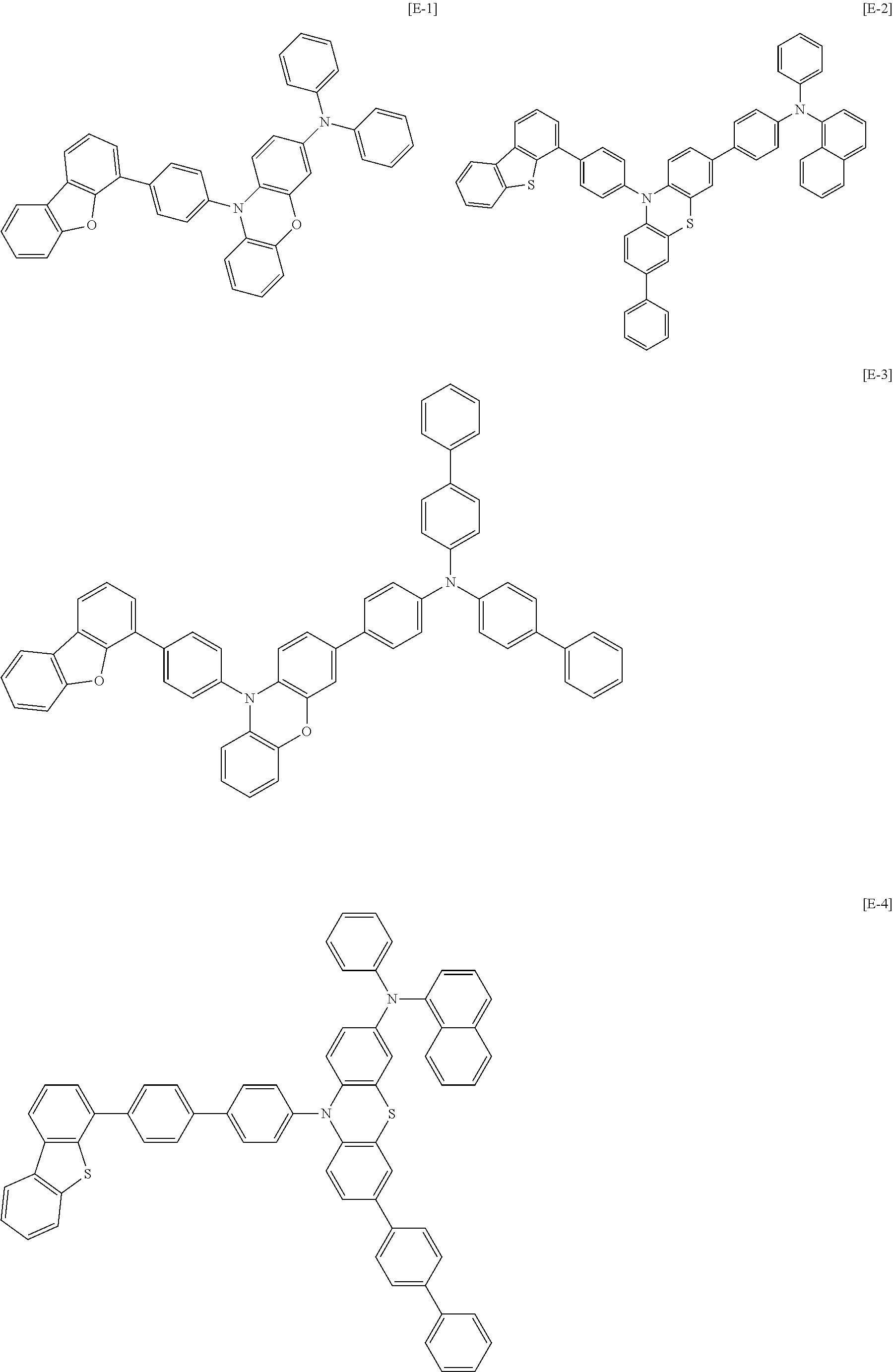 [SMILES: c1ccc(N(c2ccccc2)c2ccc3c(c2)Oc2ccccc2N3c2ccc(-c3cccc4c3oc3ccccc34)cc2)cc1 ; c1ccc(-c2ccc3c(c2)Sc2cc(-c4ccc(N(c5ccccc5)c5cccc6ccccc56)cc4)ccc2N3c2ccc(-c3cccc4c3sc3ccccc34)cc2)cc1 ; c1ccc(-c2ccc(N(c3ccc(-c4ccccc4)cc3)c3ccc(-c4ccc5c(c4)Oc4ccccc4N5c4ccc(-c5cccc6c5oc5ccccc56)cc4)cc3)cc2)cc1 ; c1ccc(-c2ccc(-c3ccc4c(c3)Sc3cc(N(c5ccccc5)c5cccc6ccccc56)ccc3N4c3ccc(-c4ccc(-c5cccc6c5sc5ccccc56)cc4)cc3)cc2)cc1]

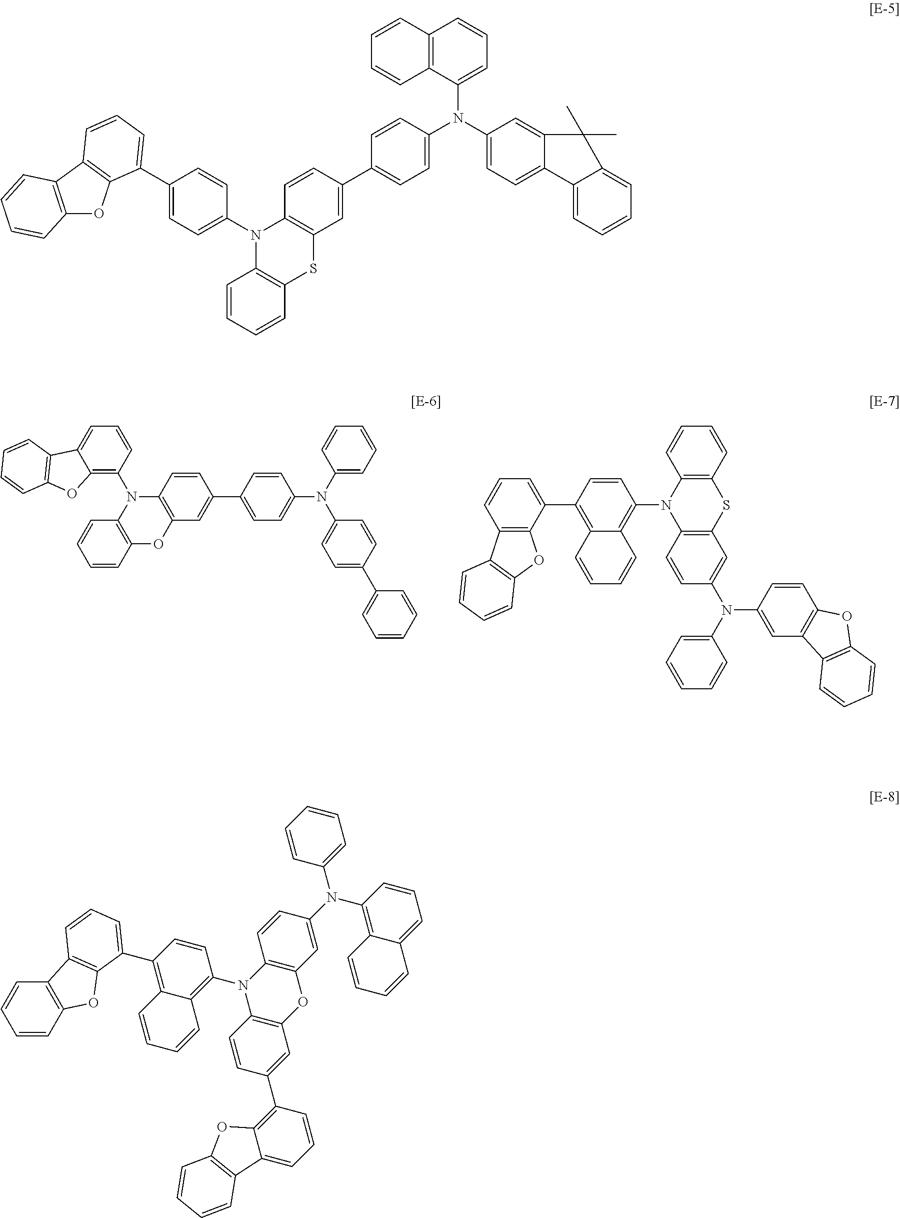 [SMILES: CC1(C)c2ccccc2-c2ccc(N(c3ccc(-c4ccc5c(c4)Sc4ccccc4N5c4ccc(-c5cccc6c5oc5ccccc56)cc4)cc3)c3cccc4ccccc34)cc21 ; c1ccc(-c2ccc(N(c3ccccc3)c3ccc(-c4ccc5c(c4)Oc4ccccc4N5c4cccc5c4oc4ccccc45)cc3)cc2)cc1 ; c1ccc(N(c2ccc3c(c2)Sc2ccccc2N3c2ccc(-c3cccc4c3oc3ccccc34)c3ccccc23)c2ccc3oc4ccccc4c3c2)cc1 ; c1ccc(N(c2ccc3c(c2)Oc2cc(-c4cccc5c4oc4ccccc45)ccc2N3c2ccc(-c3cccc4c3oc3ccccc34)c3ccccc23)c2cccc3ccccc23)cc1]

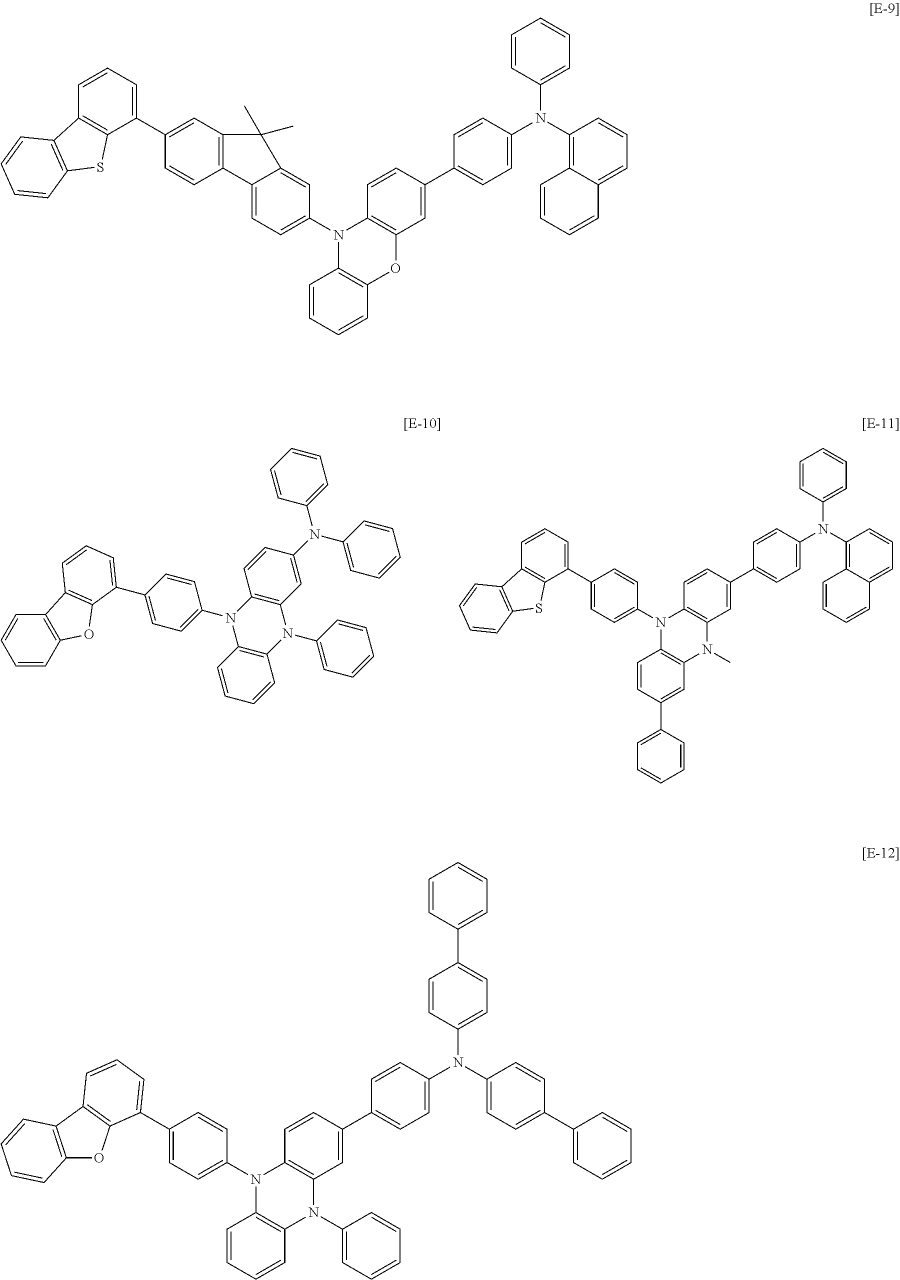 [SMILES: CC1(C)c2cc(-c3cccc4c3sc3ccccc34)ccc2-c2ccc(N3c4ccccc4Oc4cc(-c5ccc(N(c6ccccc6)c6cccc7ccccc67)cc5)ccc43)cc21 ; c1ccc(N(c2ccccc2)c2ccc3c(c2)N(c2ccccc2)c2ccccc2N3c2ccc(-c3cccc4c3oc3ccccc34)cc2)cc1 ; CN1c2cc(-c3ccccc3)ccc2N(c2ccc(-c3cccc4c3sc3ccccc34)cc2)c2ccc(-c3ccc(N(c4ccccc4)c4cccc5ccccc45)cc3)cc21 ; c1ccc(-c2ccc(N(c3ccc(-c4ccccc4)cc3)c3ccc(-c4ccc5c(c4)N(c4ccccc4)c4ccccc4N5c4ccc(-c5cccc6c5oc5ccccc56)cc4)cc3)cc2)cc1]

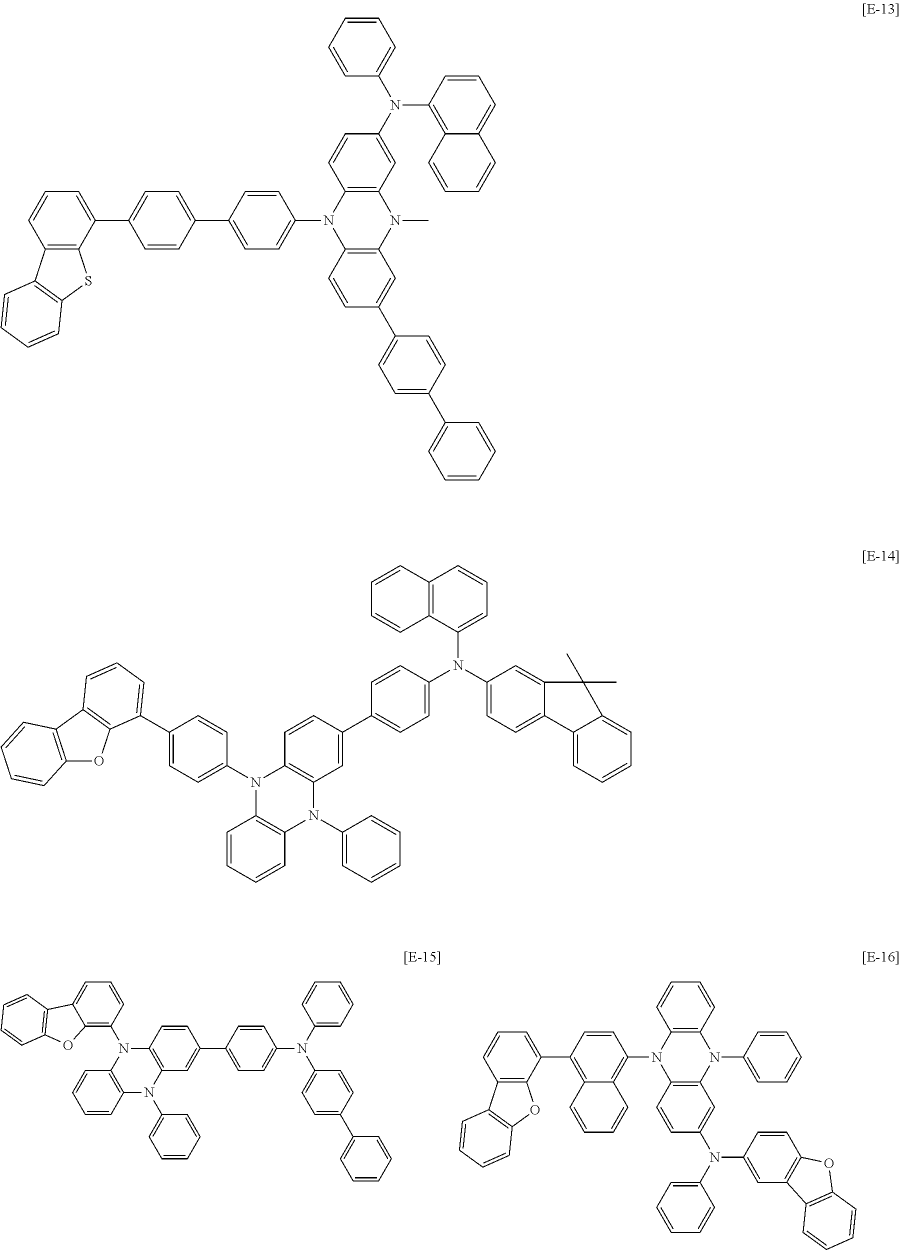 [SMILES: CN1c2cc(-c3ccc(-c4ccccc4)cc3)ccc2N(c2ccc(-c3ccc(-c4cccc5c4sc4ccccc45)cc3)cc2)c2ccc(N(c3ccccc3)c3cccc4ccccc34)cc21 ; CC1(C)c2ccccc2-c2ccc(N(c3ccc(-c4ccc5c(c4)N(c4ccccc4)c4ccccc4N5c4ccc(-c5cccc6c5oc5ccccc56)cc4)cc3)c3cccc4ccccc34)cc21 ; c1ccc(-c2ccc(N(c3ccccc3)c3ccc(-c4ccc5c(c4)N(c4ccccc4)c4ccccc4N5c4cccc5c4oc4ccccc45)cc3)cc2)cc1 ; c1ccc(N(c2ccc3c(c2)N(c2ccccc2)c2ccccc2N3c2ccc(-c3cccc4c3oc3ccccc34)c3ccccc23)c2ccc3oc4ccccc4c3c2)cc1]

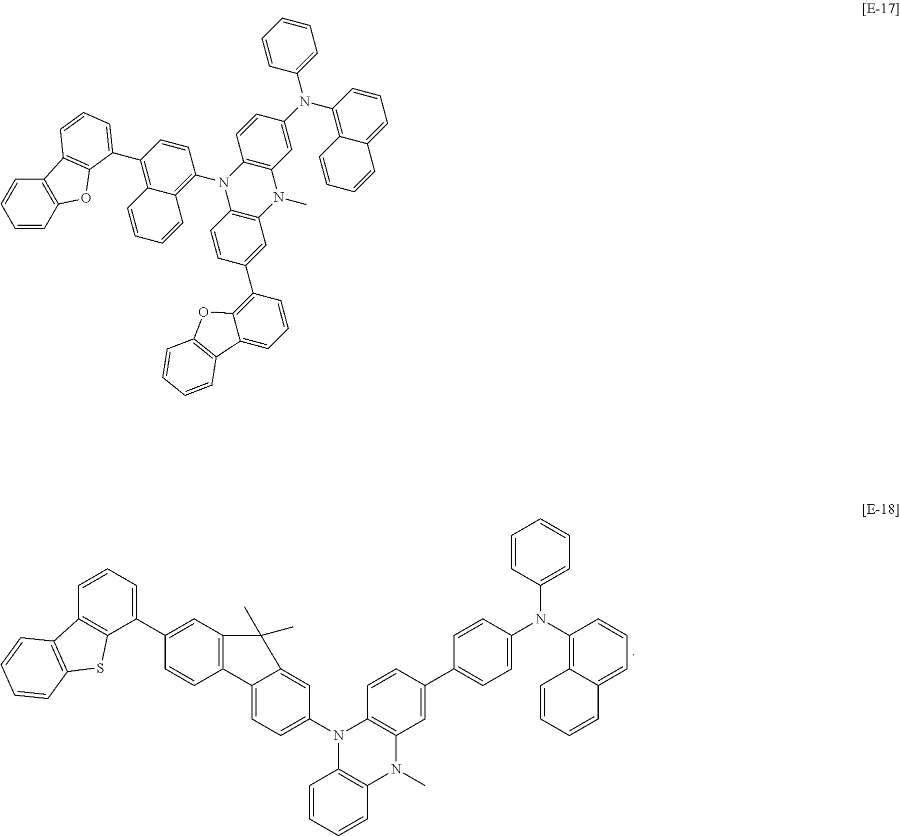 [SMILES: CN1c2cc(-c3cccc4c3oc3ccccc34)ccc2N(c2ccc(-c3cccc4c3oc3ccccc34)c3ccccc23)c2ccc(N(c3ccccc3)c3cccc4ccccc34)cc21 ; CN1c2ccccc2N(c2ccc3c(c2)C(C)(C)c2cc(-c4cccc5c4sc4ccccc45)ccc2-3)c2ccc(-c3ccc(N(c4ccccc4)c4cccc5ccccc45)cc3)cc21]

12. The compound for an organic optoelectronic device as claimed in claim 1, wherein the organic optoelectronic device is selected from an organic photoelectric device, an organic light emitting diode, an organic solar cell, an organic transistor, an organic photo-conductor drum, and an organic memory device.

13. An organic light emitting diode, comprising:
an anode, a cathode, and one or more organic thin layers between the anode and the cathode,
wherein at least one of the organic thin layers includes the compound for an organic optoelectronic device as claimed in claim 1.

14. The organic light emitting diode as claimed in claim 13, wherein the organic thin layer is selected from an emission layer, a hole transport layer (HTL), a hole injection layer (HIL), an electron transport layer (ETL), an electron injection layer (EIL), a hole blocking layer, and a combination thereof.

15. The organic light emitting diode as claimed in claim 13, wherein the compound for an organic optoelectronic device is included in a hole transport layer (HTL) or a hole injection layer (HIL).

16. The organic light emitting diode as claimed in claim 13, wherein the compound for an organic optoelectronic device is included in an emission layer.

17. The organic light emitting diode as claimed in claim 13, wherein the compound for an organic optoelectronic device is used as a phosphorescent or fluorescent host material in an emission layer.

18. The organic light emitting diode as claimed in claim 13, wherein the compound for an organic optoelectronic device is used as a fluorescent blue dopant material in an emission layer.

19. A display device comprising the organic light emitting diode as claimed in claim 13.
